(19) United States
(12) Patent Application Publication
(10) Pub. No.: US 2024/0237461 A1
(43) Pub. Date: Jul. 11, 2024

(54) OPTO-ELECTRONIC DEVICE INCLUDING EM RADIATION TRANSMISSIVE REGIONS BETWEEN EMISSIVE REGIONS

(71) Applicant: OTI Lumionics Inc., Mississauga (CA)

(72) Inventor: Zhibin WANG, Mississauga (CA)

(73) Assignee: OTI Lumionics Inc., Mississauga, ON (CA)

(21) Appl. No.: 18/556,861

(22) PCT Filed: Apr. 27, 2022
(86) PCT No.: PCT/IB22/53926

§ 371 Date: Oct. 23, 2023

Related U.S. Application Data
(60) Provisional application No. 63/180,612, filed on Apr. 27, 2021.
(60) Provisional application No. 63/183,512, filed on May 3, 2021.
(60) Provisional application No. 63/194,110, filed on May 27, 2021.
(60) Provisional application No. 63/239,782, filed on Sep. 1, 2021.

(51) Int. Cl. H10K 59/35

(52) U.S. Cl. CPC H10K 59/353; H10K 59/352

(57) ABSTRACT

A display panel comprises at least one display part comprising a display part (sub-) pixel arrangement comprising a plurality of emissive regions each corresponding to a (sub-) pixel, and at least one signal-exchanging part comprising a signal-exchanging part (sub-) pixel arrangement comprising at least one transmissive region and a plurality of emissive regions each corresponding to a (sub-) pixel, wherein the signal-exchanging part (sub-) pixel arrangement accommodates the at least one transmissive region by varying from the display part (sub-) pixel arrangement in at least one feature selected from: at least one of a size, shape, configuration, and orientation of at least one (sub-) pixel therein; a pixel density; and a pitch of the (sub-) pixels therein.

### RELATED APPLICATIONS

The present disclosure is a National Stage Entry under 35 U.S.C. § 371 of International Application No. PCT/IB2022/053926, filed Apr. 27, 2022, which claims the benefit of priority to: US Provisional Patent Application Nos. 63/180,612 filed Apr. 27, 2021, 63/183,512 filed May 3, 2021, 63/194,110 filed May 27, 2021, and 63/239,782 filed Sep. 1, 2021, the contents of each of which are incorporated herein by reference in their entirety.

### TECHNICAL FIELD

The present disclosure relates to opto-electronic devices and in particular to an opto-electronic device having EM radiation transmissive regions.

### BACKGROUND

In an opto-electronic device such as an organic light emitting diode (OLED), at least one semiconducting layer is disposed between a pair of electrodes, such as an anode and a cathode. The anode and cathode are electrically coupled with a power source and respectively generate holes and electrons that migrate toward each other through the at least one semiconducting layer. When a pair of holes and electrons combine, EM radiation, in the form of a photon, may be emitted.

OLED display panels may comprise a plurality of (sub-) pixels, each of which has an associated pair of electrodes and at least one semiconducting layer between them. In some non-limiting examples, the (sub-) pixels may be selectively driven by a driving circuit comprising a plurality of thin-film transistor (TFT) structures electrically coupled by conductive metal lines, in some non-limiting examples, within a substrate upon which the electrodes and the at least one semiconducting layer are deposited. Various layers and coatings of such panels are typically formed by vacuum-based deposition processes.

Such display panels may be used, in some non-limiting examples, in electronic devices such as mobile phones.

In some applications, there may be an aim to make at least a part of the display panel substantially transparent therethrough, while still capable of emitting light therefrom. In some non-limiting examples, the part that is substantially transparent may be capable of exchanging EM radiation, including without limitation, EM signals, therethrough. In some non-limiting examples, such part of the display panel may be denoted as a signal-exchanging part thereof. In some non-limiting examples, the signal-exchanging part of the display panel may comprise at least one (EM signal) transmissive region and at least one (EM signal) emissive region. In some non-limiting examples, the at least one emissive region may correspond to a (sub-) pixel of the display panel.

U.S. Pat. No. 11,145,702 filed 26 Mar. 2020 by Google LLC, issued 12 Oct. 2021 and entitled “Boundary panel layout for artifact compensation in multi-pixel density display panel” discloses a display panel that includes a plurality of array sites arranged in an array defined by a plurality of rows and a plurality of columns. The display panel includes a first area of the array having a first pixel density and a second area of the array having a second pixel density lower than the first pixel density. The second area of the array includes a plurality of the array sites that are devoid of pixels. Rows of the second area that border the first area include at least one pixel and columns of the second area that border the first area include at least one pixel.

PCT International Patent Application Publication No. WO 2020/219267 filed 8 Apr. 2020 by Apple Inc. and entitled “Methods and configurations for improving the performance of sensors under a display” discloses an electronic device that may include a display and a sensor under the display. The display may include an array of subpixels for displaying an image to a user of the electronic device. At least a portion of the array of subpixels may be selectively removed in a pixel removal region to improve optical transmittance to the sensor through the display. The pixel removal region may include a plurality of pixel free regions that are devoid of thin-film transistor structures, that are devoid of power supply lines, that have continuous open areas due to rerouted row/column lines, that are partially devoid of touch circuitry, that optionally include dummy contacts, and/or have selectively patterned display layers.

Chinese Patent Application No. 113745271 filed 29 May 2020 by Huawei Technologies Co. Ltd. and entitled “Display panel and display device” discloses a display panel and a display device, comprising a first display area and a second display area, wherein the pixel density of the first display area is less than that of the second display area; the first display area comprises a plurality of first pixel units, each first pixel unit comprises a first sub-pixel, a second sub-pixel and a third sub-pixel, and the minimum distance between the first sub-pixel in each first pixel unit and the second sub-pixel in the adjacent first pixel unit is 1.2-2.5 times of the distance between the first sub-pixel and the second sub-pixel in one first pixel unit. The embodiment of the application provides a display panel and a display device, which can reduce the diffraction phenomenon after light penetrates through the display panel and improve the optical effect of an optical element under a screen.

Chinese Patent Application Nos. 112436029 filed 1 Jul. 2020 by Kunshan Govisionox Optoelectronics Co. Ltd. and entitled “Pixel arrangement structure, display panel and display device” discloses a pixel arrangement structure, in a first pixel unit, taking the respective centers of a first sub-pixel, a second sub-pixel, a third sub-pixel and a fourth sub-pixel as vertexes to form a common-side triangle with non-overlapping areas; and the center of the first sub-pixel and the center of the second sub-pixel are taken as the vertex of the common side triangle; the second sub-pixel has a second long axis and a second short axis, and a center line of the second sub-pixel along the long axis direction does not pass through the center of the third sub-pixel and/or the fourth sub-pixel in the first pixel unit. According to the pixel arrangement structure, when the sub-pixels are staggered and arranged under the limiting conditions, the sub-pixels emitting the same color light are prevented from being independently arranged in a line, and the color edge problem of the display edge is improved. A display panel and a display device are also provided.

Chinese Patent Application No. 112436030 filed 1 Jul. 2020 by Kunshan Govisionox Optoelectronics Co. Ltd. and entitled “Pixel arrangement structure, display panel and display device” discloses a pixel arrangement structure, which comprises a plurality of first pixel units and a plurality of second pixel units, wherein the first pixel units and the second pixel units are arranged at intervals in a first direction and a second direction; each of the first pixel unit and the second pixel unit comprises a first sub-pixel, a second sub-pixel, a third sub-pixel and a fourth sub-pixel; the first sub-pixel is positioned on one side of a central connecting line of the third sub-pixel and the fourth sub-pixel, and the second sub-pixel is positioned on the other side of the central connecting line of the third sub-pixel and the fourth sub-pixel; after rotating a preset angle, each sub-pixel structure in the second pixel unit is in mirror symmetry with each sub-pixel structure in the first pixel unit. The pixel arrangement structure can give consideration to the arrangement compactness of the sub-pixels and the space between the sub-pixels, a balance is sought between the arrangement compactness and the space between the sub-pixels, and the pixel arrangement structure has high resolution and is beneficial to reducing the color mixing risk and color cast, improving the color edge and improving the visual granular sensation. A display panel and a display device are also provided.

Chinese Patent Application No. 112436031 filed 1 Jul. 2020 by Kunshan Govisionox Optoelectronics Co. Ltd. and entitled “Pixel arrangement structure, display panel and display device” discloses a pixel arrangement structure, which comprises a first sub-pixel, a second sub-pixel, a third sub-pixel and a fourth sub-pixel; the centers of the two first sub-pixels arranged in an aligned mode and the centers of the two second sub-pixels arranged in an aligned mode are vertex connecting lines to form a virtual quadrangle, and the virtual quadrangle comprises two opposite sides, short sides and long sides, wherein the short sides and the long sides are arranged oppositely and are connected with the vertices of the two opposite sides; the short side of the virtual quadrangle is not parallel to the long side of the virtual quadrangle; and a third sub-pixel or a fourth sub-pixel is arranged in the virtual quadrangle, and the light emitting color of the third sub-pixel is the same as that of the fourth sub-pixel. In the pixel arrangement structure, the sub-pixels are staggered and arranged under the limiting conditions, so that the sub-pixels emitting the same color light are prevented from being independently arranged in a line, and the color edge problem of the display edge is improved. A display panel and a display device are also provided.

Chinese Patent Application No. 112436032 filed 1 Jul. 2020 by Kunshan Govisionox Optoelectronics Co. Ltd. and entitled “Display panel and display device” discloses a display panel, which comprises a plurality of sub-pixels and a plurality of light-transmitting reserved areas, wherein the plurality of sub-pixels comprise a plurality of first sub-pixels, a plurality of second sub-pixels and a plurality of third sub-pixels, and one second sub-pixel and one light-transmitting reserved area are adjacently arranged to form a combined area; the display panel comprises a plurality of first pixel rows and a plurality of second pixel rows, wherein the first pixel rows and the second pixel rows are alternately arranged at intervals; a plurality of first sub-pixels and a plurality of combination regions are arranged in each first pixel row, the first sub-pixels and the combination regions are alternately arranged in the first pixel row at intervals, and a plurality of third sub-pixels are arranged in each second pixel row; in two adjacent first pixel rows, the arrangement structure of the combined area in one first pixel row is different from that of the combined area in the other first pixel row, and the combined areas are identical after being rotated by 90 degrees. The display panel is beneficial to reducing the color mixing risk and color cast. A display device is also provided.

Chinese Patent Application No. 112054048 filed 17 Sep. 2020 by Hefei Visionox Technology Co. Ltd. and entitled “Light-transmitting display module, display panel and preparation method thereof” discloses a light-transmitting display module, a display panel and a preparation method thereof, wherein the light-transmitting display module comprises: the pixel definition layer comprises an isolation structure and a pixel opening formed by the isolation structure in a surrounding mode; the nucleation inhibition layer is positioned on one side of the pixel definition layer, which is far away from the substrate, and comprises a plurality of inhibition units, the first orthographic projection of the inhibition units on the pixel definition layer covers at least part of the isolation structure, and at least part of the inhibition units are discontinuously arranged; and the first common electrode is positioned on one side of the pixel defining layer, which is far away from the substrate, and the second orthographic projection of the first common electrode on the pixel defining layer covers at least part of the area except the first orthographic projection. In the light-transmitting display module provided by the embodiment of the invention, under the condition that the normal display of the light-transmitting display module is not influenced, the light transmittance of the light-transmitting display module can be improved, and the photosensitive component can be conveniently integrated under a screen at one side of the light-transmitting display module.

Chinese Patent Application No. 112103318 filed 17 Sep. 2020 by Hefei Visionox Technology Co. Ltd. and entitled “Display panel, preparation method display panel and display device” discloses a display panel, a preparation method of the display panel and a display device, wherein the display panel is provided with a first display area and a second display area, the light transmittance of the first display area is greater than that of the second display area, and the display panel comprises: a substrate; the pixel definition layer is positioned on the substrate and comprises an isolation structure and a pixel opening formed by the enclosure of the isolation structure; a nucleation suppression layer including a first suppression unit in a pixel opening of the first orthographic projection coverage transition display area on the pixel definition layer; and the common electrode comprises a first common electrode and a second common electrode, the second common electrode is formed in the second display area and the transition display area, and the second orthographic projection of the first common electrode on the pixel definition layer covers at least partial area except the first orthographic projection in the first display area and the transition display area. At least partial area of the display panel can be light-permeable and can display, and the photosensitive assembly is convenient to integrate under a screen.

U.S. Pat. No. 11,222,929 filed 16 Apr. 2021 by Xiamen Tianma Microelectronics Co. Ltd., issued 11 Jan. 2022 and entitled “Display panel and display device” discloses a display panel and a display device. The display panel includes a first display region, a second display region, and a transition display region between the first display region and the second display region. The second display region includes second pixel units, the transition display region includes third pixel units, and each second pixel unit and each third pixel unit both include a first sub-pixel, a second sub-pixel, a third sub-pixel, and a white sub-pixel. A ratio of a total opening area of white sub-pixels in the second pixel units to a total area of the second pixel units is A, and a ratio of a total opening area of white sub-pixels in the third pixel units to a total area of the third pixel units is B, where B<A. The white sub-pixel is turned on or off in a display stage of the display panel.

United States Patent Application Publication No. 2021/0240026 filed 23 Apr. 2021 by Apple Inc. and entitled “Pixel Design for Electronic Display Devices” discloses systems and methods for through-display imaging. A display includes an imaging aperture defined through an opaque backing. An optical imaging array is aligned with the aperture. Above the aperture, the display is arranged and/or configured for increased optical transmittance. For example, a region of the display above, or adjacent to, the imaging aperture can be formed with a lower pixel density than other regions of the display, thereby increasing inter-pixel distance (e.g., pitch) and increasing an area through which light can traverse the display to reach the optical imaging array.

Chinese Patent Application No. CN 113327972, filed 1 Jul. 2021 by Wuhan Tianma Microelectronics Co. Ltd. and entitled “Display panel, preparation method and display device” discloses a display panel, a preparation method and a display device. The pixel structure comprises a plurality of first sub-pixels, second sub-pixels and third sub-pixels; the plurality of third sub-pixels form a first virtual trapezoid, and the first sub-pixels are in the first virtual trapezoid; the plurality of first sub-pixels and the plurality of second sub-pixels form a second virtual trapezoid, and the third sub-pixel is in the second virtual trapezoid; the first virtual trapezoid comprises a first long edge, a first oblique edge, a first short edge and a second oblique edge; the second virtual trapezoid comprises a second long edge, a third oblique edge, a second short edge and a fourth oblique edge; the first long edge and the first bevel edge form a first included angle, and the first long edge and the second bevel edge form a second included angle; the second long edge and the third oblique edge form a third included angle, and the second long edge and the fourth oblique edge form a fourth included angle; the sum of the angles of the first included angle and the second included angle is a first angle, the sum of the angles of the third included angle and the fourth included angle is a second angle, and the difference value of the first angle and the second angle is within a first preset range.

Chinese Patent Application No. 113327973, filed 1 Jul. 2021 by Wuhan Tianma Microelectronics Co. Ltd. and entitled “Display panel and display device” discloses a display panel and a display device, wherein the display panel comprises a plurality of pixel repeating units which are arranged in an array mode, and each pixel repeating unit comprises two first sub-pixels, two second sub-pixels and four third sub-pixels; in the display panel, one first sub-pixel is positioned among four third sub-pixels; there is one second sub-pixel located between four third sub-pixels; a third sub-pixel is simultaneously positioned between the two first sub-pixels and the two second sub-pixels; and the centers of four third sub-pixels surrounding the first sub-pixel form a first trapezoid, wherein the lengths of two groups of opposite sides of the first trapezoid are different. The technical scheme of the embodiment of the application can improve the display effect of the display panel.

PCT International Patent Application Publication No. WO 2022/035527 filed 7 Jul. 2021 by Apple Inc. and entitled “Displays having transparent openings” discloses an electronic device that may include a display and an optical sensor formed underneath the display. The electronic device may include a plurality of transparent windows that overlap the optical sensor. The resolution of the display panel may be reduced in some areas due to the presence of the transparent windows. To mitigate diffraction artifacts, a first sensor (13-1) may sense light through a first pixel removal region having transparent windows arranged according to a first pattern. A second sensor (13-2) may sense light through a second pixel removal region having transparent windows arranged according to a second pattern that is different than the first pattern. The first and second patterns of the transparent windows may result in the first and second sensors having different diffraction artifacts. Therefore, an image from the first sensor may be corrected for diffraction artifacts based on an image from the second sensor.

United States Patent Application Publication No. 2022/0102446 filed 9 Dec. 2021 by Samsung Display Co. Ltd. discloses a display device that includes a display region which includes a first display region and a second display region, where the first display region includes a plurality of first pixels, and the second display region includes a plurality of second pixels and at least one light transmission region, where the light transmission region has light transmittance that is higher than light transmittance of the first pixel and light transmittance of the second pixel, and the second display region has light transmittance that is higher than light transmittance of the first display region.

In some non-limiting examples, the at least one transmissive region(s) may be interspersed among the at least one emissive region(s). Since emissive regions generally comprise layers, coatings, and/or components that may attenuate or inhibit transmission of EM radiation through such regions, in some non-limiting examples, the transmissive regions may generally be provided in non-emissive regions of the display panel that may be substantially devoid of such layers, coatings, and/or components.

In some non-limiting examples, there may be an aim to provide at least one transmissive region in at least a part of the display panel, while also providing at least one emissive region in such part of the display panel, to maintain at least one of an aperture ratio of the at least one emissive region and a relatively high pixel density, in some non-limiting examples, relative to a part of the display panel that is substantially devoid of such at least one transmissive region(s).

### BRIEF DESCRIPTION OF THE DRAWINGS

Examples of the present disclosure will now be described by reference to the following figures, in which identical reference numerals in different figures indicate identical and/or in some non-limiting examples, analogous and/or corresponding elements and in which:

FIG. 1 is a simplified block diagram from a cross-sectional aspect, of an example device having a plurality of layers in a lateral aspect, formed by selective deposition of a patterning coating in a first portion of the lateral aspect, followed by deposition of a closed coating of deposited material in a second portion thereof, according to an example in the present disclosure;

FIG. 2A is a schematic diagram illustrating an example cross-sectional view of an example display panel having a plurality of layers, comprising at least one aperture therewithin, through which at least one electromagnetic (EM) signal may be exchanged according to an example in the present disclosure;

FIGS. 2B-2D are schematic diagrams showing, in plan, a display panel comprising a signal-exchanging part and a display part according to an example in the present disclosure;

FIGS. 3A-3B are schematic diagrams showing, in plan, respective example (sub-) pixel arrangements according to examples in the present disclosure;

FIG. 3C is a schematic diagram showing, in plan, at least a fragment of a signal-exchanging region populated by the example (sub-) pixel arrangement of FIG. 3A;

FIGS. 3D-3H are schematic diagrams showing, in plan, respective example (sub-) pixel arrangements according to examples in the present disclosure;

FIG. 3I is a schematic diagram showing, in plan, at least a fragment of a signal-exchanging region populated by the example (sub-) pixel arrangement of FIG. 3G;

FIG. 3J is a schematic diagram showing, in plan, an example (sub-) pixel arrangement according to an example in the present disclosure;

FIG. 3K is a schematic diagram showing, in plan, at least a fragment of a signal-exchanging part populated by alternating example (sub-) pixel arrangement of FIG. 3E and FIG. 3F;

FIGS. 3L-3S are schematic diagrams showing, in plan, respective example (sub-) pixel arrangements according to examples in the present disclosure;

FIGS. 3L-3S are schematic diagrams showing, in plan, respective example (sub-) pixel arrangements according to examples in the present disclosure;

FIGS. 4A-4D are schematic diagrams showing, in plan, respective example fragments of (sub-) pixel arrangements in both a signal-exchanging part and a display part, according to examples in the present disclosure;

FIGS. 5A-5B are schematic diagrams showing, in plan, respective example fragments of (sub-) pixel arrangement in each of a signal-exchanging part, a transition region, and a display part, according to examples in the present disclosure;

FIG. 6 is a schematic diagram showing an example process for depositing a patterning coating in a pattern on an exposed layer surface of an underlying layer in an example version of the device of FIG. 1, according to an example in the present disclosure;

FIG. 7 is a schematic diagram showing an example process for depositing a deposited material in the second portion on an exposed layer surface that comprises the deposited pattern of the patterning coating of FIG. 6, where the patterning coating is a nucleation-inhibiting coating (NIC);

FIG. 8A is a schematic diagram illustrating an example version of the device of FIG. 1 in a cross-sectional view;

FIG. 8B is a schematic diagram illustrating the device of FIG. 8A in a complementary plan view;

FIG. 8C is a schematic diagram illustrating an example version of the device of FIG. 1 in a cross-sectional view;

FIG. 8D is a schematic diagram illustrating the device of FIG. 8C in a complementary plan view;

FIG. 8E is a schematic diagram illustrating an example of the device of FIG. 1 in a cross-sectional view;

FIG. 8F is a schematic diagram illustrating an example of the device of FIG. 1 in a cross-sectional view;

FIG. 8G is a schematic diagram illustrating an example of the device of FIG. 1 in a cross-sectional view;

FIGS. 9A-9I are schematic diagrams that show various potential behaviours of an NIC at a deposition interface with a deposited layer in an example version of the device of FIG. 1, according to various examples in the present disclosure;

FIG. 10 is a block diagram from a cross-sectional aspect, of an example electro-luminescent device according to an example in the present disclosure;

FIG. 11 is a cross-sectional view of the device of FIG. 1;

FIG. 12 is a schematic diagram illustrating, in plan, an example patterned electrode suitable for use in a version of the device of FIG. 11, according to an example in the present disclosure;

FIG. 13 is a schematic diagram illustrating an example cross-sectional view of the device of FIG. 12 taken along line 13-13;

FIG. 14A is a schematic diagram illustrating, in plan view, a plurality of example patterns of electrodes suitable for use in an example version of the device of FIG. 11, according to an example in the present disclosure;

FIG. 14B is a schematic diagram illustrating an example cross-sectional view, at an intermediate stage, of the device of FIG. 14A taken along line 14B-14B;

FIG. 14C is a schematic diagram illustrating an example cross-sectional view of the device of FIG. 14A taken along line 14C-14C;

FIG. 15 is a schematic diagram illustrating a cross-sectional view of an example version of the device of FIG. 11, having an example patterned auxiliary electrode according to an example in the present disclosure;

FIG. 16 is a schematic diagram illustrating, in plan view an example pattern of an auxiliary electrode overlaying at least one emissive region and at least one non-emissive region according to an example in the present disclosure;

FIG. 17A is a schematic diagram illustrating, in plan view, an example pattern of an example version of the device of FIG. 11, having a plurality of groups of emissive regions in a diamond configuration according to an example in the present disclosure;

FIG. 17B is a schematic diagram illustrating an example cross-sectional view of the device of FIG. 17A taken along line 17B-17B;

FIG. 17C is a schematic diagram illustrating an example cross-sectional view of the device of FIG. 17A taken along line 17C-17C;

FIG. 18 is a schematic diagram illustrating an example cross-sectional view of an example version of the device of FIG. 11 with additional example deposition steps according to an example in the present disclosure;

FIG. 19 is a schematic diagram illustrating an example cross-sectional view of an example version of the device of FIG. 11 with additional example deposition steps according to an example in the present disclosure;

FIG. 20 is a schematic diagram illustrating an example cross-sectional view of an example version of the device of FIG. 11 with additional example deposition steps according to an example in the present disclosure;

FIG. 21 is a schematic diagram illustrating an example cross-sectional view of an example version of the device of FIG. 11 with additional example deposition steps according to an example in the present disclosure;

FIG. 22A is a schematic diagram illustrating, in plan view, an example of a transparent version of the device of FIG. 11 comprising at least one example pixel region and at least one example light-transmissive region, with at least one auxiliary electrode according to an example in the present disclosure;

FIG. 22B is a schematic diagram illustrating an example cross-sectional view of the device of FIG. 22A taken along line 22B-22B;

FIG. 23A is a schematic diagram illustrating, in plan view, an example of a transparent version of the device of FIG. 11 comprising at least one example pixel region and at least one example light-transmissive region according to an example in the present disclosure;

FIG. 23B is a schematic diagram illustrating an example cross-sectional view of the device of FIG. 23A taken along line 23-23;

FIG. 23C is a schematic diagram illustrating an example cross-sectional view of the device of FIG. 23A taken along line 23-23;

FIG. 24 is a schematic diagram that may show example stages of an example process for manufacturing an example version of the device of FIG. 11 having sub-pixel regions having a second electrode of different thickness according to an example in the present disclosure;

FIG. 25 is a schematic diagram illustrating an example cross-sectional view of an example version of the device of FIG. 14 in which a second electrode is coupled with an auxiliary electrode according to an example in the present disclosure;

FIG. 26 is a schematic diagram illustrating an example cross-sectional view of an example version of the device of FIG. 14 having a partition and a sheltered region, such as a recess, in a non-emissive region thereof according to an example in the present disclosure;

FIGS. 27A-27B are schematic diagrams that show example cross-sectional views of an example version of the device of FIG. 14 having a partition and a sheltered region, such as an aperture, in a non-emissive region, according to various examples in the present disclosure;

FIGS. 28A-28C are schematic diagrams that show example stages of an example process for depositing a deposited layer in a pattern on an exposed layer surface of an example version of the device of FIG. 14, by selective deposition and subsequent removal process, according to an example in the present disclosure;

FIG. 29 is an example energy profile illustrating relative energy states of an adatom absorbed onto a surface according to an example in the present disclosure; and

FIG. 30 is a schematic diagram illustrating the formation of a film nucleus according to an example in the present disclosure.

In the present disclosure, a reference numeral having at least one numeric value (including without limitation, in subscript) and/or lower-case alphabetic character(s) (including without limitation, in lower-case) appended thereto, may be considered to refer to a particular instance, and/or subset thereof, of the element or feature described by the reference numeral. Reference to the reference numeral without reference to the appended value(s) and/or character(s) may, as the context dictates, refer generally to the element(s) or feature(s) described by the reference numeral, and/or to the set of all instances described thereby. Similarly, a reference numeral may have the letter “x’ in the place of a numeric digit. Reference to such reference numeral may, as the context dictates, refer generally to the element(s) or feature(s) described by the reference numeral, where the character “x” is replaced by a numeric digit, and/or to the set of all instances described thereby.

In the present disclosure, for purposes of explanation and not limitation, specific details are set forth to provide a thorough understanding of the present disclosure, including, without limitation, particular architectures, interfaces and/or techniques. In some instances, detailed descriptions of well-known systems, technologies, components, devices, circuits, methods, and applications are omitted to not obscure the description of the present disclosure with unnecessary detail.

Further, it will be appreciated that block diagrams reproduced herein can represent conceptual views of illustrative components embodying the principles of the technology.

Accordingly, the system and method components have been represented where appropriate by conventional symbols in the drawings, showing only those specific details that are pertinent to understanding the examples of the present disclosure, to not obscure the disclosure with details that will be readily apparent to those of ordinary skill in the art having the benefit of the description herein.

Any drawings provided herein may not be drawn to scale and may not be considered to limit the present disclosure in any way.

Any feature or action shown in dashed outline may in some examples be considered as optional.

### SUMMARY

It is an object of the present disclosure to obviate or mitigate at least one disadvantage of the prior art.

The present disclosure discloses a display panel comprising at least one display part comprising a display part (sub-) pixel arrangement comprising a plurality of emissive regions each corresponding to a (sub-) pixel, and at least one signal-exchanging part comprising a signal-exchanging part (sub-) pixel arrangement comprising at least one transmissive region and a plurality of emissive regions each corresponding to a (sub-) pixel. The signal-exchanging part (sub-) pixel arrangement accommodates the at least one transmissive region by varying from the display part (sub-) pixel arrangement in at least one feature selected from: at least one of a size, shape, configuration, and orientation of at least one (sub-) pixel therein; a pixel density; and a pitch of the (sub-) pixels therein.

According to a broad aspect, there is disclosed a display panel comprising at least one display part comprising a display part (sub-) pixel arrangement comprising a plurality of emissive regions each corresponding to a (sub-) pixel, and at least one signal-exchanging part comprising a signal-exchanging part (sub-) pixel arrangement comprising at least one transmissive region and a plurality of emissive regions each corresponding to a (sub-) pixel, wherein the signal-exchanging part (sub-) pixel arrangement accommodates the at least one transmissive region by varying from the display part (sub-) pixel arrangement in at least one feature selected from: at least one of a size, shape, configuration, and orientation of at least one (sub-) pixel therein; a pixel density; and a pitch of the (sub-) pixels therein.

In some non-limiting examples, the at least one signal-exchanging part may be positioned proximate to an extremity of the display panel.

In some non-limiting examples, the at least one display part may substantially surround the at least one signal-exchanging part.

In some non-limiting examples, a separation between a boundary of the at least one transmissive region and a boundary of a sub-pixel proximate thereto may be one of at least about: 5 microns, 6 microns, 8 microns, 10 microns, 11 microns, and 12 microns.

In some non-limiting examples, a separation between a boundary of the at least one transmissive region and a boundary of a sub-pixel proximate thereto in the signal-exchanging part may be one of between about: 5-15 microns, 6-12 microns, and 8-10 microns.

In some non-limiting examples, a size of each transmissive region may be at least 10 microns.

In some non-limiting examples, a size of each transmissive region may be one of between about: 10-150 microns, 10-130 microns, 15-120 microns, 15-100 microns, 20-80 microns, 20-65 microns, 25-60 microns, and 30-50 microns.

In some non-limiting examples, a total combined aperture ratio of all of the emissive regions and transmissive regions in the signal-exchanging part may be one of no more than about: 60%, 55%, 50%, 45%, and 40%.

In some non-limiting examples, a total combined aperture ratio of all of the emissive regions and transmissive regions in the signal-exchanging part may be one of between about: 30-60%, 35-60%, 40-60%, 35-55%, 40-50%, 45-55%, and 45-50%.

In some non-limiting examples, the at least one transmissive region may have a boundary defined by a plurality of transmissive boundary segments.

In some non-limiting examples, the transmissive boundary segments may comprise at least one curved segment.

In some non-limiting examples, a majority of the transmissive boundary segments may be substantially parallel to a part of a boundary of an emissive region corresponding to a (sub-) pixel proximate thereto.

In some non-limiting examples, the at least one transmissive region may be substantially devoid of a cathode material.

In some non-limiting examples, the cathode material may be substantially precluded from nucleating within the at least one transmissive region by depositing a patterning coating within the at least one transmissive region prior to deposition of the cathode material.

In some non-limiting examples, the cathode material may be removed from the at least one transmissive region by laser ablation thereof.

In some non-limiting examples, the at least one feature may be at least one of a size, shape, configuration, and the signal-exchanging part (sub-) pixel arrangement and the display part (sub-) pixel arrangement may have in common, a pixel density of the at least one (sub-) pixels therein.

In some non-limiting examples, the signal-exchanging part (sub-) pixel arrangement and the display part (sub-) pixel arrangement may have in common, a pitch of the at least one (sub-) pixels therein.

In some non-limiting examples, a size of at least one of the (sub-) pixels in the signal-exchanging part (sub-) pixel arrangement may be less than a size of corresponding (sub-) pixels in the display part (sub-) pixel arrangement.

In some non-limiting examples, a size of each of the (sub-) pixels in the signal-exchanging part (sub-) pixel arrangement may be less than a size of corresponding (sub-) pixels in the display part (sub-) pixel arrangement.

In some non-limiting examples, the sub-pixels of the pixel of the signal-exchanging part (sub-) pixel arrangement may be spaced-apart laterally in at least two dimensions.

In some non-limiting examples, the signal-exchanging part (sub-) pixel arrangement may comprise a plurality of pixels each comprising a first sub-pixel, a second sub-pixel, and a third sub-pixel.

In some non-limiting examples, the pixels of the signal-exchanging part (sub-) pixel arrangement further may comprise a second second sub-pixel.

In some non-limiting examples, a region defined by a plurality of non-overlapping vectors each having endpoints located within the emissive region associated with a pair of the sub-pixels of the pixel of the signal-exchanging part (sub-) pixel arrangement may define an outline associated with the pixel.

In some non-limiting examples, each vector may be a linear vector.

In some non-limiting examples, each vector may have an endpoint located at a centroid of the emissive region of the sub-pixel.

In some non-limiting examples, the outline may comprise four vectors defining a box and a unit cell comprising four adjacent boxes each having a common vertex defines a smallest repeating unit of the signal-exchanging part (sub-) pixel arrangement.

In some non-limiting examples, at least one transmissive region may be disposed in at least one outline in the unit cell.

In some non-limiting examples, the at least one transmissive region may lie entirely within a single at least one outline.

In some non-limiting examples, an aperture ratio of the transmissive regions of the signal-exchanging part may be one of no more than about: 50%, 45%, 40%, 35%, 33%, and 25%.

In some non-limiting examples, an aperture of the transmissive regions of the signal-exchanging part may be one of at least about: 5%, 10%, and 15%.

In some non-limiting examples, an aperture ratio of all emissive regions of the signal-exchanging part may be one of no more than about: 20%, 15%, and 10%.

In some non-limiting examples, an aperture ratio of all emissive regions of the signal-exchanging part may be between about: 5-10% and an aperture ratio of all transmissive regions therein may be between about 30-50%.

In some non-limiting examples, an aperture ratio of all emissive regions of the signal-exchanging part may be between about: 6-9% and an aperture ratio of all transmissive regions therein may be between about 35-45%.

In some non-limiting examples, the at least one feature may be a pixel density, and the signal-exchanging part (sub-) pixel arrangement and the display part (sub-) pixel arrangement have in common, at least one of a size, shape, configuration, orientation, and pitch of at least one (sub-) pixel therein.

In some non-limiting examples, the signal-exchanging part (sub-) pixel arrangement and the display part (sub-) pixel arrangement may have in common, each of a size, shape, configuration, orientation, and pitch of at least one (sub-) pixel therein.

In some non-limiting examples, the signal-exchanging part (sub-) pixel arrangement and the display part (sub-) pixel arrangement may have in common, a pitch of the at least one (sub-) pixels therein.

In some non-limiting examples, a pixel density of the signal-exchanging part (sub-) pixel arrangement may be less than a pixel density of the display part (sub-) pixel arrangement.

In some non-limiting examples, at least one sub-pixel of at least one pixel corresponding to a sub-pixel of a pixel in the display part (sub-) pixel arrangement may be omitted in the signal-exchanging part (sub-) pixel arrangement.

In some non-limiting examples, every sub-pixel of at least one pixel corresponding to a sub-pixel of a pixel present in the display part (sub-) pixel arrangement may be omitted in the signal-exchanging part (sub-) pixel arrangement.

In some non-limiting examples, every sub-pixel of every other pixel corresponding to a sub-pixel of a pixel present in the display part (sub-) pixel arrangement may be omitted in the signal-exchanging part (sub-) pixel arrangement.

In some non-limiting examples, the omitted sub-pixels may be chosen to maximize a size of at least one void formed thereby.

In some non-limiting examples, a pixel density in the signal-exchanging part (sub-) pixel arrangement may be one of: 50%, 62.5%, and 75% of a pixel density in the display part (sub-) pixel arrangement.

In some non-limiting examples, at least one transmissive region may be disposed in at least one void formed by omitting at least one sub-pixel of at least one pixel in the signal-exchanging part (sub-) pixel arrangement.

In some non-limiting examples, an aperture ratio of the transmissive regions of the signal-exchanging part may be one of between about: 15-40%, 20-40%, 15-35%, and 20-35%.

In some non-limiting examples, an aperture of the transmissive regions of the signal-exchanging part may be one of at least about: 5%, 10%, and 15%.

In some non-limiting examples, an aperture ratio of all emissive regions of the signal-exchanging part may be between about: 12-25%.

In some non-limiting examples, an aperture ratio of all emissive regions of the signal-exchanging part may be between about: 12-25% and an aperture ratio of all transmissive regions therein may be between about 30-45%.

In some non-limiting examples, the at least one feature may be a pitch and a pitch of the (sub-) pixels in the signal-exchanging part (sub-) pixel arrangement may be less than a pitch of the (sub-) pixels in the display part (sub-) pixel arrangement.

In some nom-limiting examples, the at least one feature may comprise a plurality of the features.

In some nom-limiting examples, the display panel may further comprise at least one transition region disposed between the display part and the signal-exchanging part, comprising a transition region (sub-) pixel arrangement comprising a plurality of emissive regions each corresponding to a (sub-) pixel, wherein the transition region (sub-) pixel arrangement varies from both the display part (sub-) pixel arrangement and the signal-exchanging (sub-) pixel arrangement in the at least one feature, such that the interposition of the at least one transition region therebetween reduces a visually perceived difference therebetween.

In some nom-limiting examples, the at least one transition region may comprise at least one transmissive region.

In some nom-limiting examples, the at least one transition region may be arranged around a boundary of the signal-exchanging part.

In some nom-limiting examples, the at least one transition region may surround the at least one signal-exchanging part and the at least one display part may surround the at least one transition region.

In some nom-limiting examples, the at least one transition region may comprise a first transition region and a second transition region, wherein the first transition region is disposed between the display part and the second transition region, and the second transition region is disposed between the first transition region and the signal-exchanging part and the transition region (sub-) pixel arrangement of the second transition region varies from both the transition region (sub-) pixel arrangement of the first transition region and the signal-exchanging part (sub-) pixel arrangement in the at least one feature, such that the interposition of the second transition region therebetween reduces a visually perceived difference therebetween

### DESCRIPTION

### Layered Device

The present disclosure relates generally to layered semiconductor devices, and more specifically, to opto-electronic devices. An opto-electronic device may generally encompass any device that converts electrical signals into photons and vice versa. Non-limiting examples of opto-electronic devices include organic light-emitting diodes (OLEDs).

An organic opto-electronic device may encompass any opto-electronic device where one or more active layers and/or strata thereof are formed primarily of an organic (carbon-containing) material, and more specifically, an organic semiconductor material.

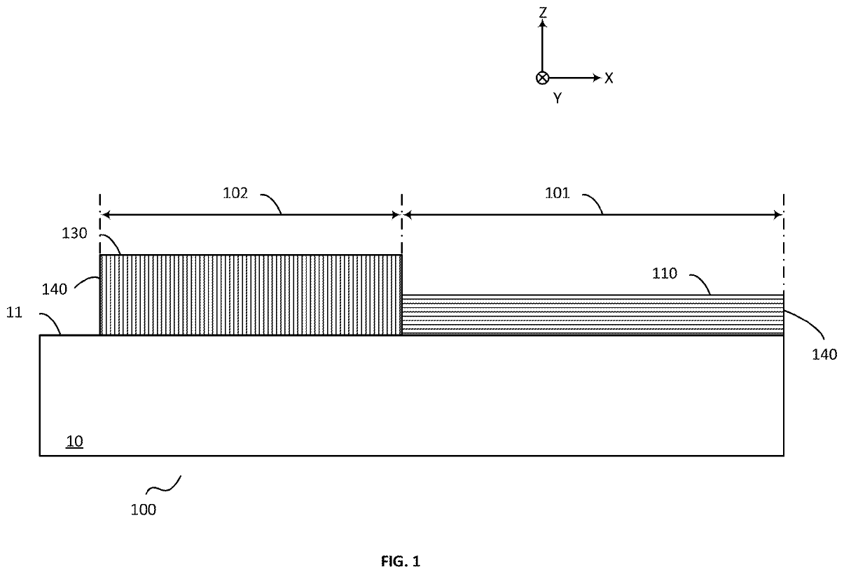

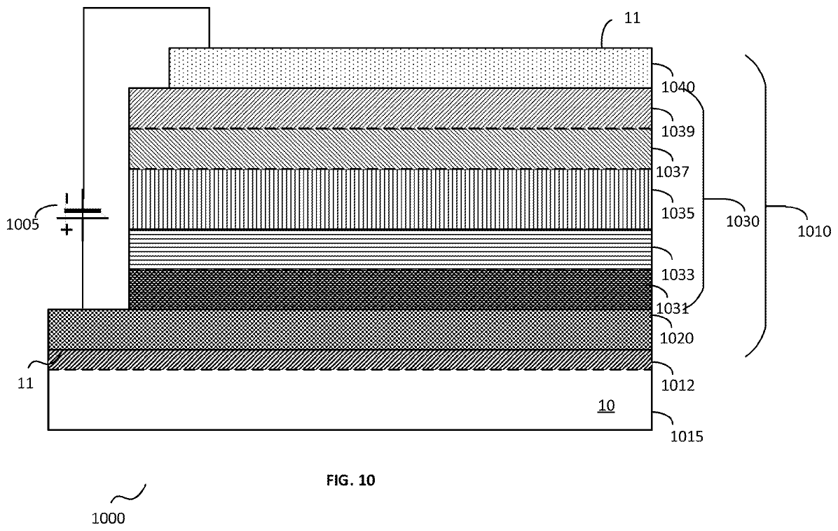

Turning now to FIG. 1, there may be shown a cross-sectional view of an example layered semiconductor device 100. In some non-limiting examples, as shown in greater detail in FIG. 10, the device 100 may comprise a plurality of layers deposited upon a substrate 10.

A lateral axis, identified as the X-axis, may be shown, together with a longitudinal axis, identified as the Z-axis. A second lateral axis, identified as the Y-axis, may be shown as being substantially transverse to both the X-axis and the Z-axis. At least one of the lateral axes may define a lateral aspect of the device 100. The longitudinal axis may define a longitudinal aspect of the device 100.

The layers of the device 100 may extend in the lateral aspect substantially parallel to a plane defined by the lateral axes. Those having ordinary skill in the relevant art will appreciate that the substantially planar representation shown in FIG. 1 may be, in some non-limiting examples, an abstraction for purposes of illustration. In some non-limiting examples, there may be, across a lateral extent of the device 100, localized substantially planar strata of different thicknesses and dimension, including, in some non-limiting examples, the substantially complete absence of a layer, and/or layer(s) separated by non-planar transition areas (including lateral gaps and even discontinuities).

Thus, while for illustrative purposes, the device 100 may be shown in its lateral aspect as a substantially stratified structure of substantially parallel planar layers, such device may illustrate locally, a diverse topography to define features, each of which may substantially exhibit the stratified profile discussed in the cross-sectional aspect.

In some non-limiting examples, a lateral aspect of an exposed layer surface 11 of the device 100 may comprise a first portion 101 and a second portion 102. In some non-limiting examples, the second portion 102 may comprise that part of the exposed layer surface 11 of the device 100 that lies beyond the first portion 101.

### Display Panel and User Device

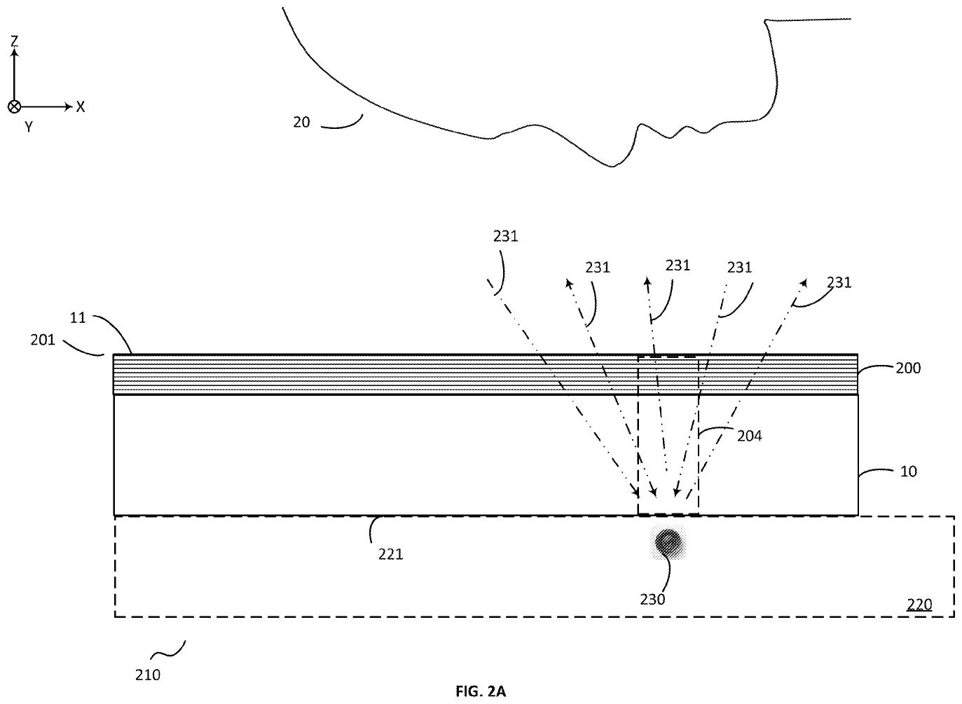

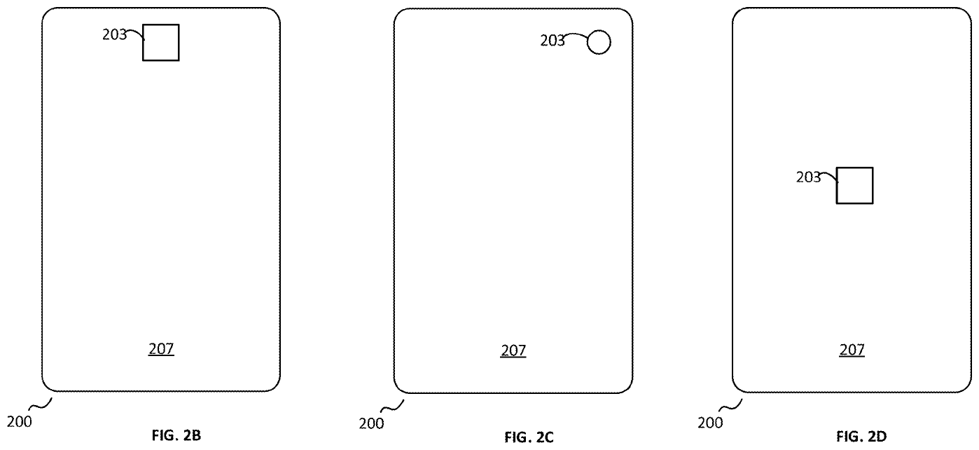

Turning now to FIG. 2A, there is shown a cross-sectional view of an example layered device, such as a display panel 200. In some non-limiting examples, the display panel 200 may comprise a plurality of layers deposited on a substrate 10, culminating with an outermost layer that forms a face 201 thereof. In some non-limiting examples, the display panel 200 may be a version of the device 100.

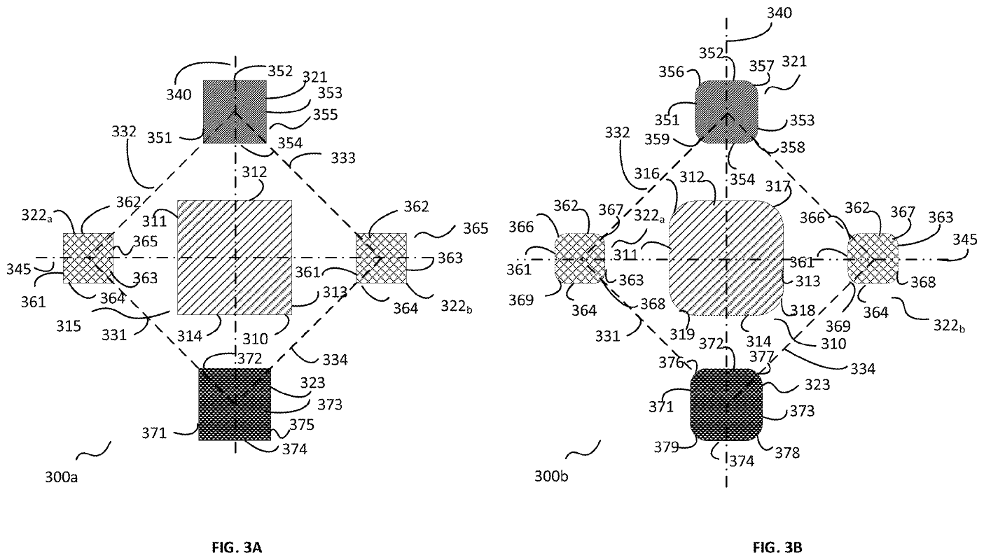

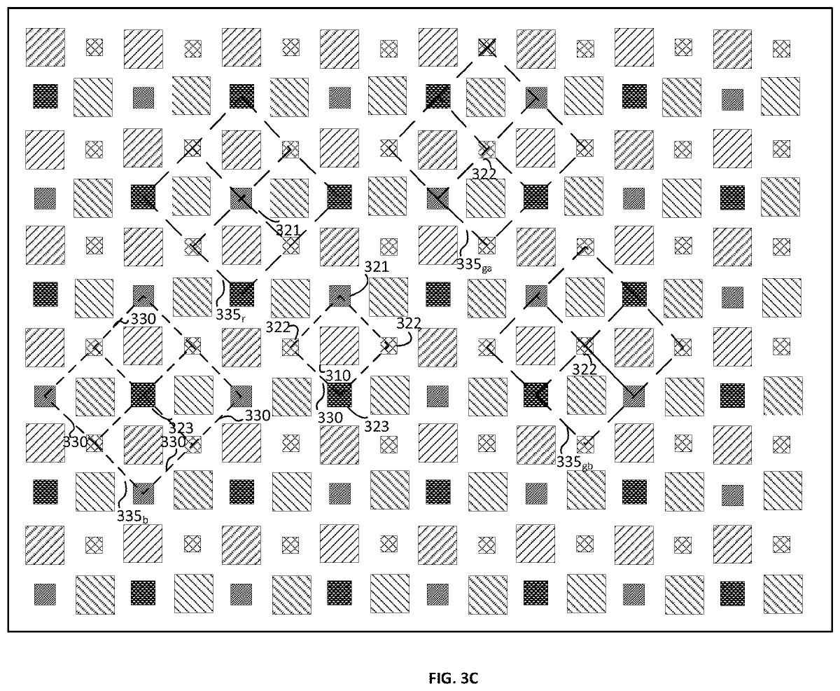

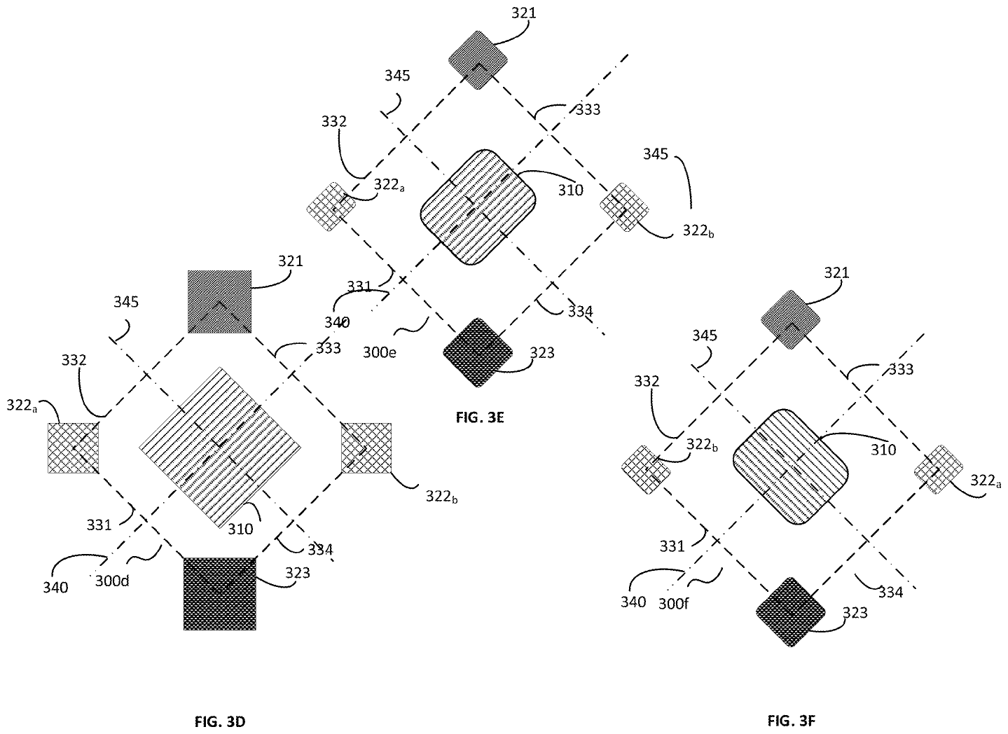

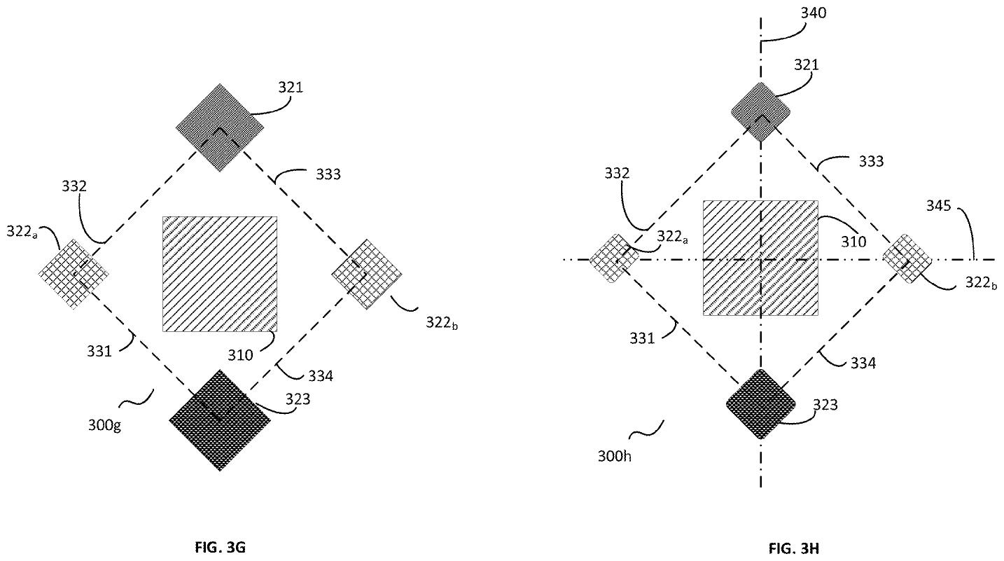

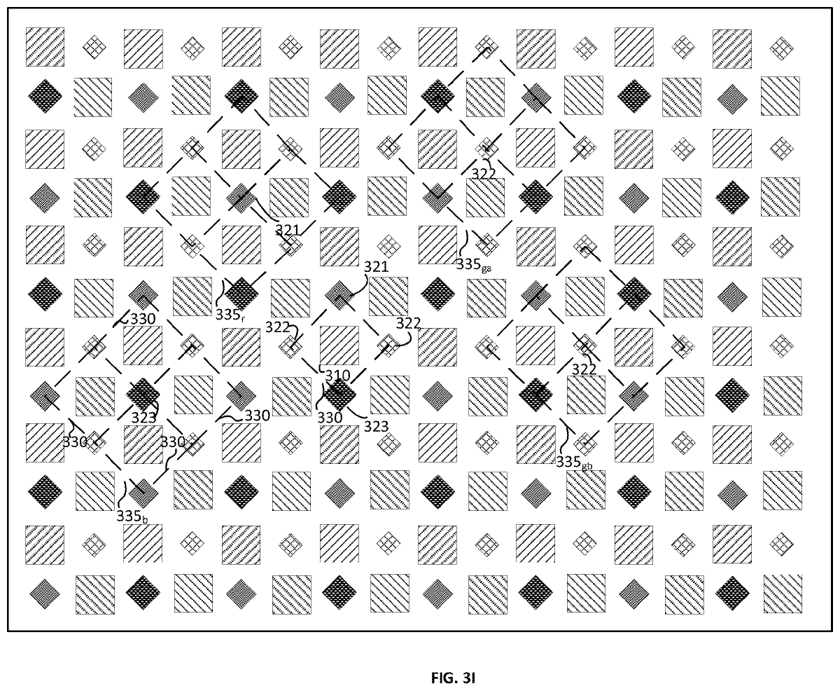

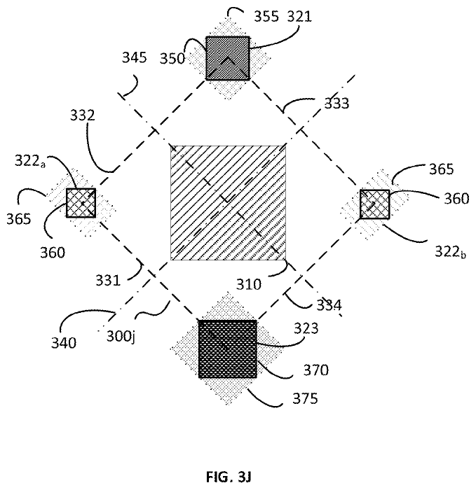

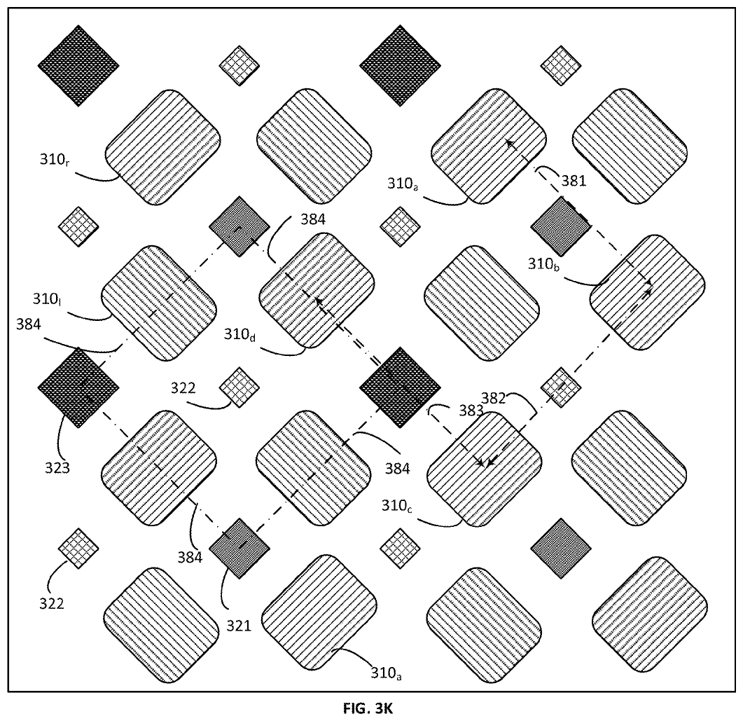

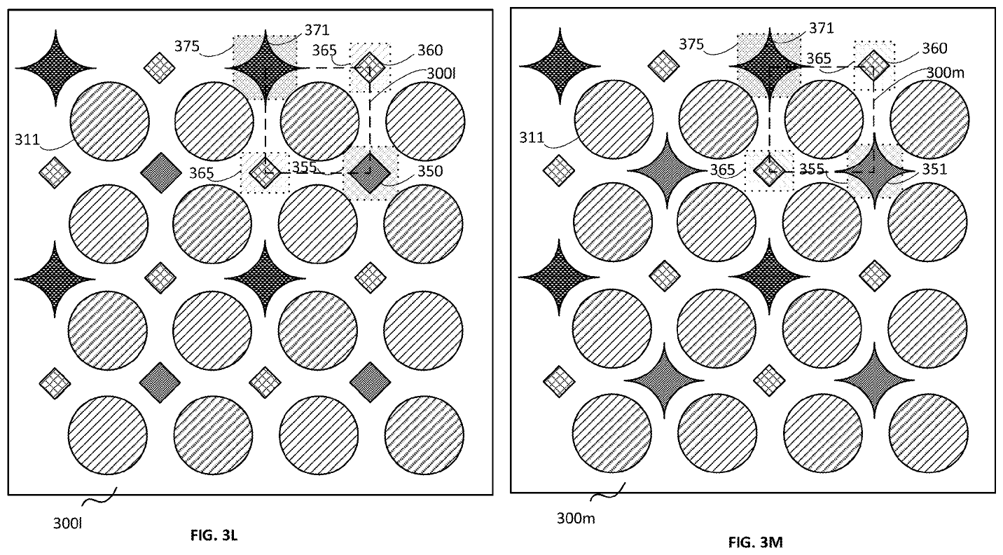

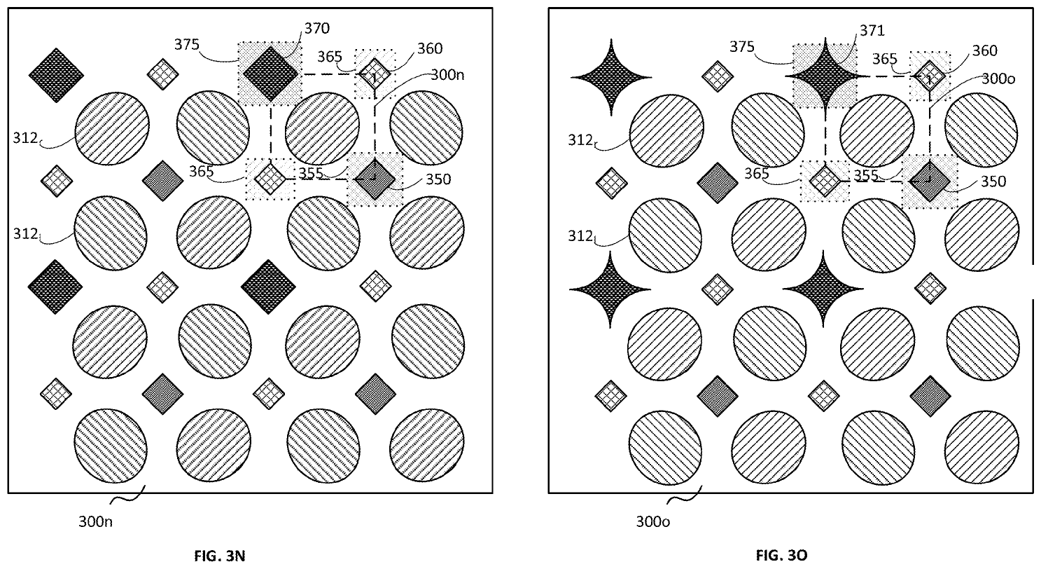

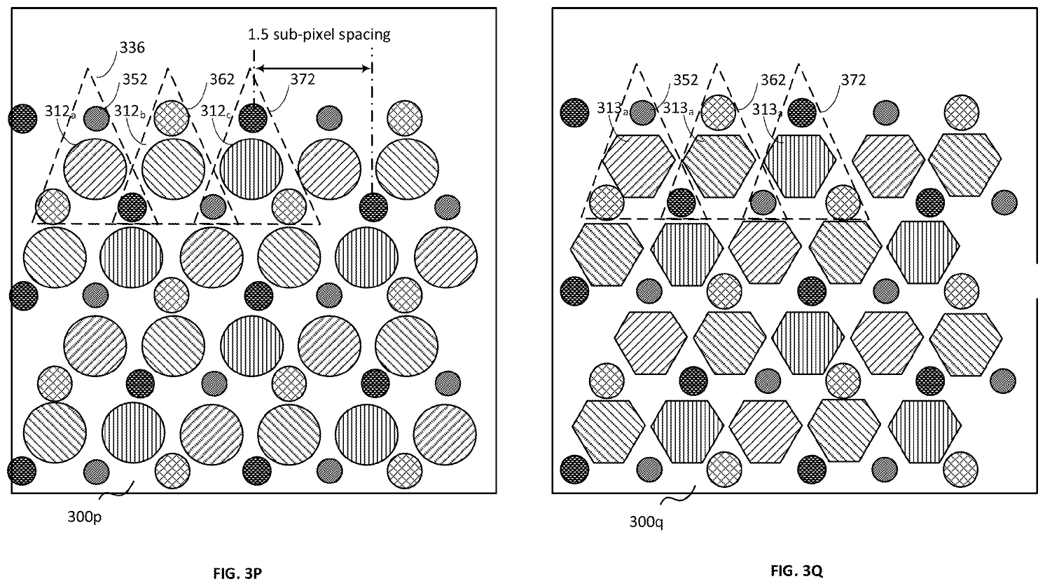

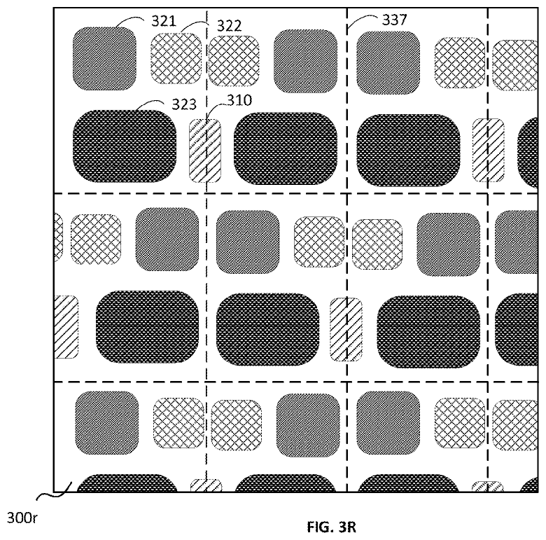

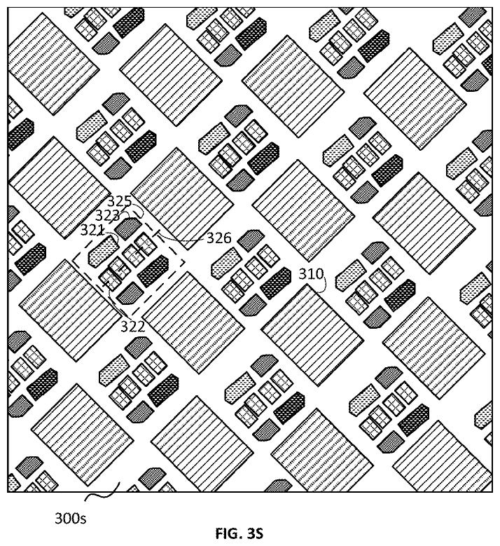

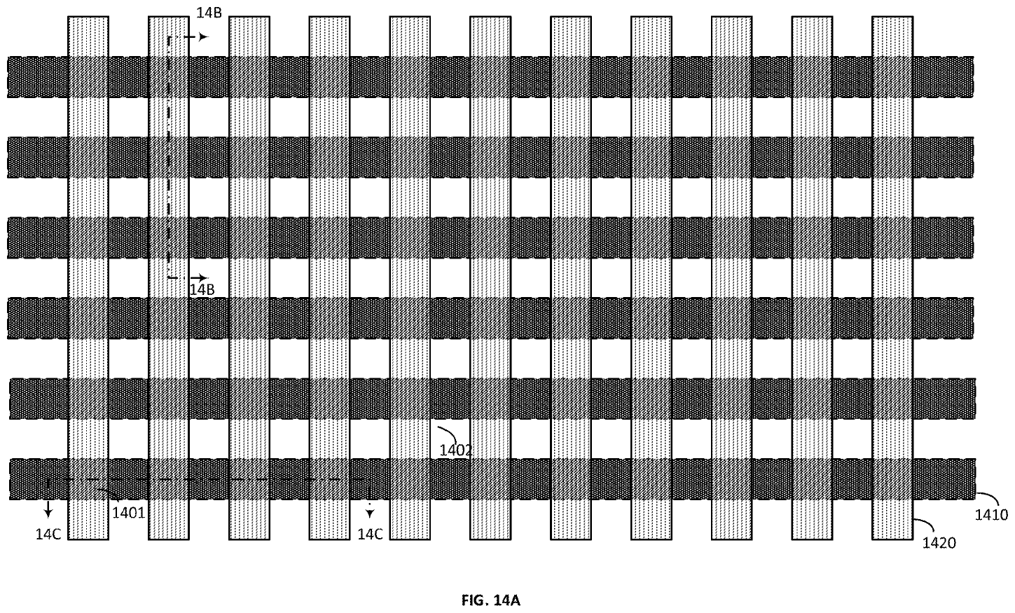

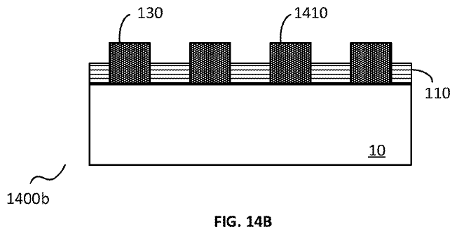

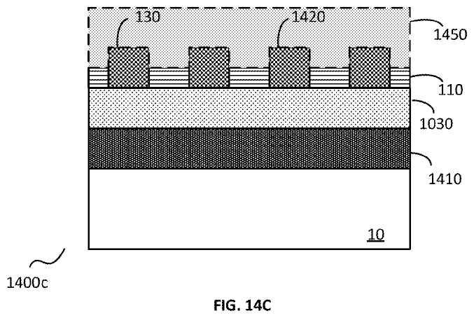

As may be better seen in FIGS. 2B-2D, in some non-limiting examples, the display panel 200 may comprise at least one signal-exchanging part 203 and at least one display part 207. The at least one signal-exchanging part 203 may comprise at least one (EM radiation) transmissive region 31x (FIG. 3A) and at least one (light) emissive region 1401 (FIG. 14A).

The at least one display part 207 may comprise at least one emissive region 1401. In some non-limiting examples, the at least one display part 207 may further comprise at least one region or part that permits transmission, to a greater or lesser extent, of EM radiation therethrough.

In some non-limiting examples, the at least one display part 207 may individually, and/or in conjunction with at least one other display part 207, substantially surround the at least one signal-exchanging part 203. In some non-limiting examples, the at least one signal-exchanging part 203 may be positioned proximate to an extremity of the display panel 200. In some non-limiting examples, the at least one signal-exchanging part 203 may be positioned proximate to an extremity and configured such that the at least one display part(s) 207 do not completely surround the at least one signal-exchanging part 203.

In some non-limiting examples, the at least one signal-exchanging part 203 may be positioned proximate to an extremity of the display panel 200, including without limitation, an edge, such as shown in FIG. 2B, or a corner, such as shown in FIG. 2C.

In some non-limiting examples, the at least one signal-exchanging part 203 may be positioned substantially centrally within the lateral aspect of the display panel 200, such as shown in FIG. 2D.

As shown in FIG. 2B, in some non-limiting examples, the at least one signal-exchanging part 203 may have a polygonal contour, including without limitation, at least one of a substantially square, and rectangular configuration.

As shown in FIG. 2C, in some non-limiting examples, the at least one signal-exchanging part 203 may have a curved contour, including without limitation, at least one of a substantially circular, oval and elliptical configuration.

Those having ordinary skill in the relevant art will appreciate that there may be scenarios calling for the layout of (sub-) pixels 2210/32x in the signal-exchanging part 203 of the display panel 200 to resemble, to a greater or lesser extent, the layout thereof in the display part 207 of the display panel, including without limitation, for simplicity of manufacturing, including without limitation, to permit the use of a fine metal mask (FMM) that has an aperture layout that is substantially the same for both the signal-exchanging part 203 and the display part 207 of the display panel 200, including without limitation, a size, shape, and configuration of (sub-) pixel apertures, and wherein a spacing between adjacent (sub-) pixels 2210/32x (“pitch”) in the signal-exchanging part 203 is one of the same and an integer multiple thereof, of a pitch thereof in the display part 207.

Having said this, examples in the present disclosure may have applicability in scenarios in which the layout of (sub-) pixels 2210/32x in the signal-exchanging part 203 may be substantially different than the layout thereof in the display part 207 of the display panel 200.

In some non-limiting examples, an aperture ratio of the at least one emissive region 1401 of the at least one signal-exchanging part 203 may be substantially the same as an aperture ratio of the at least one emissive region 1401 of the at least one display part 207 proximate thereto, at least in an area thereof that is adjacent and/or substantially proximate to the at least one signal-exchanging part 203. In some non-limiting examples, the aperture ratio of the display panel 200 may be substantially uniform thereacross. In at least some applications, there may be scenarios calling for the at least one signal-exchanging part 203 and the at least one display part 207 to have substantially the same aperture ratio, including without limitation, so that an apparent brightness of the display panel 200 may be substantially the same across both the at least one signal-exchanging part 203 and the at least one display part 207 thereof.

In some non-limiting examples, a pixel density of the at least one emissive region 1401 of the at least one signal-exchanging part 203 may be substantially the same as a pixel density of the at least one emissive region 1401 of the at least one display part 207 proximate thereto, at least in an area thereof that is adjacent and/or substantially proximate to the at least one signal-exchanging part 203. In some non-limiting examples, the pixel density of the display panel 200 may be substantially uniform thereacross. In at least some applications, there may be scenarios calling for the at least one signal-exchanging part 203 and the at least one display part 207 to have substantially the same pixel density, including without limitation, so that a resolution of the display panel 200 may be substantially the same across both the at least one signal-exchanging part 203 and the at least one display part 207 thereof.

In some non-limiting examples, an arrangement of the at least one emissive region 1401 of the at least one signal-exchanging part 203 may be substantially the same as that of the at least one emissive region 1401 of the at least one display part 207 proximate thereto, at least in an area thereof that is adjacent and/or substantially proximate to the at least one signal-exchanging part 203. In some non-limiting examples, a (sub-) pixel layout in the at least one signal-exchanging part 203 may be substantially the same as that of the at least one display part 207.

In the present disclosure, the term “transmissive region” refers to region(s) of the display panel 200, including but not limited to the at least one transmissive region 31x, that may be configured to permit a greater fraction of EM radiation, incident upon the display panel 200, to be transmitted therethrough, at least in comparison to another region of the display panel 200 that is not a transmissive region 31x.

In some non-limiting examples, the at least one transmissive region 31x may comprise and/or be formed by and/or from transparent conducting materials, such as in some non-limiting examples, at least one transparent conducting oxide (TCO), including without limitation, ITO, IZO, and/or IGZO.

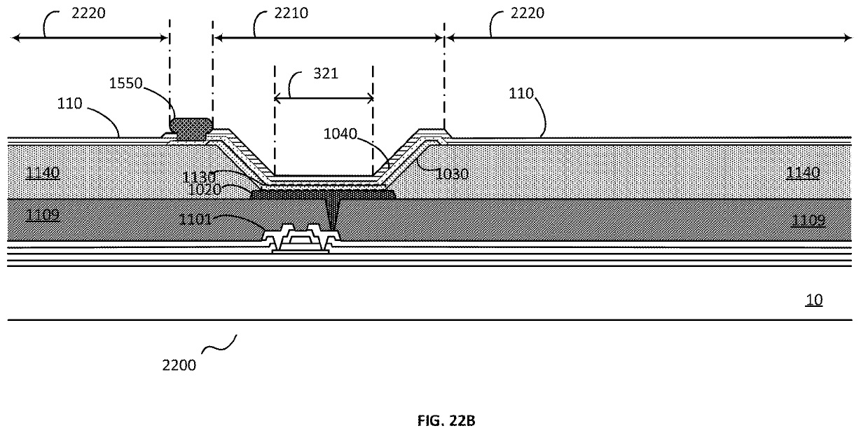

In some non-limiting examples, including without limitation, where the display panel 200 comprises an OLED display device, the at least one emissive region 1401 may emit EM radiation, including without limitation, in the form of at least one photon, therefrom. In some non-limiting examples, a given emissive region 1401 may correspond to a pixel 2210 (FIG. 22A) and/or a sub-pixel 32x (FIG. 3A) of such pixel 2210. In some non-limiting examples, a pixel 2210 may comprise a plurality of (sub-) pixels 2210/32x, each configured to emit EM radiation, including without limitation, in the form of photons, of a given wavelength range, in some non-limiting examples, corresponding to respective colours, including without limitation, R(ed), G(reen), and B(lue).

In some non-limiting examples, a pixel 2210 may comprise three (sub-) pixels 2210/32x, corresponding respectively to a single (sub-) pixel 2210/32x of each of three colours, including without limitation, R(ed) 321, G(reen) 322, and B(lue) 323.

In some non-limiting examples, a pixel 2210 may comprise four (sub-) pixels 2210/32x, each corresponding respectively to a single (sub-) pixel 2210/32x of each of two colours, including without limitation, R(ed) 321 and B(lue) 323, and two (sub-) pixels 2210/32x of a third colour, including without limitation, G(reen) 322.

In some non-limiting examples, a size and/or shape (“geometry”) of the (sub-) pixels 2210/32x of a given colour may be substantially the same or different across a plurality of pixels 2210.

In some non-limiting examples, a size and/or geometry of the (sub-) pixels 2210/32x of a first colour may be substantially the same or different from a size and/or geometry of the (sub-) pixels 2210/32x of at least one of a second colour and a third colour.

In some non-limiting examples, a relative geometry of, and/or wavelength ranges emitted by, the (sub-) pixels 2210/32x of at least one of a first colour, a second colour and a third colour may be selected having regard to how various wavelengths are visually processed, and/or the existence of engineering constraints, including without limitation, power consumption, device reliability, and/or device lifetime.

Those having ordinary skill in the relevant art will appreciate that the specific arrangement of (sub-) pixel(s) 2210/32x may be varied depending on the design of display panel 200. In some non-limiting examples, the (sub-) pixel(s) 2210/32x may be arranged according to known arrangement schemes, including without limitation, RGB, side-by-side, diamond, and/or PenTile®.

In some non-limiting examples, the (sub-) pixels 2210/32x may be disposed in a side-by-side arrangement. In some non-limiting examples, a (colour) order of the (sub-) pixels 2210/32x of a first pixel 2210 may be the same as a (colour) order of the (sub-) pixels 2210/32x of a second pixel 2210. In some non-limiting examples, a (colour) order of the (sub-) pixels 2210/32x of a first pixel 2210 may be different from a (colour) order of the (sub-) pixels 2210/32x of a second pixel 2210.

In some non-limiting examples, the (sub-) pixels 2210/32x of adjacent pixels 2210 may be aligned in at least one of a row, column, and array arrangement.

In some non-limiting examples, a first at least one of a row and a column of aligned (sub-) pixels 2210/32x of adjacent pixels 2210 may comprise (sub-) pixels 2210/32x of a same or a different colour.

In some non-limiting examples, a first at least one of a row and a column of aligned (sub-) pixels 2210/32x of adjacent pixels 2210 may be aligned with at least one of a second and a third at least one of a row and a column of aligned (sub-) pixels 2210/32x of adjacent pixels.

In some non-limiting examples, a first at least one of a row and a column of aligned (sub-) pixels 2210/32x of adjacent pixels 2210 may be offset, or mis-aligned with at least one of a second and a third at least one of row and a column of aligned (sub-) pixels 2210/32x of adjacent pixels 2210.

In some non-limiting examples, the (sub-) pixels 2210/32x of adjacent pixels 2210 of such first, second, and/or third at least one of a row and a column may be arranged such that corresponding (sub-) pixels 2210/32x of each of the first, second, and/or third at least one of a row and a column may be of a common colour.

In some non-limiting examples, the (sub-) pixels 2210/32x of adjacent pixels 2210 of such first, second, and/or third at least one of a row and a column may be arranged such that corresponding (sub-) pixels 2210/32x of each of the first, second and/or third at least one of a row and a column may be of different colours.

In some non-limiting examples, in the at least one signal-exchanging part 203, the at least one transmissive region 31x may be disposed between a plurality of emissive regions 1401. In some non-limiting examples, the at least one transmissive region 31x may be disposed between adjacent (sub-) pixels 2210/32x. In some non-limiting examples, the adjacent (sub-) pixels 2210/32x surrounding the at least one transmissive region 31x may form part of a common pixel 2210. In some non-limiting examples, the adjacent (sub-) pixels 2210/32x surrounding the at least one transmissive region 31x may be associated with different pixels 2210.

With reference again to FIG. 2A, the face 201 of the display panel 200 may extend across a lateral aspect thereof, substantially along a plane defined by the lateral axes. In some non-limiting examples, the face 201, and indeed the display panel 200 may act as a face of a user device 210 through which at least one EM signal 231 may be exchanged therethrough at an angle relative to the plane of the face 201. In some non-limiting examples, the user device 210 may be a computing device, such as, without limitation, a smartphone, a tablet, a laptop, and/or an e-reader, and/or some other electronic device, such as a monitor, a television set, and/or a smart device, including without limitation, an automotive display and/or windshield, a household appliance, and/or a medical, commercial, and/or industrial device.

In some non-limiting examples, the face 201 may correspond to and/or mate with a body 220, and/or an opening 221 therewithin, within which at least one under-display component 230 may be housed.

In some non-limiting examples, the at least one under-display component 230 may be formed integrally, or as an assembled module, with the display panel 200 on a surface thereof opposite to the face 201. In some non-limiting examples, the at least one under-display component 230 may be formed on a surface of the substrate 10 of the display panel 200 opposite to the face 201.

In some non-limiting examples, at least one aperture 204 may be formed in the display panel 200 to allow for the exchange of at least one EM signal 231 through the face 201 of the display panel 200, at an angle to the plane defined by the lateral axes, or concomitantly, the layers of the display panel 200, including without limitation, the face 201 of the display panel 200. In some non-limiting examples, the at least one EM signal 231 may be exchanged between the at least one under-display component 230 and an external object 20, including without limitation, a user of the user device 210.

In some non-limiting examples, at least one aperture 204 may correspond to at least one transmissive region 31x of the at least one signal-exchanging part 203. In some non-limiting examples, a given signal-exchanging part 203 may comprise a plurality of the at least one aperture 204.

In some non-limiting examples, the at least one aperture 204 may be understood to comprise the absence and/or reduction in thickness and/or opacity of a substantially opaque coating otherwise disposed across the display panel 200.

In other words, the at least one EM signal 231 may pass through the at least one aperture 204 such that it passes through the face 201. As a result, the at least one EM signal 231 may be considered to exclude any EM radiation that may extend along the plane defined by the lateral axes, including without limitation, any electric current that may be conducted across a deposited layer 130 laterally across the display panel 200.

Further, those having ordinary skill in the relevant art will appreciate that the at least one EM signal 231 may be differentiated from EM radiation per se, including without limitation, electric current, and/or an electric field generated thereby, in that the at least one EM signal 231 may convey, either alone, or in conjunction with other EM signals 231, some information content, including without limitation, an identifier by which the at least one EM signal 231 may be distinguished from other EM signals 231. In some non-limiting examples, the information content may be conveyed by specifying, altering, and/or modulating at least one of the wavelength, frequency, phase, timing, bandwidth, and/or other characteristic of the at least one EM signal 231.

In some non-limiting examples, the at least one EM signal 231 passing through the at least one aperture 204 of the display panel 200 may comprise at least one photon and, in some non-limiting examples, may have a wavelength spectrum that lies, without limitation, within at least one of the visible spectrum, the IR spectrum, and/or the NIR spectrum.

In some non-limiting examples, the at least one EM signal 231 passing through the at least one aperture 204 of the display panel 200 may comprise ambient light incident thereon.

In some non-limiting examples, the at least one EM signal 231 exchanged through the at least one aperture 204 of the display panel 200 may be transmitted and/or received by the at least one under-display component 230.

In some non-limiting examples, the at least one under-display component 230 may have a size that is greater than a single transmissive region 31x, but may underlie not only a plurality of transmissive regions 31x but also at least one emissive region 1401 extending therebetween. Similarly, in some non-limiting examples, the at least one under-display component 230 may have a size that is greater than a single one of the at least one aperture 204.

In some non-limiting examples, the at least one under-display component 230 may comprise a receiver 230ᵣ adapted to receive and process at least one EM signal 231 passing through the at least one aperture 204 from beyond the user device 210. Non-limiting examples of such receiver 230ᵣ include an under-display camera (UDC), and/or a sensor, including without limitation, an IR sensor, an NIR sensor, a LIDAR sensing module, a fingerprint sensing module, an optical sensing module, an IR (proximity) sensing module, an iris recognition sensing module, and/or a facial recognition sensing module.

In some non-limiting examples, the at least one under-display component 230 may comprise a transmitter 230ₜ adapted to emit at least one EM signal 231 passing through the at least one aperture 204 beyond the user device 210. Non-limiting examples of such transmitter 230ₜ include a source of EM radiation, including without limitation, a built-in flash, a flashlight, an IR emitter, and/or an NIR emitter, and/or a LIDAR sensing module, a fingerprint sensing module, an optical sensing module, an IR (proximity) sensing module, an iris recognition sensing module, and/or a facial recognition sensing module.

In some non-limiting examples, the at least one EM signal 231 passing through the at least one aperture 204 of the display panel 200 beyond the user device 210, including without limitation, those emitted by the at least one under-display component 230 that comprises a transmitter 230ₜ, may emanate from the display panel 200 and pass back through the at least one aperture 204 of the display panel 200 to at least one under-display component 230 that comprises a receiver 230ᵣ.

In some non-limiting examples, there may be a plurality of under-display components 230 within the user device 210, a first one of which comprises a transmitter 230ₜ for emitting at least one EM signal 231 to pass through the at least one aperture 204, beyond the user device 210, and a second one of which comprises a receiver 230ᵣ, for receiving at least one EM signal 231. In some non-limiting examples, such transmitter 230ₜ and receiver 230ᵣ may be embodied in a single, common one of the at least one under-display components 230.

In some non-limiting examples, the at least one under-display component 230 may not emit EM signals 231, but rather the display panel 200 may comprise an opto-electronic device, including without limitation, an opto-luminescent device, including without limitation, an OLED device that emits at least one EM signal 231.

In some non-limiting examples, the object 20 may present a surface for reflecting the at least one EM signal 231. In some non-limiting examples, the at least one EM signal 231 may be light, which by way of non-limiting example may be ambient light, reflected off the surface of the object 20.

Arrangements of Pixels with Interspersed Transmissive Regions in Signal-Exchanging Part to Maintain Pixel Density of Display Cart

Turning now to FIG. 3A, there is shown, by way of non-limiting example, an example (sub-) pixel arrangement 300a in plan that may be applied across a signal-exchanging part 203 of the display panel 200.

In some non-limiting examples, a pixel density of the signal-exchanging part 203 of the display panel 200 may be substantially the same as a pixel density of the display part 207 of the display panel 200.

In some non-limiting examples, an aperture ratio of the at least one emissive region 1401 of the at least one signal-exchanging part 203 may be substantially the same as an aperture ratio of the at least one emissive region 1401 of the at least one display part 207 proximate thereto, at least in an area thereof that is adjacent and/or substantially proximate to the at least one signal-exchanging part 203. In some non-limiting examples, this may be achieved by having at least one of the size, shape, and orientation, of the emissive region 1401 corresponding to the (sub-) pixels 2210/32x to be substantially the same in both the at least one signal-exchanging part 203 and the at least one display part 207.

In some non-limiting examples, at least one of a size, shape, and configuration of the (sub-) pixels 2210/32x in the signal-exchanging part 203 of the display panel 200 may be different, including without limitation, a size reduction, from that of the display part 207 of the display panel 200 in order to provide space to accommodate the addition of the transmissive regions 31x, including without limitation, to maximize an aperture ratio of the transmissive regions 31x, in the signal-exchanging part 203.

Those having ordinary skill in the relevant art will readily appreciate that altering at least one of the size, shape, and orientation, of the emissive regions 1401 of the (sub-) pixels 2210/32x as between the signal-exchanging part 203 and the display part 207 of the display panel 200, may, in some non-limiting examples, alter the aperture ratio therebetween, although the pixel density therebetween may remain unchanged.

In some non-limiting examples, an aperture ratio of all emissive regions 1401 of the (sub-) pixels 2210/32x in the signal-exchanging part 203 of the display panel 200 may be one of no more than about: 20%, 15%, and 10%.

In some non-limiting examples, an aperture ratio of the transmissive regions 31x in the signal-exchanging part 203 of the display panel 200, which may be a sum of the aperture ratios of all of the transmissive regions 31x present in such part, may be one of no more than about: 50%, 45%, 40%, 35%, 33%, 30%, and 25%. In some non-limiting examples, an aperture ratio of the transmissive regions 31x may be one of at least about: 5%, 10%, and 15%.

In some non-limiting examples, an aperture ratio of all emissive regions 1401 of the (sub-) pixels 2210/32x in the signal-exchanging part 203 of the display panel 200, which may be a sum of the aperture ratios of all of the (sub-) pixels 2210/32x present in such part, including without limitation, the first sub-pixels 321, the second sub-pixels 322, and the third sub-pixels 323, may be between about 5-10% and an aperture ratio of the transmissive regions 31x therein may be between about 30-50%.

In some non-limiting examples, an aperture ratio of all emissive regions 1401 of the (sub-) pixels 2210/32x in the signal-exchanging part 203 of the display panel 200, which may be a sum of the aperture ratios of all of the (sub-) pixels 2210/32x present in such part, including without limitation, the first sub-pixels 321, the second sub-pixels 322, and the third sub-pixels 323, may e between about 6-9% and an aperture ratio of the transmissive regions 31x therein may be between about 35-45%.

In some non-limiting examples, a total combined aperture ratio of all emissive regions 1401 of the (sub-) pixels 2210/32x and the transmissive regions 31x in the signal-exchanging part 203 of the display panel 200 may be one of no more than about: 60%, 55%, 50%, 45%, and 40%. In some non-limiting examples, a total combined aperture ratio of all emissive regions 1401 of the (sub-) pixels 2210/32x and the transmissive regions 31x in the signal-exchanging part 203 of the display panel 200 may be one of between about: 30-60%, 35-60%, 40-60%, 35-55%, 40-50%, 45-55%, and 45-50%.

In some non-limiting examples, a size of the at least one transmissive region 31x may be at least about 10 microns. In some non-limiting examples, a size of the at least one transmissive region 31x may be one of between about: 10-150 microns, 10-130 microns, 15-100 microns, 20-80 microns, 20-65 microns, 25-60 microns, and 30-50 microns.

In some non-limiting examples, an apparent or a visually perceived difference as between the signal-exchanging part 203 and the display part 207 as a result of such change in the aperture ratio may be reduced by at least one measure, including without limitation:
maintaining a relative proportion between at least one of: an aperture ratio, a size, and a shape of the emissive regions 1401 of the (sub-) pixels 2210/32x, as between the signal-exchanging part 203 and the display part 207 of the display panel 200;
altering at least one feature of at least one of the (sub-) pixels 2210/32x in at least one of the signal-exchanging part 203 and the display part 207 of the display panel 200, such at least one feature including, without limitation: an intensity of emitted radiation, and a current density; and
establishing at least one transition region about at least one of, and/or between, the signal-exchanging part 203 and the display part 207 of the display panel 200, each having an intermediate aperture ratio, size, shape, orientation, and/or pitch in order to disperse such apparent or visually perceived difference therebetween across an increased lateral aspect of the display panel 200.

### Pixels Having Four Sub-Pixels in 1:2:1 Ratio

In some non-limiting examples, the (sub-) pixel arrangement 300a may comprise a single transmissive region 31x and a plurality of emissive regions 1401 that may, in some non-limiting examples, correspond to four (sub-) pixels 2210/32x of a pixel 2210. In some non-limiting examples, the transmissive region 31x may be situated within and be surrounded by the emissive regions 1401 corresponding to the four (sub-) pixels 2210/32x.

In some non-limiting examples, the (sub-) pixel arrangement 300a may be defined by a first configuration axis 340 and a second configuration axis 345 that may both lie in a lateral plane of the display panel 200 and intersect at a point of intersection. In some non-limiting examples, the first configuration axis 340 may be substantially orthogonal to the second configuration axis 345.

In some non-limiting examples, the transmissive region 31x may be centered, in plan, about a point of intersection of the first configuration axis 340 and the second configuration axis 345.

In some non-limiting examples, a lateral extent of the transmissive region 31x may be defined by a closed transmissive boundary or perimeter 315 thereof. In some non-limiting examples, the transmissive boundary 315 may be symmetric about at least one of the first configuration axis 340 and the second configuration axis 345. In some non-limiting examples, as shown, the transmissive boundary 315 may be symmetric about both the first configuration axis 340 and the second configuration axis 345.

In some non-limiting examples, the transmissive region 310 may have a substantially quadrilateral transmissive boundary 315, comprising and defined by a plurality of linear transmissive boundary segments 391-394. In some non-limiting examples, at least one of the transmissive boundary segments 391, 393 may be substantially parallel to the first configuration axis 340. In some non-limiting examples, there may be two of such transmissive boundary segments 391, 393 that are substantially parallel to the first configuration axis 340. In some non-limiting examples, at least one of the transmissive boundary segments 392, 394 may be substantially parallel to the second configuration axis 345. In some non-limiting examples, there may be two of such transmissive boundary segments 392, 394 that are substantially parallel to the second configuration axis 345.

In some non-limiting examples, none of the transmissive boundary segments 391-394 may be parallel with one another.

In some non-limiting examples, such as is shown in FIG. 3A, each of the transmissive boundary segments 391-394 may be of substantially equal length.

In some non-limiting examples, none of the transmissive boundary segments 391-394 may have a substantially equal length.

Turning now to FIG. 3B, there is shown, by way of non-limiting example, an example (sub-) pixel arrangement 300b in plan that may be applied across a signal-exchanging part 203 of the display panel 200. The (sub-) pixel arrangement 300b may be seen to differ from the (sub-) pixel arrangement 300a in that the transmissive region 31x (and the (sub-) pixels 2210/32x) exhibits substantially rounded corners.

As discussed herein, without wishing to be bound by a particular theory, it may be postulated that when a closed boundary of a transmissive region 31x comprises at least one non-linear and/or curved segment, EM signals incident thereon and transmitted therethrough may exhibit a less distinctive and/or more uniform diffraction pattern that facilitates mitigation of interference caused by the diffraction pattern.

In some non-limiting examples, a plurality of transmissive boundary segments 391-394 may be coupled by and may extend between at least one substantially curved transmissive boundary segment 396-399. Thus, in some non-limiting examples, respective endpoints of the linear transmissive boundary segments 391-394 may be coupled with endpoints of the curved transmissive boundary segments 396-399.

In some non-limiting examples, at least one of the curved transmissive boundary segments 396-399 may have a minimum radius of curvature. In some non-limiting examples, such minimum radius of curvature, which may be correlated to a constraint in a manufacturing process, may be one of about: 8 microns, and 10 microns.

In some non-limiting examples, the pair of second sub-pixels 322 may be positioned symmetrically about at least one of the first configuration axis 340 and the second configuration axis 345, in some non-limiting examples, the first configuration axis 340, with the transmissive region 31x positioned between them. In some non-limiting examples, the first sub-pixel 321 and the third sub-pixel 323 may be positioned symmetrically about at least one of the first configuration axis 340 and the second configuration axis 345, in some non-limiting examples, the second configuration axis 345, with the transmissive region 31x positioned between them.

In some non-limiting examples, at least one of the emissive regions 1401 may have a substantially quadrilateral boundary or contour, comprising and defined by a plurality of linear segments.

In the (sub-) pixel arrangement 300a, the four (sub-) pixels 2210/32x may, in some non-limiting examples, correspond to a first sub-pixel 321, a pair of second sub-pixels 322 and a third sub-pixel 323. In some non-limiting examples, the first sub-pixel 321 may correspond to a R(ed) colour, the second sub-pixels 322 may correspond to a G(reen) colour, the third sub-pixel 323 may correspond to a B(lue) colour.

In some non-limiting examples, a transmissive region 31x may be positioned between the pair of second sub-pixels 322 corresponding to a common pixel 2210. In some non-limiting examples, a transmissive region 31x may be positioned between a second sub-pixel 322 corresponding to a first pixel 2210 and a second sub-pixel 322 corresponding to a second pixel 2210. In some non-limiting examples, a spacing between such transmissive region 31x and a first second sub-pixel 322 may be substantially the same as a spacing between such transmissive region 31x and a second second sub-pixel 322.

In some non-limiting examples, a transmissive region 31x may be positioned between the first sub-pixel 321 and the third sub-pixel 323 corresponding to a common pixel 2210. In some non-limiting examples, a transmissive region 31x may be positioned between a first sub-pixel 321 corresponding to a first pixel 2210 and a third sub-pixel 323 corresponding to a second pixel 2210. In some non-limiting examples, a spacing between such transmissive region 31x and the first sub-pixel 321 may be substantially the same as a spacing between such transmissive region 31x and the third sub-pixel 323.

In some non-limiting examples, a given transmissive region 31x may be positioned both between a first sub-pixel 321 and a third sub-pixel 323 and between two second sub-pixels 322.

In some non-limiting examples, a lateral extent of the first sub-pixel 321 may be defined by a closed first sub-pixel boundary 355 thereof. As shown, in some non-limiting examples, the first sub-pixel boundary 355 may comprise a plurality of substantially linear first sub-pixel segments 351-354. In some non-limiting examples, at least one of the first sub-pixel segments 352, 354 may be substantially parallel to a corresponding at least one of the transmissive boundary segments 392, 394 of the transmissive region 31x, proximate, and in some non-limiting examples, adjacent thereto.

In some non-limiting examples, a majority of the transmissive boundary segments 391-394 may be substantially parallel to an adjacent sub-pixel boundary segment 351-354, 361-364, 371-374.

In some non-limiting examples, as shown, with respect to the first sub-pixel 321, the first sub-pixel segment 354 may be proximate, and/or in some non-limiting examples, adjacent, to the corresponding transmissive boundary segment 392.

In some non-limiting examples, the at least one first sub-pixel segment 354 and the corresponding at least one transmissive boundary segment 392 proximate thereto may be separated by a minimum distance. In some non-limiting examples, such minimum distance, which in some non-limiting examples, may be correlated to a constraint in a manufacturing process, may be one of about: 5 microns, 6 microns, 8 microns, 10 microns, 11 microns, and 12 microns. In some non-limiting examples, such minimum distance, may be one of between about: 5-15 microns, 6-12 microns, and 8-10 microns.

In some non-limiting examples, such as is shown in FIG. 3B, a plurality of linear first sub-pixel segments 351-354 may be coupled by and may extend between at least one substantially curved first sub-pixel segment 356-359. Thus, in some non-limiting examples, respective endpoints of the linear first sub-pixel segments 351-354 may be coupled with endpoints of the curved first sub-pixel segments 356-359.

In some non-limiting examples, at least one of the curved first sub-pixel segments 356-359 may have a minimum radius of curvature. In some non-limiting examples, such minimum radius of curvature, which may be correlated to a constraint in a manufacturing process, may be one of about: 8 microns, and 10 microns.

In some non-limiting examples, a lateral extent of one of the second sub-pixels 322 may be defined by a closed second sub-pixel boundary 365 thereof. As shown, in some non-limiting examples, the second sub-pixel boundary 365 may comprise a plurality of substantially linear second sub-pixel segments 361-364. In some non-limiting examples, at least one of the second sub-pixel segments 361, 363 may be substantially parallel to a corresponding at least one of the transmissive boundary segments 391, 393 of the transmissive region 31x, proximate, and in some non-limiting examples, adjacent thereto.

In some non-limiting examples, as shown, with respect to the second sub-pixel 322ₐ, the second sub-pixel segment 363 may be proximate, and/or in some non-limiting examples, adjacent, to the corresponding transmissive boundary segment 391.

In some non-limiting examples, as shown, with respect to the second sub-pixel 322_{b}, the second sub-pixel segment 361 may be proximate, and/or in some non-limiting examples, adjacent, to the corresponding transmissive boundary segment 393.

In some non-limiting examples, the at least one second sub-pixel segment 363 and the corresponding at least one transmissive boundary segment 391 of the transmissive region 31x proximate thereto may be separated by a minimum distance. In some non-limiting examples, the at least one second sub-pixel segment 361 and the corresponding at least one transmissive boundary segment 393 of the transmissive region 31x proximate thereto may be separated by a minimum distance. In some non-limiting examples, such minimum distance, which in some non-limiting examples, may be correlated to a constraint in a manufacturing process, may be one of about: 5 microns, 6 microns, 8 microns, 10 microns, 11 microns, and 12 microns. In some non-limiting examples, such minimum distance, may be one of between about: 5-15 microns, 6-12 microns, and 8-10 microns.

In some non-limiting examples, such as is shown in FIG. 3B, a plurality of linear second sub-pixel segments 361-364 may be coupled by and may extend between at least one substantially curved second sub-pixel segment 366-369. Thus, in some non-limiting examples, respective endpoints of the linear second sub-pixel segments 361-364 may be coupled with endpoints of the curved second sub-pixel segments 366-369.

In some non-limiting examples, at least one of the curved second sub-pixel segments 366-369 may have a minimum radius of curvature. In some non-limiting examples, such minimum radius of curvature, which may be correlated to a constraint in a manufacturing process, may be one of about: 8 microns, and 10 microns.

In some non-limiting examples, a lateral extent of the third sub-pixel 323 may be defined by a closed third sub-pixel boundary 375 thereof. As shown, in some non-limiting examples, the third sub-pixel boundary 375 may comprise a plurality of substantially linear third sub-pixel segments 371-374. In some non-limiting examples, at least one of the third sub-pixel segments 372, 374 may be substantially parallel to a corresponding at least one of the transmissive boundary segments 392, 394 of the transmissive region 31x, proximate, and in some non-limiting examples, adjacent thereto.

In some non-limiting examples, as shown, with respect to the third sub-pixel 323, the third sub-pixel segment 372 may be proximate, and/or in some non-limiting examples, adjacent, to the corresponding transmissive boundary segment 394.

In some non-limiting examples, the at least one third sub-pixel segment 372 and the corresponding at least one transmissive boundary segment 394 of the transmissive region 31x proximate thereto may be separated by a minimum distance. In some non-limiting examples, such minimum distance, which in some non-limiting examples, may be correlated to a constraint in a manufacturing process, may be one of about: 5 microns, 6 microns, 8 microns, 10 microns, 11 microns, and 12 microns. In some non-limiting examples, such minimum distance, may be one of between about: 5-15 microns, 6-12 microns, and 8-10 microns.

In some non-limiting examples, such as is shown in FIG. 3B, a plurality of linear third sub-pixel segments 371-374 may be coupled by and may extend between at least one substantially curved third sub-pixel segment 376-379. Thus, in some non-limiting examples, respective endpoints of the linear third sub-pixel segments 371-374 may be coupled with endpoints of the curved third sub-pixel segments 376-379.

In some non-limiting examples, at least one of the curved third sub-pixel segments 376-379 may have a minimum radius of curvature. In some non-limiting examples, such minimum radius of curvature, which may be correlated to a constraint in a manufacturing process, may be one of about: 8 microns, and 10 microns.

Thus, the (sub-) pixel arrangement 300a maintains both a high aperture ratio and a high sub-pixel density of the (sub-) pixels 2210/32x, while providing a transmissive region 31x therewithin having an area that permits the exchange of EM signals 231 through the signal-exchanging part 203 of the display panel 200.

In some non-limiting examples, the (sub-) pixel arrangement 300a may be configured such that a plurality, including without limitation, four, of connected non-overlapping outline vectors 331-334, each beginning at an endpoint located within, including without limitation, at a centroid of, a first emissive region 1401 and terminating at an endpoint located within, including without limitation, at a centroid of, a second emissive region 1401, where the first and second emissive regions 1401 are associated with a pair of the sub-pixels 32x, without passing through the transmissive region 31x, may define an outline 330, 336, 337, which, in some non-limiting examples, may resemble a quadrilateral or box 330.

In some non-limiting examples, the first emissive region 1401 and the second emissive region 1401 may substantially abut one another, such that the corresponding outline vector 331-334 may extend laterally across at least a part of the first emissive region 1401 and at least a part of the second emissive region 1401 with nothing therebetween.

In some non-limiting examples, the first emissive region 1401 and the second emissive region 1401 may be spaced apart, such that the corresponding outline vector 331-334 may extend laterally across at least a part of the first emissive region 1401 and at least a part of the second emissive region 1401 with a region extending therebetween.

In some non-limiting examples, the position of the first sub-pixel 321, the pair of second sub-pixels 322, and the third sub-pixel 323, may be such that the box 330 may define at least one of: a square, a rectangle, a parallelogram, and a trapezoid. In some non-limiting examples, the position of the first sub-pixel 321, the pair of second sub-pixels 322, and the third sub-pixel 323, may be such that none of the outline vectors 331-334 may be of substantially equal length. In some non-limiting examples, the position of the first sub-pixel 321, the pair of second sub-pixels 322, and the third sub-pixel 323, may be such that at least two of the outline vectors 331-334 may be of substantially equal length. In some non-limiting examples, the position of the first sub-pixel 321, the pair of second sub-pixels 322, and the third sub-pixel 323, may be such that none of the outline vectors 331-334 may be parallel with one another.

In some non-limiting examples, the outline 330 may enclose at least one transmissive region 31x. In some non-limiting examples, the outline vectors 331-334 of the outline 330, 336, 337 may surround, and in some non-limiting examples, avoid passing through, the transmissive region 31x.

Turning now to FIG. 3C, the signal-exchanging part 203 of the display panel 200 is shown, with the (sub-) pixel arrangement 300a replicated across its lateral aspect. It may be seen that a plurality of adjacent outlines 330, 336, 337, including without limitation, four adjacent boxes 330, which each have a line segment that passes through the centroid of a common (sub-) pixel 2210/32x, may be combined to define a unit cell 335. While, in the figure, the unit cell 335b may have as the common (sub-) pixel 2210/32x, a B(lue) sub-pixel 323, those having ordinary skill in the relevant art will appreciate that, in some non-limiting examples, the common (sub-) pixel 2210/32x may equally be a R(ed) sub-pixel 321 (unit cell 335ᵣ) or one of the pair of G(reen) sub-pixels 322 (unit cell 335_{ga} or 335_{gb}, which in some non-limiting examples, may be considered to be a vertically or horizontally flipped version of 335_{ga} or a version thereof that has been rotated by substantially about 90° in either of a clockwise or counter-clockwise direction). Whatever the colour of the common (sub-) pixel 2210/32x, in some non-limiting examples, adjacent unit cells 335 will have a common (sub-) pixel 2210/32x of the same colour.

Those having ordinary skill in the relevant art will appreciate that, in some non-limiting examples, the unit cell 335 may constitute a repeating unit of the array of (sub-) pixels 2210/32x in the signal-exchanging part 203. In some non-limiting examples, the unit cell 335 may be a repeating unit of minimum size.

Those having ordinary skill in the relevant art will appreciate that, in some non-limiting examples, the same pixel layout may be viewed as a repetition of a unit cell 335, whether a unit cell 335 having a common (sub-) pixel 2210/32x that is a R(ed) sub-pixel 321 (unit cell 335ᵣ) or one of the pair of G(reen) sub-pixels 322 (unit cell 335_{ga} or 335_{gb}), or a B(lue) sub-pixel 323 (unit cell 335_{b}).

In some non-limiting examples, at least one outline 330, 336, 337 of the unit cell 335 may enclose at least one transmissive region 31x. In some non-limiting examples, each of the outlines 330, 336, 337 of the unit cell 335 may enclose at least one transmissive region 31x.

In some non-limiting examples, the unit cell 335 may comprise a plurality of outlines 330, 336, 337 of substantially similar shape and size. In some non-limiting examples, the unit cell 335 may comprise outlines 330, 336, 337, none of which have at least one of a shape and size that are substantially equal.

Turning now to FIG. 3D, there is shown, by way of non-limiting example, an example (sub-) pixel arrangement 300d in plan that may be applied across a signal-exchanging part 203 of the display panel 200. The (sub-) pixel arrangement 300d may be seen to differ from the (sub-) pixel arrangement 300a in that the transmissive region 31x has been rotated by substantially about 90° (in either the clockwise or counter-clockwise direction).

As such, the parallel relationship between the linear transmissive boundary segments 391-394 and at least one of the linear first sub-pixel segments 351-354, the linear second sub-pixel segments 361-364, and the linear third sub-pixel segments 371-374 may not be maintained.

In some non-limiting examples, the first configuration axis 340 and the second configuration axis 345 may be considered to be each rotated by substantially about 90° (in either the clockwise or counter-clockwise direction).

If so, in some non-limiting examples, the parallel relationship between at least one of the first configuration axis 340 and the second configuration axis 345 and the linear transmissive boundary segments 391-394 may be maintained. However, in such cases, a parallel relationship may not be considered to be maintained between at least one of the first configuration axis 340 and the second configuration axis 345 and at least one of the linear first sub-pixel segments 351-354, the linear second sub-pixel segments 361-364, and the linear third sub-pixel segments 371-374.

In some non-limiting examples, at least one of the outline vectors 331-334, including without limitation, at least one of outline vectors 332, 334, may be substantially parallel to the first configuration axis 340. In some non-limiting examples, at least one of the outline vectors 331-334, including without limitation, at least one of outline vectors 331, 333, may be substantially parallel to the second configuration axis 340.

Turning now to FIG. 3E, there is shown, by way of non-limiting example, an example (sub-) pixel arrangement 300e in plan that may be applied across a signal-exchanging part 203 of the display panel 200. The (sub-) pixel arrangement 300e may be seen to differ from the (sub-) pixel arrangement 300d in that at least one of the transmissive boundary segments 391, 393 may be of a first length and at least one of the transmissive boundary segments 392, 394 may be of a second length that is different from the first length.

Turning now to FIG. 3F, there is shown, by way of non-limiting example, an example (sub-) pixel arrangement 300f in plan that may be applied across a signal-exchanging part 203 of the display panel 200. The (sub-) pixel arrangement 300f may be seen to differ from the (sub-) pixel arrangement 300e in that the transmissive region 31x has been rotated by substantially about 90° (in either the clockwise or counter-clockwise direction).

Turning now to FIG. 3G, there is shown, by way of non-limiting example, an example (sub-) pixel arrangement 300g in plan that may be applied across a signal-exchanging part 203 of the display panel 200. The (sub-) pixel arrangement 300g may be seen to differ from the (sub-) pixel arrangement 300a in that at least one of the first sub-pixel 321, the second sub-pixels 322 and the third sub-pixel 323, have been rotated by substantially about 90° (in either the clockwise or counter-clockwise direction).

As such, the parallel relationship between the linear transmissive boundary segments 391-394 and at least one of the linear first sub-pixel segments 351-354, the linear second sub-pixel segments 361-364, and the linear third sub-pixel segments 371-374 may not be maintained.

In some non-limiting examples, a parallel relationship may be considered to be maintained between at least one of the first configuration axis 340 and the second configuration axis 345 and at least one of the linear first sub-pixel segments 351-354, the linear second sub-pixel segments 361-364, and the linear third sub-pixel segments 371-374. However, in such cases, the parallel relationship between at least one of the first configuration axis 340 and the second configuration axis 345 and the linear transmissive boundary segments 391-394 may not be maintained.

Turning now to FIG. 3H, there is shown, by way of non-limiting example, an example (sub-) pixel arrangement 300h in plan that may be applied across a signal-exchanging part 203 of the display panel 200. The (sub-) pixel arrangement 300h may be seen to differ from the (sub-) pixel arrangement 300g, in that at least one of: the linear first sub-pixel segments 351-354, the linear second sub-pixel segments 361-364, and the linear third sub-pixel segments 371-374, (in the figure, the linear second sub-pixel segments 361-364) are not all of substantially equal length and, in some non-limiting examples, may be coupled by and may extend between respective at least one of: at least one curved first sub-pixel segments 356-359, at least one curved second sub-pixel segments 366-369, and at least one curved third sub-pixel segments 376-379 (in the figure, each of them).

In some non-limiting examples, at least one of the first sub-pixel segments 351-354, including without limitation, segments 351, 353, may be of a first length and at least one of the first sub-pixel segments 351-354, including without limitation, segments 352, 354, may be of a second length that is different from the first length.

In some non-limiting examples, at least one of the second sub-pixel segments 361-364, including without limitation, segments 361, 363, may be of a first length and at least one of the second sub-pixel segments 361-364, including without limitation, segments 362, 364, may be of a second length that is different from the first length.

In some non-limiting examples, at least one of the third sub-pixel segments 371-374, including without limitation, segments 371, 373, may be of a first length and at least one of the third sub-pixel segments 371-374, including without limitation, segments 372, 374, may be of a second length that is different from the first length.

In FIG. 3I, the signal-exchanging part 203 of the display panel 200 is shown, with the (sub-) pixel arrangement 300g replicated across its lateral aspect.

Turning now to FIG. 3J, there is shown, by way of non-limiting example, an example (sub-) pixel arrangement 300j in plan that may be applied across a signal-exchanging part 203 of the display panel 200. While, in some non-limiting examples, at least one of the size, shape, and orientation, of the emissive region 1401 corresponding to the at least one (sub-) pixel 2210/32x in the signal-exchanging part 203 of the display panel 200 may be substantially identical to a corresponding at least one of the size, shape, and orientation, of the emissive region 1401 corresponding to the corresponding at least one (sub-) pixel 2210/32x of the display part 207 of the display panel 200, including as described herein, in context with at least the (sub-) pixel arrangement 300a, in some non-limiting examples, at least one of the size, shape, and orientation, of the emissive region 1401 corresponding to the at least one (sub-) pixel 2210/32x in the signal-exchanging part 203 of the display panel 200 may be different from a corresponding at least one of the size, shape, and orientation, of the emissive region 1401 corresponding to the corresponding at least one (sub-) pixel 2210/32x of the display part 207 of the display panel 200.

In the (sub-) pixel arrangement 300j, the first sub-pixel 321 may be shown as having an emissive region 1401 in the signal-exchanging part 203 that has an example size, shape, and orientation, indicated by a signal-exchanging first sub-pixel outline 350, and may be compared and contrasted with an example size, shape, and orientation, of a corresponding emissive region 1401 in the display part 207, indicated by a display first sub-pixel outline 355 superimposed thereover. Similarly, the second sub-pixels 322 may be shown as having an emissive region 1401 in the signal-exchanging part 203 that has an example size, shape, and orientation, indicated by a signal-exchanging second sub-pixel outline 360, and may be compared and contrasted with an example size, shape, and orientation, of a corresponding emissive region 1401 in the display part 207, indicated by a display second sub-pixel outline 365 superimposed thereover, and the third sub-pixel 323 may be shown as having an emissive region 1401 in the signal-exchanging part 203 that has an example size, shape, and orientation, indicated by a signal-exchanging third sub-pixel outline 370, and may be compared and contrasted with an example size, shape, and orientation, of a corresponding emissive region 1401 in the display part 207, indicated by a display third sub-pixel outline 375 superimposed thereover.

In some non-limiting examples, a size of at least one emissive region 1401 of the first sub-pixel 321, including without limitation, in the signal-exchanging part 203 of the display panel 200, may exceed a size of a corresponding at least one emissive region 1401 of the second sub-pixel 322. In some non-limiting examples, a size of at least one emissive region 1401 of the third sub-pixel 323 may exceed a size of a corresponding at least one emissive region 1401 of the first sub-pixel 321.

As shown in the (sub-) pixel arrangement 300j, in some non-limiting examples, the orientation of the emissive regions 1401 of the (sub-) pixels 2210/32x in the signal-exchanging part 203 of the display panel 200, relative to the emissive regions 1401 of the (sub-) pixels 2210/32x in the display part of the display panel 200, by rotating the emissive regions 1401 by substantially about 90° (in either the clockwise or counter-clockwise direction) relative to the emissive regions 1401 of the (sub-) pixels 2210/32x in the display panel 200.

As shown in the (sub-) pixel arrangement 300j, in some non-limiting examples, a size of at least one emissive region 1401 of at least one (sub-) pixel 2210/32x in the signal-exchanging part 203 of the display panel 200, relative to a size of a corresponding emissive region 1401 of a corresponding (sub-) pixel 2210/32x in the display part in the display panel 200, may alternatively, and/or also be reduced such that a diagonal extent of the at least one emissive region 1401 of the at least one (sub-) pixel 2210/32x in the signal-exchanging part 203 of the display panel 200 may be made substantially equal in length to one of the linear segments of the boundary of the corresponding emissive region 1401 of the corresponding (sub-) pixel 2210/32x in the display part 207 of the display panel 200, such that when superimposed as shown, the at least one emissive region 1401 of the at least one (sub-) pixels 2210/32x in the signal-exchanging part 203 of the display panel 200 may be seen to be substantially circumscribed by the sides of the corresponding emissive region 1401 of the corresponding (sub-) pixel 2210/32x in the display part 207 of the display panel 200.

In some non-limiting examples, a length of at least one of the linear first sub-pixel segments 351-354, including without limitation, in the (sub-) pixel arrangement 300j, may be about 11.6 microns. In some non-limiting examples, a length of at least one of the linear second sub-pixel segments 361-364, including without limitation, in the (sub-) pixel arrangement 300j, may be about 8.7 microns. In some non-limiting examples, a length of at least one of the linear third sub-pixel segments 371-374, including without limitation, in the (sub-) pixel arrangement 300j, may be about 14.5 microns.

In some non-limiting examples, both rotating and reducing the size of the at least one emissive region 1401 of at least one (sub-) pixel 2210/32x in the signal-exchanging part 203 of the display panel 200 relative to a corresponding emissive region 1401 of a corresponding (sub-) pixel 2210/32x of the display part 207 of the display panel 200 may provide separation between a plurality of adjacent (sub-) pixels 2210/32x in the signal-exchanging part 203 of the display panel 200 such that at least one transmissive region 31x may be introduced therebetween, without altering a pixel density between the signal-exchanging part 203 and the display part 207 of the display panel 200.

In some non-limiting examples, the pixel density exhibited by the signal-exchanging part 203 of the display panel 200, including without limitation, in the (sub-) pixel arrangement 300j, may be one of at least about: 300 ppi, 350 ppi, and 400 ppi. In some non-limiting examples, the pixel density exhibited by the signal-exchanging part 203 of the display panel 200, including without limitation, in the (sub-) pixel arrangement 300j, may be about 430 ppi.

In FIG. 3K, the signal-exchanging part 203 of the display panel 200 is shown, with alternating instances of the (sub-) pixel arrangement 300e and the (sub-) pixel arrangement 300f replicated across its lateral aspect (some features therefrom have been omitted, including without limitation, the linear second sub-pixel segments 361-364 being of different lengths and the interposition of rounded sub-pixel segments between linear sub-pixel segments).

In some non-limiting examples, the transmissive regions 31x may be regularly spaced-apart along at least one configuration axis 340, 345.

In some non-limiting examples, a first transmissive region 31xₐ separated by a first sub-pixel 321 from a second transmissive region 31x_{b}, may be spaced apart by a first separation distance, including without limitation, as represented by arrow 381 in the (sub-) pixel arrangement 300k, which in some non-limiting examples, may be substantially about 57.66 microns.

In some non-limiting examples, the second transmissive region 31x_{b} separated by a second sub-pixel 322 from a third transmissive region 31x_{c}, may be spaced apart by a second separation distance, including without limitation, as represented by arrow 382 in the (sub-) pixel arrangement 300k, which in some non-limiting examples, may be substantially about 59.11 microns.

In some non-limiting examples, the third transmissive region 31x_{c} separated by a third sub-pixel 323 from a fourth transmissive region 31x_{d}, may be spaced apart by a third separation distance, including without limitation, as represented by arrow 383 in the (sub-) pixel arrangement 300k, which in some non-limiting examples, may be substantially about 60.56 microns.

In some non-limiting examples, a distance between a centre of a first sub-pixel 321 and a third sub-pixel 323 adjacent thereto, including without limitation, as represented by any one of the dashed lines 384 in the (sub-) pixel arrangement 300k, may be substantially about 59.11 microns.

In some non-limiting examples, the third separation distance, including without limitation, as represented by arrow 383 in the (sub-) pixel arrangement 300k, may exceed the first separation distance, including without limitation, as represented by arrow 381 in the (sub-) pixel arrangement 300k.

In some non-limiting examples, an array of transmissive regions 31x may be arranged such that a distance between adjacent transmissive regions 31x in such array may alternate along at least one configuration axis 340, 345, between the first separation distance, as represented by arrow 381 in the (sub-) pixel arrangement 300k, and the third separation distance, as represented by arrow 383 in the (sub-) pixel arrangement 300k.

In some non-limiting examples, the transmissive regions 31x may be irregularly spaced-apart along at least one configuration axis 340, 345.

In some non-limiting examples, an area of each transmissive region 31x, including without limitation, in the example of FIG. 3K, may be substantially about 597.9 square microns.

In some non-limiting examples, the transmissive regions 31x, including without limitation, in the example of FIG. 3K, may occupy substantially about 34.2% of an area enclosed by the dashed lines 384.

In some non-limiting examples, the transmissive regions 31x may comprise a plurality of subsets of transmissive regions 31xₗ, and 31xᵣ, disposed in alternating arrangement. In some non-limiting examples, there may not be any difference between a transmissive region 31x of the first subset 31xₗ and a transmissive region 31x of the second subset 31xᵣ.

In some non-limiting examples, at least one of: a size, shape, and orientation, of a transmissive region 31x of the first subset 31xₗ may be different from at least one of: a size, shape, and orientation, of a transmissive region 31x of the second subset 31xᵣ, including without limitation, to maximize an aperture ratio of at least one of the transmissive regions 31x and the emissive regions 1401. In some non-limiting examples, the transmissive regions 31x of the first subset 31xₗ may be oriented toward the left, while the transmissive regions 31x of the second subset 31xᵣ may be oriented toward the right, when viewed in plan in the field of view disclosed in FIG. 3K.

In some non-limiting examples, the transmissive regions 31x of a first subset 31xₗ, 31xᵣ, may correspond to respective apertures of a first FMM and the transmissive regions 31x of a second subset 31xₗ, 31xᵣ, may correspond to respective apertures of a second FMM.

In some non-limiting examples, the transmissive regions 31x may be divided into a plurality of subsets 31xₗ, 31xᵣ, in order to achieve a maximum number, and/or a minimum spacing, of the apertures of a given FMM, including without limitation, to maintain a threshold structural integrity of the FMM.

In some non-limiting examples, the transmissive boundary 31x may have a shape other than a quadrilateral, or a quadrilateral with rounded corners ((rounded) quadrilateral) shape, such as shown in some non-limiting examples therein, including without limitation, one of a (rounded) polygonal (including without limitation, a (rounded) triangular, circular, oval, and star shape.

In some non-limiting examples, the sub-pixel boundary 350, 360, 370 of the emissive regions 1401 of respectively, at least one of: the first sub-pixel 321, the second sub-pixel 322, and the third sub-pixel 323, may have a shape other than a (rounded) quadrilateral, such as shown in some non-limiting examples herein, including without limitation, one of a (rounded) polygonal (including without limitation, a (rounded) triangular, circular, oval, elliptical, and star shape.

In some non-limiting examples, a shape of the transmissive boundary 31x and of at least one sub-pixel boundary 350, 360, 370 may be complementary, in that at least a part of a sub-pixel boundary 350, 360, 370 is substantially a constant separation from a corresponding part of the transmissive boundary 31x so as to facilitate an increased fraction of the panel area in the signal-exchanging part 203 of the display panel to be used for transmission and/or emission of EM radiation, so as to increase an aperture ratio of the transmissive regions 31x and/or the emissive regions 1401 respectively.

Turning now to FIG. 3L, the signal-exchanging part 203 of the display panel 200 is shown, with an example (sub-) pixel arrangement 300l replicated across its lateral aspect. In the (sub-) pixel arrangement 300l, the rectangular transmissive boundary 31x may have been replaced with a circular transmissive boundary 391.

In some non-limiting examples, the emissive region 1401 of the third sub-pixel 323 may have a substantially star-shaped signal-exchanging third sub-pixel outline 370₁, which in some non-limiting examples, may be formed by joining a plurality (including without limitation, four) of curved vertices, including without limitation, a concave fraction (including without limitation, a quarter) of a curved perimeter, including without limitation, one of: a circle, an oval, and an ellipse.

In some non-limiting examples, replacing a polygonal sub-pixel outline with a star-shaped sub-pixel outline for at least one (sub-) pixel 2210/32x may facilitate increasing an aperture ratio of the (sub-) pixels 2210/32x, including without limitation, where the transmissive regions 31x have a transmissive boundary that is one of: a circle, oval, and ellipse.

In some non-limiting examples, a radius of curvature of the curved perimeter of the star-shaped signal-exchanging third sub-pixel outline 370₁ may be substantially equal to a radius of curvature of one of: a circle, oval, and ellipse, defining the transmissive boundary 31x proximate thereto, so as to maintain a substantially constant separation between the transmissive boundary 391 and the curved perimeter of the third sub-pixel boundary 370₁. In some non-limiting examples, such separation may be one of at least about: 8 microns, 10 microns, 11 microns, and 12 microns.

By way of comparison, at least one instance of the signal-exchanging first sub-pixel outline 350 in the (sub-) pixel arrangement 300l is shown superimposed over an example of a corresponding display first sub-pixel outline 355. In some non-limiting examples, the lateral extent of the signal-exchanging first sub-pixel outline 350 may not overlap the lateral extent of either the display first sub-pixel outline 355 nor the lateral extent of the at least one transmissive region 311. In some non-limiting examples, the lateral extent of the display first sub-pixel outline 355 may overlap the lateral extent of the at least one transmissive region 311.

By way of comparison, at least one instance of the signal-exchanging second sub-pixel outline 360 in the (sub-) pixel arrangement 300l is shown superimposed over an example of a corresponding display second sub-pixel outline 365. In some non-limiting examples, the lateral extent of the signal-exchanging second sub-pixel outline 360 may not overlap the lateral extent of either the display second sub-pixel outline 365 nor the lateral extent of the at least one transmissive region 311. In some non-limiting examples, the lateral extent of the display second sub-pixel outline 365 may not overlap the lateral extent of the at least one transmissive region 311.

By way of comparison, at least one instance of the star-shaped signal-exchanging third sub-pixel outline 370₁ in the (sub-) pixel arrangement 300l is shown superimposed over an example of a corresponding display third sub-pixel outline 375. In some non-limiting examples, the vertices of the star-shaped signal-exchanging third sub-pixel outline 370₁ may extend beyond the lateral extent of such display third sub-pixel outline 375. In some non-limiting examples, the lateral extent of the display third sub-pixel outline 375 may overlap the lateral extent of the at least one transmissive region 311. However, because of its shape, in some non-limiting examples, the lateral extent of the star-shaped signal-exchanging third sub-pixel outline 370₁ may not overlap the lateral extent of the at least one transmissive region 311.

Turning now to FIG. 3M, the signal-exchanging part 203 of the display panel 200 is shown, with an example (sub-) pixel arrangement 300m replicated across its lateral aspect. The (sub-) pixel arrangement 300m differs from the (sub-) pixel arrangement 300l, in that the emissive region 1401 of the first sub-pixel 321 may also have a substantially star-shaped signal-exchanging first sub-pixel outline 3501, which in some non-limiting examples, may be formed by joining a plurality (including without limitation, four) of curved vertices, including without limitation, a concave fraction (including without limitation, a quarter) of a curved perimeter, including without limitation, one of: a circle, an oval, and an ellipse.

In so doing, in some non-limiting examples, the aperture ratio of the (sub-) pixels 2210/32x may be increased. Although not shown, in some non-limiting examples, the aperture ratio of the (sub-) pixels 2210/32x may be still further increased by replacing at least one of the signal-exchanging second sub-pixel outlines 360 with a substantially star-shaped second sub-pixel outline.

By way of comparison, at least one instance of the star-shaped signal-exchanging first sub-pixel outline 3501 in the (sub-) pixel arrangement 300m is shown superimposed over an example of a corresponding display first sub-pixel outline 355. In some non-limiting examples, the vertices of the star-shaped signal-exchanging first sub-pixel outline 3501 may extend beyond the lateral extent of such display first sub-pixel outline 355. In some non-limiting examples, the lateral extent of the display first sub-pixel outline 355 may overlap the lateral extent of the at least one transmissive region 311. However, because of its shape, in some non-limiting examples, the lateral extent of the star-shaped signal-exchanging first sub-pixel outline 3501 may not overlap the lateral extent of the at least one transmissive region 311.

Turning now to FIG. 3N, the signal-exchanging part 203 of the display panel 200 is shown, with an example (sub-) pixel arrangement 300n replicated across its lateral aspect. The (sub-) pixel arrangement 300n differs from the (sub-) pixel arrangement 300j, in that the rectangular transmissive regions 31x have been replaced by a plurality of subsets 312ₗ, 312ᵣ of elliptical transmissive regions 312. In some non-limiting examples, the transmissive regions 312 of the first subset 312ₗ may be oriented toward the left, while the transmissive regions 312 of the second subset 312ᵣ may be oriented toward the right, when viewed in plan in the field of view disclosed in FIG. 3N.

Turning now to FIG. 3O, the signal-exchanging part 203 of the display panel 200 is shown, with an example (sub-) pixel arrangement 300o replicated across its lateral aspect. The (sub-) pixel arrangement 300n differs from the (sub-) pixel arrangement 300n, in that the signal-exchanging third sub-pixel outline 350 of the third sub-pixels 323 has been replaced by the star-shaped signal-exchanging third sub-pixel outline 370₁ of the third sub-pixels 323 shown in FIG. 3L.

### Pixels Having Three Sub-Pixels in 1:1:1 Ratio

Turning now to FIG. 3P, the signal-exchanging part 203 of the display panel 200 is shown, with an example (sub-) pixel arrangement 300p replicated across its lateral aspect. The (sub-) pixel arrangement 300p differs from the (sub-) pixel arrangement 300n, in that the signal-exchanging sub-pixel outlines 350, 360, 370, of respectively the first sub-pixels 321, the second sub-pixels 322, and the third sub-pixels 323, have been replaced by circular signal-exchanging sub-pixel outlines 350₂, 360₂, 370₂ respectively.

Additionally, the sub-pixel configuration of the pixels 2210 has been changed from a quadrilateral 4 sub-pixel (R-G-B in a 1:2:1 ratio) configuration to a triangular 3 sub-pixel (R-G-B in a 1:1:1 ratio) delta configuration, shown by dashed outlines 336, each enclosing an elliptical transmissive region 312. In some non-limiting examples, an area of the second sub-pixel 322 may be increased to compensate for the reduction in the number of second sub-pixels 322 in such 3 sub-pixel configuration relative to the number of second sub-pixels 322 in the 4 sub-pixel configuration.

In some non-limiting examples, the transmissive regions 312 may comprise a plurality of subsets of transmissive regions 312ₐ, 312_{b}, and 312_{c}, disposed in alternating arrangement. In some non-limiting examples, there may not be any difference between a transmissive region 312 of the first subset 312ₐ, a transmissive region 312 of the second subset 312_{b}, and a transmissive region 312 of the third subset 312_{c}.

Those having ordinary skill in the relevant art will appreciate that, in some non-limiting examples, the (sub-) pixel arrangement 300p may be understood to comprise a first row of an alternating series of first sub-pixels 321, second sub-pixels 322, and third sub-pixels 323 and a second row of a similar alternating series, laterally offset by a spacing of about 1.5 sub-pixels, with a row of (an alternating series of subsets of) transmissive regions 312 disposed therebetween.

Turning now to FIG. 3Q, the signal-exchanging part 203 of the display panel 200 is shown, with an example (sub-) pixel arrangement 300q replicated across its lateral aspect. The (sub-) pixel arrangement 300q differs from the (sub-) pixel arrangement 300p, in that the (subsets of) elliptical transmissive regions 312 have been replaced by a plurality of subsets 313ₐ, 313_{b}, 313_{c} of substantially triangular transmissive regions 313.

In some non-limiting examples, there may be some scenarios calling for substantially triangular transmissive regions 313, including without limitation, where the (sub-) pixels 2210/32x of the pixels 2210 are arranged in a triangular 3-pixel delta configuration, such as in the (sub-) pixel arrangement 300q, so as to substantially increase an aperture ratio of the transmissive regions 313, including without limitation, relative to an aperture ratio of the substantially elliptical transmissive regions 312 of the (sub-) pixel arrangement 300p.

In some non-limiting examples, such as is shown, the vertices of the triangle are truncated such that the perimeter has a substantially hexagonal configuration, with three elongated linear segments coupled by and extending between three truncated linear segments. Although not shown, in some non-limiting examples, the vertices of the triangle may be present. Although not shown, in some non-limiting examples, the three elongated linear segments may be coupled by and may extend between three substantially curved segments.

Although not shown, in some non-limiting examples, an aperture ratio of the transmissive regions 313 may be increased by replacing the substantially circular signal-exchanging sub-pixel outlines 350₂, 360₂, 370₂, of respectively the first sub-pixels 321, the second sub-pixels 322, and the third sub-pixels 323 by triangular signal-exchanging sub-pixel outlines respectively.

Turning now to FIG. 3R, the signal-exchanging part 203 of the display panel 200 is shown, with an example (sub-) pixel arrangement 300r replicated across its lateral aspect. In some non-limiting examples, the (sub-) pixel arrangement 300r comprises a first 3 (sub-) pixel 2210/32x pixel 2210 positioned in substantially a conventional RGB configuration, but one of the (sub-) pixels 2210/32x (in the figure, the third sub-pixel 323) moved laterally to one side, and a second 3 (sub-) pixel 2210/32x pixel 2210 wherein the corresponding (sub-) pixel 2210/32x is moved laterally to an opposite side thereof, so that between the instances of the moved (sub-) pixel 2210/32x, a transmissive region 310 may be inserted. In some non-limiting examples, there may be a substantially quadrilaterally-shaped outline 337 enclosing each pixel 2210. In some non-limiting examples, the transmissive region 310 may overlap the boundary of the outline 337.

Turning now to FIG. 3S, the signal-exchanging part 203 of the display panel 200 is shown, with an example (sub-) pixel arrangement 300s replicated across its lateral aspect. In some non-limiting examples, the (sub-) pixel arrangement 300s comprises an alternating array of sub-pixel groups 325 and transmissive regions 31x. In some non-limiting examples, the sub-pixel groups 325 and the transmissive regions 31x may be disposed in a substantially checkerboard configuration. In some non-limiting examples, at least one of the sub-pixel group 325 and the transmissive region 31x may define a substantially rectangular configuration.

In some non-limiting examples, the sub-pixel group 325 may comprise a plurality of each of the first sub-pixels 321, the second sub-pixels 322, and the third sub-pixels 323. In some non-limiting examples, the sub-pixel group 325 may comprise two of each of the first sub-pixels 321, and the third sub-pixels 323, and four of each of the second sub-pixels 322, so that a sub-pixel group 325 may be considered to be an equivalent of two 4 sub-pixel (R-G-B in a 1:2:1 ratio) pixels 2210.

In some non-limiting examples, each of the plurality of second sub-pixels 322 may have a substantially identical size and configuration. In some non-limiting examples, each of the plurality of second sub-pixels 322 may have a substantially rectangular configuration having a major axis and a minor axis. In some non-limiting examples, the plurality of second sub-pixels 322 may be aligned along a sub-pixel group axis 326 of the sub-pixel group 325. In some non-limiting examples, the sub-pixel group axis 326 may substantially bisect the sub-pixel group 325. In some non-limiting examples, the sub-pixel group axis 326 may be substantially parallel to the minor axis of the second sub-pixels 322.

In some non-limiting examples, each of the plurality of first sub-pixels 321 may have a substantially identical size and configuration. In some non-limiting examples, a first one of the first sub-pixels 321 may be disposed substantially parallel to the sub-pixel axis 326, on one side of the plurality of second sub-pixels 322, and toward one extremity of the sub-pixel group 325 in the direction of the sub-pixel axis 326, and a second one of the first sub-pixels 321 may be disposed on an opposite side of the plurality of second sub-pixels 322, and toward an opposite extremity of the sub-pixel group 325 in the direction of the sub-pixel axis 326. In some non-limiting examples, the configuration of the second one of the first sub-pixels 321 may be rotated 180° relative to the configuration of the first one of the first sub-pixels 321.

In some non-limiting examples, each of the plurality of third sub-pixels 323 may have a substantially identical size and configuration. In some non-limiting examples, a first one of the third sub-pixels 323 may be disposed substantially parallel to the sub-pixel axis 326, on one side of the plurality of second sub-pixels 322, and toward one extremity of the sub-pixel group 325 in the direction of the sub-pixel axis 326, and a second one of the third sub-pixels 321 may be disposed on an opposite side of the plurality of second sub-pixels 322, and toward an opposite extremity of the sub-pixel group 325 in the direction of the sub-pixel axis 326. In some non-limiting examples, the first one of the third sub-pixels 323 may be disposed on the same side of the plurality of second sub-pixels 322 and toward the opposite extremity of the sub-pixel group 325 relative to the first one of the first sub-pixels 321. In some non-limiting examples, the configuration of the second one of the third sub-pixels 321 may be rotated 180° relative to the configuration of the first one of the third sub-pixels 321.

In some non-limiting examples, an aperture ratio of the emissive regions 1401 in the signal-exchanging part 203 of the display panel 200, in some non-limiting examples, an aperture ratio taking into account all of: the emissive regions 1401 of the first sub-pixels 321, the emissive regions 1401 of the second sub-pixels 322, and the emissive regions 1401 of the third sub-pixels 323, may be one of at least about: 20%, 15%, 10%, and 8%.

In some non-limiting examples, an aperture ratio of the transmissive regions 31x in the signal-exchanging part 203 of the display panel 200, may be one of at least about: 50%, 45%, 40%, 35%, 33%, 30%, and 25%.

In some non-limiting examples, a sum of the aperture ratio of the emissive regions 1401 and the transmissive regions 31x in the signal-exchanging part 203 of the display panel 200, may be one of between about: 30-60%, 35-60%, 40-60%, 35-55%, 40-50%, 45-55%, and 45-50%.

In some non-limiting examples, in the signal-exchanging part 203 of the display panel 200, the aperture ratio of the emissive regions 1401 may be between about 5-10% and the aperture ratio of the transmissive regions 31x may be between about 30-50%. In some non-limiting examples, in the signal-exchanging part 203 of the display panel 200, the aperture ratio of the emissive regions 1401 may be between about 6-9% and the aperture ratio of the transmissive regions 31x may be between about 35-45%.

### **Reducing Pixels in Signal-Exchanging Part Relative to Display Part to Accommodate Transmissive Regions

In some non-limiting examples, a pixel density of the signal-exchanging part 203 of the display panel 200 may be less than a pixel density of the display part 207 of the display panel 200.

In some non-limiting examples, at least one of the size, shape, configuration and pitch of the (sub-) pixels 2210/32x in the signal-exchanging part 203 of the display panel 200 may be substantially identical to that of the (sub-) pixels 2210/32x in the display part 207 of the display panel 200, however the number of such (sub-) pixels 2210/32x may be reduced in the signal-exchanging part 203 of the display panel 200. In such scenarios, a common FMM may be used for both the signal-exchanging part 203 and the display part 207, with an attendant reduction of manufacturing cost and complexity. In such scenarios, those apertures in the FMM corresponding to those (sub-) pixels 2210/32x that are not present (omitted) in the signal-exchanging part 203 may be covered or blocked when in use with the signal-exchanging part 203 so that at least one void may result therefrom.

In some non-limiting examples, at least one transmissive region 31x may be formed in those voids corresponding to those (sub-) pixels 2210/32x that have been omitted from the signal-exchanging part 203.

In some non-limiting examples, an aperture ratio of all emissive regions 1401 of the (sub-) pixels 2210/32x in the signal-exchanging part 203 of the display panel 200 may be one of between about 12-25%.

In some non-limiting examples, an aperture ratio of the transmissive regions 31x in the signal-exchanging part 203 of the display panel 200, which may be a sum of the aperture ratios of all of the transmissive regions 31x present in such part, may be one of between about: 15-40%, 20-40%, 15-35%, and 20-35%.

In some non-limiting examples, an aperture ratio of all emissive regions 1401 of the (sub-) pixels 2210/32x in the signal-exchanging part 203 of the display panel 200, which may be a sum of the aperture ratios of all of the (sub-) pixels 2210/32x present in such part, including without limitation, the first sub-pixels 321, the second sub-pixels 322, and the third sub-pixels 323, may be between about 12-25% and an aperture ratio of the transmissive regions 31x therein may be between about 30-45%.

In some non-limiting examples, a total sum of the aperture ratio of all emissive regions 1401 of the (sub-) pixels 2210/32x and the transmissive regions 31x in the signal-exchanging part 203 of the display panel 200 may be one of no more than about: 60%, 55%, 505, 45%, and 40%. In some non-limiting examples, a total sum of the aperture ratio of all emissive regions 1401 of the (sub-) pixels 2210/32x and the transmissive regions 31x in the signal-exchanging part 203 of the display panel 200 may be one of between about: 30-60%, 35-60%, 40-60%, 35-55%, 40-50%, 45-55%, and 45-50%.

In some non-limiting examples, a size of the at least one transmissive region 31x may be at least about 10 microns. In some non-limiting examples, a size of the at least one transmissive region 31x may be one of between about: 10-150 microns, 10-130 microns, 15-100 microns, 20-80 microns, 20-65 microns, 25-60 microns, and 30-50 microns.

In some non-limiting examples, the at least one sub-pixel segment 351-354, 361-364, 371-374 and the corresponding at least one transmissive boundary segment 391-394 proximate thereto may be separated by a minimum distance. In some non-limiting examples, such minimum distance, which in some non-limiting examples, may be correlated to a constraint in a manufacturing process, may be one of about: 5 microns, 6 microns, 8 microns, 10 microns, 11 microns, and 12 microns. In some non-limiting examples, such minimum distance, may be one of between about: 5-15 microns, 6-12 microns, and 8-10 microns.

In some non-limiting examples, at least one entire pixel 2210 may have been omitted from the signal-exchanging part 203.

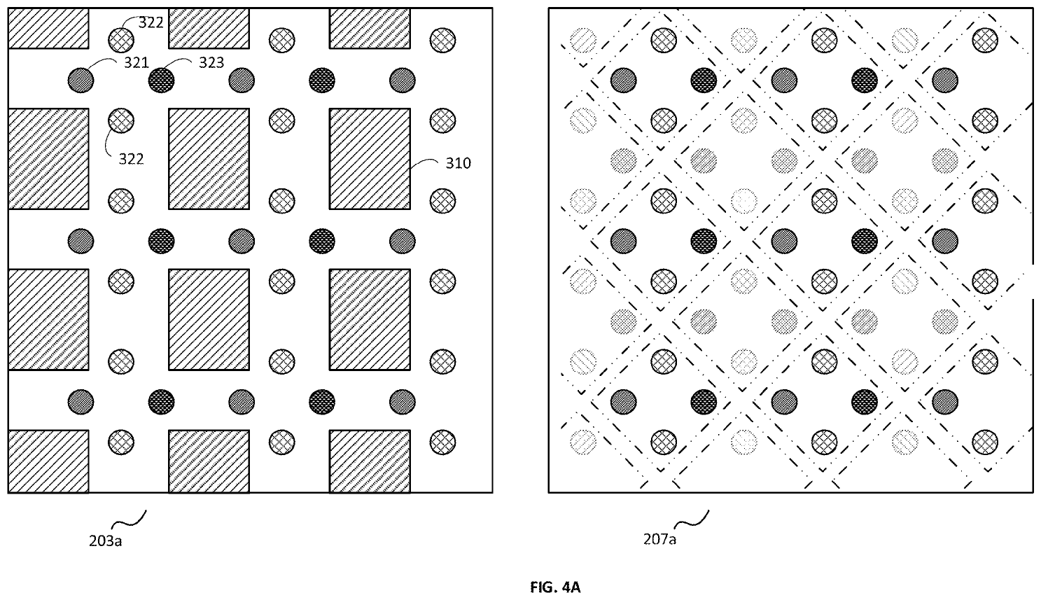

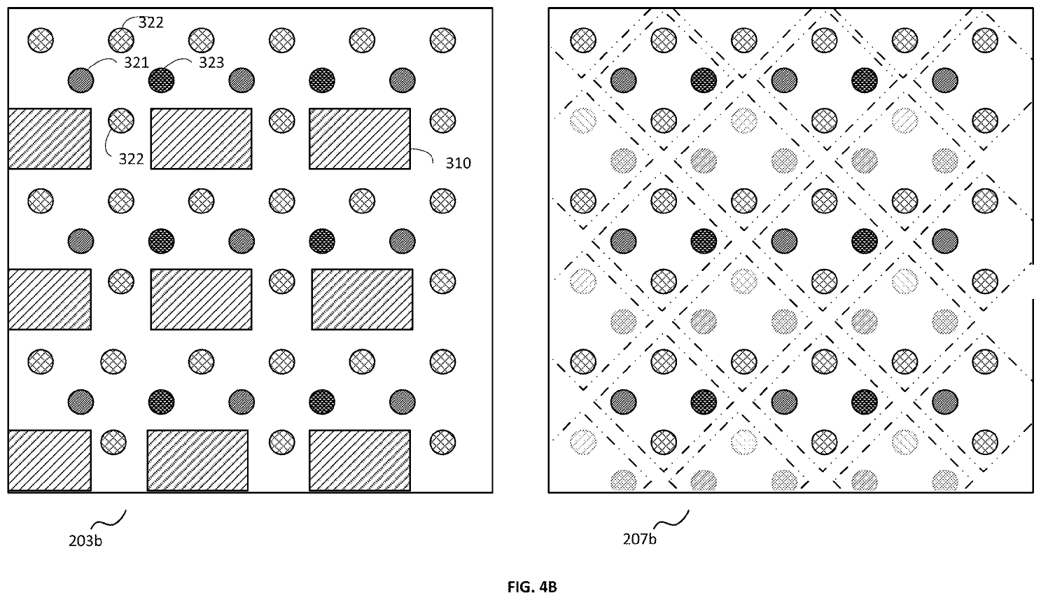

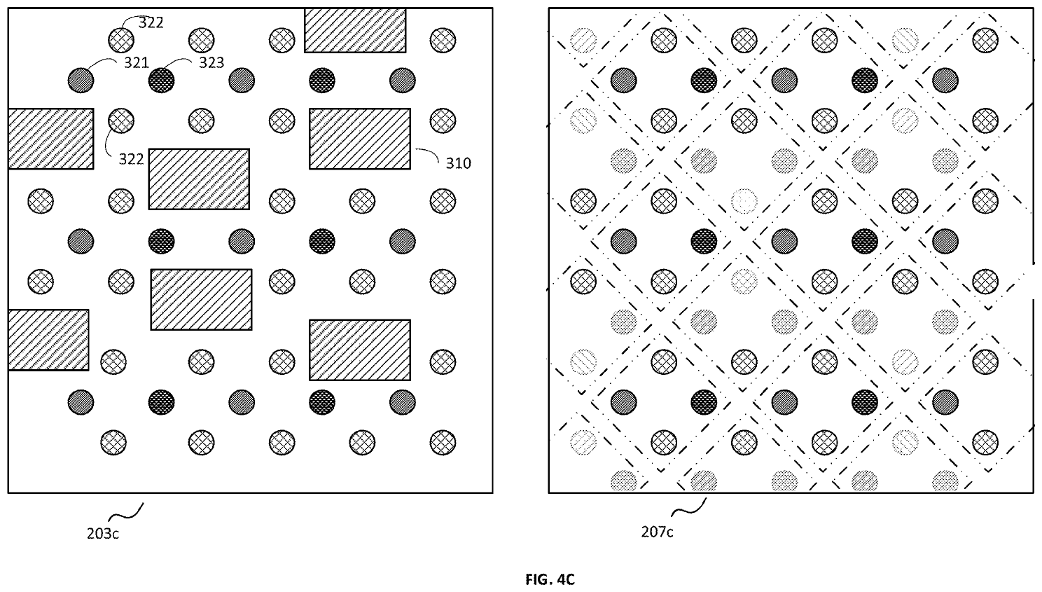

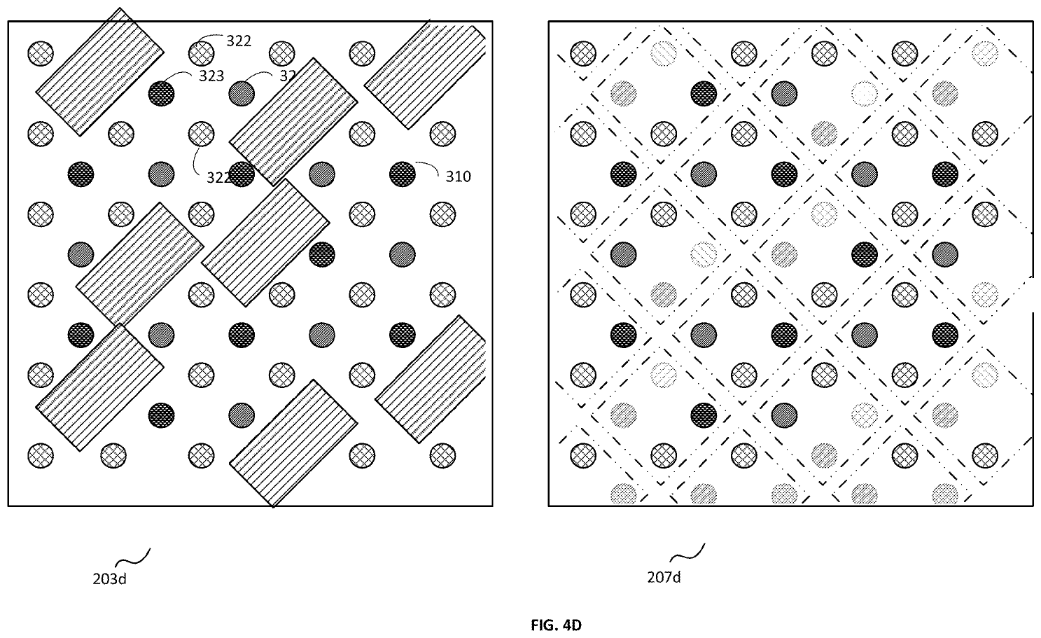

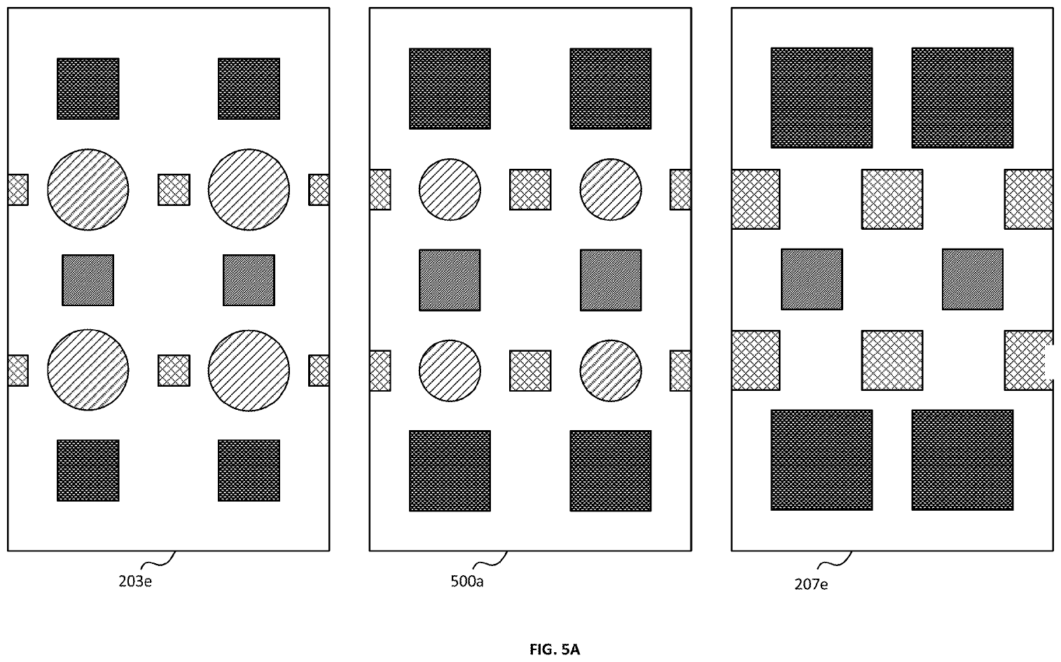

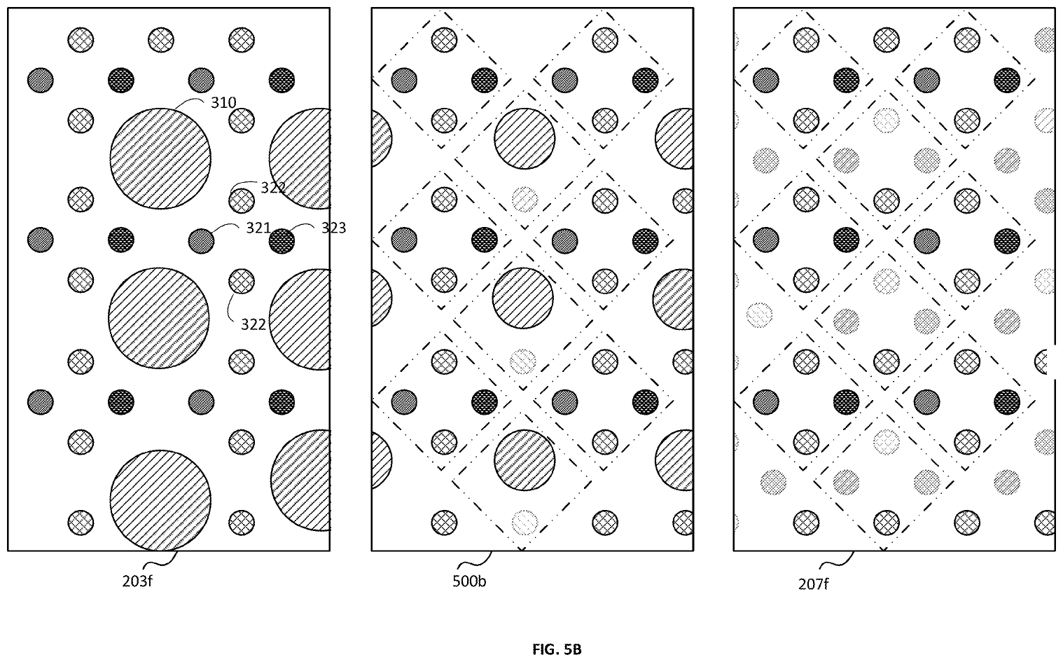

Turning now to FIG. 4A, there is shown, in plan, a fragment 203a of the signal-exchanging part 203 and a fragment 207a of the display part 207 of the display panel 200. For purposes of illustration, some example pixels 2210 are shown in dashed outline in the display part fragment 207a. It will be appreciated that between the signal-exchanging part fragment 203a and the display part fragment 207a shown, there may be other parts of the display panel 200, which may comprise, at least one of: (a fragment of) the same signal-exchanging part 203, at least one different signal-exchanging part 203, (a fragment of) the same display part 207, at least one different display part 207, and at least one transition region 500.

In some non-limiting examples, the size, shape, configuration, and pitch of the (sub-) pixels 2210/32x in the signal-exchanging part 203 is the same as in the display part 207. However, from comparison of the signal-exchanging part fragment 203a, with the display part fragment 207a, in the signal-exchanging part 203, in some non-limiting examples, there may be a void corresponding to every second pixel 2210 in the display part 207 (shown with increased transparency), where at least one transmissive region 31x may be disposed. Thus, it may be understood that a pixel density in the signal-exchanging part 203 may be substantially about 50% of a pixel density in the display part 207.

The sub-pixels 32x are shown, in each fragment 203a, 207a, having a substantially circular shape and a substantially uniform size and pitch, and in a four sub-pixel (R-G-B in a 1:2:1 ratio) pixel 2210 box configuration solely for illustrative purposes and the examples discussed herein, including without limitation, any of the (sub-) pixel configurations (with or without omitted (sub-) pixels 2210/32x and/or transmissive regions 31x) in the (sub-) pixel arrangements 300, should not be considered as limiting, in any fashion, any of the size, shape, configuration, orientation, and pitch of the (sub-) pixels 2210/32x in either the signal-exchanging part 203 or the display part 207.

The transmissive regions 31x are shown having a substantially rectangular shape and a substantially uniform size and orientation solely for illustrative purposes and the examples discussed herein, including without limitation, any of the (sub-) pixel configurations (with or without omitted (sub-) pixels and/or transmissive regions 31x) in the (sub-) pixel arrangements 300, should not be considered as limiting, in any fashion, any of the size, shape, configuration, and orientation of the transmissive regions 31x in the signal-exchanging part 203.

Turning now to FIG. 4B, there is shown, in plan, a fragment 203b of the signal-exchanging part 203 and a fragment 207b of the display part 207 of the display panel 200. From comparison of the signal-exchanging part fragment 203b, with the display part fragment 207b, in the signal-exchanging part 203, in some non-limiting examples, there may be a void corresponding to three of the four sub-pixels 32x of every second pixel 2210 in the display part 207 (shown with increased transparency), where at least one transmissive region 31x may be disposed. Thus, it may be understood that a pixel density in the signal-exchanging part 203 may be substantially about 62.5% of a pixel density in the display part 207.

In some non-limiting examples, the three omitted sub-pixels 32x may correspond to any combination of three of the four sub-pixels 32x of every second pixel 2210, including without limitation, as shown, one each of the first sub-pixel 321, the second sub-pixel 322, and the third sub-pixel 323.

In some non-limiting examples, the three omitted sub-pixels 32x may be different successive second pixels 2210. Byway of non-limiting example, turning now to FIG. 4C, there is shown, in plan, a fragment 203c of the signal-exchanging part 203 and a fragment 207c of the display part 207 of the display panel 200. The signal-exchanging part fragment 203c differs from the signal-exchanging part fragment 203b, in that in every second block of second pixels 2210, the three sub-pixels 32x omitted include a different one of the second sub-pixels 322.

Turning now to FIG. 4D, there is shown, in plan, a fragment 203d of the signal-exchanging part 203 and a fragment 207d of the display part 207 of the display panel 200. From comparison of the signal-generating part fragment 203d, with the display part fragment 207d, in the signal-exchanging part 203, in some non-limiting examples, there may be a void corresponding to two of the four sub-pixels 32x of every second pixel 2210 in the display part 207 (shown with increased transparency), where at least one transmissive region 31x may be disposed. Thus, it may be understood that a pixel density in the signal-exchanging part 203 may be substantially about 75% of a pixel density in the display part 207.

In some non-limiting examples, the two omitted sub-pixels 32x may correspond to any combination of two of the four sub-pixels 32x of every second pixel 2210, including without limitation, as shown, in every second block of second pixels 2210, the two sub-pixels 32x comprise a different one of the second sub-pixel 322, and a different one of the first sub-pixel 321 and the third sub-pixel 323.

**Altering Pitch of (Sub-) Pixels in Signal-Exchanging Part to Other than Multiple of Pitch in Display Part

While, in some non-limiting examples, there may be scenarios calling for the pitch in the signal-exchanging part 203 of the display panel 200 to be substantially equal to that of, or an integer multiple of, the pitch in the display part 207 of the display panel 200, including without limitation, for simplicity of manufacturing, including without limitation, to permit the use of an FMM for both the signal-exchanging part 203 and the display part 207 of the display panel 200, in some non-limiting examples, a (sub-) pixel arrangement of the signal-exchanging part 203 may be altered to accommodate the introduction of transmissive regions 31x therein by altering the pitch of the (sub-) pixels 2210/32x in the signal-exchanging part 203 of the display panel 200 to a value that is a non-integer multiple of the pitch in the display part 207 of the display panel 200.

### Hybrid Approaches

Examples have been provided of various approaches to accommodate the introduction of transmissive regions 31x in the signal-exchanging part 203 of the display panel 207, including without limitation:
reducing at least one of a size, shape, and configuration of the (sub-) pixels 2210/32x in the signal-exchanging part 203 of the display panel;
reducing a number of, and/or density of (sub-) pixels 2210/32x in the signal-exchanging part 203 of the display panel; and
altering a pitch of the (sub-) pixels 2210/32x in the signal-exchanging part 203 to a value that is a non-integer multiple of a pitch in the display part 207 of the display panel 200.

Those having ordinary skill in the relevant art will appreciate that, in some non-limiting examples, a plurality of, or all of such approaches may be combined in a hybrid approach to accommodate the introduction of transmissive regions 31x in the signal-exchanging part 203 of the display panel 200.

Further, it will be appreciated that adoption of one or more of the foregoing approaches and/or a hybrid combination thereof may be combined with at least one other approach to accommodate the introduction of transmissive regions 31x in the signal-exchanging part 203 of the display panel 200 without departing from the spirit or scope of the present disclosure.

### **Introducing Transition Region(s) Between Signal-Exchanging Part and Display Cart to Reduce Apparent Difference Therebetween

In some non-limiting examples, one measure for reducing an apparent or visually perceived difference as between at least one of an aperture ratio of the emissive regions 1401, and a pixel density, in the signal-exchanging part 203 and in the display part 207 of the display panel 200 may comprise establishing at least one transition region 500 about at least one of, and/or between, the signal-exchanging part 203 and the display part 207 of the display panel 200, each having an intermediate aperture ratio, size, shape, orientation, and/or pitch of the emissive regions 1401, in order to disperse such apparent or visually perceived difference therebetween across an increased lateral aspect of the display panel 200.

In some non-limiting examples, such transition regions 500 may be introduced, whether the signal-exchanging part 203 is characterized by a pixel density that is substantially equal to that of the display part 207, wherein a reduction at least one of a size, shape, and configuration of the (sub-) pixels 2210/32x in the signal-exchanging part to accommodate the introduction of transmissive regions 31x therein, or whether the signal-exchanging part 203 is characterized by a reduction of a number of, and/or density of (sub-) pixels 2210/32x in the signal-exchanging part 203 to accommodate the introduction of transmissive regions 31x therein, or whether the signal-exchanging part 203 is characterized by an alteration of the pitch of the (sub-) pixels in the signal-exchanging part 203 of the display panel 200 to a value that is a non-integer multiple of the pitch in the display part 207 of the display panel 200, or whether the signal-exchanging part 203 is characterized by any hybrid combination of any of the foregoing.

In some non-limiting examples, the at least one transition region 500 may be arranged along a perimeter or boundary of, including without limitation, surrounding, at least one of the signal-exchanging part 203 and the display part 207.

Turning now to FIG. 5A, there is shown, in plan, a fragment 203e of the signal-exchanging part 203, a fragment 207e of the display part 207, and a fragment 500a of at least one transition region 500 extending laterally therebetween. For purposes of illustration, some example pixels 2210 are shown in dashed outline in both the display part fragment 207e and the transition region fragment 500a. It will be appreciated that between display part fragment 207e and the transition region fragment 500a shown, there may be other parts of the display panel 200, which may comprise, at least one of: (a fragment of) the same display part 207, (a fragment of) at least one different display part 207, (a fragment of) the same transition region 500, and at least one different transition region 500.

In some non-limiting examples, the pixel density of the (sub-) pixels 2210/32x in the signal-exchanging part 203 is the same as in the transition region 500 and as in the display part 207. However, from comparison of the signal-exchanging part fragment 203e, with both the transition region fragment 500a, and the display part fragment 207e, in some non-limiting examples, at least one of the size, shape, configuration, and pitch, of the (sub-) pixels 2210/32x in the transition region 500, may be changed, including without limitation, a reduction in size, relative to a corresponding at least one of the size, shape, configuration, and pitch thereof, in the display part 207, and in some non-limiting examples, at least one of the size, shape, configuration, and pitch, of the (sub-) pixels 2210/32x in the signal-exchanging part 203 may be changed, including without limitation, a reduction in size, relative to a corresponding at least one of the size, shape, configuration, and pitch thereof, in the transition region 500.

Thus, the interposition of at least one transition region 500 between the signal-exchanging part 203 and the display part 207 may facilitate reducing an apparent or visually perceived difference as between a pixel density in the signal-exchanging part 203 and the display part 207.

The sub-pixels 32x are shown, in each fragment 203e, 500a, 207e, as having a substantially square shape, with different sizes, ranging from the third sub-pixels 323 (largest), to the first sub-pixels 321, to the second sub-pixels 322 (smallest), and in a four sub-pixel (R-G-B in a 1:2:1 ratio) pixel 2210 box configuration, solely for illustrative purposes and the example discussed herein, including without limitation, any of the (sub-) pixel configurations (with or without omitted (sub-) pixels 2210/32x and/or transmissive regions 31x) in the (sub-) pixel arrangements 300, should not be considered as limiting, in any fashion, any of the size, shape, configuration, orientation, pixel density, and pitch, of the (sub-) pixels 2210/32x in either the signal-exchanging part 203, the transition region 500, or the display part 207.

The transmissive regions 31x are shown having a substantially circular shape and a substantially uniform size and orientation in each fragment, solely for illustrative purposes and the examples discussed herein, including without limitation, any of the (sub-) pixel configurations with or without omitted (sub-) pixels and/or transmissive regions 31x) in the (sub-) pixel arrangements 300, should not be considered as limiting, in any fashion, any of the size, shape, configuration, orientation, pixel density, and pitch, of the (sub-) pixels 2210/32x in either the signal-exchanging part 203, the transition region 500, or the display part 207.

Turning now to FIG. 5B, there is shown, in plan, a fragment 203f of the signal-exchanging part 203, a fragment 207f of the display part 207, and a fragment 500b of at least one transition region 500 extending laterally therebetween. From comparison of the transition region fragment 500b, with the display part 207f, in some non-limiting examples, in the transition region 500, there may be a void corresponding to three of the four sub-pixels 32x of every second pixel 2210 in the display part 207 (shown with increased transparency), where at least one transmissive region 31x may be disposed.

In some non-limiting examples, the three omitted sub-pixels 32x may correspond to any combination of three of the four sub-pixels 32x of every second pixel 2210, including without limitation, as shown, one each of the first sub-pixel 321, the second sub-pixel 322, and the third sub-pixel 323.

From comparison of the signal-exchanging part 203 with the transition region 500, in the signal-exchanging part 203, there may be a void corresponding to the remaining sub-pixel 32x of every second sub-pixel 2210 in the transition region 500 (shown with increased transparency), where at least one transmissive region 31x (of increased size) may be disposed.

Thus it may be understood that a pixel density in the transition region 500 may be substantially about 62.5% of a pixel density in the display part 207 and a pixel density in the signal-exchanging part 203 may be substantially about 50% of a pixel density in the display part 207.

While in the present disclosure, transmissive regions 31x have been shown as discrete features arranged between emissive regions 1401 in the signal-exchanging part 203 of the display panel 200, in some non-limiting examples, although not shown, at least one transmissive region 31x may be continuously formed such that it extends laterally across and substantially surrounds a plurality of emissive regions 1401.

In some non-limiting examples, there may be disposed, in at least each emissive region 1401, a plurality of layers upon a substrate 10, including a first electrode 1020 (FIG. 10) and a second electrode 1040 (FIG. 10) surrounding at least one organic and/or semiconducting layer 1030 (FIG. 10), where the electrodes 1020, 1040 may be electrically coupled with a power source 1005 (FIG. 10). When energized, one of the electrodes 1020, 1040 (“anode”) may generate electrons and the other electrode 1020, 1040 (“cathode”) may generate holes, which tend to migrate toward one another through the at least one semiconducting layer 1030 and eventually combine, to emit EM radiation, in the form of a photon, therefrom.

In some non-limiting examples, the transmissive region 31x may be configured to omit or reduce the presence of at least one layer or material to enhance the transmission of external EM radiation therethrough. In some non-limiting examples, an average layer thickness of the second electrode 1040 in the transmissive region 31x may be no more than that of another region of the display panel 200. In some non-limiting examples, an average layer thickness of the second electrode 1040 in a transmissive region 31x may be no more than an average layer thickness thereof in an emissive region 1401. In some non-limiting examples, the transmissive region 31x may be substantially devoid of a closed coating 140 of a material for forming the second electrode 1040 (“second electrode material”).

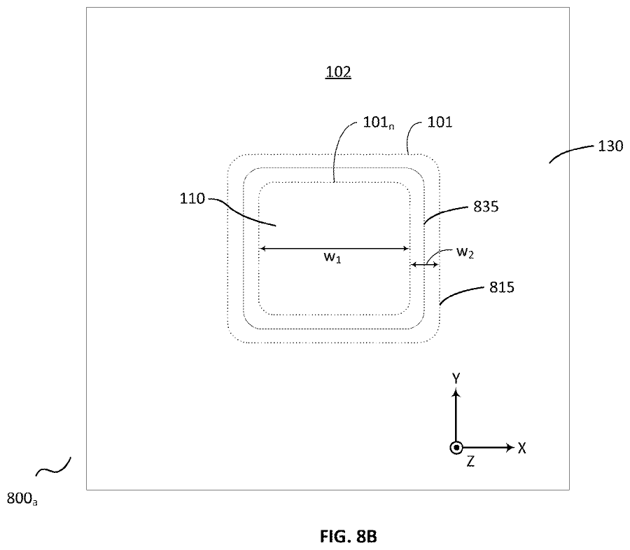

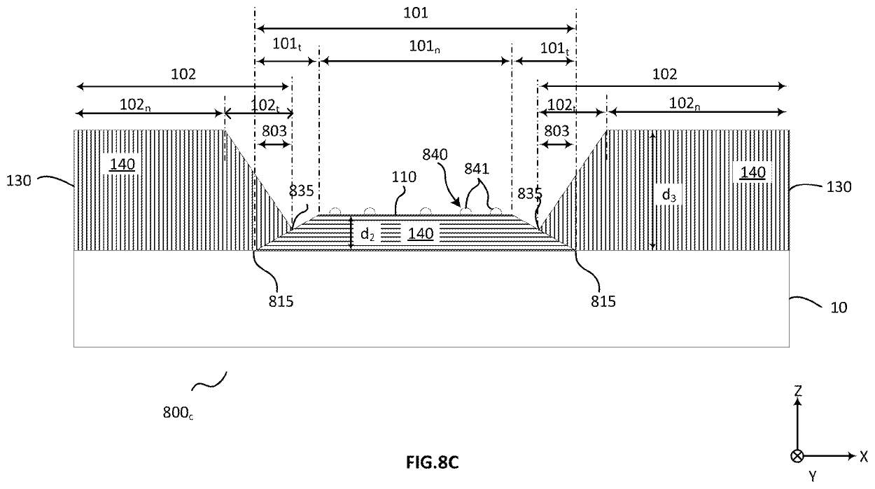

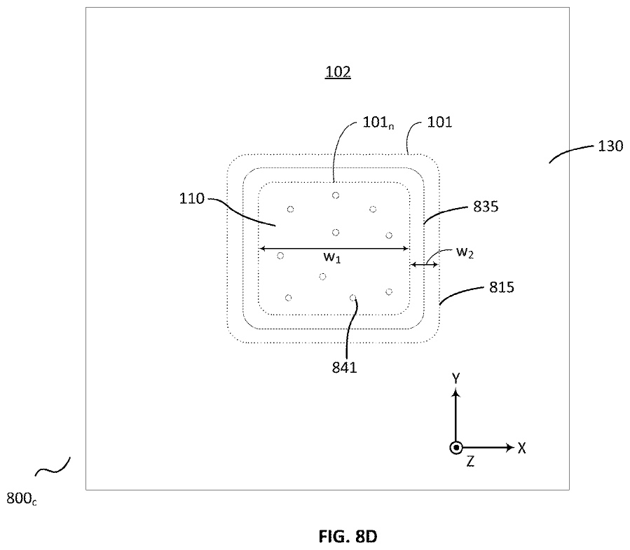

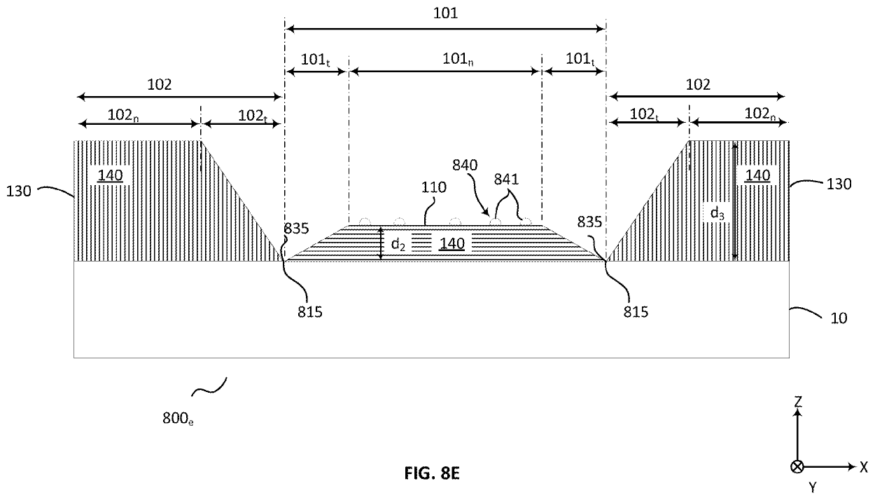

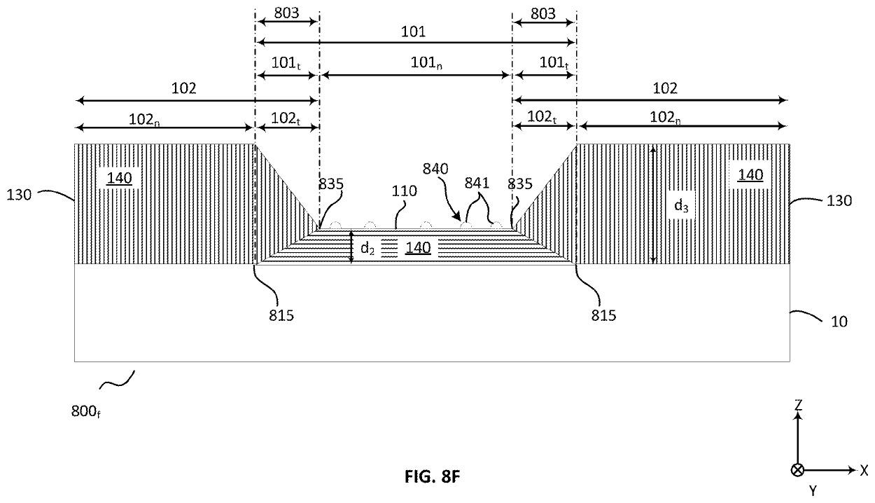

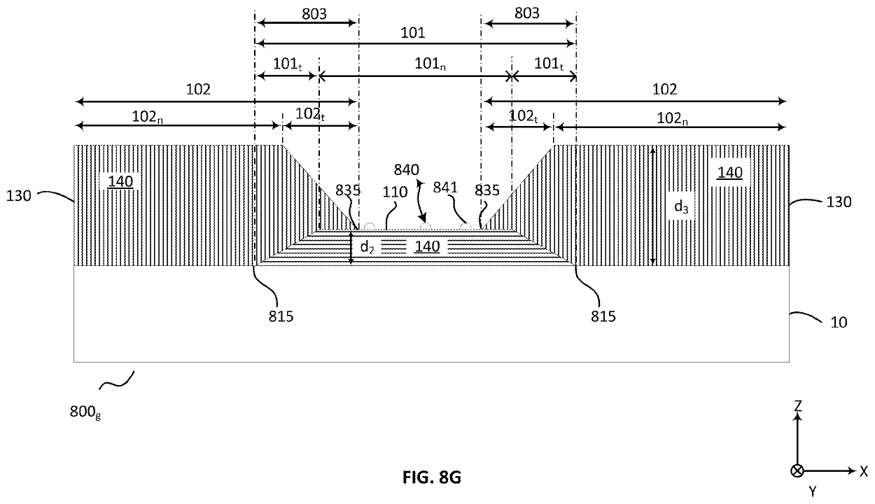

In some non-limiting examples, a region that is substantially devoid of a closed coating 140 of a second electrode material (“cathode-free region”), including without limitation, the at least one transmissive region 31x, in some non-limiting examples, may exhibit different opto-electronic characteristics from other regions, including without limitation, the at least one emissive region 1401. In some non-limiting examples, such cathode-free regions may nevertheless contain some second electrode material, including without limitation, in the form of a discontinuous layer 840 (FIG. 8C) of at least one particle structure 841 (FIG. 8C) or of at least one instance of such particle structures 841.

In some non-limiting examples, this may be achieved by laser ablation of the second electrode material. However, in some non-limiting examples, laser ablation may create a debris cloud, which may impact the vapour deposition process.

In some non-limiting examples, this may be achieved be disposing a patterning coating 110, which may, in some non-limiting examples, be a nucleation inhibiting coating (NIC), using an FMM, in a pattern on an exposed layer surface 11 of the at least one semiconducting layer 1030 prior to depositing a deposited material 731 for forming the second electrode 1040 thereon.

In some non-limiting examples, the patterning coating 110 may be adapted to impact a propensity of a vapor flux of the deposited material 731 to be deposited thereon, including without limitation, an initial sticking probability against the deposition of the deposited material 711 that is no more than an initial sticking probability against the deposition of the deposited material 731 of the exposed layer surface 11 of the at least one semiconducting layer 1030.

In some non-limiting examples, the patterning coating 110 may be deposited in a pattern that may correspond to the first portion 101 of a lateral aspect, including without limitation, of at least some of the transmissive regions 31x.

In some non-limiting examples, the patterning coating 110 may be deposited in a plurality of stages, each using a different FMM defining a different pattern within the first portion 101, that respectively correspond to a different subset 340ₐ, 340_{b} of the transmissive regions 31x.

In some non-limiting examples, the display panel 200 may, subsequent to (all of the stages of) the deposition of the patterning coating 110, be subjected to a vapor flux of the deposited material 731, in at least one of an open mask and/or mask-free deposition process, to form the second electrode 1040 for each of the emissive regions 1401 corresponding to a (sub-) pixel 34x in at least the second portion 102 of the lateral aspect, but not in the first portion 101 of the lateral aspect.

### Patterning

In some non-limiting examples, in the first portion 101, a patterning coating 110, comprising a patterning material 611, which in some non-limiting examples, may be an NIC material, may be selectively deposited as a closed coating 140 on the exposed layer surface 11 of an underlying layer, including without limitation, a substrate 10, of the device 100, only in the first portion 101. However, in the second portion 102, the exposed layer surface 11 of the underlying layer may be substantially devoid of a closed coating 140 of the patterning material 611.

### Patterning Coating

The patterning coating 110 may comprise a patterning material 611. In some non-limiting examples, the patterning coating 110 may comprise a closed coating 140 of the patterning material 611.

The patterning coating 110 may provide an exposed layer surface 11 with a relatively low propensity (including without limitation, a relatively low initial sticking probability (in some non-limiting examples, under the conditions identified in the dual QCM technique described by Walker et al.) against the deposition) of a deposited material 731 to be deposited thereon upon exposing such surface to a vapor flux of the deposited material, which, in some non-limiting examples, may be substantially less than the propensity against the deposition of the deposited material 731 to be deposited on the exposed layer surface 11 of the underlying layer of the device 100, upon which the patterning coating 110 has been deposited.

Because of the attributes, including without limitation, a low initial sticking probability, of the pattering coating 110, and/or the patterning material 611, in some non-limiting examples, when deposited as a film, and/or coating in a form, and under similar circumstances to the deposition of the patterning coating 110 within the device 100, against the deposition of the deposited material 731, the first portion 101 comprising the patterning coating 110 may be substantially devoid of a closed coating 140 of the deposited material 731.

However, exposure of the device 100 to a vapor flux of the deposited material 731 may, in some non-limiting examples, result in the formation of a closed coating 140 of a deposited layer 130 of the deposited material in the second portion 102, where the exposed layer surface 11 of the underlying layer is substantially devoid of the patterning coating 110.

Attributes of Patterning Coating and/or Patterning Material

### Initial Sticking Probability

In some non-limiting examples, the patterning coating 110, and/or the patterning material 611, in some non-limiting examples, when deposited as a film, and/or coating in a form, and under similar circumstances to the deposition of the patterning coating 110 within the device 100, may have an initial sticking probability against the deposition of the deposited material 731, that is at least one of no more than about: 0.3, 0.2, 0.15, 0.1, 0.08, 0.05, 0.03, 0.02, 0.01, 0.008, 0.005, 0.003, 0.001, 0.0008, 0.0005, 0.0003, and 0.0001.

In some non-limiting examples, the patterning coating 110, and/or the patterning material 611, in some non-limiting examples, when deposited as a film, and/or coating in a form, and under similar circumstances to the deposition of the patterning coating 110 within the device 100, may have an initial sticking probability against the deposition of silver (Ag), and/or magnesium (Mg) that is at least one of no more than about: 0.3, 0.2, 0.15, 0.1, 0.08, 0.05, 0.03, 0.02, 0.01, 0.008, 0.005, 0.003, 0.001, 0.0008, 0.0005, 0.0003, and 0.0001.

In some non-limiting examples, the patterning coating 110, and/or the patterning material 611, in some non-limiting examples, when deposited as a film, and/or coating in a form, and under similar circumstances to the deposition of the patterning coating 110 within the device 100, may have an initial sticking probability against the deposition of a deposited material 731 of at least one of between about: 0.15-0.0001, 0.1-0.0003, 0.08-0.0005, 0.08-0.0008, 0.05-0.001, 0.03-0.0001, 0.03-0.0003, 0.03-0.0005, 0.03-0.0008, 0.03-0.001, 0.03-0.005, 0.03-0.008, 0.03-0.01, 0.02-0.0001, 0.02-0.0003, 0.02-0.0005, 0.02-0.0008, 0.02-0.001, 0.02-0.005, 0.02-0.008, 0.02-0.01, 0.01-0.0001, 0.01-0.0003, 0.01-0.0005, 0.01-0.0008, 0.01-0.001, 0.01-0.005, 0.01-0.008, 0.008-0.0001, 0.008-0.0003, 0.008-0.0005, 0.008-0.0008, 0.008-0.001, 0.008-0.005, 0.005-0.0001, 0.005-0.0003, 0.005-0.0005, 0.005-0.0008, and 0.005-0.001.

In some non-limiting examples, the patterning coating 110, and/or the patterning material 611, in some non-limiting examples, when deposited as a film, and/or coating in a form, and under similar circumstances to the deposition of the patterning coating 110 within the device 100, may have an initial sticking probability against the deposition of a plurality of deposited materials 731 that is no more than a threshold value. In some non-limiting examples, such threshold value may be at least one of about: 0.3, 0.2, 0.18, 0.15, 0.13, 0.1, 0.08, 0.05, 0.03, 0.02, 0.01, 0.008, 0.005, 0.003, and 0.001.

In some non-limiting examples, the patterning coating 110, and/or the patterning material 611, in some non-limiting examples, when deposited as a film, and/or coating in a form, and under similar circumstances to the deposition of the patterning coating 110 within the device 100, may have an initial sticking probability that is less than such threshold value against the deposition of a plurality of deposited materials 731 selected from at least one of: Ag, Mg, ytterbium (Yb), cadmium (Cd), and zinc (Zn). In some further non-limiting examples, the patterning coating 110 may exhibit an initial sticking probability of or below such threshold value against the deposition of a plurality of deposited materials 731 selected from at least one of: Ag, Mg, and Yb.

In some non-limiting examples, the patterning coating 110, and/or the patterning material 611, in some non-limiting examples, when deposited as a film, and/or coating in a form, and under similar circumstances to the deposition of the patterning coating 110 within the device 100, may exhibit an initial sticking probability against the deposition of a first deposited material 731 of, or below, a first threshold value, and an initial sticking probability against the deposition of a second deposited material 731 of, or below, a second threshold value. In some non-limiting examples, the first deposited material 731 may be Ag, and the second deposited material 731 may be Mg. In some other non-limiting examples, the first deposited material 731 may be Ag, and the second deposited material may be Yb. In some other non-limiting examples, the first deposited material 731 may be Yb, and the second deposited material 731 may be Mg. In some non-limiting examples, the first threshold value may exceed the second threshold value.

In some non-limiting examples, there may be scenarios calling for providing a patterning coating 110 for causing formation of a discontinuous layer 840 of at least one particle structure 841, upon the patterning coating 110 being subjected to a vapor flux of a deposited material 731. In at least some applications, the pattering coating 110 may exhibit a sufficiently low initial sticking probability such that a closed coating 140 of the deposited material may be formed in the second portion 102, which may be substantially devoid of the patterning coating 110, while the discontinuous layer 840 of at least one particle structure 841 having at least one characteristic may be formed in the first portion 101 on the pattering coating 110. In some non-limiting examples, there may be scenarios calling for formation of a discontinuous layer 840 of at least one particle structure 841 of a deposited material 731, which may be, in some non-limiting examples, of a metal or metal alloy, in the second portion 102, while depositing a closed coating 140 of the deposited material 731 having a thickness of, for example, at least one of no more than about: 100 nm, 50 nm, 25 nm, and 15 nm. In some non-limiting examples, a relative amount of the deposited material 731 deposited as a discontinuous layer 840 of at least one particle structure 841 in the first portion 101 may correspond to one of between about: 1-50%, 2-25%, 5-20%, and 7-10% of the amount of the deposited material 731 deposited as a closed coating 140 in the second portion 102, which in some non-limiting examples may correspond to a thickness of at least one of no more than about: 100 nm, 75 nm, 50 nm, 25 nm, and 15 nm.

Without wishing to be bound by any particular theory, it has now been found that a patterning coating 110 containing a material which, when deposited as a thin film, exhibits a relatively high surface energy, may, in some non-limiting examples, form a discontinuous layer 840 of at least one particle structure 841 of a deposited material 731 in the first portion 101, and a closed coating 140 of the deposited material 731 in the second portion 202, including without limitation, in cases where the thickness of the closed coating is, by way of non-limiting example, no more than at least one of about: 100 nm, 75 nm, 50 nm, 25 nm, and 15 nm.

### Transmittance

In some non-limiting examples, the patterning coating 110, and/or the patterning material 611, in some non-limiting examples, when deposited as a film, and/or coating in a form, and under circumstances similar to the deposition of the patterning coating 110 within the device 100 may have a transmittance for EM radiation of at least a threshold transmittance value, after being subjected to a vapor flux of the deposited material 731, including without limitation, Ag.

In some non-limiting examples, such transmittance may be measured after exposing the exposed layer surface 11 of the patterning coating 110 and/or the patterning material 611, formed as a thin film, to a vapor flux of the deposited material 731, including without limitation, Ag, under typical conditions that may be used for depositing an electrode of an opto-electronic device, which in some non-limiting examples, may be a cathode of an organic light-emitting diode (OLED) device.

In some non-limiting examples, the conditions for subjecting the exposed layer surface 11 to the vapor flux of the deposited material 731, including without limitation, Ag, may be as follows: (i) vacuum pressure of one of about: 10⁻⁴ Torr and 10⁻⁵ Torr; (ii) the vapor flux of the deposited material 731, including without limitation, Ag being substantially consistent with a reference deposition rate of about 1 angstrom (Å)/sec, which in some non-limiting examples, may be monitored and/or measured using a QCM; (iii) the vapor flux of the deposited material 731 is directed toward the exposed layer surface 11 at an angle that is substantially close to orthogonal to a plane of the exposed layer surface 11; and (iv) the exposed layer surface 11 being subjected to the vapor flux of the deposited material 731, including without limitation, Ag until a reference average layer thickness of about 15 nm is reached, and upon such reference average layer thickness being attained, the exposed layer surface 11 not being further subjected to the vapor flux of the deposited material, including without limitation, Ag.

In some non-limiting examples, the exposed layer surface 11 being subjected to the vapor flux of the deposited material 731, including without limitation, Ag, may be substantially at room temperature (e.g. about 25° C.). In some non-limiting examples, the exposed layer surface 11 being subjected to the vapor flux of the deposited material 731, including without limitation, Ag, may be positioned about 65 cm away from an evaporation source by which the deposited material 731, including without limitation, Ag, is evaporated.

In some non-limiting examples, the threshold transmittance value may be measured at a wavelength in the visible spectrum. In some non-limiting examples, the threshold transmittance value may be measured at a wavelength of about 460 nm. In some non-limiting examples, the threshold transmittance value may be measured at a wavelength in the IR and/or NIR spectrum. In some non-limiting examples, the threshold transmittance value may be measured at a wavelength of one of about: 700 nm, 900 nm, and 1,000 nm. In some non-limiting examples, the threshold transmittance value may be expressed as a percentage of incident EM power that may be transmitted through a sample. In some non-limiting examples, the threshold transmittance value may be at least one of at least about: 60%, 65%, 70%, 75%, 80%, 85%, and 90%.

In some non-limiting examples, there may be a positive correlation between the initial sticking probability of the patterning coating 110, and/or the patterning material 611, in some non-limiting examples, when deposited as a film, and/or coating in a form, and under circumstances similar to the deposition of the patterning coating 110 within the device 100, against the deposition of the deposited material 731 and an average layer thickness of the deposited material 731 thereon.

It would be appreciated by a person having ordinary skill in the relevant art that high transmittance may generally indicate an absence of a closed coating 140 of the deposited material 731, which in some non-limiting examples, may be Ag. On the other hand, low transmittance may generally indicate presence of a closed coating 140 of the deposited material 731, including without limitation, at least one of: Ag, Mg, and Yb, since metallic thin films, particularly when formed as a closed coating 140, may exhibit a high degree of absorption of EM radiation.

It may be further postulated that exposed layer surfaces 11 exhibiting low initial sticking probability with respect to the deposited material 731, including without limitation, Ag, Mg, and Yb, may exhibit high transmittance. On the other hand, exposed layer surfaces 11 exhibiting high sticking probability with respect to the deposited material 731, including without limitation, Ag, Mg, and Yb, may exhibit low transmittance.

A series of samples was fabricated to measure the transmittance of an example material, as well as to visually observe whether or not a closed coating 140 of Ag was formed on the exposed layer surface 11 of such example material. Each sample was prepared by depositing, on a glass substrate 10, an approximately 50 nm thick coating of an example material, then subjecting the exposed layer surface 11 of the coating to a vapor flux 732 of Ag at a rate of about 1 Å/sec until a reference layer thickness of about 15 nm was reached. Each sample was then visually analyzed and the transmittance through each sample was measured.

The molecular structures of the example materials used in the samples herein are set out in Table 1 below:

TABLE 1

| Material | Molecular Structure/Name |
|---|---|
| HT211 | 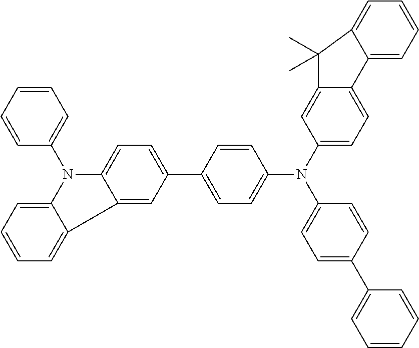 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21] |
| HT01 | 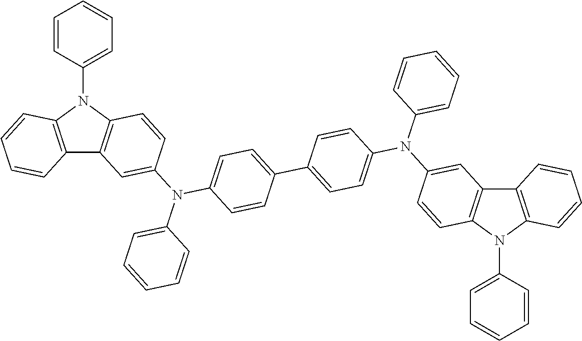 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1] |
| TAZ | 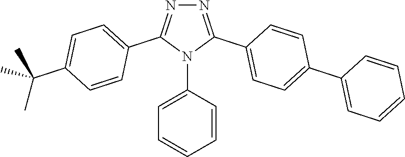 |
| Balq | 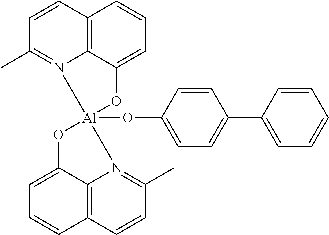 |
| Liq | 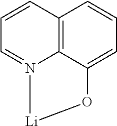 |
| Example Material 1 | 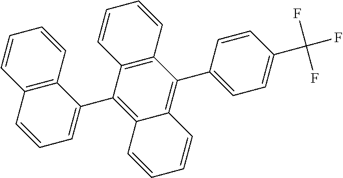 [SMILES: FC(F)(F)c1ccc(-c2c3ccccc3c(-c3cccc4ccccc34)c3ccccc23)cc1] |
| Example Material 2 | 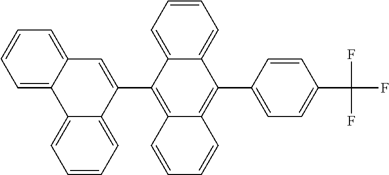 [SMILES: FC(F)(F)c1ccc(-c2c3ccccc3c(-c3cc4ccccc4c4ccccc34)c3ccccc23)cc1] |
| Example Material 3 | 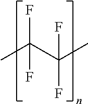 |
| Example Material 4 | 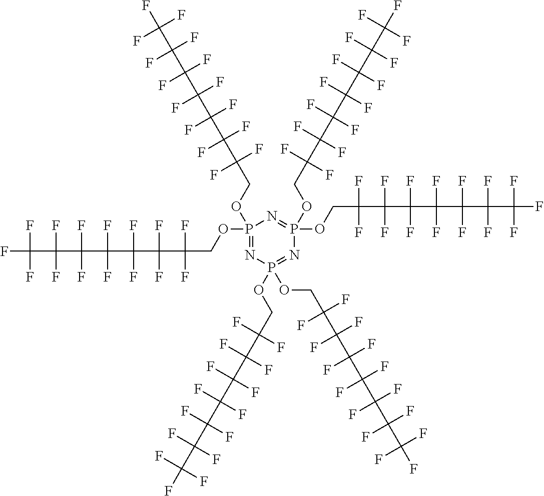 [SMILES: FC(F)(F)C(F)(F)C(F)(F)C(F)(F)C(F)(F)C(F)(F)C(F)(F)COP1(OCC(F)(F)C(F)(F)C(F)(F)C(F)(F)C(F)(F)C(F)(F)C(F)(F)F)=NP(OCC(F)(F)C(F)(F)C(F)(F)C(F)(F)C(F)(F)C(F)(F)C(F)(F)F)(OCC(F)(F)C(F)(F)C(F)(F)C(F)(F)C(F)(F)C(F)(F)C(F)(F)F)=NP(OCC(F)(F)C(F)(F)C(F)(F)C(F)(F)C(F)(F)C(F)(F)C(F)(F)F)(OCC(F)(F)C(F)(F)C(F)(F)C(F)(F)C(F)(F)C(F)(F)C(F)(F)F)=N1] |
| Example Material 5 | 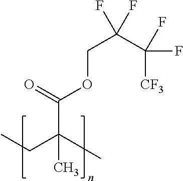 |
| Example Material 6 | 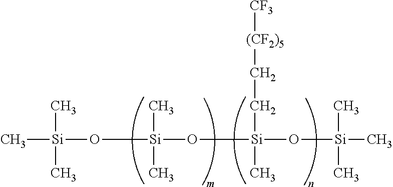 |
| Example Material 7 | 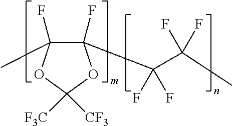 |
| Example Material 8 | 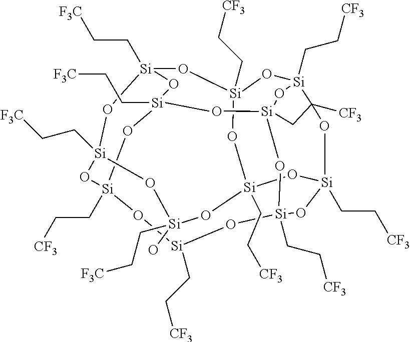 |
| Example Material 9 | 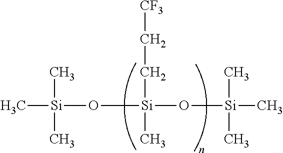 |

The samples in which a substantially closed coating 140 of Ag had formed were visually identified, and the presence of such coating in these samples was further confirmed by measurement of transmittance therethrough, which showed transmittance of no more than about 50% at a wavelength of about 460 nm.

The samples in which no closed coating 140 of Ag had formed were also identified, and the absence of such coating in these samples was further confirmed by measurement of transmittance therethrough, which showed transmittance in excess of about 70% at a wavelength of about 460 nm.

The results are summarized in Table 2 below:

TABLE 2

| Material | Closed Coating of Ag? |
|---|---|
| HT211 | Present |
| HT01 | Present |
| TAZ | Present |
| Balq | Present |
| Liq | Present |
| Example Material 1 | Present |
| Example Material 2 | Present |
| Example Material 3 | Not Present |
| Example Material 4 | Not Present |
| Example Material 5 | Not Present |
| Example Material 6 | Not Present |
| Example Material 7 | Not Present |
| Example Material 8 | Not Present |
| Example Material 9 | Not Present |

Based on the foregoing, it was found that the materials used in the first 7 samples in Tables 1 and 2 (HT211 to Example Material 2) may be less suitable for inhibiting the deposition of the deposited material 731 thereon, including without limitation, Ag, and/or Ag-containing materials.

On the other hand, it was found that Example Material 3 to Example Material 9 may be suitable, at least in some non-limiting applications, to act as a patterning coating 110 for inhibiting the deposition of the deposited material 731 thereon, including without limitation, Ag, and/or Ag-containing materials.

### Deposition Contrast

In some non-limiting examples, a material, including without limitation, a patterning material 611, that may function as an NIC for a given at least one of: a metal and an alloy (metaValloy), including without limitation, at least one of: Mg, Ag, and MgAg, may have a substantially high deposition contrast when deposited on a substrate 10.

In some non-limiting examples, if a substrate 10 tends to act as a nucleation promoting coating (NPC) 920, and a portion thereof is coated with a material, including without limitation, a patterning material 611, that may tend to function as an NIC against deposition of a given metal/alloy, including without limitation, at least one of: Mg, Ag, and MgAg, a coated portion (first portion 101) and an uncoated portion (second portion 102) may tend to have different initial sticking probabilities and/or nucleation rates, such that the metaValloy deposited thereon may tend to have different average film thicknesses.

As used herein, a deposition contrast may generally refer to a ratio of an average film thickness between the first portion 101 and the second portion 102 of the substrate 10. Thus, if the deposition contrast is substantially high, the average film thickness of the metaValloy in the second portion 102 may be substantially greater than the average film thickness of the metaValloy in the first portion 101.

In some non-limiting examples, if the deposition contrast is substantially high, there may be little to no metal/alloy deposited in the first portion 101, when there is sufficient deposition of the metaValloy so as to form a closed coating 140 thereof in the second portion 102.

In some non-limiting examples, if the deposition contrast is substantially low, there may be a discontinuous layer 840 of at least one particle structure 841 of the metaValloy deposited in the first portion 101, when there is sufficient deposition of the metaValloy so as to form a closed coating 140 in the second portion 102.

In some non-limiting examples, a material, including without limitation, a patterning material 611, having a substantially high deposition contrast against deposition of a given metaValloy, including without limitation, at least one of: Mg, Ag, and MgAg, may have reduced applicability in some scenarios calling for a reduced deposition contrast, in some non-limiting examples, where the average layer thickness of the metaValloy in the first portion 101 is substantially low, including without limitation, one of no more than about: 100 nm, 50 nm, 25 nm, and 15 nm, including without limitation, in some scenarios that call for a deposition of a discontinuous layer 840 of at least one particle structure 841 in the second portion 102.

In some non-limiting examples, there may be scenarios calling for the formation of a discontinuous layer 840 of at least one particle structure 841 of the metaValloy in the second portion 102, when an average layer thickness of a closed coating 140 of the metal/alloy in the first portion 101 is substantially small, including without limitation, one of no more than about: 100 nm, 50 nm, 25 nm, and 15 nm, including without limitation, the formation of nanoparticles (NPs) in the second portion 102, where absorption of EM radiation by such NPs is called for, including without limitation, to protect an underlying layer from EM radiation having a wavelength of no more than about 460 nm.

In some non-limiting examples, in such scenarios, there may be applicability for a deposition contrast of one of between about: 2-100, 4-50, 5-20, and 10-15.

In some non-limiting examples, a material, including without limitation, a patterning material 611, having a substantially low deposition contrast against deposition of a given metaValloy, including without limitation, at least one of: Mg, Ag, and MgAg, may have reduced applicability in some scenarios calling for substantially high deposition contrast, including without limitation, where the average layer thickness of the metaValloy in the first portion 101 is large, including without limitation, one of at least about: 95 nm, 45 nm, 20 nm, 10 nm, and 8 nm.

In some non-limiting examples, a material, including without limitation, a patterning material 611, having a substantially low deposition contrast against deposition of a given metaValloy, including without limitation, at least one of: Mg, Ag, and MgAg, may have reduced applicability in some scenarios calling for substantially high deposition contrast, including without limitation, scenarios calling for the substantial absence of a continuous coating 140, or a high density of, particle structures 841 in the first portion 101, including without limitation, when an average layer thickness of the metaValloy in the first portion 101 is large, including without limitation, one of at least about: 95 nm, 45 nm, 20 nm, 10 nm, and 8 nm, including without limitation, in some scenarios calling for the substantial absence of absorption of EM radiation in at least one of the visible spectrum and the NIR spectrum, including without limitation, scenarios calling for an increased transparency to EM radiation having a wavelength that is at least about 460 nm.

In some non-limiting examples, a material, including without limitation, a patterning material 611, against the deposition of a given metaValloy, including without limitation, at least one of: Mg, Ag, and MgAg, may have applicability in some scenarios calling for a discontinuous layer 840 of, or a low density of, particle structures 841 of the metaValloy in the first portion 101, when an average layer thickness of a closed coating 140 of the metaValloy in the second portion 102 is substantially high, including without limitation, one of at least about: 95 nm, 45 nm, 20 nm, 10 nm, and 8 nm. By way of non-limiting example, a deposition contrast of one of between about: 2-100, 4-50, 5-20, and 10-15 may have applicability in some scenarios when an average layer thickness of the metaValloy in the second portion 102 is substantially high, including without limitation, one of at least about: 95 nm, 45 nm, 20 nm, 10 nm, and 8 nm.

In some non-limiting examples, a material, including without limitation, a patterning material 611, may tend to have a substantially low deposition contrast if the initial sticking probability of such material against deposition of a metal/alloy, including without limitation, at least one of: Mg, Ag, and MgAg, is substantially high.

### Surface Energy

A characteristic surface energy, as used herein particularly with respect to a material, may generally refer to a surface energy determined from such material. In some non-limiting examples, a characteristic surface energy may be measured from a surface formed by the material deposited and/or coated in a thin film form. Various methods and theories for determining the surface energy of a solid are known. In some non-limiting examples, a surface energy may be calculated or derived based on a series of contact angle measurements, in which various liquids may be brought into contact with a surface of a solid to measure the contact angle between the liquid-vapor interface and the surface. In some non-limiting examples, a surface energy of a solid surface may be equal to the surface tension of a liquid with the highest surface tension that completely wets the surface. In some non-limiting examples, a Zisman plot may be used to determine a highest surface tension value that would result in complete wetting (i.e. a contact angle of 0°) of the surface.

In some non-limiting examples, the critical surface tension of a surface may be determined according to the Zisman method, as further detailed in W. A. Zisman, Advances in Chemistry 43 (1964), pp. 1-51.

By way of non-limiting example, a series of samples was fabricated to measure the critical surface tension of the surfaces formed by the various materials. The results of the measurement are summarized in Table 3 below:

TABLE 3

| Material | Critical Surface Tension (dynes/cm) |
|---|---|
| HT211 | 25.6 |
| HT01 | >24 |
| TAZ | 22.4 |
| Balq | 25.9 |
| Liq | 24 |
| Example Material 1 | 26.3 |
| Example Material 2 | 24.8 |
| Example Material 3 | 19 |
| Example Material 4 | 7.6 |
| Example Material 5 | 15.9 |
| Example Material 6 | <20 |
| Example Material 7 | 13.1 |
| Example Material 8 | 20 |
| Example Material 9 | 18.9 |

Based on the foregoing measurement of the critical surface tension in Table 3 and the previous observation regarding the presence or absence of a substantially closed coating 140 of Ag, it was found that materials that form low surface energy surfaces when deposited as a coating, which by way of non-limiting example, may be those having a critical surface tension of at least one of between about: 13-20 dynes/cm, or 13-19 dynes/cm, may be suitable for forming the patterning coating 110 to inhibit deposition of a deposited material 731 thereon, including without limitation, Ag, and/or Ag-containing materials.

Without wishing to be bound by any particular theory, it may be postulated that materials that form a surface having a surface energy lower than, by way of non-limiting example, about 13 dynes/cm, may be less suitable as a patterning material 611 in certain applications, as such materials may exhibit relatively poor adhesion to layer(s) surrounding such materials, exhibit a low melting point, and/or exhibit a low sublimation temperature.

In some non-limiting examples, the surface energy in a material, including without limitation, a patterning material 611, in a coating, including without limitation, a patterning coating 110, may be determined by depositing the material as a neat coating on a substrate 10 and measuring a contact angle thereof with a suitable series of probe liquids.

In some non-limiting examples, a patterning material 611 that may tend to function as an NIC for a given metal/alloy, including without limitation, at least one of: Mg, Ag, and MgAg, may tend to exhibit a substantially low surface energy when coated on an exposed layer surface 11.

In some non-limiting examples, a material, including without limitation, a patterning material 611, may tend to exhibit a substantially low surface energy when deposited as a thin film or coating on an exposed layer surface 11.

In some non-limiting examples, a material, including without limitation, a patterning material 611, with a substantially low surface energy may tend to exhibit substantially low inter-molecular forces.

In some non-limiting examples, a material, including without limitation, a patterning material 611, may tend to have a substantially high initial sticking probability against deposition of the metal/alloy, if the material has a substantially high surface energy.

In some non-limiting examples, there may be scenarios calling for a pattering material 611 that has a substantially low surface energy that is not unduly low.

In some non-limiting examples, a material, including without limitation, a pattering material 611, with a substantially high surface energy may have applicability for some scenarios to detect a film of such material using optical techniques.

Without wishing to be bound by any particular theory, it may be postulated that, in some non-limiting examples, a material, including without limitation, a patterning material 611, having a substantially high surface energy may have applicability for some scenarios that call for substantially high temperature reliability.

In some non-limiting examples, a patterning material 611 that has a substantially low surface tension that is not unduly low, may have applicability in some scenarios calling for a substantially high melting point.

In some non-limiting examples, a patterning coating 110 having a substantially low surface energy and a substantially high melting point may have applicability in some scenarios calling for high temperature reliability. In some non-limiting examples, there may be challenges in achieving such a combination from a single material given that in some non-limiting examples, a unitary material having a low surface energy may tend to exhibit a low melting point.

In some non-limiting examples, a material, including without limitation, a patterning material 611, having a substantially low surface energy may have applicability in some scenarios calling for weak, or substantially no, photoluminescence or absorption in a wavelength range that is one of at least about: 365 nm and 460 nm.

In some non-limiting examples, a material, including without limitation, a patterning material 611, that may function as an NIC for a given metaValloy, including without limitation, at least one of Mg, Ag, and MgAg, having a substantially high surface energy may have applicability in some scenarios calling for a discontinuous layer 840 of particle structures 841 of the metaValloy in the first portion 101, when an average layer thickness of a continuous coating 140 of the metaValloy in the second portion 102 is substantially low, including without limitation, one of no more than about: 100 nm, 50 nm, 25 nm, and 15 nm.

In some non-limiting examples, a material, including without limitation, a patterning material 611, that may function as an NIC for a given metaValloy, including without limitation, at least one of Mg, Ag, and MgAg, having a substantially low surface energy may have applicability in some scenarios calling for a discontinuous layer 840 of, or a low density of, particle structures 841 of the metaValloy in the first portion 101, when an average layer thickness of a continuous coating 140 of the metaValloy in the second portion 102 is substantially high, including without limitation, one of at least about: 95 nm, 45 nm, 20 nm, 10 nm, and 8 nm.

In some non-limiting examples, the surface of the NIC and/or patterning coating containing the compounds described herein may exhibit a surface energy of one of no more than at least one of about: 24 dynes/cm, 22 dynes/cm, 20 dynes/cm, 19 dynes/cm, 18 dynes/cm, 16 dynes/cm, 15 dynes/cm, 13 dynes/cm, 12 dynes/cm, and 11 dynes/cm. In some non-limiting examples, the surface values in various non-limiting examples herein may correspond to such values measured at around normal temperature and pressure (NTP), which may correspond to a temperature of 20° C., and an absolute pressure of 1 atm.

In some non-limiting examples, the surface energy may be at least one of at least about: 6 dynes/cm, 7 dynes/cm, and 8 dynes/cm.

In some non-limiting examples, the surface energy may be at least one of between about: 10-22 dynes/cm, 11-21 dynes/cm, 13-20 dynes/cm, and 13-19 dynes/cm.

Without wishing to be bound by any particular theory, it may be postulated that materials that form a surface having a surface energy of no more than, in some non-limiting examples, about 13 dynes/cm, may reduced applicability as a patterning material 611 in some scenarios, as such materials may exhibit substantially low adhesion to layer(s) surrounding such materials, exhibit a substantially low melting point, and/or exhibit a substantially low sublimation temperature.

It has also now been found, somewhat surprisingly, that patterning coating 110 formed by a compound exhibiting a relatively low surface energy may also exhibit a relatively low refractive index, n.

### Temperature

### Glass Transition Temperature

In some non-limiting examples, the patterning coating 110, and/or the patterning material 611, in some non-limiting examples, when deposited as a film, and/or coating in a form, and under circumstances similar to the deposition of the patterning coating 110 within the device 100, may have a glass transition temperature that is one of: (i) one of at least about: 300° C., 150° C., and 130° C., and (ii) one of no more than about: 30° C., 0° C., −30° C., and −50° C.

### Sublimation Temperature

In some non-limiting examples, a material, including without limitation, a patterning material 611, having substantially low inter-molecular forces may tend to exhibit a substantially low sublimation temperature.

In some non-limiting examples, a material, including without limitation, a patterning material 611, having a substantially low sublimation temperature, may have reduced applicability for manufacturing processes that may call for substantially precise control of an average layer thickness in a deposited film of the material.

In some non-limiting examples, a material, including without limitation, a patterning material 611, having a sublimation temperature that is one of no more than about: 140° C., 120° C., 110° C., 100° C. and 90° C., may tend to encounter constraints on at least one of: the deposition rate and the average layer thickness, of a film comprising such material that may be deposited using known deposition methods, including without limitation, vacuum thermal evaporation.

In some non-limiting examples, a material, including without limitation, a pattering material 611, may have applicability in some scenarios calling for substantially high precision in the control of the average layer thickness of a film comprising such material.

In some non-limiting examples, a material, including without limitation, a pattering material 611, having a surface tension that is substantially low, but not unduly low, may have applicability in some scenarios that call for a substantially high sublimation temperature.

In some non-limiting examples, a coating, including without limitation, a patterning coating 110, comprised of a material, including without limitation, a patterning material 611, having a substantially low surface energy and a substantially high sublimation temperature may have application in some scenarios calling for substantially high precision in the control of the average layer thickness of a film comprising such material.

In some non-limiting examples, the patterning material may have a sublimation temperature of at least one of between about: 100-320° C., 120-300° C., 140-280° C., and 150-250° C. In some non-limiting examples, such sublimation temperature may allow the patterning material 611 to be substantially readily deposited as a coating using PVD.

In some non-limiting examples, a material with substantially low intermolecular forces may exhibit a substantially low sublimation temperature. In some non-limiting examples, a material having a substantially low sublimation temperature, may have reduced applicability for manufacturing processes that call for a substantially high degree of control over a layer thickness of a deposited film of the material. In some non-limiting examples, for materials with sublimation temperature of one of no more than about: 140° C., 120° C., 110° C., 100° C., and 90° C., there may be constraints imposed in controlling the deposition rate and layer thickness of a film deposited using deposition methods, including without limitation, vacuum thermal evaporation. In some non-limiting examples, a material with substantially high sublimation temperature may have application in some scenarios that call for a substantially high degree of control over the film thickness.

The sublimation temperature of a material, including without limitation, a patterning material 611, may be determined using various methods apparent to those having ordinary skill in the relevant art, including without limitation, by heating the material under substantially high vacuum in a crucible and by determining a temperature that may be attained, to:
observe commencement of the deposition of the material onto an exposed layer surface 11 on a QCM mounted a fixed distance from the crucible;
observe a specific deposition rate, in some non-limiting examples, 0.1 Å/sec, onto an exposed layer surface 11 on a QCM mounted a fixed distance from the crucible; and/or
reach a threshold vapor pressure of the material, in some non-limiting examples, about 10⁻⁴ or 10⁻⁵ Torr.

In some non-limiting examples, the sublimation temperature of a material, including without limitation, a patterning material 611, may be determined by heating the material in an evaporation source under a substantially high vacuum environment, in some non-limiting examples, about 10⁻⁴ Torr, and by determining a temperature that may be attained to cause the material to evaporate, thus generating a vapor flux sufficient to cause deposition of the material, in some non-limiting examples, at a deposition rate of about 0.1 Å/sec onto an exposed layer surface 11 on a QCM mounted a fixed distance from the source.

In some non-limiting examples, the QCM may be mounted about 65 cm away from the crucible for the purpose of determining the sublimation temperature.

In some non-limiting examples, the patterning material 611 may have a sublimation temperature of one of between about: 100-320° C., 100-300° C., 120-300° C., 100-250° C., 140-280° C., 120-230° C., 130-220° C., 140-210° C., 140-200° C., 150-250° C., and 140-190° C.

### Melting Point

In some non-limiting examples, a material, including without limitation, a patterning material 611, with substantially low inter-molecular forces may tend to exhibit a substantially low melting point.

In some non-limiting examples, a material, including without limitation, a patterning material 611, having a substantially low melting point may have reduced applicability in some scenarios calling for substantial temperature reliability for temperatures of one of no more than about: 60° C., 80° C., and 100° C., in some non-limiting examples, because of changes in physical properties of such material at operating temperatures that approach the melting point.

In some non-limiting examples, a material with a melting point of about 120° C. may have reduced applicability in some scenarios calling for substantially high temperature reliability, including without limitation, of at least about: 100° C.

In some non-limiting examples, a material, including without limitation, a patterning material 611, having a substantially high melting point may have applicability in some scenarios calling for substantially high temperature reliability.

In some non-limiting examples, the patterning coating 110 and/or the compound thereof may have a melting temperature that is one of at least about: 90° C., 100° C., 110° C., 120° C., 140° C., 150° C., and 180° C.

### Cohesion Energy

According to Young's equation, the cohesion energy (or fracture toughness or cohesion strength) of a material may tend to be proportional to its surface energy (cf. Young, Thomas (1805) “An essay on the cohesion of fluids”, Philosophical Transactions of the Royal Society of London, 95: 65-87).

According to Lindemann's criterion, the cohesive energy of a material may tend to be proportional to its melting temperature [Nanda, K. K., Sahu, S. N, and Behera, S. N (2002), “Liquid-drop model for the size-dependent melting of low-dimensional systems” Phys. Rev. A. 66 (1): 013208].

In some non-limiting examples, a material, including without limitation, a patterning material 611, having substantially low inter-molecular forces may tend to exhibit a substantially low cohesion energy.

In some non-limiting examples, a material, including without limitation, a patterning material 611, having a substantially low cohesion energy may have reduced applicability in some scenarios that call for substantial fracture toughness, including without limitation, in a device that may tend to undergo at least one of sheer and bending stress during at least one of manufacture and use, as such material may tend to crack or fracture in such scenarios. In some non-limiting examples, a material, including without limitation, a patterning material 611, having a cohesion energy of no more than about 30 dynes/cm may have reduced applicability in some scenarios in a device manufactured on a flexible substrate 10.

In some non-limiting examples, a material, including without limitation, a patterning material 611, that has a substantially high cohesion energy, may have applicability in some scenarios calling for substantially high reliability under at least one of sheer and bending stress, including without limitation, a device manufactured on a flexible substrate 10.

In some non-limiting examples, a material, including without limitation, a patterning material 611, having a surface energy that is substantially low but is not unduly low may have applicability in some scenarios that call for substantial reliability under at least one of sheer and bending stress, including without limitation, a device manufactured on a flexible substrate 10.

In some non-limiting examples, a material, including without limitation, a patterning material 611, having a substantially low surface energy and a substantially high cohesion energy may have applicability in some scenarios that call for substantially high reliability under at least one of sheer and bending stress. In some non-limiting examples, there may be challenges in achieving such a combination from a single material, given that, in some non-limiting examples, a unitary material having a substantially low surface energy may tend to exhibit a substantially low cohesion energy.

In some non-limiting examples, a coating, including without limitation, a patterning coating 110, having a substantially low surface energy, a substantially high cohesion energy and a substantially high melting point may have applicability in some scenarios that call for substantially high reliability under various conditions. In some non-limiting examples, there may be challenges in achieving such a combination from a single material, given that, in some non-limiting examples, a unitary material having a substantially low surface energy may tend to exhibit a substantially low cohesion energy and a substantially low melting point.

### Optical or Band Gap

In the present disclosure, a semiconductor material may be described as a material that generally exhibits a band gap. In some non-limiting examples, the band gap may be formed between a highest occupied molecular orbital (HOMO) and a lowest unoccupied molecular orbital (LUMO) of the semiconductor material. Semiconductor materials may thus tend to exhibit electrical conductivity that is substantially no more than that of a conductive material (including without limitation, a metal), but that is substantially at least as great as an insulating material (including without limitation, glass). In some non-limiting examples, the semiconductor material may comprise an organic semiconductor material. In some non-limiting examples, the semiconductor material may comprise an inorganic semiconductor material.

In some non-limiting examples, a material, including without limitation, a patterning material 611, having a substantially low surface energy may tend to exhibit a substantially large or wide optical gap. In some non-limiting examples, the optical gap of a material, including without limitation, a patterning material 611, may tend to correspond to the HOMO-LUMO gap of the material.

In some non-limiting examples, a material, including without limitation, a patterning material 611, having a substantially large or wide optical gap (and/or HOMO-LUMO gap) may tend to exhibit a substantially weak, or substantially no, photoluminescence in at least one of: the deep B(lue) region of the visible spectrum, the near UV spectrum, the visible spectrum, and/or the NIR spectrum.

In some non-limiting examples, a coating, including without limitation, a patterning coating 110, comprised of a material, including without limitation, a patterning material 611, having a substantially weak, or substantially no, photoluminescence or absorption in a wavelength range of one of at least about: 365 nm and 460 nm may tend to not act as either a photoluminescent coating or an absorbing coating and may have applicability in some scenarios calling for substantially high transparency in at least one of the visible spectrum and the NIR spectrum.

In some non-limiting examples, such material may tend to exhibit substantially low photoluminescence upon being subjected to EM radiation having a wavelength of about 365 nm, which is a common wavelength of the radiation source used in fluorescence microscopy. The presence of such materials, including without limitation, a patterning material 611, especially when deposited, in some non-limiting examples, as a thin film, may have reduced applicability in some scenarios calling for typical optical detection techniques, including without limitation, fluorescence microscopy. This may impose constraints in some scenarios in which such material may be selectively deposited, for example through an FMM, over part(s) of a substrate 10, as there may be some scenarios for determining, following the deposition of the material, the part(s) in which such materials are present.

In some non-limiting examples, a material having a relatively large HOMO-LUMO gap may have applicability in some scenarios calling for weak, or substantially no, photoluminescence or absorption in a wavelength range of one of at least about: 365 nm and 460 nm.

In some non-limiting examples, a material having a substantially small HOMO-LUMO gap may have applicability in some scenarios to detect a film of the material using optical techniques.

### Refractive Index and Extinction Coefficient

In some non-limiting examples, the patterning coating 110, and/or the patterning material 611, in some non-limiting examples, when deposited as a film, and/or coating in a form, and under circumstances similar to the deposition of the pattering coating 110 within the device 100, may have a low refractive index.

In some non-limiting examples, the patterning coating 110, and/or the patterning material 611, in some non-limiting examples, when deposited as a film, and/or coating in a form, and under circumstances similar to the deposition of the pattering coating 110 within the device 100, may have a refractive index for EM radiation at a wavelength of 550 nm that may be at least one of no more than about: 1.55, 1.5, 1.45, 1.43, 1.4, 1.39, 1.37, 1.35, 1.32, and 1.3.

In some non-limiting examples, the refractive index, n, of the pattering coating 110 may be no more than about 1.7. For example, the refractive index of the patterning coating 110 may be one of no more than about: 1.6, 1.5, 1.4, and 1.3. In some non-limiting examples, the refractive index n of the patterning coating 110 may be one of between about: 1.2-1.6, 1.2-1.5, and 1.25-1.45. As further described in various non-limiting examples above, the pattering coating 110 exhibiting a substantially low refractive index may have application in some scenarios, to enhance the optical properties and/or performance of the device, including without limitation, by enhancing outcoupling of EM radiation emitted by the opto-electronic device.

Without wishing to be bound by any particular theory, it has been observed that providing the patterning coating 110 having a substantially low refractive index may, at least in some devices 100, enhance transmission of external EM radiation through the second portion 102 thereof. In some non-limiting examples, devices 100 including an air gap therein, which may be arranged near or adjacent to the patterning coating 110, may exhibit a substantially high transmittance when the patterning coating 110 has a substantially low refractive index relative to a similarly configured device in which such low-index patterning coating 110 was not provided.

By way of non-limiting example, a series of samples was fabricated to measure the refractive index at a wavelength of 550 nm for the coatings formed by some of the various example materials. The results of the measurement are summarized in Table 4 below:

TABLE 4

| Material | Refractive Index |
|---|---|
| HT211 | 1.76 |
| HT01 | 1.80 |
| TAZ | 1.69 |
| Balq | 1.69 |
| Liq | 1.64 |
| Example Material 2 | 1.72 |
| Example Material 3 | 1.37 |
| Example Material 5 | 1.38 |
| Example Material 7 | 1.3 |

Based on the foregoing measurement of refractive index in Table 4, and the previous observation regarding the presence or absence of a substantially closed coating 140 of Ag in Table 4, it was found that materials that form a low refractive index coating, which by way of non-limiting example, may be those having a refractive index of no more than at least one of about: 1.4 or 1.38, may be suitable for forming the patterning coating 110 to inhibit deposition of a deposited material 731 thereon, including without limitation, Ag, and/or an Ag-containing materials.

In some non-limiting examples, the patterning coating 110, and/or the patterning material 611, in some non-limiting examples, when deposited as a film, and/or coating in a form, and under circumstances similar to the deposition of the patterning coating 110 within the device 100, may have a low refractive index.

In some non-limiting examples, the patterning coating 110, and/or the patterning material 611, in some non-limiting examples, when deposited as a film, and/or coating in a form, and under circumstances similar to the deposition of the patterning coating 110 within the device 100, may have a refractive index for EM radiation at a wavelength of 550 nm that may be at least one of no more than about: 1.55, 1.5, 1.45, 1.43, 1.4, 1.39, 1.37, 1.35, 1.32, and 1.3.

In some non-limiting examples, the patterning coating 110, and/or the patterning material 611 may exhibit a surface energy of no more than about 25 dynes/cm and a refractive index of no more than about 1.45. In some non-limiting examples, the patterning coating 110, and/or the patterning material 611 may comprise a material exhibiting a surface energy of no more than about 20 dynes/cm and a refractive index of no more than about 1.4.

In some non-limiting examples, the patterning coating 110 may be substantially transparent and/or EM radiation-transmissive.

In some non-limiting examples, the patterning coating 110, and/or the patterning material 611, in some non-limiting examples, when deposited as a film, and/or coating in a form, and under similar circumstances to the deposition of the patterning coating 110 within the device 100, may have an extinction coefficient that may be no more than about 0.01 for photons at a wavelength that is at least one of at least about: 600 nm, 500 nm, 460 nm, 420 nm, and 410 nm.

In some non-limiting examples, the patterning coating 110 may exhibit an extinction coefficient, κ; of one of no more than about: 0.1, 0.08, 0.05, 0.03, and 0.01 in the visible light spectrum.

### Photoluminescence, Absorption and Other Optical Effects

In some non-limiting examples, a material exhibiting substantially low, or substantially no, photoluminescence at a wavelength that is one of at least about: 365 nm, and 460 nm, may have applicability in some scenarios calling for substantially high transparency in at least one of the visible spectrum and the NIR spectrum.

In some non-limiting examples, a material with substantially low, or substantially no, absorption at a wavelength that is one of at least about: 365 nm, and 460 nm, may have applicability in some scenarios calling for substantially high transparency in at least one of the visible spectrum and the NIR spectrum.

In some non-limiting examples, the patterning coating 110, and/or the patterning material 611, in some non-limiting examples, when deposited as a film, and/or coating in a form, and under circumstances similar to the deposition of the patterning coating 110 within the device 100, may not substantially attenuate EM radiation passing therethrough, in at least the visible spectrum.

In some non-limiting examples, the patterning coating 110, and/or the patterning material 611, when deposited as a film, and/or coating in a form, and under circumstances similar to the deposition of the patterning coating 110 within the device 100, may not substantially attenuate EM radiation passing therethrough, in at least the IR spectrum and/or the NIR spectrum.

In some non-limiting examples, the patterning coating 110, and/or the patterning material 611, in some non-limiting examples, when deposited as a film, and/or coating in a form, and under circumstances similar to the deposition of the patterning coating 110 within the device 100, may have an extinction coefficient that may be one of at least about: 0.05, 0.1, 0.2, and 0.5 for EM radiation at a wavelength that is one of no more than about: 400 nm, 390 nm, 380 nm, and 370 nm.

In this way, the patterning coating 110, and/or the patterning material 611, when deposited as a film, and/or coating in a form, and under circumstances similar to the deposition of the patterning coating 110 within the device 100, may absorb EM radiation in the UVA spectrum incident upon the device 100, thereby reducing a likelihood that EM radiation in the UVA spectrum may impart constraints in terms of device performance, device stability, device reliability, and/or device lifetime.

In some non-limiting examples, the patterning coating 110 may act as an optical coating. In some non-limiting examples, the patterning coating 110 may modify at least one property, and/or characteristic of EM radiation (including without limitation, in the form of photons) emitted by the device 100. In some non-limiting examples, the patterning coating 110 may exhibit a degree of haze, causing emitted EM radiation to be scattered. In some non-limiting examples, the patterning coating 110 may comprise a crystalline material for causing EM radiation transmitted therethrough to be scattered. Such scattering of EM radiation may facilitate enhancement of the outcoupling of EM radiation from the device 100 in some non-limiting examples. In some non-limiting examples, the patterning coating 110 may initially be deposited as a substantially non-crystalline, including without limitation, substantially amorphous, coating, whereupon, after deposition thereof, the patterning coating 110 may become crystallized and thereafter serve as an optical coupling.

In some non-limiting examples, the patterning coating 110 may not exhibit any substantial EM radiation absorption at any wavelength corresponding to the visible spectrum.

### Weight

Without wishing to be bound by any particular theory, it may be postulated that, for compounds that are adapted to form surfaces with substantially low surface energy, there may be scenarios calling for, in at least some applications, the molecular weight of such compounds to be one of between about: 800-3,000 g/mol, 900-2,000 g/mol, 900-1,800 g/mol, and 900-1,600 g/mol.

Without wishing to be bound by any particular theory, it may be postulated that such compounds may exhibit at least one property that may have applicability in some scenarios for forming a coating, and/or layer having: (i) a substantially high melting point, in some non-limiting examples, of at least 100° C., (ii) a substantially low surface energy, and/or (iii) a substantially amorphous structure, when deposited, in some non-limiting examples, using vacuum-based thermal evaporation processes.

In some non-limiting examples, the molecular weight of the compound may be no more than about 5,000 g/mol. In some non-limiting examples, the molecular weight of the compound may be one of no more than about: 4,500 g/mol, 4,000 g/mol, 3,500 g/mol, and 3,000 g/mol.

In some non-limiting examples, the molecular weight of the compound may be at least about 800 g/mol. In some non-limiting examples, the molecular weight of the compound may be one of at least about: 900 g/mol, 1,000 g/mol, 1,100 g/mol, 1,200 g/mol, 1,300 g/mol, 1,500 g/mol, and 1,700 g/mol.

In some non-limiting examples, the molecular weight of the compound may be one of between about: 800-3,000 g/mol, 900-2,000 g/mol, 900-1,800 g/mol, and 900-1,600 g/mol.

In some non-limiting examples, a percentage of the molar weight of such compound that may be attributable to the presence of F atoms, may be one of between about: 40-90%, 45-85%, 50-80%, 55-75%, and 60-75%. In some non-limiting examples, F atoms may constitute a majority of the molar weight of such compound.

In some non-limiting examples, the quotient of F atoms contained in the compound/C atoms contained in the compound may be one of at least about: 0.5, 0.7, 1, 1.5, 2, and 2.5. In some non-limiting examples, the quotient of the F atoms/Si atoms may be one of no more than about: 5, 4, and 3.

Without wishing to be bound by any particular theory, it may be postulated that such compounds may exhibit at least one property that may be suitable for forming a coating, and/or layer having: (i) a relatively high melting point, in some non-limiting examples, of at least 100° C., (ii) a relatively low surface energy, and/or (iii) a substantially amorphous structure, when deposited, in some non-limiting examples, using vacuum-based thermal evaporation processes.

In some non-limiting examples, the patterning coating 110 may be disposed in a pattern that may be defined by at least one region therein that may be substantially devoid of a closed coating 140 of the patterning coating 110. In some non-limiting examples, the at least one region may separate the patterning coating 110 into a plurality of discrete fragments thereof. In some non-limiting examples, the plurality of discrete fragments of the pattering coating 110 may be physically spaced apart from one another in the lateral aspect thereof. In some non-limiting examples, the plurality of the discrete fragments of the patterning coating 110 may be arranged in a regular structure, including without limitation, an array or matrix, such that in some non-limiting examples, the discrete fragments of the patterning coating 110 may be configured in a repeating pattern.

In some non-limiting examples, at least one of the plurality of the discrete fragments of the patterning coating 110 may each correspond to an emissive region 1401.

In some non-limiting examples, an aperture ratio of the emissive regions 1401 may be at least one of no more than about: 50%, 40%, 30%, and 20%.

In some non-limiting examples, the patterning coating 110 may be formed as a single monolithic coating.

In some non-limiting examples, the patterning coating 110 may have and/or provide, including without limitation, because of the patterning material 611 used and/or the deposition environment, at least one nucleation site for the deposited material 731.

In some non-limiting examples, the patterning coating 110 may be doped, covered, and/or supplemented with another material that may act as a seed or heterogeneity, to act as such a nucleation site for the deposited material 731. In some non-limiting examples, such other material may comprise an NPC 920 material. In some non-limiting examples, such other material may comprise an organic material, such as in some non-limiting examples, a polycyclic aromatic compound, and/or a material comprising a non-metallic element such as, without limitation, at least one of: O, S, N, and C, whose presence might otherwise be a contaminant in the source material, equipment used for deposition, and/or the vacuum chamber environment. In some non-limiting examples, such other material may be deposited in a layer thickness that is a fraction of a monolayer, to avoid forming a closed coating 140 thereof. Rather, the monomers of such other material may tend to be spaced apart in the lateral aspect so as form discrete nucleation sites for the deposited material.

In some non-limiting examples, the patterning coating 110 may act as an optical coating. In some non-limiting examples, the patterning coating 110 may modify at least one property, and/or characteristic of EM radiation (including without limitation, in the form of photons) emitted by the device 100. In some non-limiting examples, the patterning coating 110 may exhibit a degree of haze, causing emitted EM radiation to be scattered. In some non-limiting examples, the patterning coating 110 may comprise a crystalline material for causing EM radiation transmitted therethrough to be scattered. Such scattering of EM radiation may facilitate enhancement of the outcoupling of EM radiation from the device in some non-limiting examples. In some non-limiting examples, the patterning coating 110 may initially be deposited as a substantially non-crystalline, including without limitation, substantially amorphous, coating, whereupon, after deposition thereof, the patterning coating 110 may become crystallized and thereafter serve as an optical coupling.

In some non-limiting examples, there may be an aim to provide a patterning coating 110 for causing formation of a discontinuous layer 840 of at least one particle structure 841, upon the patterning coating 110 being subjected to a vapor flux 732 of a deposited material 731. In at least some applications, the patterning coating 110 may exhibit a sufficiently low initial sticking probability such that a closed coating 140 of the deposited material 731 may be formed in the second portion 102, which may be substantially devoid of the patterning coating 110, while the discontinuous layer 840 of at least one particle structure 841 having at least one characteristic may be formed in the first portion 101 on the patterning coating 110. In some non-limiting examples, there may be an aim to form a discontinuous layer 840 of at least one particle structure 841 of a deposited material 731, which may be, in some non-limiting examples, of a metal or metal alloy, in the second portion 102, while depositing a closed coating 140 of the deposited material 731 having a thickness of, for example, one of no more than about: 100 nm, 50 nm, 25 nm, and 15 nm. In some non-limiting examples, a relative amount of the deposited material 731 deposited as a discontinuous layer 840 of at least one particle structure 841 in the first portion 101 may correspond to one of between about: 1-50%, 2-25%, 5-20%, and 7-10% of the amount of the deposited material 731 deposited as a closed coating 140 in the second portion 102, which in some non-limiting examples may correspond to a thickness of at least one of no more than about: 100 nm, 75 nm, 50 nm, 25 nm, and 15 nm.

### Composition

In some non-limiting examples, the patterning coating 110, and/or the patterning material 611, may comprise a fluorine (F) atom and/or an Si atom. By way of non-limiting example, the patterning material 611 for forming the patterning coating 110 may be a compound that includes F and/or Si.

In some non-limiting examples, the patterning material 611 may comprise a compound that comprises F. In some non-limiting examples, the pattering material 611 may comprise a compound that comprises F and a carbon atom. In some non-limiting examples, the patterning material 611 may comprise a compound that comprises F and C in an atomic ratio corresponding to a quotient of F/C of at least one of at least about: 1, 1.5, or 2. In some non-limiting examples, an atomic ratio of F to C may be determined by counting all of the F atoms present in the compound structure, and for C atoms, counting solely the sp³ hybridized C atoms present in the compound structure. In some non-limiting examples, the patterning material 611 may comprise a compound that comprises, as part of its molecular sub-structure, a moiety comprising F and C in an atomic ratio corresponding to a quotient of F/C of at least about: 1, 1.5, or 2.

In some non-limiting examples, the compound of the patterning material 611 may comprise an organic-inorganic hybrid material.

In some non-limiting examples, the patterning material 611 may be, or comprise, an oligomer.

In some non-limiting examples, the patterning material 611 may be, or comprise, a compound having a molecular structure containing a backbone and at least one functional group bonded to the backbone. In some non-limiting examples, the backbone may be an inorganic moiety, and the at least one functional group may be an organic moiety.

In some non-limiting examples, such compound may have a molecular structure comprising a siloxane group. In some non-limiting examples, the siloxane group may be a linear, branched, or cyclic siloxane group. In some non-limiting examples, the backbone may be, or comprise, a siloxane group. In some non-limiting examples, the backbone may be, or comprise, a siloxane group and at least one functional group containing F. In some non-limiting examples, the at least one functional group comprising F may be a fluoroalkyl group. Non-limiting examples of such compound include fluoro-siloxanes. Non-limiting examples of such compound are Example Material 6 and Example Material 9.

In some non-limiting examples, the compound may have a molecular structure comprising a silsesquioxane group. In some non-limiting examples, the silsesquioxane group may be a POSS. In some non-limiting examples, the backbone may be, or comprise, a silsesquioxane group. In some non-limiting examples, the backbone may be, or comprise, a silsesquioxane group and at least one functional group comprising F. In some non-limiting examples, the at least one functional group comprising F may be a fluoroalkyl group. Non-limiting examples of such compound include fluoro-silsesquioxane and/or fluoro-POSS. A non-limiting example of such compound is Example Material 8.

In some non-limiting examples, the compound may have a molecular structure comprising a substituted or unsubstituted aryl group, and/or a substituted or unsubstituted heteroaryl group. In some non-limiting examples, the aryl group may be phenyl, or naphthyl. In some non-limiting examples, at least one C atom of an aryl group may be substituted by a heteroatom, which by way of non-limiting example may be O, N, and/or S, to derive a heteroaryl group. In some non-limiting examples, the backbone may be, or comprise, a substituted or unsubstituted aryl group, and/or a substituted or unsubstituted heteroaryl group. In some non-limiting examples, the backbone may be, or comprise, a substituted or unsubstituted aryl group, and/or a substituted or unsubstituted heteroaryl group and at least one functional group comprising F. In some non-limiting examples, the at least one functional group comprising F may be a fluoroalkyl group.

In some non-limiting examples, the compound may have a molecular structure comprising a substituted or unsubstituted, linear, branched, or cyclic hydrocarbon group. In some non-limiting examples, one or more C atoms of the hydrocarbon group may be substituted by a heteroatom, which by way of non-limiting example may be O, N, and/or S.

In some non-limiting examples, the compound may have a molecular structure comprising a phosphazene group. In some non-limiting examples, the phosphazene group may be a linear, branched, or cyclic phosphazene group. In some non-limiting examples, the backbone may be, or comprise, a phosphazene group. In some non-limiting examples, the backbone may be, or comprise, a phosphazene group and at least one functional group comprising F. In some non-limiting examples, the at least one functional group comprising F may be a fluoroalkyl group. Non-limiting examples of such compound include fluoro-phosphazenes. A non-limiting example of such compound is Example Material 4.

In some non-limiting examples, the compound may be a fluoropolymer. In some non-limiting examples, the compound may be a block copolymer comprising F. In some non-limiting examples, the compound may be an oligomer. In some non-limiting examples, the oligomer may be a fluorooligomer. In some non-limiting examples, the compound may be a block oligomer comprising F. Non-limiting examples, of fluoropolymers and/or fluorooligomers are those having the molecular structure of Example Material 3, Example Material 5, and/or Example Material 7.

In some non-limiting examples, the compound may be a metal complex. In some non-limiting examples, the metal complex may be an organo-metal complex. In some non-limiting examples, the organo-metal complex may comprise F. In some non-limiting examples, the organo-metal complex may comprise at least one ligand comprising F. In some non-limiting examples, the at least one ligand comprising F may be, or comprise, a fluoroalkyl group.

In some non-limiting examples, the patterning material 611 may be, or comprise, an organic-inorganic hybrid material.

In some non-limiting examples, the patterning material 611 may comprise a plurality of different materials.

In some non-limiting examples, the patterning coating 110 may comprise a plurality of materials. In some non-limiting examples, the pattering coating 110 may comprise a first material and a second material.

In some non-limiting examples, at least one of the plurality of materials of the patterning coating 110 may serve as an NIC when deposited as a thin film.

In some non-limiting examples, at least one of the plurality of materials of the pattering coating 110 may serve as an NIC when deposited as a thin film, and another material thereof may form an NPC 920 when deposited as a thin film. In some non-limiting examples, the first material may form an NPC 920 when deposited as a thin film, and the second material may form an NIC when deposited as a thin film. In some non-limiting examples, the presence of the first material in the patterning coating 110 may result in an increased initial sticking probability thereof compared to cases in which the patterning coating 110 is formed of the second material and is substantially devoid of the first material.

In some non-limiting examples, at least one of the materials of the patterning coating 110 may be adapted to form a surface having a low surface energy when deposited as a thin film. In some non-limiting examples, the first material, when deposited as a thin film, may be adapted to form a surface having a lower surface energy than a surface provided by a thin film comprising the second material.

In some non-limiting examples, the patterning coating 110 may exhibit photoluminescence, including without limitation, by comprising a material which exhibits photoluminescence.

In some non-limiting examples, the patterning coating 110 may exhibit photoluminescence at a wavelength corresponding to the UV spectrum and/or visible spectrum. In some non-limiting examples, photoluminescence may occur at a wavelength (range) corresponding to the UV spectrum, including but not limited to the UVA spectrum, and/or UVB spectrum. In some non-limiting examples, photoluminescence may occur at a wavelength (range) corresponding to the visible spectrum. In some non-limiting examples, photoluminescence may occur at a wavelength (range) corresponding to deep blue or near UV.

In some non-limiting examples, the first material may have a first optical gap, and the second material may have a second optical gap. In some non-limiting examples, the second optical gap may exceed the first optical gap. In some non-limiting examples, a difference between the first optical gap and the second optical gap may exceed at least one of about: 0.3 eV, 0.5 eV, 0.7 eV, 1 eV, 1.3 eV, 1.5 eV, 1.7 eV, 2 eV, 2.5 eV, and/or 3 eV.

In some non-limiting examples, the first optical gap may be no more than at least one of about: 4.1 eV, 3.5 eV, or 3.4 eV. In some non-limiting examples, the second optical gap may exceed at least one of about: 3.4 eV, 3.5 eV, 4.1 eV, 5 eV, or 6.2 eV.

In some non-limiting examples, the first optical gap and/or the second optical gap may correspond to the HOMO-LUMO gap.

In some non-limiting examples, the first material may exhibit photoluminescence at a wavelength corresponding to the UV spectrum and/or visible spectrum. In some non-limiting examples, photoluminescence may occur at a wavelength corresponding to the UV spectrum, including but not limited to the UVA spectrum and/or the UVB spectrum. In some non-limiting examples, photoluminescence may occur at a wavelength corresponding to the visible spectrum. In some non-limiting examples, photoluminescence may occur at a wavelength corresponding to a deep B(lue) region of the visible spectrum.

In some non-limiting examples, the first material may exhibit photoluminescence at a wavelength corresponding to the visible spectrum, and the second material may not exhibit substantial photoluminescence at any wavelength corresponding to the visible spectrum.

In some non-limiting examples, at least one of the materials of the patterning coating 110 that may exhibit photoluminescence may comprise at least one of: a conjugated bond, an aryl moiety, donor-acceptor group, or a heavy metal complex.

By way of non-limiting example, photoluminescence of a coating and/or a material may be observed through a photoexcitation process. In a photoexcitation process, the coating and/or material may be subjected to EM radiation emitted by a source, including without limitation, a UV lamp. When the emitted EM radiation is absorbed by the coating and/or material, the electrons thereof may be temporarily excited. Following excitation, at least one relaxation process may occur, including without limitation, fluorescence and/or phosphorescence, in which EM radiation may be emitted from the coating and/or material. The EM radiation emitted from the coating and/or material during such process may be detected, for example by a photodetector, to characterize the photoluminescence properties of the coating and/or material. As used herein, the wavelength of photoluminescence, in relation to a coating and/or material, may generally refer to a wavelength of EM radiation emitted by such coating and/or material as a result of relaxation of electrons from an excited state. As would be understood by a person skilled in the art, a wavelength of light emitted by the coating and/or material as a result of the photoexcitation process may in some non-limiting examples, be longer than a wavelength of radiation used to initiate photoexcitation. Photoluminescence may be detected and/or characterized using various techniques known in the art, including but not limited to fluorescence microscopy. As used herein, a photoluminescent coating or material may be a coating or material that exhibits photoluminescence at a wavelength when irradiated with an excitation radiation at a certain wavelength. In some non-limiting examples, a photoluminescent coating or material may exhibit photoluminescence at a wavelength that exceeds about 365 nm upon being irradiated with an excitation radiation having a wavelength of 365 nm. A photoluminescent coating may be detected on a substrate 10 using standard optical techniques including without limitation, fluorescence microscopy, which may quantify, measure, and/or investigate the presence of such coating or material.

In some non-limiting examples, an optical gap of the various coatings and/or materials, including without limitation, the first optical gap and/or the second optical gap, may correspond to an energy gap of the coating and/or material from which EM radiation is absorbed or emitted during the photoexcitation process.

In some non-limiting examples, photoluminescence may be detected and/or characterized by subjecting the coating and/or material to EM radiation having a wavelength corresponding to the UV spectrum, including without limitation, the UVA spectrum or the UVB spectrum. In some non-limiting examples, EM radiation for initiating photoexcitation may have a wavelength of about 365 nm.

In some non-limiting examples, the second material may not substantially exhibit photoluminescence at any wavelength corresponding to the visible spectrum. In some non-limiting examples, the second material may not exhibit photoluminescence upon being subjected to EM radiation having a wavelength of at least one of at least about: 300 nm, 320 nm, 350 nm, or 365 nm. In some non-limiting examples, the second material may exhibit insignificant and/or no detectable absorption when subjected to such EM radiation. In some non-limiting examples, the second optical gap of the second material may be wider than the photon energy of the EM radiation emitted by the source, such that the second material does not undergo photoexcitation when subjected to such EM radiation. However, in some non-limiting examples, the pattering coating 110 containing such second material may nevertheless exhibit photoluminescence upon being subjected to EM radiation due to the first material exhibiting photoluminescence. In some non-limiting examples, the presence of the pattering coating 110 may be detected and/or observed using routine characterization techniques such as fluorescence microscopy upon deposition of the pattering coating 110.

In some non-limiting examples, a concentration, including without limitation by weight, of the first material in the patterning coating 110 may be no more than that of the second material in the patterning coating 110. In some non-limiting examples, the patterning coating 110 may comprise at least one of at least about: 0.1 wt. %, 0.2 wt. %, 0.5 wt. %, 0.8 wt. %, 1 wt. %, 3 wt. %, 5 wt. %, 8 wt. %, 10 wt. %, 15 wt. %, or 20 wt. %, of the first material. in some non-limiting examples, the patterning coating 110 may comprise at least one of no more than about: 50 wt. %, 40 wt. %, 30 wt. %, 25 wt. %, 20 wt. %, 15 wt. %, 10 wt. %, 8 wt. %, 5 wt. %, 3 wt. %, or 1 wt. %, of the first material. In some non-limiting examples, a remainder of the patterning coating 110 may be substantially comprised of the second material. In some non-limiting examples, the patterning coating 110 may comprise additional materials, including without limitation, a third material, and/or a fourth material.

In some non-limiting examples, at least one of the materials of the patterning coating 110, including without limitation, the first material and/or the second material, may comprise at least one of F and Si. By way of non-limiting example, at least one of the first material and the second material may comprise at least one of F and Si. In some further non-limiting examples, the first material may comprise F and/or Si, and the second material may comprise F and/or Si. In some non-limiting examples, the first material and the second material both may comprise F. In some non-limiting examples, the first material and the second material both may comprise Si. In some non-limiting examples, each of the first material and the second material may comprise F and/or Si.

In some non-limiting examples, at least one material of the first material and the second material may comprise both F and Si. In some non-limiting examples, one of the first material and the second material may not comprise F and/or Si. In some non-limiting examples, the second material may comprise F and/or Si, and the first material may not comprise F and/or Si.

In some non-limiting examples, at least one of the materials of the patterning coating 110, which for example may be the first material and/or the second material, may comprise F, and at least one of the other materials of the patterning coating 110 may comprise a sp² carbon. In some non-limiting examples, at least one of the materials of the patterning coating 110, which for example may be the first material and/or the second material, may comprise F, and at least one of the other materials of the patterning coating 110 may comprise a sp³ carbon. In some non-limiting examples, at least one of the materials of the patterning coating 110, which for example may be the first material and/or the second material, may comprise F and a sp³ carbon, and at least one of the other materials of the patterning coating 110 may comprise a sp² carbon. In some non-limiting examples, at least one of the materials of the patterning coating 110, which for example may be the first material and/or the second material, may comprise F and a sp³ carbon wherein all F bonded to a carbon (C) may be bonded to a sp³ carbon, and at least one of the other materials of the patterning coating 110 may comprise a sp² carbon. In some non-limiting examples, at least one of the materials of the patterning coating 110, which for example may be the first material and/or the second material, may comprise F and a sp³ carbon wherein all F bonded to C may be bonded to an sp³ carbon, and at least one of the other materials of the patterning coating 110 may comprise a sp² carbon and may not comprise F. By way of non-limiting example, in any of the foregoing non-limiting examples, “at least one of the materials of the patterning coating 110” may correspond to the second material, and the “at least one of the other materials of the patterning coating 110” may correspond to the first material.

As would be appreciated by those having ordinary skill in the relevant art, the presence of materials in a coating which comprises at least one of: F, sp² carbon, sp³ carbon, an aromatic hydrocarbon moiety, and/or other functional groups or moieties may be detected using various methods known in the art, including by way of non-limiting example, an X-ray Photoelectron Spectroscopy (XPS).

In some non-limiting examples, at least one of the materials of the pattering coating 110, which by way of non-limiting example may be the first material and/or the second material, may comprise F, and at least one of the other materials of the patterning coating 110 may comprise an aromatic hydrocarbon moiety. In some non-limiting examples, at least one of the materials of the patterning coating 110, which for example may be the first material and/or the second material, may comprise F, and at least one of the materials of the patterning coating 110 may not comprise an aromatic hydrocarbon moiety. In some non-limiting examples, at least one of the materials of the patterning coating 110, which for example may be the first material and/or the second material, may comprise F and may not comprise an aromatic hydrocarbon moiety, and at least one of the other materials of the patterning coating 110 may comprise an aromatic hydrocarbon moiety. In some non-limiting examples, at least one of the materials of the patterning coating 110, which for example may be the first material and/or the second material, may comprise F and may not comprise an aromatic hydrocarbon moiety, and at least one of the other materials of the patterning coating 110 may comprise an aromatic hydrocarbon moiety and may not comprise F. Non-limiting examples of the aromatic hydrocarbon moiety include at least one of: substituted polycyclic aromatic hydrocarbon moiety, unsubstituted polycyclic aromatic hydrocarbon moiety, substituted phenyl moiety, and unsubstituted phenyl moiety.

In some non-limiting examples, at least one of the materials of the patterning coating 110, which for example may be the first material and/or the second material, may comprise F, and at least one of the other materials of the patterning coating 110 may comprise a polycyclic aromatic hydrocarbon moiety. In some non-limiting examples, at least one of the materials of the patterning coating 110, which for example may be the first material and/or the second material, may comprise F, and at least one of the materials of the patterning coating 110 may not comprise a polycyclic aromatic hydrocarbon moiety. In some non-limiting examples, at least one of the materials of the patterning coating 110, which for example may be the first material and/or the second material, may comprise F and may not comprise a polycyclic aromatic hydrocarbon moiety, and at least one of the other materials of the patterning coating 110 may comprise a polycyclic aromatic hydrocarbon moiety. In some non-limiting examples, at least one of the materials of the patterning coating 110, which for example may be the first material and/or the second material, may comprise F and may not comprise a polycyclic aromatic hydrocarbon moiety, and at least one of the other materials of the patterning coating 110 may comprise a polycyclic aromatic hydrocarbon moiety and may not comprise F.

In some non-limiting examples, at least one of the materials of the patterning coating 110, which for example may be the first material and/or the second material, may comprise at least one of a fluorocarbon moiety and a siloxane moiety, and at least one of the other materials of the patterning coating 110 may comprise a polycyclic aromatic hydrocarbon moiety. In some non-limiting examples, at least one of the materials of the patterning coating 110, which for example may be the first material and/or the second material, may comprise at least one of a fluorocarbon moiety and a siloxane moiety, and at least one of the materials of the pattering coating 110 may not comprise a polycyclic aromatic hydrocarbon moiety. In some non-limiting examples, at least one of the materials of the patterning coating 110, which for example may be the first material and/or the second material, may comprise at least one of a fluorocarbon moiety and a siloxane moiety and may not comprise a polycyclic aromatic hydrocarbon moiety, and at least one of the other materials of the pattering coating 110 may comprise a polycyclic aromatic hydrocarbon moiety. In some non-limiting examples, at least one of the materials of the patterning coating 110, which for example may be the first material and/or the second material, may comprise at least one of a fluorocarbon moiety and a siloxane moiety and may not comprise a polycyclic aromatic hydrocarbon moiety, and at least one of the other materials of the pattering coating 110 may comprise a polycyclic aromatic hydrocarbon moiety and may not comprise a fluorocarbon moiety or a siloxane moiety.

In some non-limiting examples, at least one of the materials of the patterning coating 110, which for example may be the first material and/or the second material, may comprise F, and at least one of the other materials of the patterning coating 110 may comprise a phenyl moiety. In some non-limiting examples, at least one of the materials of the patterning coating 110, which for example may be the first material and/or the second material, may comprise F, and at least one of the materials of the patterning coating 110 may not comprise a phenyl moiety. In some non-limiting examples, at least one of the materials of the pattering coating 110, which for example may be the first material and/or the second material, may comprise F and may not comprise a phenyl moiety, and at least one of the other materials of the patterning coating 110 may comprise a phenyl moiety. In some non-limiting examples, at least one of the materials of the patterning coating 110, which for example may be the first material and/or the second material, may comprise F and may not comprise a phenyl moiety, and at least one of the other materials of the pattering coating 110 may comprise a phenyl moiety and may not comprise F.

In some non-limiting examples, at least one of the materials of the patterning coating 110, which for example may be the first material and/or the second material, may comprise at least one of a fluorocarbon moiety and a siloxane moiety, and at least one of the other materials of the patterning coating 110 may comprise a phenyl moiety. In some non-limiting examples, at least one of the materials of the patterning coating 110, which for example may be the first material and/or the second material, may comprise at least one of a fluorocarbon moiety and a siloxane moiety, and at least one of the materials of the patterning coating 110 may not comprise a phenyl moiety. In some non-limiting examples, at least one of the materials of the patterning coating 110, which for example may be the first material and/or the second material, may comprise at least one of a fluorocarbon moiety and a siloxane moiety and may not comprise a phenyl moiety, and at least one of the other materials of the patterning coating 110 may comprise a phenyl moiety. In some non-limiting examples, at least one of the materials of the patterning coating 110, which for example may be the first material and/or the second material, may comprise at least one of a fluorocarbon moiety and a siloxane moiety and may not comprise a phenyl moiety, and at least one of the other materials of the patterning coating 110 may comprise a phenyl moiety and may not comprise a fluorocarbon moiety or a siloxane moiety.

In general, the molecular structures and/or molecular compositions of the materials of the patterning coating 110, which for example may be the first material and the second material, may be different from one another. In some non-limiting examples, the materials may be selected such that they possess at least one property which is substantially similar to, or different from, one another, including without limitation, at least one of: a molecular structure of a monomer, a monomer backbone, and/or a functional group; a presence of a common element; a similarity in molecular structure; a characteristic surface energy; a refractive index; a molecular weight; and a thermal property, including without limitation, a melting temperature, a sublimation temperature, a glass transition temperature, or a thermal decomposition temperature.

A characteristic surface energy, as used herein particularly with respect to a material, may generally refer to a surface energy determined from such material. By way of non-limiting example, a characteristic surface energy may be measured from a surface formed by the material deposited and/or coated in a thin film form. Various methods and theories for determining the surface energy of a solid are known. By way of non-limiting example, a surface energy may be calculated or derived based on a series of contact angle measurements, in which various liquids may be brought into contact with a surface of a solid to measure the contact angle between the liquid-vapor interface and the surface. In some non-limiting examples, a surface energy of a solid surface may be equal to the surface tension of a liquid with the highest surface tension that completely wets the surface. By way of non-limiting example, a Zisman plot may be used to determine a highest surface tension value that would result in complete wetting (i.e. contact angle of 0°) of the surface.

In some non-limiting examples, at least one of the first material and the second material of the patterning coating 110 may be an oligomer.

In some non-limiting examples, the first material may comprise a first oligomer, and the second material may comprise a second oligomer. Each of the first oligomer and the second oligomer may comprise a plurality of monomers.

In some non-limiting examples, at least a fragment of the molecular structure of the at least one of the materials of the patterning coating 110, which may for example be the first material and/or the second material, may be represented by the following formula:

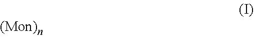

where:
Mon represents a monomer, and
n is an integer of at least 2.

In some non-limiting examples, n may be an integer of at least one of between about: 2-00, 2-50, 3-20, 3-15, 3-10, or 3-7.

In some non-limiting examples, the molecular structure of the first material and the second material of the pattering coating 110 may each be independently represented by Formula (I). By way of non-limiting example, the monomer and/or n of the first material may be different from that of the second material. In some non-limiting examples, n of the first material may be the same as n of the second material. In some non-limiting examples, n of the first material may be different from n of the second material. In some non-limiting examples, the first material and the second material may be oligomers.

In some non-limiting examples, the monomer may comprise at least one of F and Si.

In some non-limiting examples, the monomer may comprise a functional group. In some non-limiting examples, at least one functional group of the monomer may have a low surface tension. In some non-limiting examples, at least one functional group of the monomer may comprise at least one of F and Si. Non-limiting examples of such functional group include at least one of: a fluorocarbon group and a siloxane group. In some non-limiting examples, the monomer may comprise a silsesquioxane group.

While some non-limiting examples have been described herein with reference to a first material and a second material, it will be appreciated that the patterning coating may further include at least one additional material, and descriptions regarding the molecular structures and/or properties of the first material, the second material, the first oligomer, and/or the second oligomer may be applicable with respect to additional materials which may be contained in the patterning coating.

The surface tension attributable to a fragment of a molecular structure, including without limitation, a monomer, a monomer backbone unit, a linker, or a functional group, may be determined using various known method in the art. A non-limiting example of such method includes the use of a Parachor, such as may be further described, by way of non-limiting example, in “Conception and Significance of the Pa”achor”, Nature 196: 890-891. In some non-limiting examples, at least one functional group of the monomer may have a surface tension of no more than at least one of about: 25 dynes/cm, 21 dynes/cm, 20 dynes/cm, 19 dynes/cm, 18 dynes/cm, 17 dynes/cm, 16 dynes/cm, 15 dynes/cm, 14 dynes/cm, 13 dynes/cm, 12 dynes/cm, 11 dynes/cm, or 10 dynes/cm.

In some non-limiting examples, the monomer may comprise at least one of a CF₂ and a CF₂H moiety. In some non-limiting examples, the monomer may comprise at least one of a CF₂ and a CF₃ moiety. In some non-limiting examples, the monomer may comprise a CH₂CF₃ moiety. In some non-limiting examples, the monomer may comprise at least one of C and O. In some non-limiting examples, the monomer may comprise a fluorocarbon monomer. In some non-limiting examples, the monomer may comprise at least one of: a vinyl fluoride moiety, a vinylidene fluoride moiety, a tetrafluoroethylene moiety, a chlorotrifluoroethylene moiety, a hexafluoropropylene moiety, or a fluorinated 1,3-dioxole moiety.

In some non-limiting examples, the monomer may comprise a monomer backbone and a functional group. In some non-limiting examples, the functional group may be bonded, either directly or via a linker group, to the monomer backbone. In some non-limiting examples, the monomer may comprise the linker group, and the linker group may be bonded to the monomer backbone and to the functional group. In some non-limiting examples, the monomer may comprise a plurality of functional groups, which may be the same or different from one another. In such examples, each functional group may be bonded, either directly or via a linker group, to the monomer backbone. In some non-limiting examples, where a plurality of functional groups is present, a plurality of linker groups may also be present.

In some non-limiting examples, the molecular structure of at least one of the materials of the patterning coating 110, which may be the first material and/or the second material, may comprise a plurality of different monomers. In some non-limiting examples, such molecular structure may comprise monomer species that have different molecular composition and/or molecular structure. Non-limiting examples of such molecular structure include those represented by the following formulae:

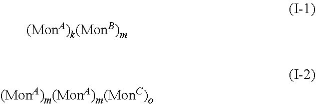

where:
Mon^{A}, Mon^{B}, and Mon^{C} each represent a monomer specie, and
k, m, and o each represent an integer of at least 2.

In some non-limiting examples, k, m, and o each represent an integer of at least one of between about: 2-100, 2-50, 3-20, 3-15, 3-10, or 3-7. Those having ordinary skill in the relevant art will appreciate that various non-limiting examples and descriptions regarding monomer, Mon, may be applicable with respect to each of Mon^{A}, Mon^{B}, and Mon^{C}.

In some non-limiting examples, the monomer may be represented by the following formula:

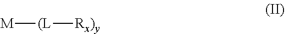

where:
M represents the monomer backbone unit,
L represents the linker group,
R represents the functional group,
x is an integer between 1 and 4, and
y is an integer between 1 and 3.

In some non-limiting examples, the linker group may be represented by at least one of: a single bond, O, N, NH, C, CH, CH₂, and S.

Various non-limiting examples of the functional group which have been described herein may apply with respect to R of Formula (II). In some non-limiting examples, the functional group R may comprise an oligomer unit, and the oligomer unit may further comprise a plurality of functional group monomer units. In some non-limiting examples, a functional group monomer unit may be at least one of: CH₂ or CF₂. In some non-limiting examples, a functional group may comprise a CH₂CF₃ moiety. For example, such functional group monomer units may be bonded together to form at least one of: an alkyl or an fluoroalkyl oligomer unit. In some non-limiting examples, the oligomer unit may further comprise a functional group terminal unit. In some non-limiting examples, the functional group terminal unit may be arranged at a terminal end of the oligomer unit and bonded to a functional group monomer unit. In some non-limiting examples, the terminal end at which the functional group terminal unit may be arranged may correspond to a fragment of the functional group that may be distal to the monomer backbone unit. In some non-limiting examples, the functional group terminal unit may comprise at least one of: CF₂H or CF₃.

In some non-limiting examples, the monomer backbone unit M may have a high surface tension. In some non-limiting examples, the monomer backbone unit may have a higher surface tension than at least one of the functional group(s) R bonded thereto. In some non-limiting examples, the monomer backbone unit may have a higher surface tension than any functional group R bonded thereto.

In some non-limiting examples, the monomer backbone unit may have a surface tension of at least one of at least about: 25 dynes/cm, 30 dynes/cm, 40 dynes/cm, 50 dynes/cm, 75 dynes/cm, 100 dynes/cm; 150 dynes/cm, 200 dynes/cm, 250 dynes/cm, 500 dynes/cm, 1,000 dynes/cm, 1,500 dynes/cm, or 2,000 dynes/cm.

In some non-limiting examples, the monomer backbone unit may comprise phosphorus (P) and N, including without limitation, a phosphazene, in which there is a double bond between P and N and may be represented as “NP” or as “N═P”. In some non-limiting examples, the monomer backbone unit may comprise Si and O, including without limitation, silsesquioxane, which may be represented as SiO_{3/2}.

In some non-limiting examples, at least a portion of the molecular structure of the at least one of the materials of the patterning coating 110, which may for example be the first material and/or the second material, is represented by the following formula:

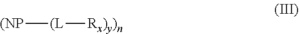

where:
NP represents the phosphazene monomer backbone unit,
L represents the linker group,
R represents the functional group,
x is an integer between 1 and 4,
y is an integer between 1 and 3, and
n is an integer of at least 2.

In some non-limiting examples, the molecular structure of the first material and/or the second material may be represented by Formula (III). In some non-limiting examples, at least one of the first material and the second material may be a cyclophosphazene. In some non-limiting examples, the molecular structure of the cyclophosphazene may be represented by Formula (III).

In some non-limiting examples, L may represent oxygen, x may be 1, and R may represent a fluoroalkyl group. In some non-limiting examples, at least a fragment of the molecular structure of the at least one material of the patterning coating 110, which may for example be the first material and/or the second material, may be represented by the following formula:

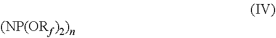

where:
R_{f} represents the fluoroalkyl group, and
n is an integer between 3 and 7.

In some non-limiting examples, the fluoroalkyl group may comprise at least one of: a CF₂ group, a CF₂H group, CH₂CF₃ group, and a CF₃ group. In some non-limiting examples, the fluoroalkyl group may be represented by the following formula:

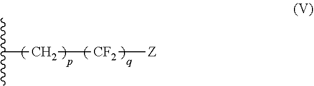

where:
p is an integer of 1 to 5;
q is an integer of 6 to 20; and
Z represents hydrogen or F.

In some non-limiting examples, p may be 1 and q may be an integer between 6 and 20.

In some non-limiting examples, the fluoroalkyl group R_{f} in Formula (IV) may be represented by Formula (V).

In some non-limiting examples, at least a fragment of the molecular structure of at least one of the materials of the patterning coating 110, which may for example be the first material and/or the second material, may be represented by the following formula:

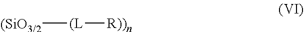

where:
L represents the linker group,
R represents the functional group, and
n is an integer between 6 and 12.

In some non-limiting embodiments, L may represent the presence of at least one of: a single bond, O, substituted alkyl, or unsubstituted alkyl. In some non-limiting examples, n may be 8, 10, or 12. In some non-limiting examples R may comprise a functional group with low surface tension. In some non-limiting examples, R may comprise at least one of: a F-containing group and a Si-containing group. In some non-limiting examples, R may comprise at least one of: a fluorocarbon group and a siloxane-containing group. In some non-limiting examples, R may comprise at least one of: a CF₂ group and a CF₂H group. In some non-limiting examples, R may comprise at least one of: a CF₂ and a CF₃ group. In some non-limiting examples, R may comprise a CH₂CF₃ group. In some non-limiting examples, the material represented by Formula (VI) may be a polyoctahedral silsesquioxane.

In some non-limiting examples, at least a fragment of the molecular structure of at least one of the materials of the patterning coating 110, which may for example be the first material and/or the second material, may be represented by the following formula:

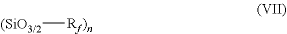

where:
n is an integer of 6-12, and
R_{f} represents a fluoroalkyl group.

In some non-limiting examples n may be 8, 10, or 12. In some non-limiting examples, R_{f} may comprise a functional group with low surface tension. In some non-limiting examples, R_{f} may comprise at least one of: a CF₂ moiety and a CF₂H moiety. In some non-limiting examples, R_{f} may comprise at least one of: a CF₂ moiety and a CF₃ moiety. In some non-limiting examples, R_{f} may comprise a CH₂CF₃ moiety. In some non-limiting examples, the material represented by Formula (VII) may be a polyoctahedral silsesquioxane.

In some non-limiting examples, the fluoroalkyl group, R_{f}, in Formula (VII) may be represented by Formula (V).

In some non-limiting examples, at least a fragment of the molecular structure of at least one of the materials of the patterning coating 110, which may for example be the first material and/or the second material, may be represented by the following formula:

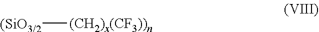

where:
x is an integer between 1 and 5, and
n is an integer between 6 and 12.

In some non-limiting examples, n may be 8, 10, or 12.

In some non-limiting examples, the compound represented by Formula (VIII) may be a polyoctahedral silsesquioxane.

In some non-limiting examples, the functional group R and/or the fluoroalkyl group R_{f} may be selected independently upon each occurrence of such group in any of the foregoing formulae. It will also be appreciated that any of the foregoing formulae may represent a sub-structure of the compound, and additional groups or moieties may be present, which are not explicitly shown in the above formulae. It will also be appreciated that various formulae provided in the present application may represent linear, branched, cyclic, cyclo-linear, and/or cross-linked structures.

In some non-limiting examples, the patterning coating 110 may comprise at least one material represented by at least one of the following Formulae: (I), (I-1), (I-2), (II), (III), (IV), (VI), (VII), and (VIII), and at least one material exhibiting at least one of the following characteristics: (a) includes an aromatic hydrocarbon moiety, (b) includes an sp2 carbon, (c) includes a phenyl moiety, (d) has a characteristic surface energy greater than about 20 dynes/cm, and (e) exhibits photoluminescence, including without limitation, exhibiting photoluminescence at a wavelength of at least about 365 nm upon being irradiated by an excitation radiation having a wavelength of about 365 nm.

In some non-limiting examples, the patterning coating may further comprise a third material that is different from the first material and the second material. In some non-limiting examples, the third material may comprise, a common monomer with at least one of the first material and the second material.

In some non-limiting examples, a difference in the sublimation temperature of the plurality of materials of the patterning coating 110, including but not limited to a difference between the first material and the second material, may be no more than at least one of about: 5° C., 10° C., 15° C., 20° C., 30° C., 40° C., or 50° C. In some non-limiting examples, at least one of the materials of the pattering coating 110, including without limitation, the first material and/or the second material, may comprise at least one of F and Si, and the sublimation temperatures of the materials of the patterning coating 110 may differ by no more than at least one of about: 5° C., 10° C., 15° C., 20° C., 25° C., 40° C., or 50° C. In some non-limiting examples, at least one of the materials of the pattering coating 110, including without limitation, the first material and/or the second material, may comprise at least one of: a fluorocarbon moiety and a siloxane moiety, and the sublimation temperatures of the materials of the patterning coating 110 may differ by no more than at least one of about: 5° C., 10° C., 15° C., 20° C., 25° C., 40° C., or 50° C.

In some non-limiting examples, a difference in a melting temperature of the plurality of materials of the patterning coating 110, including but not limited to a difference between the first NIC material and the second NIC material, may be no more than at least one of about: 5° C., 10° C., 15° C., 20° C., 30° C., 40° C., or 50° C. In some non-limiting examples, at least one of the materials of the patterning coating 110, including without limitation, the first material and/or the second material, may comprise at least one of: F and Si, and the melting temperatures of the materials of the patterning coating 110 may differ by no more than at least one of about: 5° C., 10° C., 15° C., 20° C., 25° C., 40° C., and 50° C. In some non-limiting examples, at least one of the materials of the pattering coating 110, including without limitation, the first material and/or the second material, may comprise at least one of: a fluorocarbon moiety and a siloxane moiety, and the melting temperatures of the materials of the pattering coating 110 may differ by no more than at least one of about: 5° C., 10° C., 15° C., 20° C., 25° C., 40° C., and 50° C.

In some non-limiting examples, at least one of the materials of the pattering coating 110, including without limitation, the first material and/or the second material, may have a low characteristic surface energy. In some non-limiting examples, at least one of the materials of the patterning coating 110, including without limitation, the first material and/or the second material, may have a low characteristic surface energy, and at least one of the materials of the patterning coating 110 may comprise at least one of: F and Si. In some non-limiting examples, at least one of the materials of the patterning coating 110, including without limitation, the first material and/or the second material, may a low characteristic surface energy, may comprise at least one of F and Si, and at least one other material of the patterning coating 110 may have a high characteristic surface energy. In some non-limiting examples, the presence of F and Si may be accounted for by the presence of a fluorocarbon moiety and a siloxane moiety, respectively. In some non-limiting examples, at least one of the materials, including without limitation, the second material, may have a low characteristic surface energy of at least one of between about: 10-20 dynes/cm, 12-20 dynes/cm, 15-20 dynes/cm, or 17-19 dynes/cm, and another material, including without limitation, the first material, may have a high characteristic surface energy of at least one of between about: 20-100 dynes/cm, 20-50 dynes/cm, or 25-45 dynes/cm. In some non-limiting examples, at least one of the materials may comprise at least one of: F and Si. In some non-limiting examples, the second material may comprise at least one of: F and Si.

In some non-limiting examples, at least one of the materials of the pattering coating 110, including without limitation, the second material, may a low characteristic surface energy of no more than about 20 dynes/cm and may comprise at least one of: F and/or Si, and another material, including without limitation, the first material, may have a characteristic surface energy of at least about 20 dynes/cm.

In some non-limiting examples, at least one of the materials of the pattering coating 110, including without limitation, the second material, may a low characteristic surface energy of no more than about 20 dynes/cm and may comprise at least one of: a fluorocarbon moiety and a siloxane moiety, and another material of the patterning coating 110, including without limitation, the first material, may have a characteristic surface energy of at least about 20 dynes/cm.

In some non-limiting examples, the surface energy of each of the two or more materials of the patterning coating 110, including but not limited to those of the first material and the second material, is less than about 25 dynes/cm, less than about 21 dynes/cm, less than about 20 dynes/cm, less than about 19 dynes/cm, less than about 18 dynes/cm, less than about 17 dynes/cm, less than about 16 dynes/cm, less than about 15 dynes/cm, less than about 14 dynes/cm, less than about 13 dynes/cm, less than about 12 dynes/cm, less than about 11 dynes/cm, or less than about 10 dynes/cm.

In some non-limiting examples, a refractive index at a wavelength at least one of 500 nm and 460 nm of at least one of the materials of the patterning coating 110, including without limitation, the first material and the second material, may be no more than at least one of about: 1.5, 1.45, 1.44, 1.43, 1.42, or 1.41. In some non-limiting examples, the patterning coating 110 may comprise at least one material that exhibits photoluminescence, and the patterning coating 110 may have a refractive index, at a wavelength of at least one of: 500 nm and 460 nm, of no more than at least one of about: 1.5, 1.45, 1.44, 1.43, 1.42, or 1.41.

In some non-limiting examples, a molecular weight of at least one of the materials of the pattering coating 110, including without limitation, the first material and the second material, may exceed at least one of about: 750, 1,000, 1,500, 2,000, 2,500, or 3,000 g/mol.

In some non-limiting examples, a molecular weight of at least one of the materials of the pattering coating 110, including without limitation, the first material and the second material, may be no more than at least one of about: 10,000, 7,500, or 5,000 g/mol.

In some non-limiting examples, the patterning coating 110 may comprise a plurality of materials exhibiting similar thermal properties, wherein at least one of the materials may exhibit photoluminescence. In some non-limiting examples, the patterning coating 110 may comprise a plurality of materials with similar thermal properties, wherein at least one of the materials may photoluminescence, and wherein at least one of the materials, may comprise F or Si. In some non-limiting examples, the patterning coating 110 may comprise a plurality of materials with similar thermal properties, including without limitation, a melting temperature or a sublimation temperature of the materials, wherein at least one of the materials may exhibit photoluminescence at a wavelength of at least about 365 nm when excited by a radiation having an excitation wavelength of about 365 nm, and wherein at least one of the materials may comprise at least one of: F and Si.

In some non-limiting examples, the patterning coating 110 may comprise a plurality of having at least one of: at least one common element or at least one common sub-structure, wherein at least one of the materials may exhibit photoluminescence. In some non-limiting examples, at least one of the materials, may comprise F and Si. In some non-limiting examples, the patterning coating 110 may comprise a plurality of materials with similar thermal properties, wherein at least one of the materials may exhibit photoluminescence at a wavelength that exceeds at least one of about 365 nm when excited by a radiation having an excitation wavelength of about 365 nm, and wherein at least one of the materials, may comprise at least one of: F and Si. In some non-limiting examples, the at least one common element may comprise at least one of: F and Si. In some non-limiting examples, the at least one common sub-structure may comprise at least one of: fluorocarbon, fluoroalkyl and siloxyl.

In some non-limiting examples, a method for manufacturing an opto-electronic device 100 may comprise actions of: depositing a pattering coating on a first exposed layer surface 11 of the device 100 in a first portion 101 of a lateral aspect thereof; and depositing a deposited material 731 on a second exposed layer surface 11 of the device 100 in a second portion 102 of the lateral aspect thereof. An initial sticking probability against deposition of the deposited material 731 onto an exposed layer surface 11 of the patterning coating 110 in the first portion 101, may be substantially less than the initial sticking probability against deposition of the deposited material 731 onto an exposed layer surface 11 in the second portion 102, such that the exposed layer surface 11 of the patterning coating 110 in the first portion 101 may be substantially devoid of a closed coating 140 of the deposited material 731. The pattering coating 110 deposited on the first exposed layer surface 11 of the device 100 may comprises a first material and a second material.

In some non-limiting examples, depositing the patterning coating 110 on the first exposed layer surface 11 of the device 100 may comprise providing a mixture containing a plurality of materials, and causing the mixture to be deposited onto the first exposed layer surface 11 of the device 100 to form the patterning coating 110 thereon. In some non-limiting examples, the mixture may comprise the first material and the second material. In some non-limiting examples, the first material and the second material may both be deposited onto the first exposed layer surface 11 to form the patterning coating 110 thereon.

In some non-limiting examples, the mixture containing the plurality of materials may be deposited onto the first exposed layer surface 11 of the device 100 by a PVD process, including without limitation, thermal evaporation. In some non-limiting examples, the patterning coating 110 may be formed by evaporating the mixture from a common evaporation source and causing the mixture to be deposited on the first exposed layer surface 11 of the device 100. In some non-limiting examples, the mixture containing, by way of non-limiting example, the first material and the second material, may be placed in a common crucible and/or evaporation source to be heated under vacuum. Once the evaporation temperature of the materials is reached, a vapor flux 732 generated therefrom may be directed towards the first exposed layer surface 11 of the device 100 to cause the deposition of the pattering coating 110 thereon.

In some non-limiting examples, the patterning coating 110 may be deposited by co-evaporation of the first material and the second material. In some non-limiting examples, the first material may be evaporated from a first crucible and/or first evaporation source, and the second material may be concurrently evaporated from a second crucible and/or second evaporation source such that the mixture may be formed in the vapor phase, and may be co-deposited onto the first exposed layer surface 11 to provide the patterning coating 110 thereon.

In order to evaluate properties of certain example patterning coatings 110 containing at least two materials, a series of samples were fabricated by depositing, in vacuo, an approximately 20 nm thick layer of an organic material that may be used as an HTL material, followed by depositing, over the organic material layer, a nucleation modifying coating having varying compositions as summarized in Table 5 below.

TABLE 5

| Sample Identifier | Composition of Nucleation Modifying Coating |
|---|---|
| Sample 1 | Patterning Material (15 nm) |
| Sample 2 | Patterning Material: PL Material 1 (0.5%, 15 nm) |
| Sample 3 | Patterning Material: PL Material 2 (0.5%, 15 nm) |
| Sample 4 | PL Material 1 (10 nm) |
| Sample 5 | PL Material 2 (10 nm) |
| Sample 6 | No nucleation modifying coating provided |

In the present example, the Patterning Material was selected such that, for example when deposited as a thin film, the Patterning Material exhibits a low initial sticking probability against deposition of the deposited material(s) 731, including without limitation, at least one of: Ag and Yb.

In the present example, PL Material 1 and PL Material 2 were selected such that, by way of non-limiting example, when deposited as a thin film, each of PL Material 1 and PL Material 2 may exhibit photoluminescence detectable by standard optical measurement techniques including without limitation, fluorescence microscopy.

In Table 5, Sample 1 is a comparison sample in which the nucleation modifying coating was provided by depositing the Patterning Material. Sample 2 is an example sample in which the nucleation modifying coating was provided by co-depositing the Patterning Material and PL Material 1 together to form a coating containing PL Material 1 in a concentration of 0.5 vol. %. Sample 3 is an example sample in which the nucleation modifying coating was provided by co-depositing the Patterning Material and PL Material 2 together to form a coating containing PL Material 2 in a concentration of 0.5 vol. %. Sample 4 is a comparison sample in which the nucleation modifying coating was provided by depositing PL Material 1. Sample 5 is a comparison sample in which the nucleation modifying coating was provided by depositing PL Material 2. Sample 6 is a comparison sample in which no nucleation modifying coating was provided over the organic material layer.

Each of Samples 1 to 6 was then subjected to an open mask deposition of Yb, followed by Ag. Specifically, the surfaces of the nucleation modifying coatings formed by the above materials were subjected to an open mask deposition of Yb, followed by Ag. More specifically, each sample was subjected to a Yb vapor flux 732 until a reference thickness of about 1 nm was reached, followed by an Ag vapor flux 732 until a reference thickness of about 12 nm was reached. Once the samples were fabricated, optical transmission measurements were taken to determine the relative amount of Yb and/or Ag deposited on the exposed layer surface 11 of the nucleation modifying coatings. As will be appreciated, samples having relatively little to no metal present thereon may be substantially transparent, while samples with metal deposited thereon, particularly as a closed coating 140, may generally exhibit a substantially lower light transmittance. Accordingly, the relative performance of various example coatings as a patterning coating 110 may be assessed by measuring the EM radiation transmission, which may directly correlate to an amount or thickness of metallic deposited material deposited thereon from deposition of either of both of the Yb of Ag.

The reduction in optical transmittance at a wavelength of 600 nm after each sample was subjected to an Ag vapor flux was measured and summarized in Table 6 below.

TABLE 6

| Sample Identifier | Transmittance Reduction (%) at λ = 600 nm |
|---|---|
| Sample 1 | <1% |
| Sample 2 | <2% |
| Sample 3 | <1% |
| Sample 4 | 43% |
| Sample 5 | 47% |
| Sample 6 | 45% |

Specifically, the transmittance reduction (%) for each sample in Table 6 was determined by measuring the light transmission through the sample before and after the exposure to the Yb and Ag vapor flux 732, and expressing the reduction in the EM radiation transmittance as a percentage.

As may be seen, Sample 1, Sample 2, and Sample 3 exhibited a relatively low transmittance reduction of less than 2%, or in the case of Samples 1 and 3, less than 1%. Accordingly, it may be observed that the nucleation modifying coatings provided for these samples acted as an NIC. By contrast, Sample 4, Sample 5, and Sample 6 each exhibited a transmittance reduction of 43%, 47%, and 45%, respectively. Accordingly, the nucleation modifying coatings provided for these samples did not act as an NIC but may have indeed acted as an NPC 920.

Moreover, it was found that Sample 1, in which the patterning coating 110 was comprised of substantially only the NIC Material, did not exhibit photoluminescence. However, Sample 2 and Sample 3 in which the patterning coating 110 comprised PL Material 1 and PL Material 2, respectively, in addition to the NIC material, were found to exhibit photoluminescence while also acting as an NIC by providing a surface with low initial sticking probability against the deposition of the deposited material 731.

### Deposited Layer

In some non-limiting examples, in the second portion 102 of the lateral aspect of the device 100, a deposited layer 130 comprising a deposited material 731 may be disposed as a closed coating 140 on an exposed layer surface 11 of an underlying layer, including without limitation, the substrate 10.

In some non-limiting examples, the deposited layer 130 may comprise a deposited material 731.

In some non-limiting examples, the deposited material 731 may comprise an element selected from at least one of: potassium (K), sodium (Na), lithium (Li), barium (Ba), cesium (Cs), Yb, Ag, gold (Au), Cu, aluminum (AI), Mg, Zn, Cd, tin (Sn), and yttrium (Y). In some non-limiting examples, the element may comprise at least one of: K, Na, Li, Ba, Cs, Yb, Ag, Au, Cu, Al, and Mg. In some non-limiting examples, the element may comprise at least one of: Cu, Ag, and Au. In some non-limiting examples, the element may be Cu. In some non-limiting examples, the element may be Al. In some non-limiting examples, the element may comprise at least one of: Mg, Zn, Cd, and Yb. In some non-limiting examples, the element may comprise at least one of: Mg, Ag, Al, Yb, and Li. In some non-limiting examples, the element may comprise at least one of: Mg, Ag, and Yb. In some non-limiting examples, the element may comprise at least one of: Mg, and Ag. In some non-limiting examples, the element may be Ag.

In some non-limiting examples, the deposited material 731 may be and/or comprise a pure metal. In some non-limiting examples, the deposited material 731 may be at least one of: pure Ag or substantially pure Ag. In some non-limiting examples, the substantially pure Ag may have a purity of one of at least about: 95%, 99%, 99.9%, 99.99%, 99.999%, and 99.9995%. In some non-limiting examples, the deposited material 731 may be at least one of: pure Mg or substantially pure Mg. In some non-limiting examples, the substantially pure Mg may have a purity of one of at least about: 95%, 99%, 99.9%, 99.99%, 99.999%, and 99.9995%.

In some non-limiting examples, the deposited material 731 may comprise an alloy. In some non-limiting examples, the alloy may be at least one of: an Ag-containing alloy, an Mg-containing alloy, or an AgMg-containing alloy. In some non-limiting examples, the AgMg-containing alloy may have an alloy composition that may range from about 1:10 (Ag:Mg) to about 10:1 by volume.

In some non-limiting examples, the deposited material 731 may comprise other metals in place of, and/or in combination with, Ag. In some non-limiting examples, the deposited material 731 may comprise an alloy of Ag with at least one other metal. In some non-limiting examples, the deposited material 731 may comprise an alloy of Ag with at least one of: Mg, or Yb. In some non-limiting examples, such alloy may be a binary alloy having a composition between about 5-95 vol. % Ag, with the remainder being the other metal. In some non-limiting examples, the deposited material 731 may comprise Ag and Mg. In some non-limiting examples, the deposited material 731 may comprise an Ag:Mg alloy having a composition between about 1:10-10:1 by volume. In some non-limiting examples, the deposited material 731 may comprise Ag and Yb. In some non-limiting examples, the deposited material 731 may comprise a Yb:Ag alloy having a composition between about 1:20-10:1 by volume. In some non-limiting examples, the deposited material 731 may comprise Mg and Yb. In some non-limiting examples, the deposited material 731 may comprise an Mg:Yb alloy. In some non-limiting examples, the deposited material 731 may comprise Ag, Mg, and Yb. In some non-limiting examples, the deposited layer 130 may comprise an Ag:Mg:Yb alloy.

In some non-limiting examples, the deposited layer 130 may comprise at least one additional element. In some non-limiting examples, such additional element may be a non-metallic element. In some non-limiting examples, the non-metallic element may be at least one of: O, S, N, and C. It will be appreciated by those having ordinary skill in the relevant art that, in some non-limiting examples, such additional element(s) may be incorporated into the deposited layer 130 as a contaminant, due to the presence of such additional element(s) in the source material, equipment used for deposition, and/or the vacuum chamber environment. In some non-limiting examples, the concentration of such additional element(s) may be limited to be below a threshold concentration. In some non-limiting examples, such additional element(s) may form a compound together with other element(s) of the deposited layer 130. In some non-limiting examples, a concentration of the non-metallic element in the deposited material 731 may be one of no more than about: 1%, 0.1%, 0.01%, 0.001%, 0.0001%, 0.00001%, 0.000001%, and 0.0000001%. In some non-limiting examples, the deposited layer 130 may have a composition in which a combined amount of O and C therein may be one of no more than about: 10%, 5%, 1%, 0.1%, 0.01%, 0.001%, 0.0001%, 0.00001%, 0.000001%, and 0.0000001%.

It has now been found, somewhat surprisingly, that reducing a concentration of certain non-metallic elements in the deposited layer 130, particularly in cases wherein the deposited layer 130 may be substantially comprised of metal(s), and/or metal alloy(s), may facilitate selective deposition of the deposited layer 130. Without wishing to be bound by any particular theory, it may be postulated that certain non-metallic elements, such as, in some non-limiting examples, O, or C, when present in the vapor flux 732 of the deposited layer 130, and/or in the deposition chamber, and/or environment, may be deposited onto the surface of the patterning coating 110 to act as nucleation sites for the metallic element(s) of the deposited layer 130. It may be postulated that reducing a concentration of such non-metallic elements that could act as nucleation sites may facilitate reducing an amount of deposited material 731 deposited on the exposed layer surface 11 of the patterning coating 110.

In some non-limiting examples, the deposited material 731 may be deposited on a metal-containing underlying layer. In some non-limiting examples, the deposited material 731 and the underlying layer thereunder may comprise a common metal.

In some non-limiting examples, the deposited layer 130 may comprise a plurality of layers of the deposited material 731. In some non-limiting examples, the deposited material 731 of a first one of the plurality of layers may be different from the deposited material 731 of a second one of the plurality of layers. In some non-limiting examples, the deposited layer 130 may comprise a multilayer coating. In some non-limiting examples, such multilayer coating may be one of: Yb/Ag, Yb/Mg, Yb/Mg:Ag, Yb/Yb:Ag, Yb/Ag/Mg, and Yb/Mg/Ag.

In some non-limiting examples, the deposited material 731 may comprise a metal having a bond dissociation energy, of one of no more than about: 300 kJ/mol, 200 kJ/mol, 165 kJ/mol, 150 kJ/mol, 100 kJ/mol, 50 kJ/mol, and 20 kJ/mol.

In some non-limiting examples, the deposited material 731 may comprise a metal having an electronegativity that is one of no more than about: 1.4, 1.3, and 1.2.

In some non-limiting examples, a sheet resistance of the deposited layer 130 may generally correspond to a sheet resistance of the deposited layer 130, measured or determined in isolation from other components, layers, and/or parts of the device 100. In some non-limiting examples, the deposited layer 130 may be formed as a thin film. Accordingly, in some non-limiting examples, the characteristic sheet resistance for the deposited layer 130 may be determined, and/or calculated based on the composition, thickness, and/or morphology of such thin film. In some non-limiting examples, the sheet resistance may be one of no more than about: 10Ω/□, 5Ω/□, 1Ω/□, 0.5Ω/□, 0.2Ω/□, and 0.1Ω/□.

In some non-limiting examples, the deposited layer 130 may be disposed in a pattern that may be defined by at least one region therein that is substantially devoid of a closed coating 140 of the deposited layer 130. In some non-limiting examples, the at least one region may separate the deposited layer 130 into a plurality of discrete fragments thereof. In some non-limiting examples, each discrete fragment of the deposited layer 130 may be a distinct second portion 102. In some non-limiting examples, the plurality of discrete fragments of the deposited layer 130 may be physically spaced apart from one another in the lateral aspect thereof. In some non-limiting examples, at least two of such plurality of discrete fragments of the deposited layer 130 may be electrically coupled. In some non-limiting examples, at least two of such plurality of discrete fragments of the deposited layer 130 may be each electrically coupled with a common conductive layer or coating, including without limitation, the underlying surface, to allow the flow of electrical current between them. In some non-limiting examples, at least two of such plurality of discrete fragments of the deposited layer 130 may be electrically insulated from one another.

### Selective Deposition Using Patterning Coatings

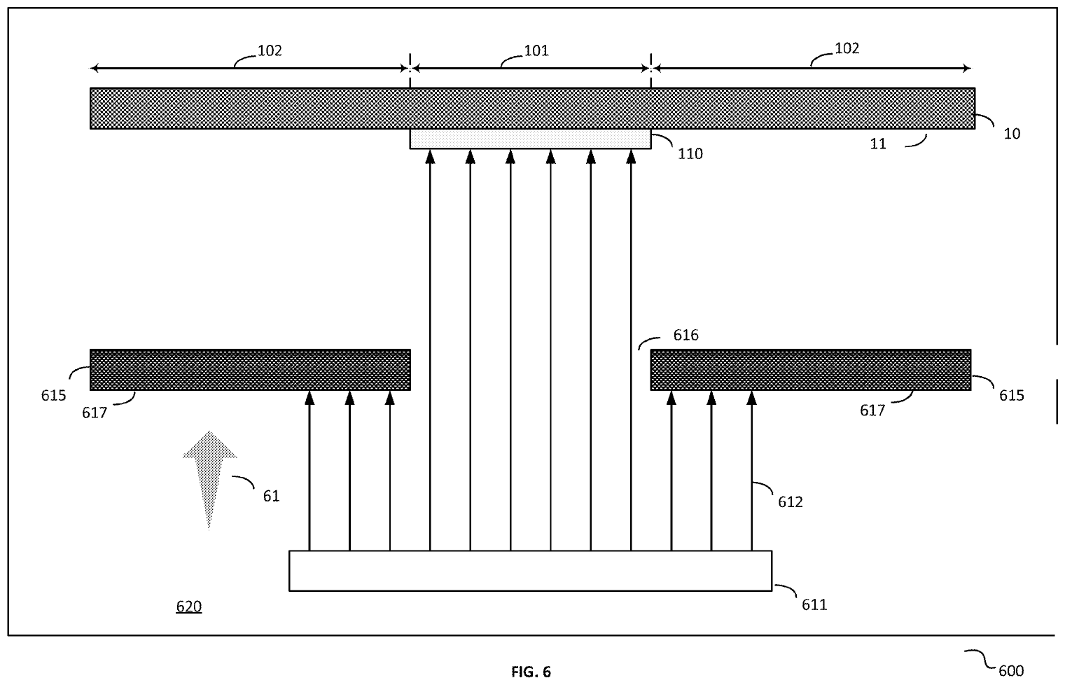

FIG. 6 is an example schematic diagram illustrating a non-limiting example of an evaporative deposition process, shown generally at 600, in a chamber 620, for selectively depositing a patterning coating 110 onto a first portion 101 of an exposed layer surface 11 of the underlying layer.

In the process 600, a quantity of a patterning material 611 is heated under vacuum, to evaporate, and/or sublime the patterning material 611. In some non-limiting examples, the patterning material 611 may comprise entirely, and/or substantially, a material used to form the patterning coating 110. In some non-limiting examples, such material may comprise an organic material.

An evaporated flux 612 of the patterning material 611 may flow through the chamber 620, including in a direction indicated by arrow 61, toward the exposed layer surface 11. When the evaporated flux 612 is incident on the exposed layer surface 11, the patterning coating 110 may be formed thereon.

In some non-limiting examples, as shown in the figure for the process 600, the patterning coating 110 may be selectively deposited only onto a portion, in the example illustrated, the first portion 101, of the exposed layer surface 11, by the interposition, between the evaporated flux 612 and the exposed layer surface 11, of a shadow mask 615, which in some non-limiting examples, may be an FMM. In some non-limiting examples, such a shadow mask 615 may, in some non-limiting examples, be used to form relatively small features, with a feature size on the order of tens of microns or smaller.

The shadow mask 615 may have at least one aperture 616 extending therethrough such that a part of the evaporated flux 612 passes through the aperture 616 and may be incident on the exposed layer surface 11 to form the patterning coating 110. Where the evaporated flux 612 does not pass through the aperture 616 but is incident on the surface 617 of the shadow mask 615, it is precluded from being disposed on the exposed layer surface 11 to form the patterning coating 110. In some non-limiting examples, the shadow mask 615 may be configured such that the evaporated flux 612 that passes through the aperture 616 may be incident on the first portion 101 but not the second portion 102. The second portion 102 of the exposed layer surface 11 may thus be substantially devoid of the patterning coating 110. In some non-limiting examples (not shown), the patterning material 611 that is incident on the shadow mask 615 may be deposited on the surface 617 thereof.

Accordingly, a patterned surface may be produced upon completion of the deposition of the pattering coating 110.

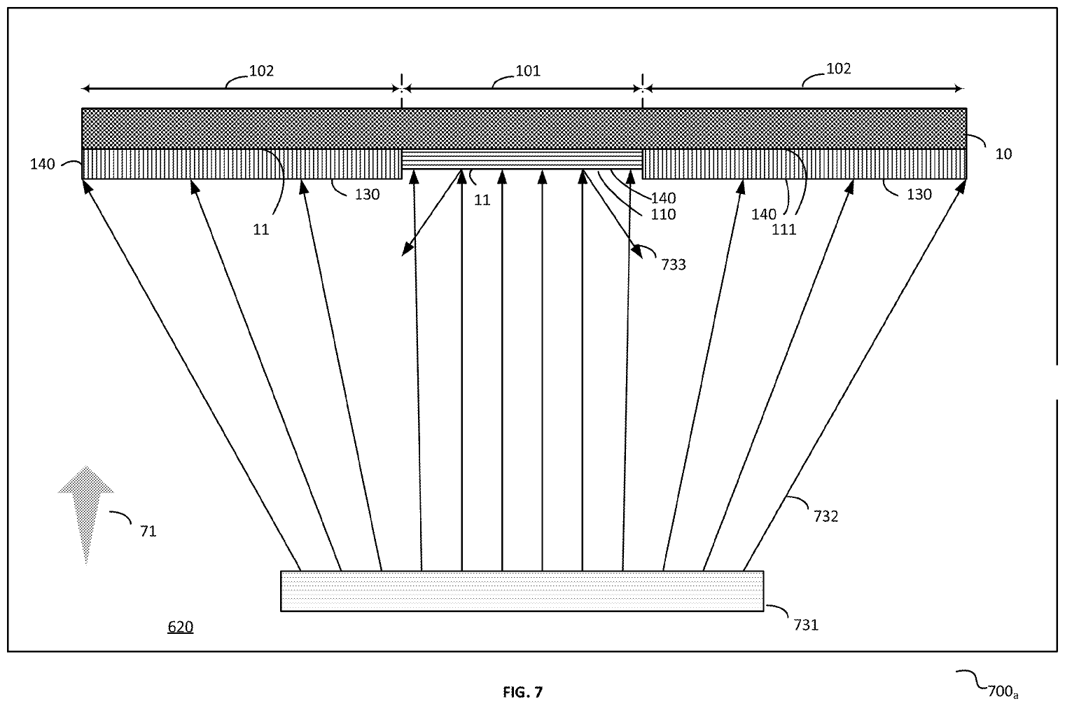

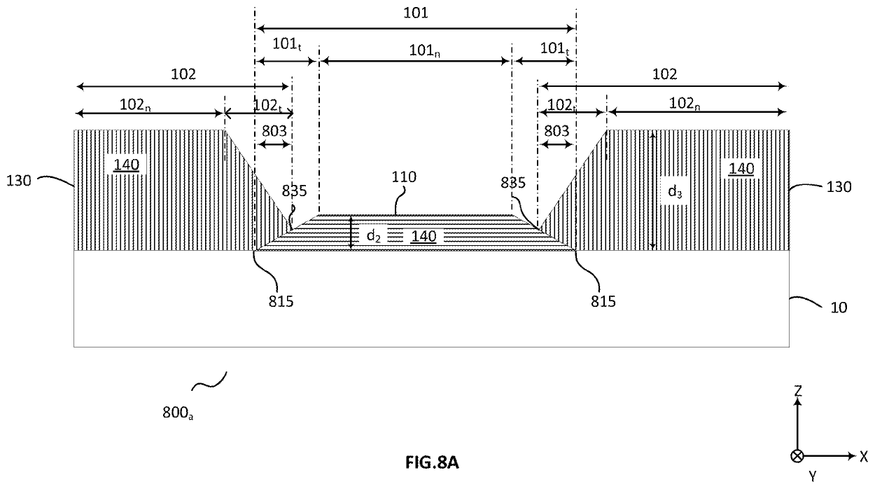

FIG. 7 is an example schematic diagram illustrating a non-limiting example of a result of an evaporative process, shown generally at 700ₐ, in a chamber 620, for selectively depositing a closed coating 140 of a deposited layer 130 onto the second portion 102 of an exposed layer surface 11 of the underlying layer that is substantially devoid of the patterning coating 110 that was selectively deposited onto the first portion 101, including without limitation, by the evaporative process 600 of FIG. 6.

In some non-limiting examples, the deposited layer 130 may be comprised of a deposited material 731, in some non-limiting examples, comprising at least one metal. It will be appreciated by those having ordinary skill in the relevant art that typically, a vaporization temperature of an organic material is low relative to the vaporization temperature of metals, such as may be employed as a deposited material 731.

Thus, in some non-limiting examples, there may be fewer constraints in employing a shadow mask 615 to selectively deposit a patterning coating 110 in a pattern, relative to directly patterning the deposited layer 130 using such shadow mask 615.

Once the patterning coating 110 has been deposited on the first portion 101 of the exposed layer surface 11 of the underlying layer, a closed coating 140 of the deposited material 731 may be deposited, on the second portion 102 of the exposed layer surface 11 that is substantially devoid of the patterning coating 110, as the deposited layer 130.

In the process 700ₐ, a quantity of the deposited material 731 may be heated under vacuum, to evaporate, and/or sublime the deposited material 731. In some non-limiting examples, the deposited material 731 may comprise entirely, and/or substantially, a material used to form the deposited layer 130.

An evaporated flux 732 of the deposited material 731 may be directed inside the chamber 620, including in a direction indicated by arrow 71, toward the exposed layer surface 11 of the first portion 101 and of the second portion 102. When the evaporated flux 732 is incident on the second portion 102 of the exposed layer surface 11, a closed coating 140 of the deposited material 731 may be formed thereon as the deposited layer 130.

In some non-limiting examples, deposition of the deposited material 731 may be performed using an open mask and/or mask-free deposition process.

It will be appreciated by those having ordinary skill in the relevant art that, contrary to that of a shadow mask 615, the feature size of an open mask may be generally comparable to the size of a device 100 being manufactured.

It will be appreciated by those having ordinary skill in the relevant art that, in some non-limiting examples, the use of an open mask may be omitted. In some non-limiting examples, an open mask deposition process described herein may alternatively be conducted without the use of an open mask, such that an entire target exposed layer surface 11 may be exposed.

Indeed, as shown in FIG. 7, the evaporated flux 732 may be incident both on an exposed layer surface 11 of the patterning coating 110 across the first portion 101 as well as the exposed layer surface 11 of the underlying layer across the second portion 102 that is substantially devoid of the patterning coating 110.

Since the exposed layer surface 11 of the patterning coating 110 in the first portion 101 may exhibit a relatively low initial sticking probability against the deposition of the deposited material 731 relative to the exposed layer surface 11 of the underlying layer in the second portion 102, the deposited layer 130 may be selectively deposited substantially only on the exposed layer surface 11, of the underlying layer in the second portion 102, that is substantially devoid of the patterning coating 110. By contrast, the evaporated flux 732 incident on the exposed layer surface 11 of the patterning coating 110 across the first portion 101 may tend to not be deposited (as shown 733), and the exposed layer surface 11 of the patterning coating 110 across the first portion 101 may be substantially devoid of a closed coating 140 of the deposited layer 130.

In some non-limiting examples, an initial deposition rate, of the evaporated flux 732 on the exposed layer surface 11 of the underlying layer in the second portion 102, may exceed one of about: 200 times, 550 times, 900 times, 1,000 times, 1,500 times, 1,900 times, and 2,000 times an initial deposition rate of the evaporated flux 732 on the exposed layer surface 11 of the patterning coating 110 in the first portion 101.

Thus, the combination of the selective deposition of a patterning coating 110 in FIG. 6 using a shadow mask 615 and the open mask and/or mask-free deposition of the deposited material 731 may result in a version 700ₐ of the device 100 shown in FIG. 7.

After selective deposition of the patterning coating 110 across the first portion 101, a closed coating 140 of the deposited material 731 may be deposited over the device 700ₐ as the deposited layer 130, in some non-limiting examples, using an open mask and/or a mask-free deposition process, but may remain substantially only within the second portion 102, which is substantially devoid of the patterning coating 110.

The patterning coating 110 may provide, within the first portion 101, an exposed layer surface 11 with a relatively low initial sticking probability, against the deposition of the deposited material 731, and that is substantially less than the initial sticking probability, against the deposition of the deposited material 731, of the exposed layer surface 11 of the underlying material of the device 700ₐ within the second portion 102.

Thus, the first portion 101 may be substantially devoid of a closed coating 140 of the deposited material 731.

While the present disclosure contemplates the patterned deposition of the pattering coating 110 by an evaporative deposition process, involving a shadow mask 615, those having ordinary skill in the relevant art will appreciate that, in some non-limiting examples, this may be achieved by any suitable deposition process, including without limitation, a micro-contact printing process.

While the present disclosure contemplates the patterning coating 110 being an NIC, those having ordinary skill in the relevant art will appreciate that, in some non-limiting examples, the pattering coating 110 may be an NPC 920. In such examples, the portion (such as, without limitation, the first portion 101) in which the NPC 920 has been deposited may, in some non-limiting examples, have a closed coating 140 of the deposited material 731, while the other portion (such as, without limitation, the second portion 102) may be substantially devoid of a closed coating 140 of the deposited material 731.

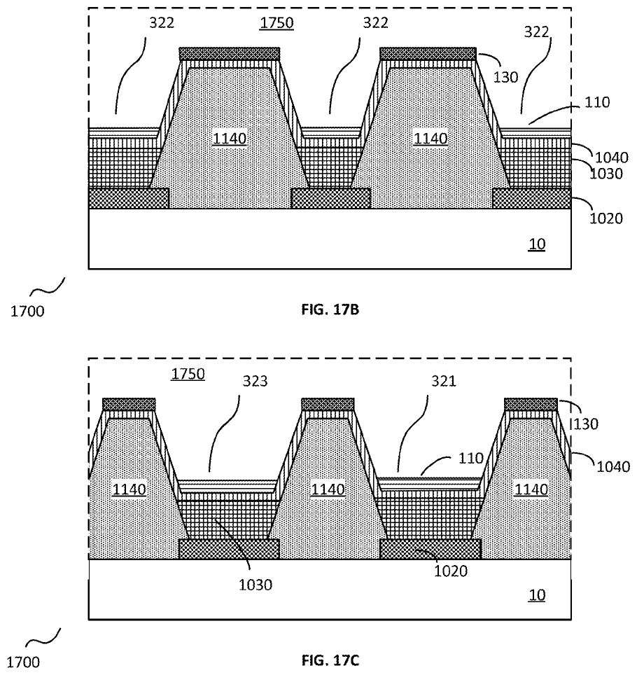

In some non-limiting examples, an average layer thickness of the patterning coating 110 and of the deposited layer 130 deposited thereafter may be varied according to a variety of parameters, including without limitation, a given application and given performance characteristics. In some non-limiting examples, the average layer thickness of the pattering coating 110 may be comparable to, and/or substantially no more than an average layer thickness of the deposited layer 130 deposited thereafter. Use of a relatively thin patterning coating 110 to achieve selective patterning of a deposited layer 130 may be suitable to provide flexible devices 100. In some non-limiting examples, a relatively thin patterning coating 110 may provide a relatively planar surface on which a barrier coating or other thin film encapsulation (TFE) layer 1750 (FIG. 17C), may be deposited. In some non-limiting examples, providing such a relatively planar surface for application of such barrier coating 1450 may increase adhesion thereof to such surface.

### Patterning Coating Transition Region

Turning to FIG. 8A, there may be shown a version 800ₐ of the device 100 of FIG. 1 that may show in exaggerated form, an interface between the patterning coating 110 in the first portion 101 and the deposited layer 130 in the second portion 102. FIG. 8B may show the device 800ₐ in plan.

As may be better seen in FIG. 8B, in some non-limiting examples, the patterning coating 110 in the first portion 101 may be surrounded on all sides by the deposited layer 130 in the second portion 102, such that the first portion 101 may have a boundary that is defined by the further extent or edge 815 of the patterning coating 110 in the lateral aspect along each lateral axis. In some non-limiting examples, the patterning coating edge 815 in the lateral aspect may be defined by a perimeter of the first portion 101 in such aspect.

In some non-limiting examples, the first portion 101 may comprise at least one patterning coating transition region 101ₜ, in the lateral aspect, in which a thickness of the patterning coating 110 may transition from a maximum thickness to a reduced thickness. The extent of the first portion 101 that does not exhibit such a transition may be identified as a patterning coating non-transition part 101ₙ of the first portion 101. In some non-limiting examples, the patterning coating 110 may form a substantially closed coating 140 in the patterning coating non-transition part 101ₙ of the first portion 101.

In some non-limiting examples, the patterning coating transition region 101ₜ may extend, in the lateral aspect, between the patterning coating non-transition part 101ₙ of the first portion 101 and the patterning coating edge 815.

In some non-limiting examples, in plan, the patterning coating transition region 101ₜ may surround, and/or extend along a perimeter of, the patterning coating non-transition part 101ₙ of the first portion 101.

In some non-limiting examples, along at least one lateral axis, the patterning coating non-transition part 101ₙ may occupy the entirety of the first portion 101, such that there is no patterning coating transition region 101ₜ between it and the second portion 102.

As illustrated in FIG. 8A, in some non-limiting examples, the patterning coating 110 may have an average film thickness d₂ in the patterning coating non-transition part 101ₙ of the first portion 101 that may be in a range of one of between about: 1-100 nm, 2-50 nm, 3-30 nm, 4-20 nm, 5-15 nm, 5-10 nm, and 1-10 nm. In some non-limiting examples, the average film thickness d₂ of the patterning coating 110 in the pattering coating non-transition part 101ₙ of the first portion 101 may be substantially the same, or constant, thereacross. In some non-limiting examples, an average layer thickness d₂ of the pattering coating 110 may remain, within the pattering coating non-transition part 101ₙ, within one of about: 95%, and 90% of the average film thickness d₂ of the patterning coating 110.

In some non-limiting examples, the average film thickness d₂ may be between about 1-100 nm. In some non-limiting examples, the average film thickness d₂ may be one of no more than about: 80 nm, 60 nm, 50 nm, 40 nm, 30 nm, 20 nm, 15 nm, and 10 nm. In some non-limiting examples, the average film thickness d₂ of the pattering coating 110 may exceed one of about: 3 nm, 5 nm, and 8 nm.

In some non-limiting examples, the average film thickness d₂ of the pattering coating 110 in the patterning coating non-transition part 101ₙ of the first portion 101 may be no more than about 10 nm. Without wishing to be bound by any particular theory, it has been found, somewhat surprisingly, that a non-zero average film thickness d₂ of the patterning coating 110 that is no more than about 10 nm may, at least in some non-limiting examples, provide certain advantages for achieving, in some non-limiting examples, enhanced patterning contrast of the deposited layer 130, relative to a patterning coating 110 having an average film thickness d₂ in the patterning coating non-transition part 101ₙ of the first portion 101 in excess of 10 nm.

In some non-limiting examples, the patterning coating 110 may have a patterning coating thickness that decreases from a maximum to a minimum within the patterning coating transition region 101ₜ. In some non-limiting examples, the maximum may be at, and/or proximate to, a boundary between the patterning coating transition region 101ₜ and the patterning coating non-transition part 101ₙ of the first portion 101. In some non-limiting examples, the minimum may be at, and/or proximate to, the patterning coating edge 815. In some non-limiting examples, the maximum may be the average film thickness d₂ in the patterning coating non-transition part 101ₙ of the first portion 101. In some non-limiting examples, the maximum may be no more than one of about: 95% and 90% of the average film thickness d₂ in the patterning coating non-transition part 101ₙ of the first portion 101. In some non-limiting examples, the minimum may be in a range of between about 0-0.1 nm.

In some non-limiting examples, a profile of the patterning coating thickness in the patterning coating transition region 101ₜ may be sloped, and/or follow a gradient. In some non-limiting examples, such profile may be tapered. In some non-limiting examples, the taper may follow a linear, non-linear, parabolic, and/or exponential decaying profile.

In some non-limiting examples, the patterning coating 110 may completely cover the underlying surface in the patterning coating transition region 101ₜ. In some non-limiting examples, at least a part of the underlying layer may be left uncovered by the pattering coating 110 in the patterning coating transition region 101ₜ. In some non-limiting examples, the patterning coating 110 may comprise a substantially closed coating 140 in at least a part of the patterning coating transition region 101ₜ and/or at least a part of the patterning coating non-transition part 101ₙ.

In some non-limiting examples, the patterning coating 110 may comprise a discontinuous layer 840 in at least a part of the patterning coating transition region 101ₜ and/or at least a part of the patterning coating non-transition part 101ₙ.

In some non-limiting examples, at least a part of the patterning coating 110 in the first portion 101 may be substantially devoid of a closed coating 140 of the deposited layer 130. In some non-limiting examples, at least a part of the exposed layer surface 11 of the first portion 101 may be substantially devoid of a closed coating 140 of the deposited layer 130 or of the deposited material 731.

In some non-limiting examples, along at least one lateral axis, including without limitation, the X-axis, the patterning coating non-transition part 101ₙ may have a width of w₁, and the patterning coating transition region 101ₜ may have a width of w₂. In some non-limiting examples, the patterning coating non-transition part 101ₙ may have a cross-sectional area that, in some non-limiting examples, may be approximated by multiplying the average film thickness d₂ by the width wt. In some non-limiting examples, the patterning coating transition region 101ₜ may have a cross-sectional area that, in some non-limiting examples, may be approximated by multiplying an average film thickness across the patterning coating transition region 101ₜ by the width w₁.

In some non-limiting examples, w₁ may exceed w₂. In some non-limiting examples, a quotient of w₁/w₂ may be one of at least about: 5, 10, 20, 50, 100, 500, 1,000, 1,500, 5,000, 10,000, 50,000, and 100,000.

In some non-limiting examples, at least one of w₁ and w₂ may exceed the average film thickness d₁ of the underlying layer.

In some non-limiting examples, at least one of w₁ and w₂ may exceed d₂. In some non-limiting examples, both w₁ and w₂ may exceed d₂. In some non-limiting examples, w₁ and w₂ both may exceed d₁, and d₁ may exceed d₂.

### Deposited Layer Transition Region

As may be better seen in FIG. 8B, in some non-limiting examples, the patterning coating 110 in the first portion 101 may be surrounded by the deposited layer 130 in the second portion 102 such that the second portion 102 has a boundary that is defined by the further extent or edge 835 of the deposited layer 130 in the lateral aspect along each lateral axis. In some non-limiting examples, the deposited layer edge 835 in the lateral aspect may be defined by a perimeter of the second portion 102 in such aspect.

In some non-limiting examples, the second portion 102 may comprise at least one deposited layer transition region 102ₜ, in the lateral aspect, in which a thickness of the deposited layer 130 may transition from a maximum thickness to a reduced thickness. The extent of the second portion 102 that does not exhibit such a transition may be identified as a deposited layer non-transition part 102ₙ of the second portion 102. In some non-limiting examples, the deposited layer 130 may form a substantially closed coating 140 in the deposited layer non-transition part 102ₙ of the second portion 102.

In some non-limiting examples, in plan, the deposited layer transition region 102ₜ may extend, in the lateral aspect, between the deposited layer non-transition part 102ₙ of the second portion 102 and the deposited layer edge 835.

In some non-limiting examples, in plan, the deposited layer transition region 102ₜ may surround, and/or extend along a perimeter of, the deposited layer non-transition part 102ₙ of the second portion 102.

In some non-limiting examples, along at least one lateral axis, the deposited layer non-transition part 102ₙ of the second portion 102 may occupy the entirety of the second portion 102, such that there is no deposited layer transition region 102ₜ between it and the first portion 101.

As illustrated in FIG. 8A, in some non-limiting examples, the deposited layer 130 may have an average film thickness d₃ in the deposited layer non-transition part 102ₙ of the second portion 102 that may be in a range of one of between about: 1-500 nm, 5-200 nm, 5-40 nm, 10-30 nm, and 10-100 nm. In some non-limiting examples, d₃ may exceed one of about: 10 nm, 50 nm, and 100 nm. In some non-limiting examples, the average film thickness d₃ of the deposited layer 130 in the deposited layer non-transition part 102ₜ of the second portion 102 may be substantially the same, or constant, thereacross.

In some non-limiting examples, d₃ may exceed the average film thickness d of the underlying layer.

In some non-limiting examples, a quotient d₃/d₁ may be one of at least about: 1.5, 2, 5, 10, 20, 50, and 100. In some non-limiting examples, the quotient d₃/d₁ may be in a range of one of between about: 0.1-10, and 0.2-40.

In some non-limiting examples, d₃ may exceed an average film thickness d₂ of the patterning coating 110.

In some non-limiting examples, a quotient d₃/d₂ may be one of at least about: 1.5, 2, 5, 10, 20, 50, and 100. In some non-limiting examples, the quotient d₃/d₂ may be in a range of one of between about: 0.2-10, and 0.5-40.

In some non-limiting examples, d₃ may exceed d₂ and d₂ may exceed d₁. In some other non-limiting examples, d₃ may exceed d₁ and d₁ may exceed d₂.

In some non-limiting examples, a quotient d₂/d₁ may be between one of about: 0.2-3, and 0.1-5.

In some non-limiting examples, along at least one lateral axis, including without limitation, the X-axis, the deposited layer non-transition part 102ₙ of the second portion 102 may have a width of w₃. In some non-limiting examples, the deposited layer non-transition part 102ₙ of the second portion 102 may have a cross-sectional area a₃ that, in some non-limiting examples, may be approximated by multiplying the average film thickness d₃ by the width w₃.

In some non-limiting examples, w₃ may exceed the width w₁ of the patterning coating non-transition part 101ₙ. In some non-limiting examples, w₁ may exceed w₃.

In some non-limiting examples, a quotient w₁/w₃ may be in a range of one of between about: 0.1-10, 0.2-5, 0.3-3, and 0.4-2. In some non-limiting examples, a quotient w₃/w₁ may be one of at least about: 1, 2, 3, and 4.

In some non-limiting examples, w₃ may exceed the average film thickness d₃ of the deposited layer 130.

In some non-limiting examples, a quotient w₃/d₃ may be at least one of at least about: 10, 50, 100, or 500. In some non-limiting examples, the quotient w₃/d₃ may be no more than about 100,000.

In some non-limiting examples, the deposited layer 130 may have a thickness that decreases from a maximum to a minimum within the deposited layer transition region 102ₜ. In some non-limiting examples, the maximum may be at, and/or proximate to, the boundary between the deposited layer transition region 102ₜ and the deposited layer non-transition part 102ₙ of the second portion 102. In some non-limiting examples, the minimum may be at, and/or proximate to, the deposited layer edge 835. In some non-limiting examples, the maximum may be the average film thickness d₃ in the deposited layer non-transition part 102ₙ of the second portion 102. In some non-limiting examples, the minimum may be in a range of between about 0-0.1 nm. In some non-limiting examples, the minimum may be the average film thickness d₃ in the deposited layer non-transition part 102ₙ of the second portion 102.

In some non-limiting examples, a profile of the thickness in the deposited layer transition region 102ₜ may be sloped, and/or follow a gradient. In some non-limiting examples, such profile may be tapered. In some non-limiting examples, the taper may follow a linear, non-linear, parabolic, and/or exponential decaying profile.

In some non-limiting examples, as shown in some non-limiting examples in the example version 800ₑ in FIG. 8E of the device 100, the deposited layer 130 may completely cover the underlying surface in the deposited layer transition region 102ₜ. In some non-limiting examples, the deposited layer 130 may comprise a substantially closed coating 140 in at least a part of the deposited layer transition region 102ₜ. In some non-limiting examples, at least a part of the underlying surface may be uncovered by the deposited layer 130 in the deposited layer transition region 102ₜ.

In some non-limiting examples, the deposited layer 130 may comprise a discontinuous layer 840 in at least a part of the deposited layer transition region 102ₜ.

Those having ordinary skill in the relevant art will appreciate that, while not explicitly illustrated, the patterning material 611 may also be present to some extent at an interface between the deposited layer 130 and an underlying layer. Such material may be deposited as a result of a shadowing effect, in which a deposited pattern is not identical to a pattern of a mask and may, in some non-limiting examples, result in some evaporated patterning material 611 being deposited on a masked part of a target exposed layer surface 11. In some non-limiting examples, such material may form as particle structures 841 and/or as a thin film having a thickness that may be substantially no more than an average thickness of the patterning coating 110.

### Overlap

In some non-limiting examples, the deposited layer edge 835 may be spaced apart, in the lateral aspect from the patterning coating transition region 101ₜ of the first portion 101, such that there is no overlap between the first portion 101 and the second portion 102 in the lateral aspect.

In some non-limiting examples, at least a part of the first portion 101 and at least a part of the second portion 102 may overlap in the lateral aspect. Such overlap may be identified by an overlap portion 803, such as may be shown in some non-limiting examples in FIG. 8A, in which at least a part of the second portion 102 overlaps at least a part of the first portion 101.

In some non-limiting examples, as shown in some non-limiting examples in FIG. 8F, at least a part of the deposited layer transition region 102ₜ may be disposed over at least a part of the patterning coating transition region 101ₜ. In some non-limiting examples, at least a part of the patterning coating transition region 101ₜ may be substantially devoid of the deposited layer 130, and/or the deposited material 731. In some non-limiting examples, the deposited material 731 may form a discontinuous layer 840 on an exposed layer surface 11 of at least a part of the patterning coating transition region 101ₜ.

In some non-limiting examples, as shown in some non-limiting examples in FIG. 8G, at least a part of the deposited layer transition region 102ₜ may be disposed over at least a part of the patterning coating non-transition part 101ₙ of the first portion 101.

Although not shown, those having ordinary skill in the relevant art will appreciate that, in some non-limiting examples, the overlap portion 803 may reflect a scenario in which at least a part of the first portion 101 overlaps at least a part of the second portion 102.

Thus, in some non-limiting examples, at least a part of the patterning coating transition region 101ₜ may be disposed over at least a part of the deposited layer transition region 102ₜ. In some non-limiting examples, at least a part of the deposited layer transition region 102ₜ may be substantially devoid of the pattering coating 110, and/or the patterning material 611. In some non-limiting examples, the patterning material 611 may form a discontinuous layer 840 on an exposed layer surface of at least a part of the deposited layer transition region 102ₜ.

In some non-limiting examples, at least a part of the pattering coating transition region 101ₜ may be disposed over at least a part of the deposited layer non-transition part 102ₙ of the second portion 102.

In some non-limiting examples, the patterning coating edge 815 may be spaced apart, in the lateral aspect, from the deposited layer non-transition part 102ₙ of the second portion 102.

In some non-limiting examples, the deposited layer 130 may be formed as a single monolithic coating across both the deposited layer non-transition part 102ₙ and the deposited layer transition region 102ₜ of the second portion 102.

### Edge Effects of Patterning Coatings and Deposited Layers

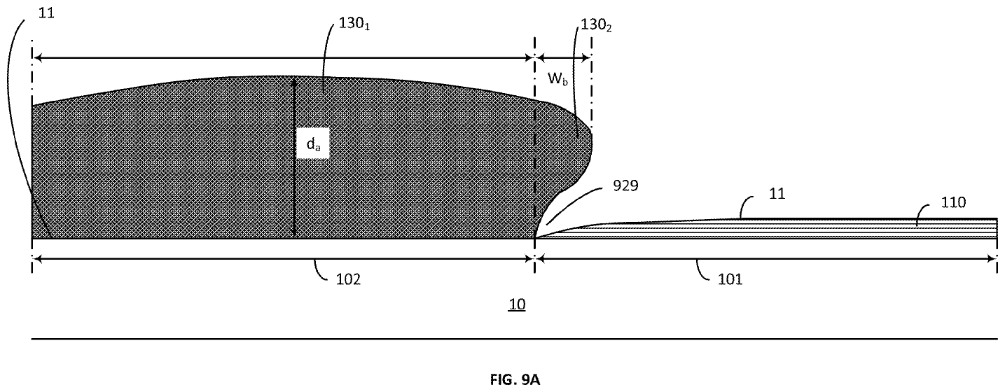

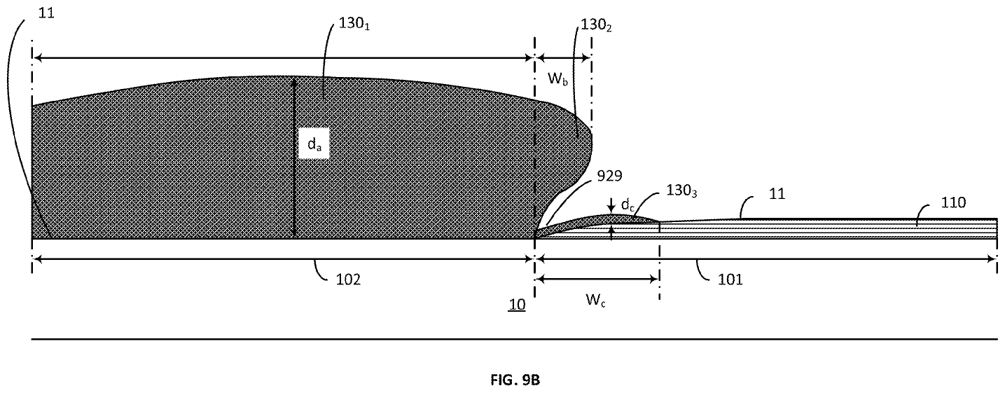

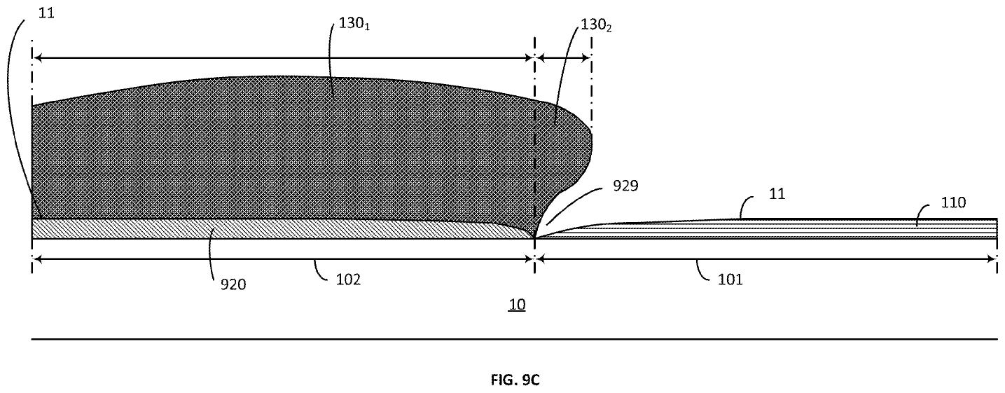

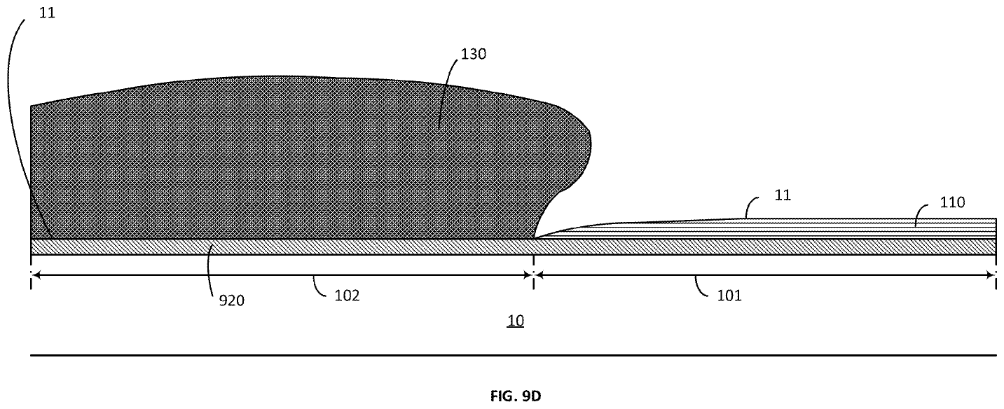

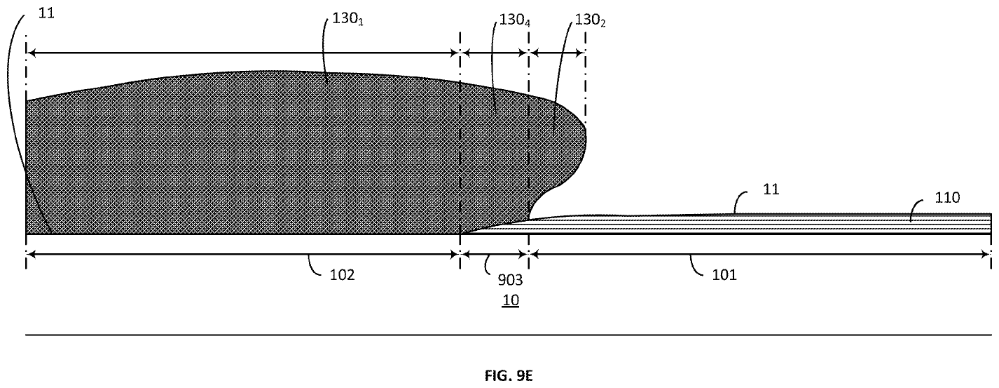

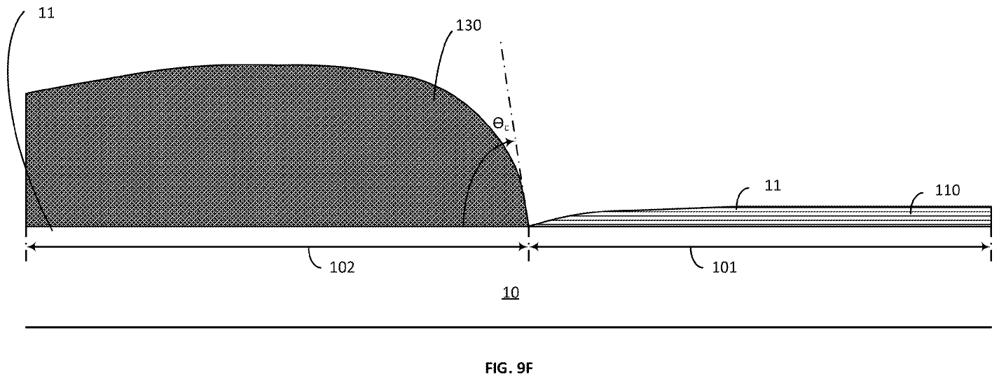

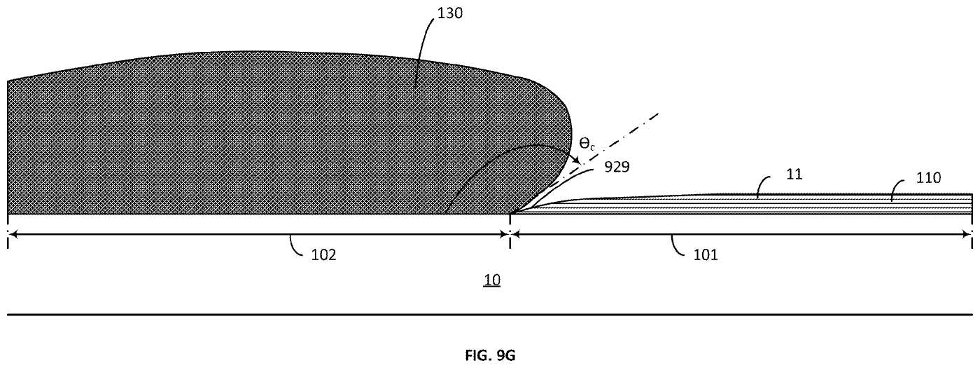

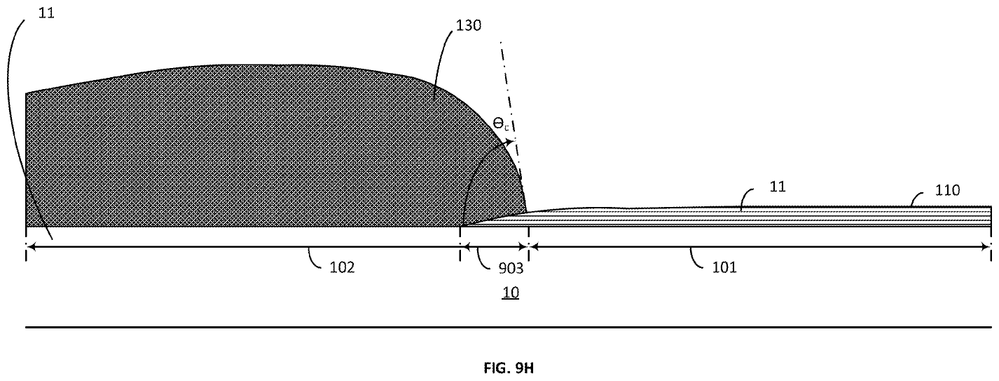

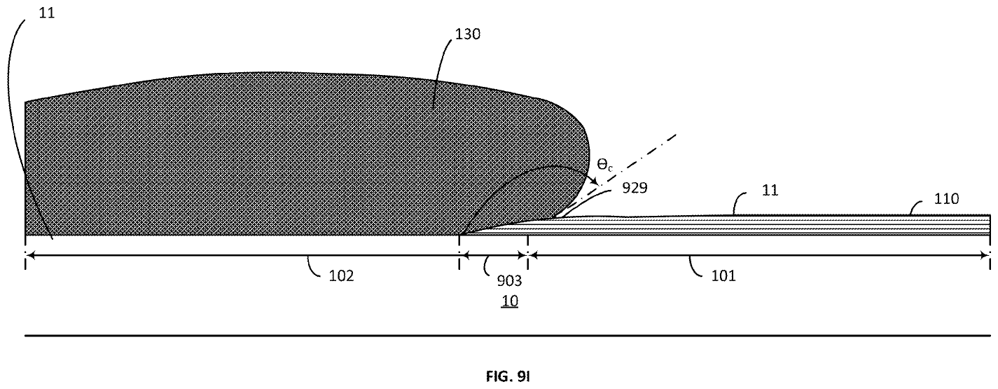

FIGS. 9A-9I describe various potential behaviours of pattering coatings 110 at a deposition interface with deposited layers 130.

Turning to FIG. 9A, there may be shown a first example of a part of an example version 900 of the device 100 at a patterning coating deposition boundary. The device 900 may comprise a substrate 10 having an exposed layer surface 11. A patterning coating 110 may be deposited over a first portion 101 of the exposed layer surface 11. A deposited layer 130 may be deposited over a second portion 102 of the exposed layer surface 11. As shown, in some non-limiting examples, the first portion 101 and the second portion 102 may be distinct and non-overlapping parts of the exposed layer surface 11.

The deposited layer 130 may comprise a first part 130₁ and a second part 130₂. As shown, in some non-limiting examples, the first part 130₁ of the deposited layer 130 may substantially cover the second portion 102 and the second part 130₂ of the deposited layer 130 may partially project over, and/or overlap a first part of the pattering coating 110.

In some non-limiting examples, since the pattering coating 110 may be formed such that its exposed layer surface 11 exhibits a relatively low initial sticking probability against deposition of the deposited material 731, there may be a gap 929 formed between the projecting, and/or overlapping second part 130₂ of the deposited layer 130 and the exposed layer surface 11 of the pattering coating 110. As a result, the second part 130₂ may not be in physical contact with the pattering coating 110 but may be spaced-apart therefrom by the gap 929 in a cross-sectional aspect. In some non-limiting examples, the first part 130₁ of the deposited layer 130 may be in physical contact with the patterning coating 110 at an interface, and/or boundary between the first portion 101 and the second portion 102.

In some non-limiting examples, the projecting, and/or overlapping second part 130₂ of the deposited layer 130 may extend laterally over the patterning coating 110 by a comparable extent as an average layer thickness dₐ of the first part 130₁ of the deposited layer 130. In some non-limiting examples, as shown, a width w_{b} of the second part 130₂ may be comparable to the average layer thickness do of the first part 130₁. In some non-limiting examples, a ratio of a width w_{b} of the second part 130₂ by an average layer thickness dₐ of the first part 130₁ may be in a range of one of between about: 1:1-1:3, 1:1-1:1.5, and 1:1-1:2. While the average layer thickness dₐ may in some non-limiting examples be relatively uniform across the first part 130₁, in some non-limiting examples, the extent to which the second part 130₂ may project, and/or overlap with the patterning coating 110 (namely m) may vary to some extent across different parts of the exposed layer surface 11.

Turning now to FIG. 9B, the deposited layer 130 may be shown to include a third part 130₃ disposed between the second part 130₂ and the patterning coating 110. As shown, the second part 130₂ of the deposited layer 130 may extend laterally over and is longitudinally spaced apart from the third part 130₃ of the deposited layer 130 and the third part 130₃ may be in physical contact with the exposed layer surface 11 of the patterning coating 110. An average layer thickness de of the third part 130₃ of the deposited layer 130 may be no more than, and in some non-limiting examples, substantially less than, the average layer thickness dₐ of the first part 130₁ thereof. In some non-limiting examples, a width w_{c} of the third part 130₃ may exceed the width w_{b} of the second part 130₂. In some non-limiting examples, the third part 130₃ may extend laterally to overlap the patterning coating 110 to a greater extent than the second part 130₂. In some non-limiting examples, a ratio of a width w_{c} of the third part 130₃ by an average layer thickness dₐ of the first part 130₁ may be in a range of one of between about: 1:2-3:1, and 1:1.2-2.5:1. While the average layer thickness dₐ may in some non-limiting examples be relatively uniform across the first part 130₁, in some non-limiting examples, the extent to which the third part 130₃ may project, and/or overlap with the patterning coating 110 (namely w_{c}) may vary to some extent across different parts of the exposed layer surface 11.

In some non-limiting examples, the average layer thickness de of the third part 130₃ may not exceed about 5% of the average layer thickness dₐ of the first part 130₁. In some non-limiting examples, de may be one of no more than about: 4%, 3%, 2%, 1%, and 0.5% of dₐ. Instead of, and/or in addition to, the third part 130₃ being formed as a thin film, as shown, the deposited material 731 of the deposited layer 130 may form as particle structures 841 on a part of the patterning coating 110. In some non-limiting examples, such particle structures 841 may comprise features that are physically separated from one another, such that they do not form a continuous layer.

Turning now to FIG. 9C, an NPC 920 may be disposed between the substrate 10 and the deposited layer 130. The NPC 920 may be disposed between the first part 130₁ of the deposited layer 130 and the second portion 102 of the substrate 10. The NPC 920 is illustrated as being disposed on the second portion 102 and not on the first portion 101, where the patterning coating 110 has been deposited. The NPC 920 may be formed such that, at an interface, and/or boundary between the NPC 920 and the deposited layer 130, a surface of the NPC 920 may exhibit a relatively high initial sticking probability against deposition of the deposited material 731. As such, the presence of the NPC 920 may promote the formation, and/or growth of the deposited layer 130 during deposition.

Turning now to FIG. 9D, the NPC 920 may be disposed on both the first portion 101 and the second portion 102 of the substrate 10 and the patterning coating 110 may cover a part of the NPC 920 disposed on the first portion 101. Another part of the NPC 920 may be substantially devoid of the patterning coating 110 and the deposited layer 130 may cover such part of the NPC 920.

Turning now to FIG. 9E, the deposited layer 130 may be shown to partially overlap a part of the patterning coating 110 in a third portion 903 of the substrate 10. In some non-limiting examples, in addition to the first part 130₁ and the second part 130₂, the deposited layer 130 may further include a fourth part 130₄. As shown, the fourth part 130₄ of the deposited layer 130 may be disposed between the first part 130₁ and the second part 130₂ of the deposited layer 130 and the fourth part 130₄ may be in physical contact with the exposed layer surface 11 of the patterning coating 110. In some non-limiting examples, the overlap in the third portion 903 may be formed as a result of lateral growth of the deposited layer 130 during an open mask and/or mask-free deposition process. In some non-limiting examples, while the exposed layer surface 11 of the patterning coating 110 may exhibit a relatively low initial sticking probability against deposition of the deposited material 731, and thus a probability of the material nucleating on the exposed layer surface 11 may be low, as the deposited layer 130 grows in thickness, the deposited layer 130 may also grow laterally and may cover a subset of the patterning coating 110 as shown.

Turning now to FIG. 9F the first portion 101 of the substrate 10 may be coated with the patterning coating 110 and the second portion 102 adjacent thereto may be coated with the deposited layer 130. In some non-limiting examples, it has been observed that conducting an open mask and/or mask-free deposition of the deposited layer 130 may result in the deposited layer 130 exhibiting a tapered cross-sectional profile at, and/or near an interface between the deposited layer 130 and the patterning coating 110.

In some non-limiting examples, an average layer thickness of the deposited layer 130 at, and/or near the interface may be less than an average layer thickness d₃ of the deposited layer 130. While such tapered profile may be shown as being curved, and/or arched, in some non-limiting examples, the profile may, in some non-limiting examples be substantially linear, and/or non-linear. In some non-limiting examples, an average layer thickness d₃ of the deposited layer 130 may decrease, without limitation, in a substantially linear, exponential, and/or quadratic fashion in a region proximal to the interface.

It has been observed that a contact angle θ_{c} of the deposited layer 130 at, and/or near the interface between the deposited layer 130 and the pattering coating 110 may vary, depending on properties of the patterning coating 110, such as a relative initial sticking probability. It may be further postulated that the contact angle θ_{c} of the nuclei may, in some non-limiting examples, dictate the thin film contact angle of the deposited layer 130 formed by deposition. Referring to FIG. 9F, in some non-limiting examples, the contact angle θ_{c} may be determined by measuring a slope of a tangent of the deposited layer 130 at and/or near the interface between the deposited layer 130 and the pattering coating 110. In some non-limiting examples, where the cross-sectional taper profile of the deposited layer 130 may be substantially linear, the contact angle θ_{c} may be determined by measuring the slope of the deposited layer 130 at, and/or near the interface. As will be appreciated by those having ordinary skill in the relevant art, the contact angle θ_{c} may be generally measured relative to a non-zero angle of the underlying layer. In the present disclosure, for purposes of simplicity of illustration, the pattering coating 110 and the deposited layer 130 may be shown deposited on a planar surface. However, those having ordinary skill in the relevant art will appreciate that the patterning coating 110 and the deposited layer 130 may be deposited on non-planar surfaces.

In some non-limiting examples, the contact angle θ_{c} of the deposited layer 130 may exceed about 90°. Referring now to FIG. 9G, in some non-limiting examples, the deposited layer 130 may be shown as including a part extending past the interface between the patterning coating 110 and the deposited layer 130 and may be spaced apart from the patterning coating 110 by a gap 929. In such non-limiting scenario, the contact angle θ_{c} may, in some non-limiting examples, exceed 90°.

In some non-limiting examples, it may be advantageous to form a deposited layer 130 exhibiting a relatively high contact angle θ_{c}. In some non-limiting examples, the contact angle θ_{c} e may exceed one of about: 10°, 15°, 20°, 25°, 30°, 35°, 40°, 50°, 70°, 75°, and 80°. In some non-limiting examples, a deposited layer 130 having a relatively high contact angle θ_{c} may allow for creation of finely patterned features while maintaining a relatively high aspect ratio. In some non-limiting examples, there may be an aim to form a deposited layer 130 exhibiting a contact angle θ_{c} greater than about 90°. In some non-limiting examples, the contact angle θ_{c} may exceed at least one of about: 90°, 95°, 100°, 105°, 110° 120°, 130°, 135°, 140°, 145°, 150°, and 170°.

Turning now to FIGS. 9H-9I, the deposited layer 130 may partially overlap a part of the patterning coating 110 in the third portion 903 of the substrate 10, which may be disposed between the first portion 101 and the second portion 102 thereof. As shown, the subset of the deposited layer 130 partially overlapping a subset of the patterning coating 110 may be in physical contact with the exposed layer surface 11 thereof. In some non-limiting examples, the overlap in the third portion 903 may be formed because of lateral growth of the deposited layer 130 during an open mask and/or mask-free deposition process. In some non-limiting examples, while the exposed layer surface 11 of the patterning coating 110 may exhibit a relatively low initial sticking probability against deposition of the deposited material 731 and thus the probability of the material nucleating on the exposed layer surface 11 is low, as the deposited layer 130 grows in thickness, the deposited layer 130 may also grow laterally and may cover a subset of the pattering coating 110.

In the case of FIGS. 9H-9I, the contact angle θ_{c} of the deposited layer 130 may be measured at an edge thereof near the interface between it and the patterning coating 110, as shown. In FIG. 9I, the contact angle θ_{c} may exceed about 90°, which may in some non-limiting examples result in a subset of the deposited layer 130 being spaced apart from the patterning coating 110 by the gap 929.

### Particle Structure

A nanoparticle (NP) is a particle structure 841 of matter whose predominant characteristic size is of nanometer (nm) scale, generally understood to be between about: 1-300 nm. At nm scale, NPs of a given material may possess unique properties (including without limitation, optical, chemical, physical, and/or electrical) relative to the same material in bulk form.

These properties may be exploited when a plurality of NPs is formed into a layer of a layered semiconductor device, including without limitation, an opto-electronic device, to improve its performance.

Current mechanisms for introducing such a layer of NPs into a device have some drawbacks.

First, typically, such NPs are formed into a close-packed layer, and/or dispersed into a matrix material, of such device. Consequently, the thickness of such an NP layer may be typically much thicker than the characteristic size of the NPs themselves. The thickness of such NP layer may impart undesirable characteristics in terms of device performance, device stability, device reliability, and/or device lifetime that may reduce or even obviate any perceived advantages provided by the unique properties of NPs.

Second, techniques to synthesize NPs, in and for use in such devices may introduce large amounts of carbon (C), oxygen (O), and/or sulfur (S) through various mechanisms.

In some non-limiting examples, wet chemical methods may be typically used to introduce NPs that have a precisely controlled characteristic size, size distribution, shape, surface coverage, configuration, and/or deposited density into a device. However, such methods typically employ an organic capping group (such as the synthesis of citrate-capped Ag NPs) to stabilize the NPs, but such organic capping groups introduce C, O, and/or S, into the synthesized NPs.

Still further, an NP layer deposited from solution may typically comprise C, O, and/or S, because of the solvents used in deposition.

Additionally, these elements may be introduced as contaminants during the wet chemical process and/or the deposition of the NP layer.

However introduced, the presence of a high amount of C, O, and/or S, in the NP layer of such a device, may erode the performance, stability, reliability, and/or lifetime of such device.

Third, when depositing an NP layer from solution, as the employed solvents dry, the NP layer tends to have non-uniform properties across the NP layer, and/or between different patterned regions of such layer. In some non-limiting examples, an edge of a given NP layer may be considerably thicker or thinner than an internal region of such NP layer, which disparities may adversely impact the device performance, stability, reliability, and/or lifetime.

Fourth, while there are other methods and/or processes, beyond wet chemical synthesis and solution deposition processes, of synthesizing and/or depositing NPs, including without limitation, a vacuum-based process such as, without limitation, PVD, existing methods tend to provide poor control of the characteristic size, size distribution, shape, surface coverage, configuration, deposited density, and/or dispersity of the NPs deposited thereby. In some non-limiting examples, in a conventional PVD process, the NPs tend to form a close-packed film as their size increases. As a result, methods such as conventional PVD methods are generally not well-suited to form an NP layer of large disperse NPs with low surface coverage. Rather, the poor control of characteristic size, size distribution, shape, surface coverage, configuration, and/or deposited density, imparted by such conventional methods may result in poor device performance, stability, reliability, and/or lifetime.

In some non-limiting examples, such as may be shown in FIG. 8C, there may be at least one particle, including without limitation, a nanoparticle (NP), an island, a plate, a disconnected cluster, and/or a network (collectively particle structure 841) disposed on an exposed layer surface 11 of an underlying layer. In some non-limiting examples, the underlying layer may be the patterning coating 110 in the first portion 101. In some non-limiting examples, the at least one particle structure 841 may be disposed on an exposed layer surface 11 of the patterning coating 110. In some non-limiting examples, there may be a plurality of such particle structures 841.

In some non-limiting examples, the at least one particle structure 841 may comprise a particle material. In some non-limiting examples, the particle material may be the same as the deposited material 731 in the deposited layer.

In some non-limiting examples, the particle material in the discontinuous layer 840 in the first portion 101, the deposited material 731 in the deposited layer 130, and/or a material of which the underlying layer thereunder may be comprised, may comprise a common metal.

In some non-limiting examples, the particle material may comprise an element selected from at least one of: K, Na, Li, Ba, Cs, Yb, Ag, Au, Cu, Al, Mg, Zn, Cd, Sn, and Y. In some non-limiting examples, the element may comprise at least one of: K, Na, Li, Ba, Cs, Yb, Ag, Au, Cu, Al, and Mg. In some non-limiting examples, the element may comprise at least one of: Cu, Ag, and Au. In some non-limiting examples, the element may be Cu. In some non-limiting examples, the element may be Al. In some non-limiting examples, the element may comprise at least one of: Mg, Zn, Cd, and Yb. In some non-limiting examples, the element may comprise at least one of: Mg, Ag, Al, Yb, and Li. In some non-limiting examples, the element may comprise at least one of: Mg, Ag, and Yb. In some non-limiting examples, the element may comprise at least one of: Mg, and Ag. In some non-limiting examples, the element may be Ag.

In some non-limiting examples, the particle material may comprise a pure metal. In some non-limiting examples, the at least one particle structure 841 may be a pure metal. In some non-limiting examples, the at least one particle structure 841 may be at least one of: pure Ag or substantially pure Ag. In some non-limiting examples, the substantially pure Ag may have a purity of one of about: 95%, 99%, 99.9%, 99.99%, 99.999%, and 99.9995%. In some non-limiting examples, the at least one particle structure 841 may be one of: pure Mg or substantially pure Mg. In some non-limiting examples, the substantially pure Mg may have a purity of one of at least about: 95%, 99%, 99.9%, 99.99%, 99.999%, and 99.9995%.

In some non-limiting examples, the at least one particle structure 841 may comprise an alloy. In some non-limiting examples, the alloy may be at least one of: an Ag-containing alloy, an Mg-containing alloy, and an AgMg-containing alloy. In some non-limiting examples, the AgMg-containing alloy may have an alloy composition that may range from about 1:10 (Ag:Mg) to about 10:1 by volume.

In some non-limiting examples, the particle material may comprise other metals in place of, or in combination with Ag. In some non-limiting examples, the particle material may comprise an alloy of Ag with at least one other metal. In some non-limiting examples, the particle material may comprise an alloy of Ag with at least one of: Mg, and Yb. In some non-limiting examples, such alloy may be a binary alloy having a composition of between about: 5-95 vol. % Ag, with the remainder being the other metal. In some non-limiting examples, the particle material may comprise Ag and Mg. In some non-limiting examples, the particle material may comprise an Ag:Mg alloy having a composition of between about 1:10-10:1 by volume. In some non-limiting examples, the particle material may comprise Ag and Yb. In some non-limiting examples, the particle material may comprise a Yb:Ag alloy having a composition of between about 1:20-10:1 by volume. In some non-limiting examples, the particle material may comprise Mg and Yb. In some non-limiting examples, the particle material may comprise an Mg:Yb alloy. In some non-limiting examples, the particle material may comprise an Ag:Mg:Yb alloy.

In some non-limiting examples, the at least one particle structure 841 may comprise at least one additional element. In some non-limiting examples, such additional element may be a non-metallic element. In some non-limiting examples, the non-metallic material may be at least one of: O, S, N, and C. It will be appreciated by those having ordinary skill in the relevant art that, in some non-limiting examples, such additional element(s) may be incorporated into the at least one particle structure 841 as a contaminant, due to the presence of such additional element(s) in the source material, equipment used for deposition, and/or the vacuum chamber environment. In some non-limiting examples, such additional element(s) may form a compound together with other element(s) of the at least one particle structure 841. In some non-limiting examples, a concentration of the non-metallic element in the particle material may be one of no more than about: 1%, 0.1%, 0.01%, 0.001%, 0.0001%, 0.00001%, 0.000001%, and 0.0000001%. In some non-limiting examples, the at least one particle structure 841 may have a composition in which a combined amount of O and C therein is one of no more than about: 10%, 5%, 1%, 0.1%, 0.01%, 0.001%, 0.0001%, 0.00001%, 0.000001%, and 0.0000001%.

The at least one particle 841 take advantage of plasmonics, a branch of nanophotonics, which studies the resonant interaction of EM radiation with metals. Those having ordinary skill in the relevant art will appreciate that metal NPs may exhibit LSP excitations and/or coherent oscillations of free electrons, whose optical response may be tailored by varying a characteristic size, size distribution, shape, surface coverage, configuration, deposited density, and/or composition of the nanostructures. Such optical response, in respect of particle structures 841, may include absorption of EM radiation incident thereon, thereby reducing reflection thereof and/or shifting to a lower or higher wavelength ((sub-) range) of the EM spectrum, including without limitation, the visible spectrum, and/or a sub-range thereof.

It has also been reported that arranging certain metal NPs near a medium having relatively low refractive index, may shift the absorption spectrum of such NPs to a lower wavelength (sub-) range (blue-shifted).

Accordingly, it may be further postulated that disposing particle material, in some non-limiting examples, as a discontinuous layer 840 of at least one particle structure 841 on an exposed layer surface 11 of an underlying layer, such that the at least one particle structure 841 is in physical contact with the underlying layer, may, in some non-limiting examples, favorably shift the absorption spectrum of the particle material, including without limitation, blue-shift, such that it does not substantially overlap with a wavelength range of the EM spectrum of EM radiation being emitted by and/or transmitted at least partially through the device 100.

In some non-limiting examples, a peak absorption wavelength of the at least one particle structure 841 may be less than a peak wavelength of the EM radiation being emitted by and/or transmitted at least partially through the device 100. In some non-limiting examples, the particle material may exhibit a peak absorption at a wavelength (range) that is one of no more than about: 470 nm, 460 nm, 455 nm, 450 nm, 445 nm, 440 nm, 430 nm, 420 nm, and 400 nm.

It has now been found, somewhat surprisingly, that providing particle material, including without limitation, in the form of at least one particle structure 841, including without limitation, those comprised of a metal, within and/or proximate to the at least one low(er)-index coating, may further impact the absorption and/or transmittance of EM radiation passing through the device 100, including without limitation, in the first direction, in at least a wavelength (sub-) range of the EM spectrum, including without limitation, the visible spectrum, and/or a sub-range thereof, passing in the first direction from and/or through the at least one low(er)-index layer(s), the at least one particle structure(s) 841, and across the index interface.

In some non-limiting examples, absorption may be reduced, and/or transmittance may be facilitated, in at least a wavelength (sub-) range of the EM spectrum, including without limitation, the visible spectrum, and/or a sub-range thereof.

In some non-limiting examples, the absorption may be concentrated in an absorption spectrum that is a wavelength (sub-) range of the EM spectrum, including without limitation, the visible spectrum, and/or a sub-range thereof.

In some non-limiting examples, the absorption spectrum may be blue-shifted and/or shifted to a higher wavelength (sub-) range (red-shifted), including without limitation, to a wavelength (sub-) range of the EM spectrum, including without limitation, the visible spectrum, and/or a sub-range thereof, and/or to a wavelength (sub-) range of the EM spectrum that lies, at least in part, beyond the visible spectrum.

Those having ordinary skill in the relevant art will appreciate that in some non-limiting examples, a plurality of layers of at least one particle 841 may be disposed on one another, whether or not separated by additional layers, with varying lateral aspects and having different absorption spectra. In this fashion, the absorption of certain regions of the device may be tuned according to one or more desired absorption spectra.

In some non-limiting examples, the presence of the at least one particle structure 841, including without limitation, NPs, including without limitation, in a discontinuous layer 840, on an exposed layer surface 11 of the patterning coating 110 may affect some optical properties of the device 100.

In some non-limiting examples, such plurality of particle structures 841 may form a discontinuous layer 840.

Without wishing to be limited to any particular theory, it may be postulated that, while the formation of a closed coating 140 of the particle material may be substantially inhibited by and/or on the patterning coating 110, in some non-limiting examples, when the patterning coating 110 is exposed to deposition of the particle material thereon, some vapor monomers of the particle material may ultimately form at least one particle structure 841 of the particle material thereon.

In some non-limiting examples, at least some of the particle structures 841 may be disconnected from one another. In other words, in some non-limiting examples, the discontinuous layer 840 may comprise features, including particle structures 841, that may be physically separated from one another, such that the particle structures 841 do not form a closed coating 140. Accordingly, such discontinuous layer 840 may, in some non-limiting examples, thus comprise a thin disperse layer of deposited material 731 formed as particle structures 841, inserted at, and/or substantially across the lateral extent of, an interface between the patterning coating 110 and at least one covering layer in the device 100.

In some non-limiting examples, at least one of the particle structures 841 of particle material may be in physical contact with an exposed layer surface 11 of the pattering coating 110. In some non-limiting examples, substantially all of the particle structures 841 of particle material may be in physical contact with the exposed layer surface 11 of the patterning coating 110.

Without wishing to be bound by any particular theory, it has been found, somewhat surprisingly, that the presence of such a thin, disperse discontinuous layer 840 of particle material, including without limitation, at least one particle structure 841, including without limitation, metal particle structures 841, on an exposed layer surface 11 of the patterning coating 110, may exhibit at least one varied characteristic and concomitantly, varied behaviour, including without limitation, optical effects and properties of the device 100, as discussed herein. In some non-limiting examples, such effects and properties may be controlled to some extent by judicious selection of at least one of: the characteristic size, size distribution, shape, surface coverage, configuration, deposited density, and/or dispersity of the particle structures 841 on the patterning coating 110.

In some non-limiting examples, the particle structures 841 may be controllably selected so as to have a characteristic size, length, width, diameter, height, size distribution, shape, surface coverage, configuration, deposited density, dispersity, and/or composition to achieve an effect related to an optical response exhibited by the particle structures 841.

Those having ordinary skill in the relevant art will appreciate that, having regard to the mechanism by which materials are deposited, due to possible stacking and/or clustering of monomers and/or atoms, an actual size, height, weight, thickness, shape, profile, and/or spacing thereof, the at least one particle structure 841 may be, in some non-limiting examples, substantially non-uniform. Additionally, although the at least one particle structure 841 are illustrated as having a given profile, this is intended to be illustrative only, and not determinative of any size, height, weight, thickness, shape, profile, and/or spacing thereof.

In some non-limiting examples, the at least one particle structure 841 may have a characteristic dimension of no more than about 200 nm. In some non-limiting examples, the at least one particle structure 841 may have a characteristic diameter that may be one of between about: 1-200 nm, 1-160 nm, 1-100 nm, 1-50 nm, and 1-30 nm.

In some non-limiting examples, the at least one particle structure 841 may be, and/or comprise discrete metal plasmonic islands or clusters.

In some non-limiting examples, the at least one particle structure 841 may comprise a particle material.

In some non-limiting examples, such particle structures 841 may be formed by depositing a scant amount, in some non-limiting examples, having an average layer thickness that may be on the order of a few, or a fraction of an angstrom, of a particle material on an exposed layer surface 11 of the underlying layer. In some non-limiting examples, the exposed layer surface 11 may be of a nucleation-promoting coating (NPC) 920 (FIG. 9C).

In some non-limiting examples, the particle material may comprise at least one of Ag, Yb, and/or magnesium (Mg).

In some non-limiting examples, the formation of at least one of: the characteristic size, size distribution, shape, surface coverage, configuration, deposited density, and/or dispersity of such discontinuous layer 840 may be controlled, in some non-limiting examples, by judicious selection of at least one of: at least one characteristic of the patterning material 611, an average film thickness d₂ of the patterning coating 110, the introduction of heterogeneities in the patterning coating 110, and/or a deposition environment, including without limitation, a temperature, pressure, duration, deposition rate, and/or deposition process for the patterning coating 110.

In some non-limiting examples, the formation of at least one of the characteristic size, size distribution, shape, surface coverage, configuration, deposited density, and/or dispersity of such discontinuous layer 840 may be controlled, in some non-limiting examples, by judicious selection of at least one of: at least one characteristic of the particle material (which may be the deposited material 731), an extent to which the patterning coating 110 may be exposed to deposition of the particle material (which, in some non-limiting examples may be specified in terms of a thickness of the corresponding discontinuous layer 840), and/or a deposition environment, including without limitation, a temperature, pressure, duration, deposition rate, and/or method of deposition for the particle material.

In some non-limiting examples, the discontinuous layer 840 may be deposited in a pattern across the lateral extent of the patterning coating 110.

In some non-limiting examples, the discontinuous layer 840 may be disposed in a pattern that may be defined by at least one region therein that is substantially devoid of the at least one particle structure 841.

In some non-limiting examples, the characteristics of such discontinuous layer 840 may be assessed, in some non-limiting examples, somewhat arbitrarily, according to at least one of several criteria, including without limitation, a characteristic size, size distribution, shape, configuration, surface coverage, deposited distribution, dispersity, and/or a presence, and/or extent of aggregation instances of the particle material, formed on a part of the exposed layer surface 11 of the underlying layer.

In some non-limiting examples, an assessment of the discontinuous layer 840 according to such at least one criterion, may be performed on, including without limitation, by measuring, and/or calculating, at least one attribute of the discontinuous layer 840, using a variety of imaging techniques, including without limitation, at least one of: transmission electron microscopy (TEM), atomic force microscopy (AFM), and scanning electron microscopy (SEM).

Those having ordinary skill in the relevant art will appreciate that such an assessment of the discontinuous layer 840 may depend, to a greater, and/or lesser extent, by the extent, of the exposed layer surface 11 under consideration, which in some non-limiting examples may comprise an area, and/or region thereof. In some non-limiting examples, the discontinuous layer 840 may be assessed across the entire extent, in a first lateral aspect, and/or a second lateral aspect that is substantially transverse thereto, of the exposed layer surface 11. In some non-limiting examples, the discontinuous layer 840 may be assessed across an extent that comprises at least one observation window applied against (a part of) the discontinuous layer 840.

In some non-limiting examples, the at least one observation window may be located at at least one of: a perimeter, interior location, and/or grid coordinate of the lateral aspect of the exposed layer surface 11. In some non-limiting examples, a plurality of the at least one observation windows may be used in assessing the discontinuous layer 840.

In some non-limiting examples, the observation window may correspond to a field of view of an imaging technique applied to assess the discontinuous layer 840, including without limitation, at least one of: TEM, AFM, and SEM. In some non-limiting examples, the observation window may correspond to a given level of magnification, including without limitation, one of: 2.00 microns, 1.00 microns, 500 nm, and 200 nm.

In some non-limiting examples, the assessment of the discontinuous layer 840, including without limitation, at least one observation window used, of the exposed layer surface 11 thereof, may involve calculating, and/or measuring, by any number of mechanisms, including without limitation, manual counting, and/or known estimation techniques, which may, in some non-limiting examples, may comprise curve, polygon, and/or shape fitting techniques.

In some non-limiting examples, the assessment of the discontinuous layer 840, including without limitation, at least one observation window used, of the exposed layer surface 11 thereof, may involve calculating, and/or measuring an average, median, mode, maximum, minimum, and/or other probabilistic, statistical, and/or data manipulation of a value of the calculation, and/or measurement.

In some non-limiting examples, one of the at least one criterion by which such discontinuous layer 840 may be assessed, may be a surface coverage of the particle material on such (part of the) discontinuous layer 840. In some non-limiting examples, the surface coverage may be represented by a (non-zero) percentage coverage by such particle material of such (part of the) discontinuous layer 840. In some non-limiting examples, the percentage coverage may be compared to a maximum threshold percentage coverage.

In some non-limiting examples, a (part of a) discontinuous layer 840 having a surface coverage that may be substantially no more than the maximum threshold percentage coverage, may result in a manifestation of different optical characteristics that may be imparted by such part of the discontinuous layer 840, to EM radiation passing therethrough, whether transmitted entirely through the device 100, and/or emitted thereby, relative to EM radiation passing through a part of the discontinuous layer 840 having a surface coverage that substantially exceeds the maximum threshold percentage coverage.

In some non-limiting examples, one measure of a surface coverage of an amount of an electrically conductive material on a surface may be a (EM radiation) transmittance, since in some non-limiting examples, electrically conductive materials, including without limitation, metals, including without limitation: Ag, Mg, and Yb, attenuate, and/or absorb EM radiation.

Those having ordinary skill in the relevant art will appreciate that in some non-limiting examples, surface coverage may be understood to encompass one or both of particle size, and deposited density. Thus, in some non-limiting examples, a plurality of these three criteria may be positively correlated. Indeed, in some non-limiting examples, a criterion of low surface coverage may comprise some combination of a criterion of low deposited density with a criterion of low particle size.

In some non-limiting examples, one of the at least one criterion by which such discontinuous layer 840 may be assessed, may be a characteristic size of the constituent particle structures 841.

In some non-limiting examples, the at least one particle structure 841 of the discontinuous layer 840, may have a characteristic size that is no more than a maximum threshold size. Non-limiting examples of the characteristic size may include at least one of: height, width, length, and/or diameter.

In some non-limiting examples, substantially all of the particle structures 841, of the discontinuous layer 840 may have a characteristic size that lies within a specified range.

In some non-limiting examples, such characteristic size may be characterized by a characteristic length, which in some non-limiting examples, may be considered a maximum value of the characteristic size. In some non-limiting examples, such maximum value may extend along a major axis of the particle structure 841. In some non-limiting examples, the major axis may be understood to be a first dimension extending in a plane defined by the plurality of lateral axes. In some non-limiting examples, a characteristic width may be identified as a value of the characteristic size of the particle structure 841 that may extend along a minor axis of the particle structure 841. In some non-limiting examples, the minor axis may be understood to be a second dimension extending in the same plane but substantially transverse to the major axis.

In some non-limiting examples, the characteristic length of the at least one particle structure 841, along the first dimension, may be no more than the maximum threshold size.

In some non-limiting examples, the characteristic width of the at least one particle structure 841, along the second dimension, may be no more than the maximum threshold size.

In some non-limiting examples, a size of the constituent particle structures 841, in the (part of the) discontinuous layer 840, may be assessed by calculating, and/or measuring a characteristic size of such at least one particle structure 841, including without limitation, a mass, volume, length of a diameter, perimeter, major, and/or minor axis thereof.

In some non-limiting examples, one of the at least one criterion by which such discontinuous layer 840 may be assessed, may be a deposited density thereof.

In some non-limiting examples, the characteristic size of the particle structure 841 may be compared to a maximum threshold size.

In some non-limiting examples, the deposited density of the particle structures 841 may be compared to a maximum threshold deposited density.

In some non-limiting examples, at least one of such criteria may be quantified by a numerical metric. In some non-limiting examples, such a metric may be a calculation of a dispersity D that describes the distribution of particle (area) sizes in a deposited layer 130 of particle structures 841, in which:

$$D = \frac{\overline{{S}_{s}}}{\overline{{S}_{n}}} \qquad ( 1 )$$

$$where :$$

$$\overline{{S}_{s}} = \frac{{\sum }_{i = 1}^{n} {{S}_{i}}^{2}}{{\sum }_{i = 1}^{n} {S}_{i}} , \overline{{S}_{n}} = \frac{{\sum }_{i = 1}^{n} {S}_{i}}{n} , \qquad ( 2 )$$

n is the number of particle structures 841 in a sample area,
Sᵢ is the (area) size of the i^{th} particle structure 841,
S̅ₙ is the number average of the particle (area) sizes and
S̅ₛ is the (area) size average of the particle (area) sizes.

Those having ordinary skill in the relevant art will appreciate that the dispersity is roughly analogous to a polydispersity index (PDI) and that these averages are roughly analogous to the concepts of number average molecular weight and weight average molecular weight familiar in organic chemistry, but applied to an (area) size, as opposed to a molecular weight of a sample particle structure 841.

Those having ordinary skill in the relevant will also appreciate that while the concept of dispersity may, in some non-limiting examples, be considered a three-dimensional volumetric concept, in some non-limiting examples, the dispersity may be considered to be a two-dimensional concept. As such, the concept of dispersity may be used in connection with viewing and analyzing two-dimensional images of the deposited layer 130, such as may be obtained by using a variety of imaging techniques, including without limitation, at least one of: TEM, AFM and/or SEM. It is in such a two-dimensional context, that the equations set out above are defined.

In some non-limiting examples, the dispersity and/or the number average of the particle (area) size and the (area) size average of the particle (area) size may involve a calculation of at least one of: the number average of the particle diameters and the (area) size average of the particle diameters:

$$\overline{{d}_{n}} = 2 \sqrt{\frac{\overline{{S}_{n}}}{π}} , \overline{{d}_{s}} = 2 \sqrt{\frac{\overline{{S}_{s}}}{π}} \qquad ( 3 )$$

In some non-limiting examples, the particle material, including without limitation as particle structures 841, of the at least one deposited layer 130, may be deposited by a mask-free and/or open mask deposition process.

In some non-limiting examples, the particle structures 841 may have a substantially round shape. In some non-limiting examples, the particle structures 841 may have a substantially spherical shape.

For purposes of simplification, in some non-limiting examples, it may be assumed that a longitudinal extent of each particle structure 841 may be substantially the same (and, in any event, may not be directly measured from a plan view SEM image) so that the (area) size of the particle structure 841 may be represented as a two-dimensional area coverage along the pair of lateral axes. In the present disclosure, a reference to an (area) size may be understood to refer to such two-dimensional concept, and to be differentiated from a size (without the prefix “area”) that may be understood to refer to a one-dimensional concept, such as a linear dimension.

Indeed, in some early investigations, it appears that, in some non-limiting examples, the longitudinal extent, along the longitudinal axis, of such particle structures 841, may tend to be small relative to the lateral extent (along at least one of the lateral axes), such that the volumetric contribution of the longitudinal extent thereof may be much less than that of such lateral extent. In some non-limiting examples, this may be expressed by an aspect ratio (a ratio of a longitudinal extent to a lateral extent) that may be no more than 1. In some non-limiting examples, such aspect ratio may be one of about: 1:10, 1:20, 1:50, 1:75, and 1:300.

In this regard, the assumption set out above (that the longitudinal extent is substantially the same and can be ignored) to represent the particle structure 841 as a two-dimensional area coverage may be appropriate.

Those having ordinary skill in the relevant art will appreciate, having regard to the non-determinative nature of the deposition process, especially in the presence of defects, and/or anomalies on the exposed layer surface 11 of the underlying material, including without limitation, heterogeneities, including without limitation, at least one of: a step edge, a chemical impurity, a bonding site, a kink, and/or a contaminant thereon, and consequently the formation of particle structures 841 thereon, the non-uniform nature of coalescence thereof as the deposition process continues, and in view of the uncertainty in the size, and/or position of observation windows, as well as the intricacies and variability inherent in the calculation, and/or measurement of their characteristic size, spacing, deposited density, degree of aggregation, and the like, there may be considerable variability in terms of the features, and/or topology within observation windows.

In the present disclosure, for purposes of simplicity of illustration, certain details of particle materials, including without limitation, thickness profiles, and/or edge profiles of layer(s) have been omitted.

Those having ordinary skill in the relevant art will appreciate that certain metal NPs, whether or not as part of a discontinuous layer 840 of particle material, including without limitation, at least one particle structure 841, may exhibit surface plasmon (SP) excitations, and/or coherent oscillations of free electrons, with the result that such NPs may absorb, and/or scatter light in a range of the EM spectrum, including without limitation, the visible spectrum, and/or a sub-range thereof. The optical response, including without limitation, the (sub-)range of the EM spectrum over which absorption may be concentrated (absorption spectrum), refractive index, and/or extinction coefficient, of such localized SP (LSP) excitations, and/or coherent oscillations, may be tailored by varying properties of such NPs, including without limitation, at least one of: a characteristic size, size distribution, shape, surface coverage, configuration, deposition density, dispersity, and/or property, including without limitation, material, and/or degree of aggregation, of the nanostructures, and/or a medium proximate thereto.

Such optical response, in respect of photon-absorbing coatings, may include absorption of photons incident thereon, thereby reducing reflection. In some non-limiting examples, the absorption may be concentrated in a range of the EM spectrum, including without limitation, the visible spectrum, and/or a sub-range thereof. While the at least one particle 841 may absorb EM radiation incident thereon from beyond the layered semiconductor device 100, thus reducing reflection, those having ordinary skill in the relevant art will appreciate that, in some non-limiting examples, the at least one particle 841 may absorb EM radiation incident thereon that is emitted by the device 100. In some non-limiting examples, employing a photon-absorbing layer as part of an opto-electronic device may reduce reliance on a polarizer therein.

It has been reported in Fusella et al., “Plasmonic enhancement of stability and brightness in organic light-emitting devices”, Nature 2020, 585, at 379-382 (“Fusella et al.”), that the stability of an OLED device may be enhanced by incorporating an NP-based outcoupling layer above the cathode layer to extract energy from the plasmon modes. The NP-based outcoupling layer was fabricated by spin-casting cubic Ag NPs on top of an organic layer on top of a cathode. However, since most commercial OLED devices are fabricated using vacuum-based processing, spin-casting from solution may not constitute an appropriate mechanism for forming such an NP-based outcoupling layer above the cathode.

It has been discovered that such an NP-based outcoupling layer above the cathode may be fabricated in vacuum (and thus, may be suitable for use in a commercial OLED fabrication process), by depositing a metal particle material in a discontinuous layer 840 onto a patterning coating 110, which in some non-limiting examples, may be, and/or be deposited on, the cathode. Such process may avoid the use of solvents or other wet chemicals that may cause damage to the OLED device, and/or may adversely impact device reliability.

In some non-limiting examples, the presence of such a discontinuous layer 840 of particle material, including without limitation, at least one particle structure 841, may contribute to enhanced extraction of EM radiation, performance, stability, reliability, and/or lifetime of the device.

In some non-limiting examples, the existence, in a layered device 100, of at least one discontinuous layer 840, on, and/or proximate to the exposed layer surface 11 of a patterning coating 110, and/or, in some non-limiting examples, and/or proximate to the interface of such patterning 110 with at least one covering layer, may impart optical effects to EM signals, including without limitation, photons, emitted by the device, and/or transmitted therethrough.

Those having ordinary skill in the relevant art will appreciate that, while a simplified model of the optical effects is presented herein, other models, and/or explanations may be applicable.

In some non-limiting examples, the presence of such a discontinuous layer 840 of the particle material, including without limitation, at least one particle structure 841, may reduce, and/or mitigate crystallization of thin film layers, and/or coatings disposed adjacent in the longitudinal aspect, including without limitation, the patterning coating 110, and/or at least one covering layer, thereby stabilizing the property of the thin film(s) disposed adjacent thereto, and, in some non-limiting examples, reducing scattering. In some non-limiting examples, such thin film may be, and/or comprise at least one layer of an outcoupling, and/or encapsulating coating 1750 of the device, including without limitation, a capping layer (CPL).

In some non-limiting examples, the presence of such a discontinuous layer 840 of particle material, including without limitation, at least one particle structure 841, may provide an enhanced absorption in at least a part of the UV spectrum. In some non-limiting examples, controlling the characteristics of such particle structures 841, including without limitation, at least one of: characteristic size, size distribution, shape, surface coverage, configuration, deposited density, dispersity, particle material, and refractive index, of the particle structures 841, may facilitate controlling the degree of absorption, wavelength range and peak wavelength of the absorption spectrum, including in the UV spectrum. Enhanced absorption of EM radiation in at least a part of the UV spectrum may be advantageous, for example, for improving device performance, stability, reliability, and/or lifetime.

In some non-limiting examples, the optical effects may be described in terms of its impact on the transmission, and/or absorption wavelength spectrum, including a wavelength range, and/or peak intensity thereof.

Additionally, while the model presented may suggest certain effects imparted on the transmission, and/or absorption of photons passing through such discontinuous layer 840, in some non-limiting examples, such effects may reflect local effects that may not be reflected on a broad, observable basis.

### Opto-Electronic Device

FIG. 10 is a simplified block diagram from a cross-sectional aspect, of an example electro-luminescent device 1000 according to the present disclosure. In some non-limiting examples, the device 1000 may be an OLED.

The device 1000 may comprise a substrate 10, upon which a frontplane 1010, comprising a plurality of layers, respectively, a first electrode 1020, at least one semiconducting layer 1030, and a second electrode 1040, are disposed. In some non-limiting examples, the frontplane 1010 may provide mechanisms for photon emission, and/or manipulation of emitted photons.

In some non-limiting examples, the deposited layer 130 and the underlying layer may together form at least a part of at least one of the first electrode 1020 and the second electrode 1040 of the device 1000. In some non-limiting examples, the deposited layer 130 and the underlying layer thereunder may together form at least a part of a cathode of the device 1000.

In some non-limiting examples, the device 1000 may be electrically coupled with a power source 1005. When so coupled, the device 1000 may emit photons as described herein.

### Substrate

In some examples, the substrate 10 may comprise a base substrate 1012. In some examples, the base substrate 1012 may be formed of material suitable for use thereof, including without limitation, an inorganic material, including without limitation, Si, glass, metal (including without limitation, a metal foil), sapphire, and/or other inorganic material, and/or an organic material, including without limitation, a polymer, including without limitation, a polyimide, and/or an Si-based polymer. In some examples, the base substrate 1012 may be rigid or flexible. In some examples, the substrate 10 may be defined by at least one planar surface. In some non-limiting examples, the substrate 10 may have at least one surface that supports the remaining frontplane 1010 components of the device 1000, including without limitation, the first electrode 1020, the at least one semiconducting layer 1030, and/or the second electrode 1040.

In some non-limiting examples, such surface may be an organic surface, and/or an inorganic surface.

In some examples, the substrate 10 may comprise, in addition to the base substrate 1012, at least one additional organic, and/or inorganic layer (not shown nor specifically described herein) supported on an exposed layer surface 11 of the base substrate 1012.

In some non-limiting examples, such additional layers may comprise, and/or form at least one organic layer, which may comprise, replace, and/or supplement at least one of the at least one semiconducting layer 1030.

In some non-limiting examples, such additional layers may comprise at least one inorganic layer, which may comprise, and/or form at least one electrode, which in some non-limiting examples, may comprise, replace, and/or supplement the first electrode 1020, and/or the second electrode 1040.

In some non-limiting examples, such additional layers may comprise, and/or be formed of, and/or as a backplane 1015. In some non-limiting examples, the backplane 1015 may contain power circuitry, and/or switching elements for driving the device 1000, including without limitation, electronic TFT structure(s) 1101, and/or component(s) thereof, that may be formed by a photolithography process, which may not be provided under, and/or may precede the introduction of a low pressure (including without limitation, a vacuum) environment.

### Backplane and TFT Structure(s) Embodied Therein

In some non-limiting examples, the backplane 1015 of the substrate 10 may comprise at least one electronic, and/or opto-electronic component, including without limitation, transistors, resistors, and/or capacitors, such as which may support the device 1000 acting as an active-matrix, and/or a passive matrix device. In some non-limiting examples, such structures may be a thin-film transistor (TFT) structure 1101.

Non-limiting examples of TFT structures 1101 include top-gate, bottom-gate, n-type and/or p-type TFT structures 1101. In some non-limiting examples, the TFT structure 1101 may incorporate any at least one of amorphous silicon (a-Si), indium gallium zinc oxide (IGZO), and/or low-temperature polycrystalline silicon (LTPS).

### First Electrode

The first electrode 1020 may be deposited over the substrate 10. In some non-limiting examples, the first electrode 1020 may be electrically coupled with a terminal of the power source 1005, and/or to ground. In some non-limiting examples, the first electrode 1020 may be so coupled through at least one driving circuit which in some non-limiting examples, may incorporate at least one TFT structure 1101 in the backplane 1015 of the substrate 10.

In some non-limiting examples, the first electrode 1020 may comprise an anode, and/or a cathode. In some non-limiting examples, the first electrode 1020 may be an anode.

In some non-limiting examples, the first electrode 1020 may be formed by depositing at least one thin conductive film, over (a part of) the substrate 10. In some non-limiting examples, there may be a plurality of first electrodes 1020, disposed in a spatial arrangement over a lateral aspect of the substrate 10. In some non-limiting examples, at least one of such at least one first electrodes 1020 may be deposited over (a part of) a TFT insulating layer 1109 disposed in a lateral aspect in a spatial arrangement. If so, in some non-limiting examples, at least one of such at least one first electrodes 1020 may extend through an opening of the corresponding TFT insulating layer 1109 to be electrically coupled with an electrode of the TFT structures 1101 in the backplane 1015.

In some non-limiting examples, the at least one first electrode 1020, and/or at least one thin film thereof, may comprise various materials, including without limitation, at least one metallic material, including without limitation, Mg, Al, calcium (Ca), Zn, Ag, Cd, Ba, or Yb, or combinations of any plurality thereof, including without limitation, alloys containing any of such materials, at least one metal oxide, including without limitation, a TCO, including without limitation, ternary compositions such as, without limitation, fluorine tin oxide (FTO), indium zinc oxide (IZO), or ITO, or combinations of any plurality thereof, or in varying proportions, or combinations of any plurality thereof in at least one layer, any at least one of which may be, without limitation, a thin film.

### Second Electrode

The second electrode 1040 may be deposited over the at least one semiconducting layer 1030. In some non-limiting examples, the second electrode 1040 may be electrically coupled with a terminal of the power source 1005, and/or with ground. In some non-limiting examples, the second electrode 1040 may be so coupled through at least one driving circuit, which in some non-limiting examples, may incorporate at least one TFT structure 1101 in the backplane 1015 of the substrate 10.

In some non-limiting examples, the second electrode 1040 may comprise an anode, and/or a cathode. In some non-limiting examples, the second electrode 1040 may be a cathode.

In some non-limiting examples, the second electrode 1040 may be formed by depositing a deposited layer 130, in some non-limiting examples, as at least one thin film, over (a part of) the at least one semiconducting layer 1030. In some non-limiting examples, there may be a plurality of second electrodes 1040, disposed in a spatial arrangement over a lateral aspect of the at least one semiconducting layer 1030.

In some non-limiting examples, the at least one second electrode 1040 may comprise various materials, including without limitation, at least one metallic material, including without limitation, Mg, Al, Ca, Zn, Ag, Cd, Ba, or Yb, or combinations of any plurality thereof, including without limitation, alloys containing any of such materials, at least one metal oxides, including without limitation, a TCO, including without limitation, ternary compositions such as, without limitation, FTO, IZO, and ITO, or combinations of any plurality thereof, or in varying proportions, or zinc oxide (ZnO), or other oxides containing indium (In), or Zn, or combinations of any plurality thereof in at least one layer, and/or at least one non-metallic materials, any at least one of which may be, without limitation, a thin conductive film. In some non-limiting examples, for a Mg:Ag alloy, such alloy composition may range between about 1:9-9:1 by volume.

In some non-limiting examples, the deposition of the second electrode 1040 may be performed using an open mask and/or a mask-free deposition process.

In some non-limiting examples, the second electrode 1040 may comprise a plurality of such layers, and/or coatings. In some non-limiting examples, such layers, and/or coatings may be distinct layers, and/or coatings disposed on top of one another.

In some non-limiting examples, the second electrode 1040 may comprise a Yb/Ag bi-layer coating. In some non-limiting examples, such bi-layer coating may be formed by depositing a Yb coating, followed by an Ag coating. In some non-limiting examples, a thickness of such Ag coating may exceed a thickness of the Yb coating.

In some non-limiting examples, the second electrode 1040 may be a multi-layer electrode 1040 comprising at least one metallic layer, and/or at least one oxide layer.

In some non-limiting examples, the second electrode 1040 may comprise a fullerene and Mg.

In some non-limiting examples, such coating may be formed by depositing a fullerene coating followed by an Mg coating. In some non-limiting examples, a fullerene may be dispersed within the Mg coating to form a fullerene-containing Mg alloy coating. Non-limiting examples of such coatings are described in United States Patent Application Publication No. 2015/0287846 published 8 Oct. 2015, and/or in PCT International Application No. PCT/IB2017/054970 filed 15 Aug. 2017 and published as WO2018/033860 on 22 Feb. 2018.

### Semiconducting Layer

In some non-limiting examples, the at least one semiconducting layer 1030 may comprise a plurality of layers 1031, 1033, 1035, 1037, 1039, any of which may be disposed, in some non-limiting examples, in a thin film, in a stacked configuration, which may include, without limitation, at least one of a hole injection layer (HIL) 1031, a hole transport layer (HTL) 1033, an emissive layer (EML) 1035, an electron transport layer (ETL) 1037, and/or an electron injection layer (EIL) 1039.

In some non-limiting examples, the at least one semiconducting layer 1030 may form a “tandem” structure comprising a plurality of EMLs 1035. In some non-limiting examples, such tandem structure may also comprise at least one charge generation layer (CGL).

Those having ordinary skill in the relevant art will readily appreciate that the structure of the device 1000 may be varied by omitting, and/or combining at least one of the semiconductor layers 1031, 1033, 1035, 1037, 1039.

Further, any of the layers 1031, 1033, 1035, 1037, 1039 of the at least one semiconducting layer 1030 may comprise any number of sub-layers. Still further, any of such layers 1031, 1033, 1035, 1037, 1039, and/or sub-layer(s) thereof may comprise various mixture(s), and/or composition gradient(s). In addition, those having ordinary skill in the relevant art will appreciate that the device 1000 may comprise at least one layer comprising inorganic, and/or organometallic materials and may not be necessarily limited to devices comprised solely of organic materials. In some non-limiting examples, the device 1000 may comprise at least one QD.

In some non-limiting examples, the HIL 1031 may be formed using a hole injection material, which may facilitate injection of holes by the anode.

In some non-limiting examples, the HTL 1033 may be formed using a hole transport material, which may, in some non-limiting examples, exhibit high hole mobility.

In some non-limiting examples, the ETL 1037 may be formed using an electron transport material, which may, in some non-limiting examples, exhibit high electron mobility.

In some non-limiting examples, the EIL 1039 may be formed using an electron injection material, which may facilitate injection of electrons by the cathode.

In some non-limiting examples, the EML 1035 may be formed, in some non-limiting examples, by doping a host material with at least one emitter material. In some non-limiting examples, the emitter material may be a fluorescent emitter, a phosphorescent emitter, a thermally activated delayed fluorescence (TADF) emitter, and/or a plurality of any combination of these.

In some non-limiting examples, the device 1000 may be an OLED in which the at least one semiconducting layer 1030 comprises at least an EML 1035 interposed between conductive thin film electrode 1020, 1040, whereby, when a potential difference is applied across them, holes may be injected into the at least one semiconducting layer 1030 through the anode and electrons may be injected into the at least one semiconducting layer 1030 through the cathode, migrate toward the EML 1035 and combine to emit EM radiation in the form of photons.

In some non-limiting examples, the device 1000 may be an electro-luminescent QD device in which the at least one semiconducting layer 1030 may comprise an active layer comprising at least one QD. When current may be provided by the power source 1005 to the first electrode 1020 and second electrode 1040, photons may be emitted from the active layer comprising the at least one semiconducting layer 1030 between them.

Those having ordinary skill in the relevant art will readily appreciate that the structure of the device 1000 may be varied by the introduction of at least one additional layer (not shown) at appropriate position(s) within the at least one semiconducting layer 1030 stack, including without limitation, a hole blocking layer (HBL) (not shown), an electron blocking layer (EBL) (not shown), an additional charge transport layer (CTL) (not shown), and/or an additional charge injection layer (CIL) (not shown).

In some non-limiting examples, including where the OLED device 1000 comprises a lighting panel, an entire lateral aspect of the device 1000 may correspond to a single emissive element. As such, the substantially planar cross-sectional profile shown in FIG. 10 may extend substantially along the entire lateral aspect of the device 1000, such that EM radiation is emitted from the device 1000 substantially along the entirety of the lateral extent thereof. In some non-limiting examples, such single emissive element may be driven by a single driving circuit of the device 1000.

In some non-limiting examples, including where the OLED device 1000 comprises a display module, the lateral aspect of the device 1000 may be sub-divided into a plurality of emissive regions 1401 of the device 1000, in which the cross-sectional aspect of the device structure 1000, within each of the emissive region(s) 1401, may cause EM radiation to be emitted therefrom when energized.

### Emissive Regions

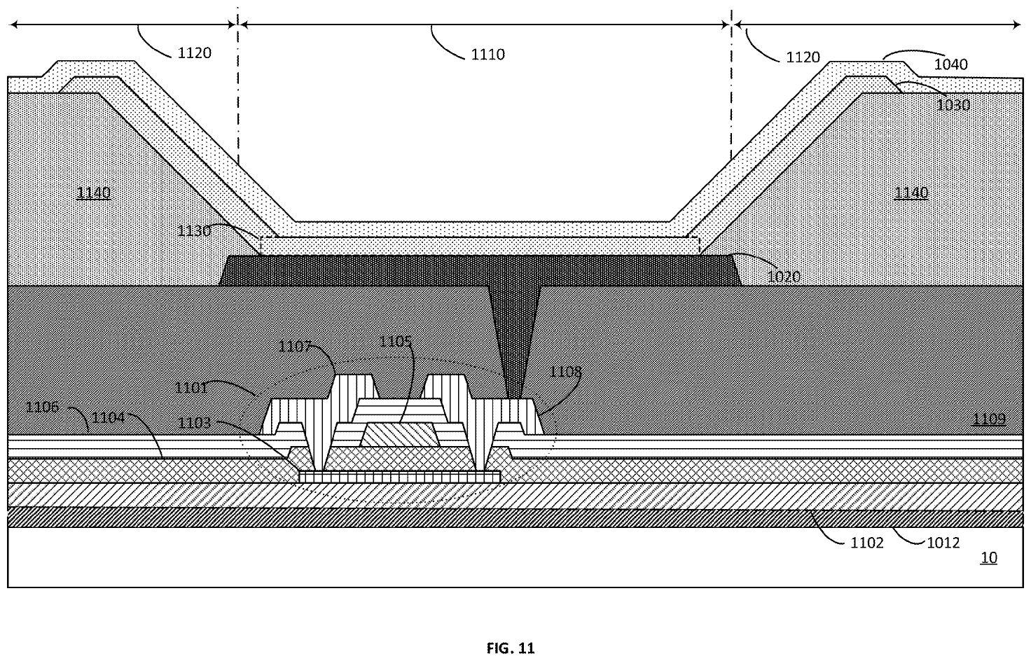

In some non-limiting examples, such as may be shown in some non-limiting examples in FIG. 11, an active region 1130 of an emissive region 1401 may be defined to be bounded, in the transverse aspect, by the first electrode 1020 and the second electrode 1040, and to be confined, in the lateral aspect, to an emissive region 1401 defined by the first electrode 1020 and the second electrode 1040. Those having ordinary skill in the relevant art will appreciate that the lateral aspect 1110 of the emissive region 1401, and thus the lateral boundaries of the active region 1130, may not correspond to the entire lateral aspect of either, or both, of the first electrode 1020 and the second electrode 1040. Rather, the lateral aspect 1110 of the emissive region 1401 may be substantially no more than the lateral extent of either of the first electrode 1020 and the second electrode 1040. In some non-limiting examples, parts of the first electrode 1020 may be covered by the PDL(s) 1140 and/or parts of the second electrode 1040 may not be disposed on the at least one semiconducting layer 1030, with the result, in either, or both, scenarios, that the emissive region 1401 may be laterally constrained.

In some non-limiting examples, individual emissive regions 1401 of the device 1000 may be laid out in a lateral pattern. In some non-limiting examples, the pattern may extend along a first lateral direction. In some non-limiting examples, the pattern may also extend along a second lateral direction, which in some non-limiting examples, may be substantially normal to the first lateral direction. In some non-limiting examples, the pattern may have a number of elements in such pattern, each element being characterized by at least one feature thereof, including without limitation, a wavelength of EM radiation emitted by the emissive region 1401 thereof, a shape of such emissive region 1401, a dimension (along either, or both of, the first, and/or second lateral direction(s)), an orientation (relative to either, and/or both of the first, and/or second lateral direction(s)), and/or a spacing (relative to either, or both of, the first, and/or second lateral direction(s)) from a previous element in the pattern. In some non-limiting examples, the pattern may repeat in either, or both of, the first and/or second lateral direction(s).

In some non-limiting examples, each individual emissive region 1401 of the device 1000 may be associated with, and driven by, a corresponding driving circuit within the backplane 1015 of the device 1000, for driving an OLED structure for the associated emissive region 1401. In some non-limiting examples, including without limitation, where the emissive regions 1401 may be laid out in a regular pattern extending in both the first (row) lateral direction and the second (column) lateral direction, there may be a signal line in the backplane 1015, corresponding to each row of emissive regions 1401 extending in the first lateral direction and a signal line, corresponding to each column of emissive regions 1401 extending in the second lateral direction. In such a non-limiting configuration, a signal on a row selection line may energize the respective gates of the switching TFT structure(s) 1101 electrically coupled therewith and a signal on a data line may energize the respective sources of the switching TFT structure(s) 1101 electrically coupled therewith, such that a signal on a row selection line/data line pair may electrically couple and energise, by the positive terminal of the power source 1005, the anode of the OLED structure of the emissive region 1401 associated with such pair, causing the emission of a photon therefrom, the cathode thereof being electrically coupled with the negative terminal of the power source 1005.

In some non-limiting examples, each emissive region 1401 of the device 1000 may correspond to a single display pixel 2210. In some non-limiting examples, each pixel 2210 may emit light at a given wavelength spectrum. In some non-limiting examples, the wavelength spectrum may correspond to a colour in, without limitation, the visible spectrum.

In some non-limiting examples, each emissive region 1401 of the device 1000 may correspond to a (sub-) pixel 2210/32x of a display pixel 2210. In some non-limiting examples, a plurality of (sub-) pixels 2210/32x may combine to form, or to represent, a single display pixel 2210.

In some non-limiting examples, a single display pixel 2210 may be represented by three (sub-) pixels 2210/32x. In some non-limiting examples, the three (sub-) pixels 2210/32x may be denoted as, respectively, R(ed) sub-pixels 321, G(reen) sub-pixels 322, and/or B(lue) sub-pixels 323. In some non-limiting examples, a single display pixel 2210 may be represented by four (sub-) pixels 2210/32x, in which three of such (sub-) pixels 2210/32x may be denoted as R(ed) 321, G(reen) 322 and B(lue) 323 sub-pixels and the fourth (sub-) pixel 2210/32x may be denoted as a W(hite) (sub-) pixel 2210/32x. In some non-limiting examples, the emission spectrum of the EM radiation emitted by a given (sub-) pixel 2210/32x may correspond to the colour by which the (sub-) pixel 2210/32x is denoted. In some non-limiting examples, the wavelength of the EM radiation may not correspond to such colour, but further processing may be performed, in a manner apparent to those having ordinary skill in the relevant art, to transform the wavelength to one that does so correspond.

Since the wavelength of (sub-) pixels 2210/32x of different colours may be different, the optical characteristics of such (sub-) pixels 2210/32x may differ, especially if a common electrode 1020, 1040 having a substantially uniform thickness profile may be employed for (sub-) pixels 2210/32x of different colours.

When a common electrode 1020, 1040 having a substantially uniform thickness may be provided as the second electrode 1040 in a device 1000, the optical performance of the device 1000 may not be readily be fine-tuned according to an emission spectrum associated with each (sub-) pixel 2210/32x. The second electrode 1040 used in such OLED devices 1000 may in some non-limiting examples, be a common electrode 1020, 1040 coating a plurality of (sub-) pixels 2210/32x. In some non-limiting examples, such common electrode 1020, 1040 may be a relatively thin conductive film having a substantially uniform thickness across the device 1000. While efforts have been made in some non-limiting examples, to tune the optical microcavity effects associated with each (sub-) pixel 2210/32x color by varying a thickness of organic layers disposed within different (sub-) pixel(s) 2210/32x, such approach may, in some non-limiting examples, provide a significant degree of tuning of the optical microcavity effects in at least some cases. In addition, in some non-limiting examples, such approach may be difficult to implement in an OLED display production environment.

As a result, the presence of optical interfaces created by numerous thin-film layers and coatings with different refractive indices, such as may in some non-limiting examples be used to construct opto-electronic devices including without limitation OLED devices 1000, may create different optical microcavity effects for (sub-) pixels 2210/32x of different colours.

Some factors that may impact an observed microcavity effect in a device 1000 include, without limitation, a total path length (which in some non-limiting examples may correspond to a total thickness (in the longitudinal aspect) of the device 1000 through which EM radiation emitted therefrom will travel before being outcoupled) and the refractive indices of various layers and coatings.

In some non-limiting examples, modulating a thickness of an electrode 1020, 1040 in and across a lateral aspect 1110 of emissive region(s) 1401 of a (sub-) pixel 2210/32x may impact the microcavity effect observable. In some non-limiting examples, such impact may be attributable to a change in the total optical path length.

In some non-limiting examples, a change in a thickness of the electrode 1020, 1040 may also change the refractive index of EM radiation passing therethrough, in some non-limiting examples, in addition to a change in the total optical path length. In some non-limiting examples, this may be particularly the case where the electrode 1020, 1040 may be formed of at least one deposited layer 130.

In some non-limiting examples, the optical properties of the device 1000, and/or in some non-limiting examples, across the lateral aspect 1110 of emissive region(s) 1401 of a (sub-) pixel 2210/32x that may be varied by modulating at least one optical microcavity effect, may include, without limitation, the emission spectrum, the intensity (including without limitation, luminous intensity), and/or angular distribution of emitted EM radiation, including without limitation, an angular dependence of a brightness, and/or color shift of the emitted EM radiation.

In some non-limiting examples, a (sub-) pixel 2210/32x may be associated with a first set of other (sub-) pixels 2210/32x to represent a first display pixel 2210 and also with a second set of other (sub-) pixels 2210/32x to represent a second display pixel 2210, so that the first and second display pixels 2210 may have associated therewith, the same sub-pixel(s) 32x.

The pattern, and/or organization of (sub-) pixels 2210/32x into display pixels 2210 continues to develop. All present and future patterns, and/or organizations are considered to fall within the scope of the present disclosure.

### Non-Emissive Regions

In some non-limiting examples, the various emissive regions 1401 of the device 1000 may be substantially surrounded and separated by, in at least one lateral direction, at least one non-emissive region 1402, in which the structure, and/or configuration along the cross-sectional aspect, of the device structure 1000 shown, without limitation, in FIG. 10, may be varied, to substantially inhibit EM radiation to be emitted therefrom. In some non-limiting examples, the non-emissive regions 1402 may comprise those regions in the lateral aspect, that are substantially devoid of an emissive region 1401.

Thus, as shown in the cross-sectional view of FIG. 11, the lateral topology of the various layers of the at least one semiconducting layer 1030 may be varied to define at least one emissive region 1401, surrounded (at least in one lateral direction) by at least one non-emissive region 1402.

In some non-limiting examples, the emissive region 1401 corresponding to a single display (sub-) pixel 2210/32x may be understood to have a lateral aspect 1110, surrounded in at least one lateral direction by at least one non-emissive region 1402 having a lateral aspect 1120.

A non-limiting example of an implementation of the cross-sectional aspect of the device 1000 as applied to an emissive region 1401 corresponding to a single display (sub-) pixel 2210/32x of an OLED display 1000 will now be described. While features of such implementation are shown to be specific to the emissive region 1401, those having ordinary skill in the relevant art will appreciate that in some non-limiting examples, more than one emissive region 1401 may encompass common features.

In some non-limiting examples, the first electrode 1020 may be disposed over an exposed layer surface 11 of the device 1000, in some non-limiting examples, within at least a part of the lateral aspect 1110 of the emissive region 1401. In some non-limiting examples, at least within the lateral aspect 1110 of the emissive region 1401 of the (sub-) pixel(s) 2210/32x, the exposed layer surface 11, may, at the time of deposition of the first electrode 1020, comprise the TFT insulating layer 1109 of the various TFT structures 1101 that make up the driving circuit for the emissive region 1401 corresponding to a single display (sub-) pixel 2210/32x.

In some non-limiting examples, the TFT insulating layer 1109 may be formed with an opening extending therethrough to permit the first electrode 1020 to be electrically coupled with one of the TFT electrodes 1105, 1107, 1108, including, without limitation, as shown in FIG. 11, the TFT drain electrode 1108.

Those having ordinary skill in the relevant art will appreciate that the driving circuit comprises a plurality of TFT structures 1101. In FIG. 11, for purposes of simplicity of illustration, only one TFT structure 1101 may be shown, but it will be appreciated by those having ordinary skill in the relevant art, that such TFT structure 1101 may be representative of such plurality thereof and/or at least one component thereof, that comprise the driving circuit.

In a cross-sectional aspect, the configuration of each emissive region 1401 may, in some non-limiting examples, be defined by the introduction of at least one PDL 1140 substantially throughout the lateral aspects 1120 of the surrounding non-emissive region(s) 1402. In some non-limiting examples, the PDLs 1140 may comprise an insulating organic, and/or inorganic material.

In some non-limiting examples, the PDLs 1140 may be deposited substantially over the TFT insulating layer 1109, although, as shown, in some non-limiting examples, the PDLs 1140 may also extend over at least a part of the deposited first electrode 1020, and/or its outer edges.

In some non-limiting examples, as shown in FIG. 11, the cross-sectional thickness, and/or profile of the PDLs 1140 may impart a substantially valley-shaped configuration to the emissive region 1401 of each (sub-) pixel 2210/32x by a region of increased thickness along a boundary of the lateral aspect 1120 of the surrounding non-emissive region 1402 with the lateral aspect of the surrounded emissive region 1401, corresponding to a (sub-) pixel 2210/32x.

In some non-limiting examples, the profile of the PDLs 1140 may have a reduced thickness beyond such valley-shaped configuration, including without limitation, away from the boundary between the lateral aspect 1120 of the surrounding non-emissive region 1402 and the lateral aspect 1110 of the surrounded emissive region 1401, in some non-limiting examples, substantially well within the lateral aspect 1120 of such non-emissive region 1402.

While the PDL(s) 1140 have been generally illustrated as having a linearly sloped surface to form a valley-shaped configuration that define the emissive region(s) 1401 surrounded thereby, those having ordinary skill in the relevant art will appreciate that in some non-limiting examples, at least one of the shape, aspect ratio, thickness, width, and/or configuration of such PDL(s) 1140 may be varied. In some non-limiting examples, a PDL 1140 may be formed with a more steep or more gradually sloped part. In some non-limiting examples, such PDL(s) 1140 may be configured to extend substantially normally away from a surface on which it is deposited, that may cover at least one edges of the first electrode 1020. In some non-limiting examples, such PDL(s) 1140 may be configured to have deposited thereon at least one semiconducting layer 1030 by a solution-processing technology, including without limitation, by printing, including without limitation, ink-jet printing.

In some non-limiting examples, the at least one semiconducting layer 1030 may be deposited over the exposed layer surface 11 of the device 1000, including at least a part of the lateral aspect 1110 of such emissive region 1401 of the (sub-) pixel(s) 2210/32x. In some non-limiting examples, at least within the lateral aspect 1110 of the emissive region 1401 of the (sub-) pixel(s) 2210/32x, such exposed layer surface 11, may, at the time of deposition of the at least one semiconducting layer 1030 (and/or layers 1031, 1033, 1035, 1037, 1039 thereof), comprise the first electrode 1020.

In some non-limiting examples, the at least one semiconducting layer 1030 may also extend beyond the lateral aspect 1110 of the emissive region 1401 of the (sub-) pixel(s) 2210/32x and at least partially within the lateral aspects 1120 of the surrounding non-emissive region(s) 1402. In some non-limiting examples, such exposed layer surface 11 of such surrounding non-emissive region(s) 1402 may, at the time of deposition of the at least one semiconducting layer 1030, comprise the PDL(s) 1140.

In some non-limiting examples, the second electrode 1040 may be disposed over an exposed layer surface 11 of the device 1000, including at least a part of the lateral aspect 1110 of the emissive region 1401 of the (sub-) pixel(s) 2210/32x. In some non-limiting examples, at least within the lateral aspect of the emissive region 1401 of the (sub-) pixel(s) 2210/32x, such exposed layer surface 11, may, at the time of deposition of the second electrode 1040, comprise the at least one semiconducting layer 1030.

In some non-limiting examples, the second electrode 1040 may also extend beyond the lateral aspect 1110 of the emissive region 1401 of the (sub-) pixel(s) 2210/32x and at least partially within the lateral aspects 1120 of the surrounding non-emissive region(s) 1402. In some non-limiting examples, such exposed layer surface 11 of such surrounding non-emissive region(s) 1402 may, at the time of deposition of the second electrode 1040, comprise the PDL(s) 1140.

In some non-limiting examples, the second electrode 1040 may extend throughout substantially all or a substantial part of the lateral aspects 1120 of the surrounding non-emissive region(s) 1402.

### Selective Deposition of Patterned Electrode

In some non-limiting examples, the ability to achieve selective deposition of the deposited material 731 in an open mask and/or mask-free deposition process by the prior selective deposition of a patterning coating 110, may be employed to achieve the selective deposition of a patterned electrode 1020, 1040, 1550, and/or at least one layer thereof, of an opto-electronic device, including without limitation, an OLED device 1000, and/or a conductive element electrically coupled therewith.

In this fashion, the selective deposition of a patterning coating 110 in FIG. 11 using a shadow mask 615, and the open mask and/or mask-free deposition of the deposited material 731, may be combined to effect the selective deposition of at least one deposited layer 130 to form a device feature, including without limitation, a patterned electrode 1020, 1040, 1550, and/or at least one layer thereof, and/or a conductive element electrically coupled therewith, in the device 1000 shown in FIG. 10, without employing a shadow mask 615 within the deposition process for forming the deposited layer 130. In some non-limiting examples, such patterning may permit, and/or enhance the transmissivity of the device 1000.

A number of non-limiting examples of such patterned electrode 1020, 1040, 1550, and/or at least one layer thereof, and/or a conductive element electrically coupled therewith, to impart various structural and/or performance capabilities to such devices 1000 will now be described.

As a result of the foregoing, there may be an aim to selectively deposit, across the lateral aspect 1110 of the emissive region 1401 of a (sub-) pixel 2210/32x, and/or the lateral aspect 1120 of the non-emissive region(s) 1402 surrounding the emissive region 1401, a device feature, including without limitation, at least one of the first electrode 1020, the second electrode 1040, the auxiliary electrode 1550, and/or a conductive element electrically coupled therewith, in a pattern, on an exposed layer surface 11 of a frontplane 1010 of the device 1000. In some non-limiting examples, the first electrode 1020, the second electrode 1040, and/or the auxiliary electrode 1550, may be deposited in at least one of a plurality of deposited layers 130.

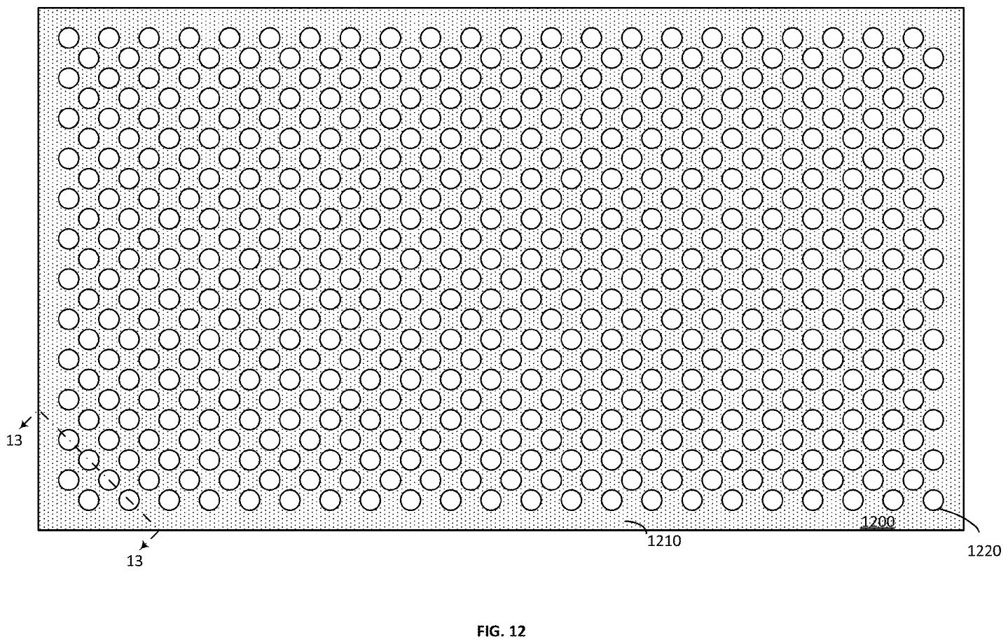

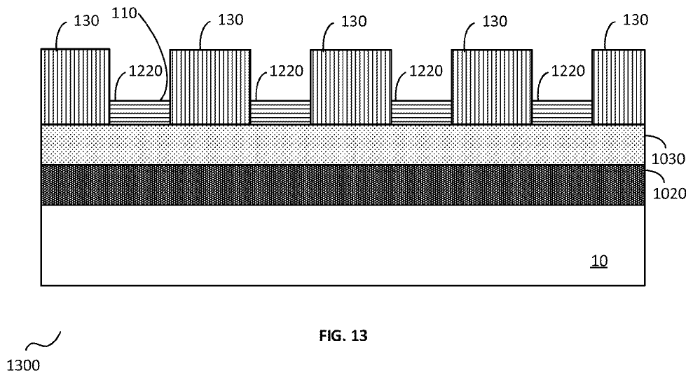

FIG. 12 may show an example patterned electrode 1200 in plan, in the figure, the second electrode 1040 suitable for use in an example version 1300 (FIG. 13) of the device 1000. The electrode 1200 may be formed in a pattern 1210 that comprises a single continuous structure, having or defining a patterned plurality of apertures 1220 therewithin, in which the apertures 1220 may correspond to regions of the device 1300 where there is no cathode.

In the figure, in some non-limiting examples, the pattern 1210 may be disposed across the entire lateral extent of the device 1300, without differentiation between the lateral aspect(s) 1110 of emissive region(s) 1401 corresponding to (sub-) pixel(s) 2210/32x and the lateral aspect(s) 1120 of non-emissive region(s) 1402 surrounding such emissive region(s) 1401. Thus, the example illustrated may correspond to a device 1300 that may be substantially transmissive relative to EM radiation incident on an external surface thereof, such that a substantial part of such externally-incident EM radiation may be transmitted through the device 1300, in addition to the emission (in a top-emission, bottom-emission, and/or double-sided emission) of EM radiation generated internally within the device 1300 as disclosed herein.

The transmittivity of the device 1300 may be adjusted, and/or modified by altering the pattern 1210 employed, including without limitation, an average size of the apertures 1220, and/or a spacing, and/or density of the apertures 1220.

Turning now to FIG. 13, there may be shown a cross-sectional view of the device 1300, taken along line 13-13 in FIG. 12. In the figure, the device 1300 may be shown as comprising the substrate 10, the first electrode 1020 and the at least one semiconducting layer 1030.

A patterning coating 110 may be selectively disposed in a pattern substantially corresponding to the pattern 1210 on the exposed layer surface 11 of the underlying layer.

A deposited layer 130 suitable for forming the patterned electrode 1200, which in the figure is the second electrode 1040, may be disposed on substantially all of the exposed layer surface 11 of the underlying layer, using an open mask and/or a mask-free deposition process. The underlying layer may comprise both regions of the patterning coating 110, disposed in the pattern 1210, and regions of the at least one semiconducting layer 1030, in the pattern 1210 where the patterning coating 110 has not been deposited. In some non-limiting examples, the regions of the patterning coating 110 may correspond substantially to a first portion 101 comprising the apertures 820 shown in the pattern 1210.

Because of the nucleation-inhibiting properties of those regions of the pattern 1210 where the patterning coating 110 was disposed (corresponding to the apertures 1220), the deposited material 731 disposed on such regions may tend to not remain, resulting in a pattern of selective deposition of the deposited layer 130, that may correspond substantially to the remainder of the pattern 1210, leaving those regions of the first portion 101 of the pattern 1210 corresponding to the apertures 1220 substantially devoid of a closed coating 140 of the deposited layer 130.

In other words, the deposited layer 130 that will form the cathode may be selectively deposited substantially only on a second portion 102 comprising those regions of the at least one semiconducting layer 1030 that surround but do not occupy the apertures 1220 in the pattern 1210.

FIG. 14A may show, in plan view, a schematic diagram showing a plurality of patterns 1410, 1420 of electrodes 1020, 1040, 1550.

In some non-limiting examples, the first pattern 1410 may comprise a plurality of elongated, spaced-apart regions that extend in a first lateral direction. In some non-limiting examples, the first pattern 1410 may comprise a plurality of first electrode 1020. In some non-limiting examples, a plurality of the regions that comprise the first pattern 1410 may be electrically coupled.

In some non-limiting examples, the second pattern 1420 may comprise a plurality of elongated, spaced-apart regions that extend in a second lateral direction. In some non-limiting examples, the second lateral direction may be substantially normal to the first lateral direction. In some non-limiting examples, the second pattern 1420 may comprise a plurality of second electrodes 1040. In some non-limiting examples, a plurality of the regions that comprise the second pattern 1420 may be electrically coupled.

In some non-limiting examples, the first pattern 1410 and the second pattern 1420 may form part of an example version, shown generally at 1400 (FIG. 14B), of the device 1000.

In some non-limiting examples, the lateral aspect(s) 1110 of emissive region(s) 1401 corresponding to (sub-) pixel(s) 2210/32x may be formed where the first pattern 1410 overlaps the second pattern 1420. In some non-limiting examples, the lateral aspect(s) 1120 of non-emissive region(s) 1402 may correspond to any lateral aspect other than the lateral aspect(s) 1110.

In some non-limiting examples, a first terminal, which, in some non-limiting examples, may be a positive terminal, of the power source 1005, may be electrically coupled with at least one electrode 1020, 1040, 1550 of the first pattern 1410. In some non-limiting examples, the first terminal may be coupled with the at least one electrode 1020, 1040, 1550 of the first pattern 1410 through at least one driving circuit. In some non-limiting examples, a second terminal, which, in some non-limiting examples, may be a negative terminal, of the power source 1005, may be electrically coupled with at least one electrode 1020, 1040, 1550 of the second pattern 1420. In some non-limiting examples, the second terminal may be coupled with the at least one electrode 1020, 1040, 1550 of the second pattern 1420 through the at least one driving circuit.

Turning now to FIG. 14B, there may be shown a cross-sectional view of the device 1400, at a deposition stage 1400b, taken along line 14B-14B in FIG. 14A. In the figure, the device 1400 at the stage 1400b may be shown as comprising the substrate 10.

A patterning coating 110 may be selectively disposed in a pattern substantially corresponding to the inverse of the first pattern 1410 on the exposed layer surface 11 of the underlying layer, which, as shown in the figure, may be the substrate 10.

A deposited layer 130 suitable for forming the first pattern 1410 of electrode 1020, 1040, 1550, which in the figure is the first electrode 1020, may be disposed on substantially all of the exposed layer surface 11 of the underlying layer, using an open mask and/or a mask-free deposition process. The underlying layer may comprise both regions of the patterning coating 110, disposed in the inverse of the first pattern 1410, and regions of the substrate 10, disposed in the first pattern 1410 where the patterning coating 110 has not been deposited. In some non-limiting examples, the regions of the substrate 10 may correspond substantially to the elongated spaced-apart regions of the first pattern 1410, while the regions of the patterning coating 110 may correspond substantially to a first portion 101 comprising the gaps therebetween.

Because of the nucleation-inhibiting properties of those regions of the first pattern 1410 where the patterning coating 110 was disposed (corresponding to the gaps therebetween), the deposited material 731 disposed on such regions may tend to not remain, resulting in a pattern of selective deposition of the deposited layer 130, that may correspond substantially to elongated spaced-apart regions of the first pattern 1410, leaving a first portion 101 comprising the gaps therebetween substantially devoid of a closed coating 140 of the deposited layer 130.

In other words, the deposited layer 130 that may form the first pattern 1410 of electrode 1020, 1040, 1550 may be selectively deposited substantially only on a second portion 102 comprising those regions of the substrate 10 that define the elongated spaced-apart regions of the first pattern 1410.

Turning now to FIG. 14C, there may be shown a cross-sectional view 1400c of the device 1400, taken along line 14C-14C in FIG. 14A. In the figure, the device 1400 may be shown as comprising the substrate 10; the first pattern 1410 of electrode 1020 deposited as shown in FIG. 14B, and the at least one semiconducting layer(s) 1030.

In some non-limiting examples, the at least one semiconducting layer(s) 1030 may be provided as a common layer across substantially all of the lateral aspect(s) of the device 1400.

A patterning coating 110 may be selectively disposed in a pattern substantially corresponding to the second pattern 1420 on the exposed layer surface 11 of the underlying layer, which, as shown in the figure, is the at least one semiconducting layer 1030.

A deposited layer 130 suitable for forming the second pattern 1420 of electrode 1020, 1040, 1550, which in the figure is the second electrode 1040, may be disposed on substantially all of the exposed layer surface 11 of the underlying layer, using an open mask and/or a mask-free deposition process. The underlying layer may comprise both regions of the patterning coating 110, disposed in the inverse of the second pattern 1420, and regions of the at least one semiconducting layer(s) 1030, in the second pattern 1420 where the patterning coating 110 has not been deposited. In some non-limiting examples, the regions of the at least one semiconducting layer(s) 1030 may correspond substantially to a first portion 101 comprising the elongated spaced-apart regions of the second pattern 1420, while the regions of the patterning coating 110 may correspond substantially to the gaps therebetween.

Because of the nucleation-inhibiting properties of those regions of the second pattern 1420 where the patterning coating 110 was disposed (corresponding to the gaps therebetween), the deposited layer 130 disposed on such regions may tend not to remain, resulting in a pattern of selective deposition of the deposited layer 130, that may correspond substantially to elongated spaced-apart regions of the second pattern 1420, leaving the first portion 101 comprising the gaps therebetween substantially devoid of a closed coating 140 of the deposited layer 130.

In other words, the deposited layer 130 that may form the second pattern 1420 of electrode 1020, 1040, 1550 may be selectively deposited substantially only on a second portion 102 comprising those regions of the at least one semiconducting layer 1030 that define the elongated spaced-apart regions of the second pattern 1420.

In some non-limiting examples, an average layer thickness of the patterning coating 110 and of the deposited layer 130 deposited thereafter for forming either, or both, of the first pattern 1410, and/or the second pattern 1420 of electrode 1020, 1550 may be varied according to a variety of parameters, including without limitation, a given application and given performance characteristics. In some non-limiting examples, the average layer thickness of the patterning coating 110 may be comparable to, and/or substantially less than an average layer thickness of the deposited layer 130 deposited thereafter. Use of a relatively thin patterning coating 110 to achieve selective patterning of a deposited layer 130 deposited thereafter may be suitable to provide flexible devices 1000. In some non-limiting examples, a relatively thin patterning coating 110 may provide a relatively planar surface on which a barrier coating 1450 may be deposited. In some non-limiting examples, providing such a relatively planar surface for application of the barrier coating 1450 may increase adhesion of the barrier coating 1450 to such surface.

At least one of the first pattern 1410 of electrode 1020, 1040, 1550 and at least one of the second pattern 1420 of electrode 1020, 1040, 1550 may be electrically coupled with the power source 1005, whether directly, and/or, in some non-limiting examples, through their respective driving circuit(s) to control EM radiation emission from the lateral aspect(s) 1110 of the emissive region(s) 1401 corresponding to (sub-) pixel(s) 2210/32x.

### Auxiliary Electrode

Those having ordinary skill in the relevant art will appreciate that the process of forming the second electrode 1040 in the second pattern 1420 shown in FIGS. 14A-14C may, in some non-limiting examples, be used in similar fashion to form an auxiliary electrode 1550 for the device 1000. In some non-limiting examples, the second electrode 1040 thereof may comprise a common electrode, and the auxiliary electrode 1550 may be deposited in the second pattern 1420, in some non-limiting examples, above or in some non-limiting examples below, the second electrode 1040 and electrically coupled therewith. In some non-limiting examples, the second pattern 1420 for such auxiliary electrode 1550 may be such that the elongated spaced-apart regions of the second pattern 1420 lie substantially within the lateral aspect(s) 1120 of non-emissive region(s) 1402 surrounding the lateral aspect(s) 1110 of emissive region(s) 1401 corresponding to (sub-) pixel(s) 2210/32x. In some non-limiting examples, the second pattern 1420 for such auxiliary electrodes 1550 may be such that the elongated spaced-apart regions of the second pattern 1420 lie substantially within the lateral aspect(s) 1110 of emissive region(s) 1401 corresponding to (sub-) pixel(s) 2210/32x, and/or the lateral aspect(s) 1120 of non-emissive region(s) 1402 surrounding them.

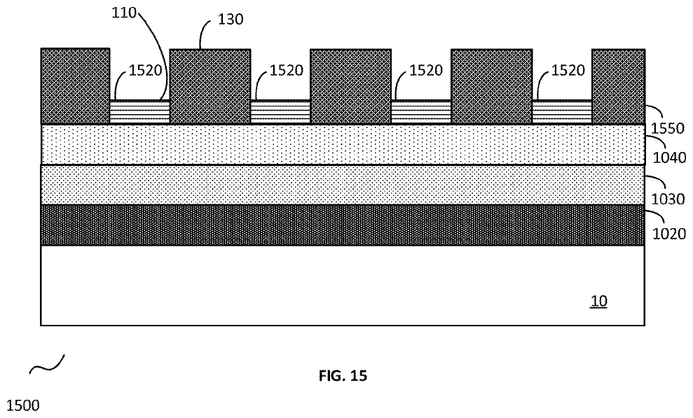

FIG. 15 may show an example cross-sectional view of an example version 1500 of the device 1000 that is substantially similar thereto, but further may comprise at least one auxiliary electrode 1550 disposed in a pattern above and electrically coupled (not shown) with the second electrode 1040.

The auxiliary electrode 1550 may be electrically conductive. In some non-limiting examples, the auxiliary electrode 1550 may be formed by at least one metal, and/or metal oxide. Non-limiting examples of such metals include Cu, Al, molybdenum (Mo), or Ag. In some non-limiting examples, the auxiliary electrode 1550 may comprise a multi-layer metallic structure, including without limitation, one formed by Mo/Al/Mo. Non-limiting examples of such metal oxides include ITO, ZnO, IZO, or other oxides containing In, and Zn. In some non-limiting examples, the auxiliary electrode 1550 may comprise a multi-layer structure formed by a combination of at least one metal and at least one metal oxide, including without limitation, Ag/ITO, Mo/ITO, ITO/Ag/ITO, or ITO/Mo/ITO. In some non-limiting examples, the auxiliary electrode 1550 comprises a plurality of such electrically conductive materials.

The device 1500 may be shown as comprising the substrate 10, the first electrode 1020 and the at least one semiconducting layer 1030.

The second electrode 1040 may be disposed on substantially all of the exposed layer surface 11 of the at least one semiconducting layer 1030.

In some non-limiting examples, particularly in a top-emission device 1500, the second electrode 1040 may be formed by depositing a relatively thin conductive film layer (not shown) in order, in some non-limiting examples, to reduce optical interference (including, without limitation, attenuation, reflections, and/or diffusion) related to the presence of the second electrode 1040. In some non-limiting examples, as discussed elsewhere, a reduced thickness of the second electrode 1040, may generally increase a sheet resistance of the second electrode 1040, which may, in some non-limiting examples, reduce the performance, and/or efficiency of the device 1500. By providing the auxiliary electrode 1550 that may be electrically coupled with the second electrode 1040, the sheet resistance and thus, the IR drop associated with the second electrode 1040, may, in some non-limiting examples, be decreased.

In some non-limiting examples, the device 1500 may be a bottom-emission, and/or double-sided emission device 1500. In such examples, the second electrode 1040 may be formed as a relatively thick conductive layer without substantially affecting optical characteristics of such a device 1500. Nevertheless, even in such scenarios, the second electrode 1040 may nevertheless be formed as a relatively thin conductive film layer (not shown), in some non-limiting examples, so that the device 1500 may be substantially transmissive relative to EM radiation incident on an external surface thereof, such that a substantial part of such externally-incident EM radiation may be transmitted through the device 1500, in addition to the emission of EM radiation generated internally within the device 1500 as disclosed herein.

A patterning coating 110 may be selectively disposed in a pattern on the exposed layer surface 11 of the underlying layer, which, as shown in the figure, may be the second electrode 1040. In some non-limiting examples, as shown in the figure, the patterning coating 110 may be disposed, in a first portion 101 of the pattern, as a series of parallel rows 1520 that may correspond to the lateral aspects 1120 of the non-emissive regions 1402.

A deposited layer 130 suitable for forming the patterned auxiliary electrode 1550, may be disposed on substantially all of the exposed layer surface 11 of the underlying layer, using an open mask and/or a mask-free deposition process. The underlying layer may comprise both regions of the patterning coating 110, disposed in the pattern of rows 1520, and regions of the second electrode 1040 where the patterning coating 110 has not been deposited.

Because of the nucleation-inhibiting properties of those rows 1520 where the patterning coating 110 was disposed, the deposited material 731 disposed on such rows 1520 may tend to not remain, resulting in a pattern of selective deposition of the deposited layer 130, that may correspond substantially to at least one second portion 102 of the pattern, leaving the first portion 101 comprising the rows 1520 substantially devoid of a closed coating 140 of the deposited layer 130.

In other words, the deposited layer 130 that may form the auxiliary electrode 1550 may be selectively deposited substantially only on a second portion 102 comprising those regions of the at least one semiconducting layer 1030, that surround but do not occupy the rows 1520.

In some non-limiting examples, selectively depositing the auxiliary electrode 1550 to cover only certain rows 1520 of the lateral aspect of the device 1500, while other regions thereof remain uncovered, may control, and/or reduce optical interference related to the presence of the auxiliary electrode 1550.

In some non-limiting examples, the auxiliary electrode 1550 may be selectively deposited in a pattern that may not be readily detected by the naked eye from a typical viewing distance.

In some non-limiting examples, the auxiliary electrode 1550 may be formed in devices other than OLED devices, including for decreasing an effective resistance of the electrodes of such devices.

The ability to pattern electrodes 1020, 1040, 1550, including without limitation, the second electrode 1040, and/or the auxiliary electrode 1550 without employing a shadow mask 615 during the high-temperature deposited layer 130 deposition process by employing a patterning coating 110, including without limitation, the process depicted in FIG. 6, may allow numerous configurations of auxiliary electrodes 1550 to be deployed.

In some non-limiting examples, the auxiliary electrode 1550 may be disposed between neighbouring emissive regions 1401 and electrically coupled with the second electrode 1040. In non-limiting examples, a width of the auxiliary electrode 1550 may be less than a separation distance between the neighbouring emissive regions 1401. As a result, there may exist a gap within the at least one non-emissive region 1402 on each side of the auxiliary electrode 1550. In some non-limiting examples, such an arrangement may reduce a likelihood that the auxiliary electrode 1550 would interfere with an optical output of the device 1500, in some non-limiting examples, from at least one of the emissive regions 1401. In some non-limiting examples, such an arrangement may be appropriate where the auxiliary electrode 1550 is relatively thick (in some non-limiting examples, greater than several hundred nm, and/or on the order of a few microns in thickness). In some non-limiting examples, an aspect ratio of the auxiliary electrode 1550 may exceed about 0.05, such as one of at least about: 0.1, 0.2, 0.5, 0.8, 1, and 2. In some non-limiting examples, a height (thickness) of the auxiliary electrode 1550 may exceed about 50 nm, such as one of at least about: 80 nm, 100 nm, 200 nm, 500 nm, 700 nm, 1,000 nm, 1,500 nm, 1,700 nm, and 2,000 nm.

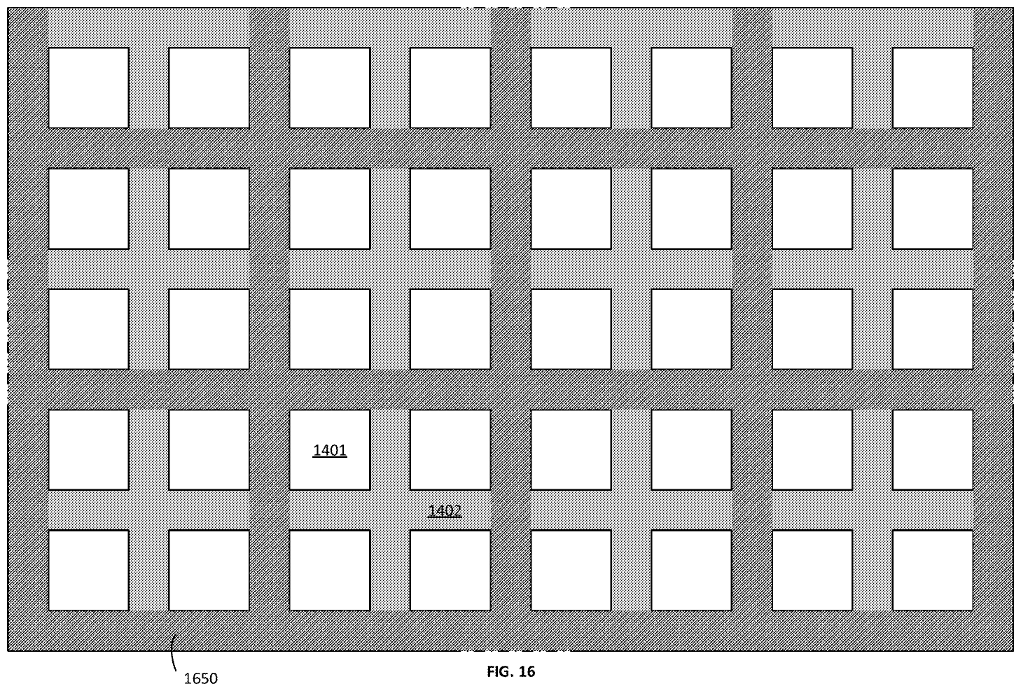

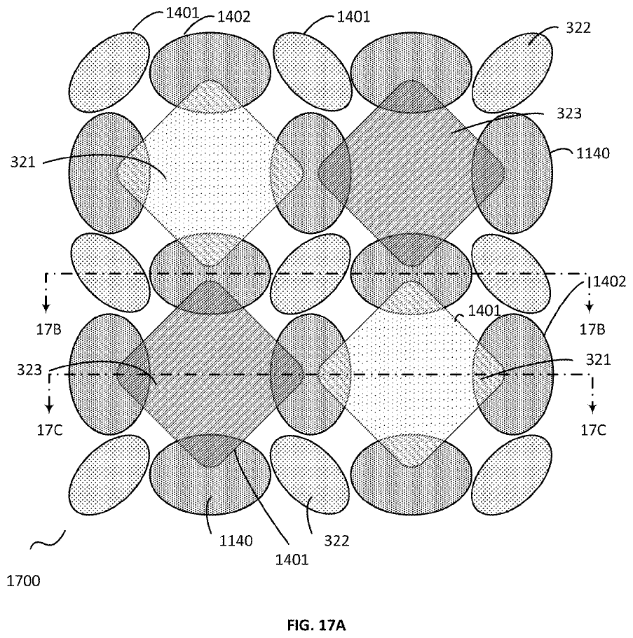

FIG. 16 may show, in plan view, a schematic diagram showing an example of a pattern 1650 of the auxiliary electrode 1550 formed as a grid that may be overlaid over both the lateral aspects 1110 of emissive regions 1401, which may correspond to (sub-) pixel(s) 2210/32x of an example version 1600 of device 1000, and the lateral aspects 1120 of non-emissive regions 1402 surrounding the emissive regions 1401.

In some non-limiting examples, the auxiliary electrode pattern 1650 may extend substantially only over some but not all of the lateral aspects 1120 of non-emissive regions 1402, to not substantially cover any of the lateral aspects 1110 of the emissive regions 1401.

Those having ordinary skill in the relevant art will appreciate that while, in the figure, the pattern 1650 of the auxiliary electrode 1550 may be shown as being formed as a continuous structure such that all elements thereof are both physically connected to and electrically coupled with one another and electrically coupled with at least one electrode 1020, 1040, 1550, which in some non-limiting examples may be the first electrode 1020, and/or the second electrode 1040, in some non-limiting examples, the pattern 1650 of the auxiliary electrode 1550 may be provided as a plurality of discrete elements of the pattern 1650 of the auxiliary electrode 1550 that, while remaining electrically coupled with one another, may not be physically connected to one another. Even so, such discrete elements of the pattern 1650 of the auxiliary electrode 1550 may still substantially lower a sheet resistance of the at least one electrode 1020, 1040, 1550 with which they are electrically coupled, and consequently of the device 1600, to increase an efficiency of the device 1600 without substantially interfering with its optical characteristics.

In some non-limiting examples, auxiliary electrodes 1550 may be employed in devices 1600 with a variety of arrangements of (sub-) pixel(s) 2210/32x. In some non-limiting examples, the (sub-) pixel 2210/32x arrangement may be substantially diamond-shaped.

In some non-limiting examples, FIG. 17A may show, in plan, in an example version 1700 of device 1000, a plurality of groups 321-323 of emissive regions 1401 each corresponding to a (sub-) pixel 2210/32x, surrounded by the lateral aspects of a plurality of non-emissive regions 1402 comprising PDLs 1140 in a diamond configuration. In some non-limiting examples, the configuration may be defined by patterns 321-323 of emissive regions 1401 and PDLs 1140 in an alternating pattern of first and second rows.

In some non-limiting examples, the lateral aspects 1120 of the non-emissive regions 1402 comprising PDLs 1140 may be substantially elliptically shaped. In some non-limiting examples, the major axes of the lateral aspects 1120 of the non-emissive regions 1402 in the first row may be aligned and substantially normal to the major axes of the lateral aspects 1120 of the non-emissive regions 1402 in the second row. In some non-limiting examples, the major axes of the lateral aspects 1120 of the non-emissive regions 1402 in the first row may be substantially parallel to an axis of the first row.

In some non-limiting examples, a first group 321 of emissive regions 1401 may correspond to (sub-) pixels 2210/32x that emit EM radiation at a first wavelength, in some non-limiting examples the (sub-) pixels 2210/32x of the first group 321 may correspond to R(ed) sub-pixels 321. In some non-limiting examples, the lateral aspects 1110 of the emissive regions 1401 of the first group 321 may have a substantially diamond-shaped configuration. In some non-limiting examples, the emissive regions 1401 of the first group 321 may lie in the pattern of the first row, preceded and followed by PDLs 1140. In some non-limiting examples, the lateral aspects 1110 of the emissive regions 1401 of the first group 321 may slightly overlap the lateral aspects 1120 of the preceding and following non-emissive regions 1402 comprising PDLs 1140 in the same row, as well as of the lateral aspects 1120 of adjacent non-emissive regions 1402 comprising PDLs 1140 in a preceding and following pattern of the second row.

In some non-limiting examples, a second group 322 of emissive regions 1401 may correspond to (sub-) pixels 2210/32x that emit EM radiation at a second wavelength, in some non-limiting examples the (sub-) pixels 2210/32x of the second group 322 may correspond to G(reen) sub-pixels 322. In some non-limiting examples, the lateral aspects 1110 of the emissive regions 1401 of the second group 321 may have a substantially elliptical configuration. In some non-limiting examples, the emissive regions 1401 of the second group 321 may lie in the pattern of the second row, preceded and followed by PDLs 1140. In some non-limiting examples, a major axis of some of the lateral aspects 1110 of the emissive regions 1401 of the second group 321 may be at a first angle, which in some non-limiting examples, may be 45° relative to an axis of the second row. In some non-limiting examples, a major axis of others of the lateral aspects 1110 of the emissive regions 1401 of the second group 321 may be at a second angle, which in some non-limiting examples may be substantially normal to the first angle. In some non-limiting examples, the emissive regions 1401 of the second group 322, whose lateral aspects 1110 may have a major axis at the first angle, may alternate with the emissive regions 1401 of the second group 322, whose lateral aspects 1110 may have a major axis at the second angle.

In some non-limiting examples, a third group 323 of emissive regions 1401 may correspond to (sub-) pixels 2210/32x that emit EM radiation at a third wavelength, in some non-limiting examples the (sub-) pixels 2210/32x of the third group 323 may correspond to B(lue) sub-pixels 323. In some non-limiting examples, the lateral aspects 1110 of the emissive regions 1401 of the third group 323 may have a substantially diamond-shaped configuration. In some non-limiting examples, the emissive regions 1401 of the third group 323 may lie in the pattern of the first row, preceded and followed by PDLs 1140. In some non-limiting examples, the lateral aspects 1110 of the emissive regions 1401 of the third group 323 may slightly overlap the lateral aspects 1120 of the preceding and following non-emissive regions 1402 comprising PDLs 1140 in the same row, as well as of the lateral aspects 1120 of adjacent non-emissive regions 1402 comprising PDLs 1140 in a preceding and following pattern of the second row. In some non-limiting examples, the pattern of the second row may comprise emissive regions 1401 of the first group 321 alternating emissive regions 1401 of the third group 323, each preceded and followed by PDLs 1140.

Turning now to FIG. 17B, there may be shown an example cross-sectional view of the device 1700, taken along line 17B-17B in FIG. 17A. In the figure, the device 1700 may be shown as comprising a substrate 10 and a plurality of elements of a first electrode 1020, formed on an exposed layer surface 11 thereof. The substrate 10 may comprise the base substrate 1012 (not shown for purposes of simplicity of illustration), and/or at least one TFT structure 1101 (not shown for purposes of simplicity of illustration), corresponding to and for driving each (sub-) pixel 2210/32x. PDLs 1140 may be formed over the substrate 10 between elements of the first electrode 1020, to define emissive region(s) 1401 over each element of the first electrode 1020, separated by non-emissive region(s) 1402 comprising the PDL(s) 1140. In the figure, the emissive region(s) 1401 may all correspond to the second group 322.

In some non-limiting examples, at least one semiconducting layer 1030 may be deposited on each element of the first electrode 1020, between the surrounding PDLs 1140.

In some non-limiting examples, a second electrode 1040, which in some non-limiting examples, may be a common cathode, may be deposited over the emissive region(s) 1401 of the second group 322 to form the G(reen) sub-pixel(s) 322 thereof and over the surrounding PDLs 1140.

In some non-limiting examples, a patterning coating 110 may be selectively deposited over the second electrode 1040 across the lateral aspects 1110 of the emissive region(s) 1401 of the second group 322 of G(reen) sub-pixels 322 to allow selective deposition of a deposited layer 130 over parts of the second electrode 1040 that may be substantially devoid of the patterning coating 110, namely across the lateral aspects 1120 of the non-emissive region(s) 1402 comprising the PDLs 1140. In some non-limiting examples, the deposited layer 130 may tend to accumulate along the substantially planar parts of the PDLs 1140, as the deposited layer 130 may tend to not remain on the inclined parts of the PDLs 1140 but may tend to descend to a base of such inclined parts, which may be coated with the patterning coating 110. In some non-limiting examples, the deposited layer 130 on the substantially planar parts of the PDLs 1140 may form at least one auxiliary electrode 1550 that may be electrically coupled with the second electrode 1040.

In some non-limiting examples, the device 1700 may comprise a CPL, and/or an outcoupling layer. In some non-limiting examples, such CPL, and/or outcoupling layer may be provided directly on a surface of the second electrode 1040, and/or a surface of the patterning coating 110. In some non-limiting examples, such CPL, and/or outcoupling layer may be provided across the lateral aspect of at least one emissive region 1401 corresponding to a (sub-) 2210/32x.

In some non-limiting examples, the patterning coating 110 may also act as an index-matching coating. In some non-limiting examples, the patterning coating 110 may also act as an outcoupling layer.

In some non-limiting examples, the device 1700 may comprise an encapsulation layer 1750. Non-limiting examples of such encapsulation layer 1750 include a glass cap, a barrier film, a barrier adhesive, a barrier coating 1450, and/or a TFE layer such as shown in dashed outline in the figure, provided to encapsulate the device 1700. In some non-limiting examples, the TFE layer 1750 may be considered a type of barrier coating 1450.

In some non-limiting examples, the encapsulation layer 1750 may be arranged above at least one of the second electrode 1040, and/or the patterning coating 110. In some non-limiting examples, the device 1700 may comprise additional optical, and/or structural layers, coatings, and components, including without limitation, a polarizer, a color filter, an anti-reflection coating, an anti-glare coating, cover glass, and/or an optically clear adhesive (OCA).

Turning now to FIG. 17C, there may be shown an example cross-sectional view of the device 1700, taken along line 17C-17C in FIG. 17A. In the figure, the device 1700 may be shown as comprising a substrate 10 and a plurality of elements of a first electrode 1020, formed on an exposed layer surface 11 thereof. PDLs 1140 may be formed over the substrate 10 between elements of the first electrode 1020, to define emissive region(s) 1401 over each element of the first electrode 1020, separated by non-emissive region(s) 1402 comprising the PDL(s) 1140. In the figure, the emissive region(s) 1401 may correspond to the first group 321 and to the third group 323 in alternating fashion.

In some non-limiting examples, at least one semiconducting layer 1030 may be deposited on each element of the first electrode 1020, between the surrounding PDLs 1140.

In some non-limiting examples, a second electrode 1040, which in some non-limiting examples, may be a common cathode, may be deposited over the emissive region(s) 1401 of the first group 321 to form the R(ed) sub-pixel(s) 321 thereof, over the emissive region(s) 1401 of the third group 323 to form the B(lue) sub-pixel(s) 323 thereof, and over the surrounding PDLs 1140.

In some non-limiting examples, a pattering coating 110 may be selectively deposited over the second electrode 1040 across the lateral aspects 1110 of the emissive region(s) 1401 of the first group 321 of R(ed) sub-pixels 321 and of the third group 323 of B(lue) sub-pixels 323 to allow selective deposition of a deposited layer 130 over parts of the second electrode 1040 that may be substantially devoid of the patterning coating 110, namely across the lateral aspects 1120 of the non-emissive region(s) 1402 comprising the PDLs 1140. In some non-limiting examples, the deposited layer 130 may tend to accumulate along the substantially planar parts of the PDLs 1140, as the deposited layer 130 may tend to not remain on the inclined parts of the PDLs 1140 but may tend to descend to a base of such inclined parts, which are coated with the patterning coating 110. In some non-limiting examples, the deposited layer 130 on the substantially planar parts of the PDLs 1140 may form at least one auxiliary electrode 1550 that may be electrically coupled with the second electrode 1040.

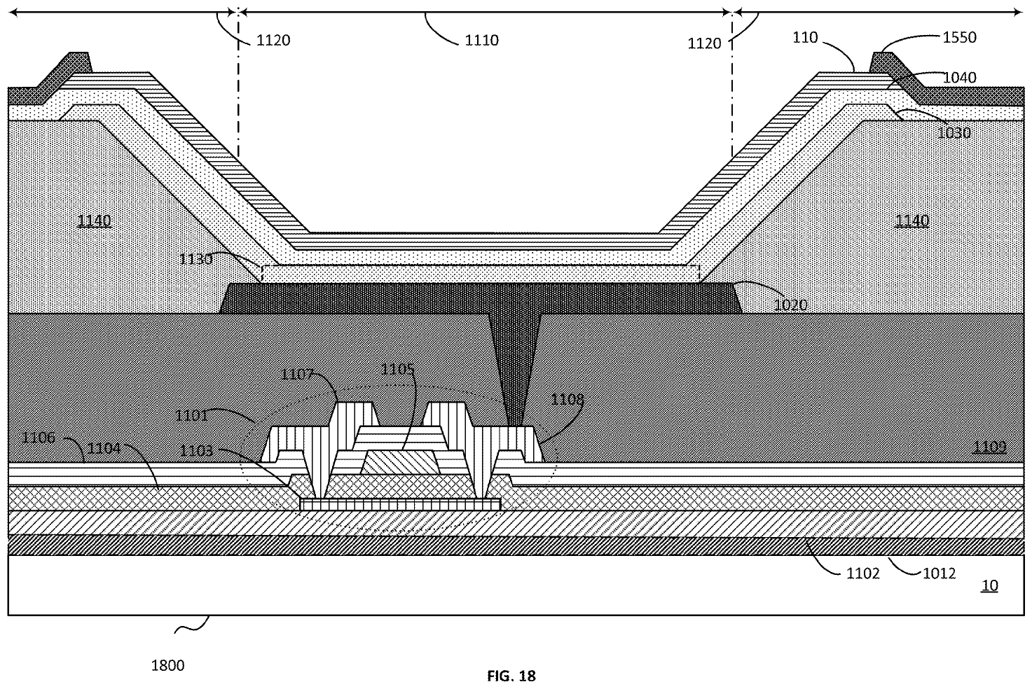

Turning now to FIG. 18, there may be shown an example version 1800 of the device 1000, which may encompass the device shown in cross-sectional view in FIG. 11, but with additional deposition steps that are described herein.

The device 1800 may show a patterning coating 110 selectively deposited over the exposed layer surface 11 of the underlying layer, in the figure, the second electrode 1040, within a first portion 101 of the device 1800, corresponding substantially to the lateral aspect 1110 of emissive region(s) 1401 corresponding to (sub-) pixel(s) 2210/32x and not within a second portion 102 of the device 1800, corresponding substantially to the lateral aspect(s) 1120 of non-emissive region(s) 1402 surrounding the first portion 101.

In some non-limiting examples, the patterning coating 110 may be selectively deposited using a shadow mask 615.

The patterning coating 110 may provide, within the first portion 101, an exposed layer surface 11 with a relatively low initial sticking probability against deposition of a deposited material 731 to be thereafter deposited as a deposited layer 130 to form an auxiliary electrode 1550.

After selective deposition of the patterning coating 110, the deposited material 731 may be deposited over the device 1800 but may remain substantially only within the second portion 102, which may be substantially devoid of any patterning coating 110, to form the auxiliary electrode 1550.

In some non-limiting examples, the deposited material 731 may be deposited using an open mask and/or a mask-free deposition process.

The auxiliary electrode 1550 may be electrically coupled with the second electrode 1040 to reduce a sheet resistance of the second electrode 1040, including, as shown, by lying above and in physical contact with the second electrode 1040 across the second portion that may be substantially devoid of any patterning coating 110.

In some non-limiting examples, the deposited layer 130 may comprise substantially the same material as the second electrode 1040, to ensure a high initial sticking probability against deposition of the deposited material 731 in the second portion 102.

In some non-limiting examples, the second electrode 1040 may comprise substantially pure Mg, and/or an alloy of Mg and another metal, including without limitation, Ag. In some non-limiting examples, an Mg:Ag alloy composition may range from about 1:9-9:1 by volume. In some non-limiting examples, the second electrode 1040 may comprise metal oxides, including without limitation, ternary metal oxides, such as, without limitation, ITO, and/or IZO, and/or a combination of metals, and/or metal oxides.

In some non-limiting examples, the deposited layer 130 used to form the auxiliary electrode 1550 may comprise substantially pure Mg.

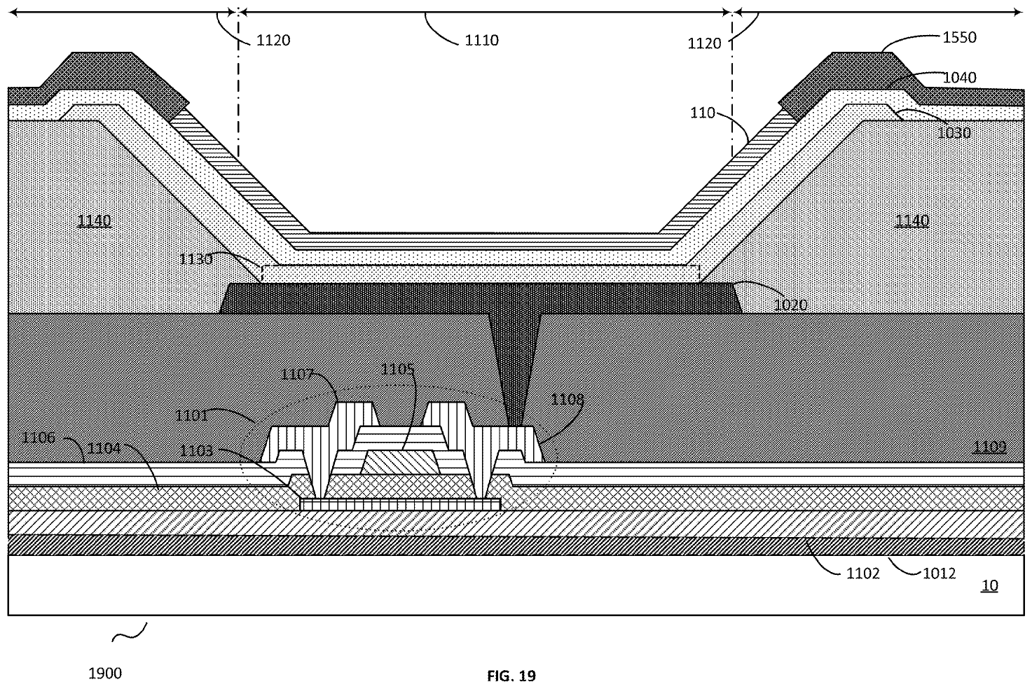

Turning now to FIG. 19, there may be shown an example version 1900 of the device 1000, which may encompass the device shown in cross-sectional view in FIG. 11, but with additional deposition steps that are described herein.

The device 1900 may show a patterning coating 110 selectively deposited over the exposed layer surface 11 of the underlying layer, in the figure, the second electrode 1040, within a first portion 101 of the device 1900, corresponding substantially to a part of the lateral aspect 1110 of emissive region(s) 1401 corresponding to (sub-) pixel(s) 2210/32x, and not within a second portion 102. In the figure, the first portion 101 may extend partially along the extent of an inclined part of the PDLs 1140 defining the emissive region(s) 1401.

In some non-limiting examples, the patterning coating 110 may be selectively deposited using a shadow mask 615.

The patterning coating 110 may provide, within the first portion 101, an exposed layer surface 11 with a relatively low initial sticking probability against deposition of a deposited material 731 to be thereafter deposited as a deposited layer 130 to form an auxiliary electrode 1550.

After selective deposition of the patterning coating 110, the deposited material 731 may be deposited over the device 1900 but may remain substantially only within the second portion 102, which may be substantially devoid of patterning coating 110, to form the auxiliary electrode 1550. As such, in the device 1900, the auxiliary electrode 1550 may extend partly across the inclined part of the PDLs 1140 defining the emissive region(s) 1401.

In some non-limiting examples, the deposited layer 130 may be deposited using an open mask and/or a mask-free deposition process.

The auxiliary electrode 1550 may be electrically coupled with the second electrode 1040 to reduce a sheet resistance of the second electrode 1040, including, as shown, by lying above and in physical contact with the second electrode 1040 across the second portion 102 that may be substantially devoid of patterning coating 110.

In some non-limiting examples, the material of which the second electrode 1040 may be comprised, may not have a high initial sticking probability against deposition of the deposited material 731.

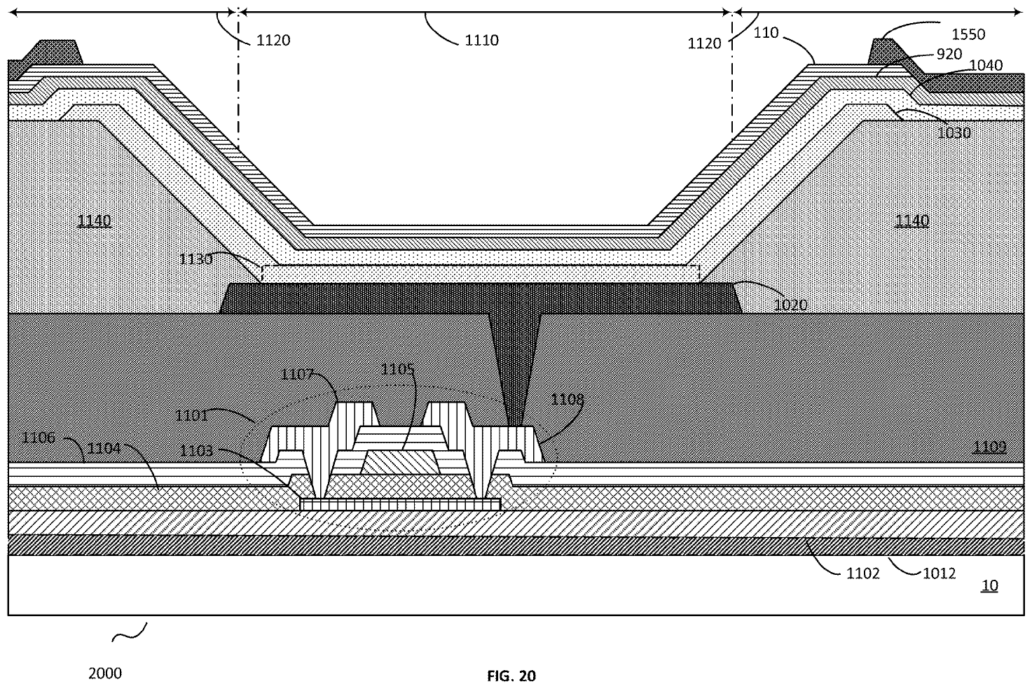

FIG. 20 may illustrate such a scenario, in which there may be shown an example version 2000 of the device 1000, which may encompass the device shown in cross-sectional view in FIG. 11, but with additional deposition steps that are described herein.

The device 2000 may show an NPC 920 deposited over the exposed layer surface 11 of the underlying material, in the figure, the second electrode 1040.

In some non-limiting examples, the NPC 920 may be deposited using an open mask and/or a mask-free deposition process.

Thereafter, a patterning coating 110 may be deposited selectively deposited over the exposed layer surface 11 of the underlying material, in the figure, the NPC 920, within a first portion 101 of the device 2000, corresponding substantially to a part of the lateral aspect 1110 of emissive region(s) 1401 corresponding to (sub-) pixel(s) 2210/32x, and not within a second portion 102 of the device 2000, corresponding substantially to the lateral aspect(s) 1120 of non-emissive region(s) 1402 surrounding the first portion 101.

In some non-limiting examples, the patterning coating 110 may be selectively deposited using a shadow mask 615.

The patterning coating 110 may provide, within the first portion 101, an exposed layer surface 11 with a relatively low initial sticking probability against deposition of a deposited material 731 to be thereafter deposited as a deposited layer 130 to form an auxiliary electrode 1550.

After selective deposition of the patterning coating 110, the deposited material 731 may be deposited over the device 2000 but may remain substantially only within the second portion 102, which may be substantially devoid of patterning coating 110, to form the auxiliary electrode 1550.

In some non-limiting examples, the deposited layer 130 may be deposited using an open mask and/or a mask-free deposition process.

The auxiliary electrode 1550 may be electrically coupled with the second electrode 1040 to reduce a sheet resistance thereof. While, as shown, the auxiliary electrode 1550 may not be lying above and in physical contact with the second electrode 1040, those having ordinary skill in the relevant art will nevertheless appreciate that the auxiliary electrode 1550 may be electrically coupled with the second electrode 1040 by several well-understood mechanisms. In some non-limiting examples, the presence of a relatively thin film (in some non-limiting examples, of up to about 50 nm) of a patterning coating 110 may still allow a current to pass therethrough, thus allowing a sheet resistance of the second electrode 1040 to be reduced.

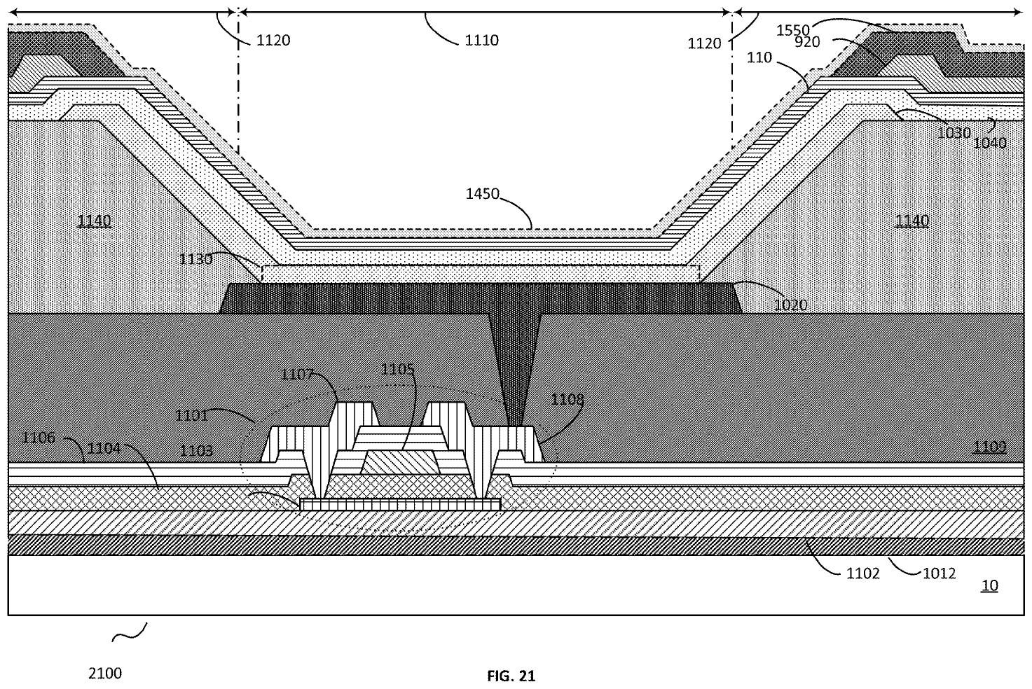

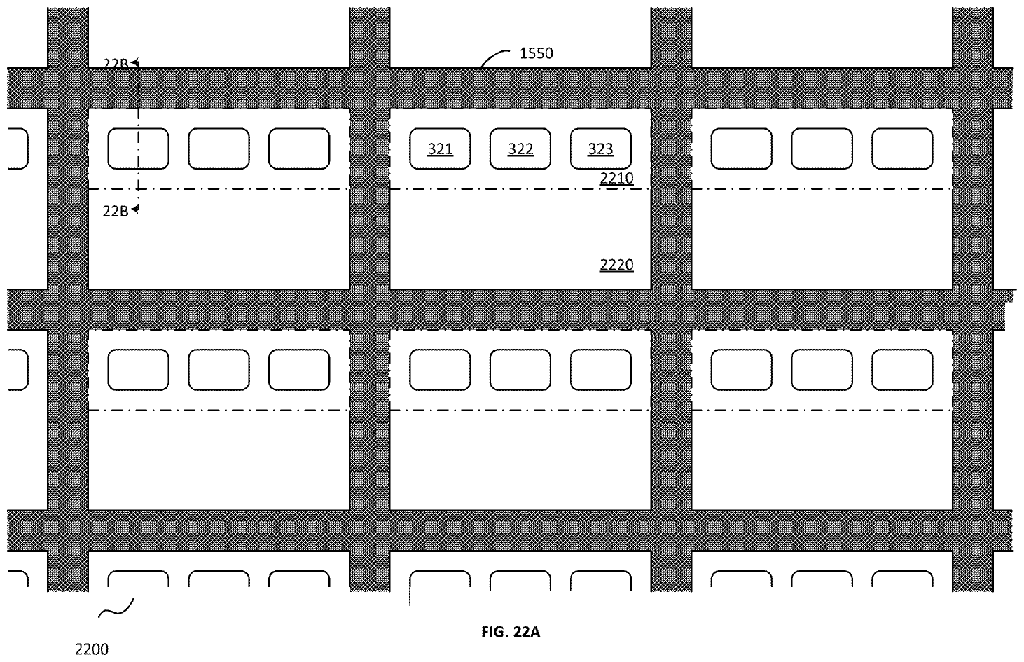

Turning now to FIG. 21, there may be shown an example version 2100 of the device 1000, which may encompass the device shown in cross-sectional view in FIG. 11, but with additional deposition steps that are described herein.

The device 2100 may show a patterning coating 110 deposited over the exposed layer surface 11 of the underlying material, in the figure, the second electrode 1040.

In some non-limiting examples, the patterning coating 110 may be deposited using an open mask and/or a mask-free deposition process.

The patterning coating 110 may provide an exposed layer surface 11 with a relatively low initial sticking probability against deposition of a deposited material 731 to be thereafter deposited as a deposited layer 130 to form an auxiliary electrode 1550.

After deposition of the patterning coating 110, an NPC 920 may be selectively deposited over the exposed layer surface 11 of the underlying layer, in the figure, the patterning coating 110, corresponding substantially to a part of the lateral aspect 1120 of non-emissive region(s) 1402, and surrounding a second portion 102 of the device 1700, corresponding substantially to the lateral aspect(s) 1110 of emissive region(s) 1401 corresponding to (sub-) pixel(s) 2210/32x.

In some non-limiting examples, the NPC 920 may be selectively deposited using a shadow mask 615.

The NPC 920 may provide, within the first portion 101, an exposed layer surface 11 with a relatively high initial sticking probability against deposition of a deposited material 731 to be thereafter deposited as a deposited layer 130 to form an auxiliary electrode 1550.

After selective deposition of the NPC 920, the deposited material 731 may be deposited over the device 2100 but may remain substantially where the patterning coating 110 has been overlaid with the NPC 920, to form the auxiliary electrode 1550.

In some non-limiting examples, the deposited layer 130 may be deposited using an open mask and/or a mask-free deposition process.

The auxiliary electrode 1550 may be electrically coupled with the second electrode 1040 to reduce a sheet resistance of the second electrode 1040.

### Transparent OLED

Because the OLED device 1000 may emit EM radiation through either, or both, of the first electrode 1020 (in the case of a bottom-emission, and/or a double-sided emission device), as well as the substrate 10, and/or the second electrode 1040 (in the case of a top-emission, and/or double-sided emission device), there may be an aim to make either, or both of, the first electrode 1020, and/or the second electrode 1040 substantially EM radiation- (or light)-transmissive (“transmissive”), in some non-limiting examples, at least across a substantial part of the lateral aspect of the emissive region(s) 1401 of the device 1000. In the present disclosure, such a transmissive element, including without limitation, an electrode 1020, 1040, a material from which such element may be formed, and/or property thereof, may comprise an element, material, and/or property thereof that is substantially transmissive (“transparent”), and/or, in some non-limiting examples, partially transmissive (“semi-transparent”), in some non-limiting examples, in at least one wavelength range.

A variety of mechanisms may be adopted to impart transmissive properties to the device 1000, at least across a substantial part of the lateral aspect of the emissive region(s) 1401 thereof.

In some non-limiting examples, including without limitation, where the device 1000 is a bottom-emission device, and/or a double-sided emission device, the TFT structure(s) 1101 of the driving circuit associated with an emissive region 1401 of a (sub-) pixel 2210/32x, which may at least partially reduce the transmissivity of the surrounding substrate 10, may be located within the lateral aspect 1120 of the surrounding non-emissive region(s) 1402 to avoid impacting the transmissive properties of the substrate 10 within the lateral aspect 1110 of the emissive region 1401.

In some non-limiting examples, where the device 1000 is a double-sided emission device, in respect of the lateral aspect 1110 of an emissive region 1401 of a (sub-) pixel 2210/32x, a first one of the electrodes 1020, 1040 may be made substantially transmissive, including without limitation, by at least one of the mechanisms disclosed herein, in respect of the lateral aspect 1110 of neighbouring, and/or adjacent (sub-) pixel(s) 2210/32x, a second one of the electrodes 1020, 1040 may be made substantially transmissive, including without limitation, by at least one of the mechanisms disclosed herein. Thus, the lateral aspect 1110 of a first emissive region 1401 of a (sub-) pixel 2210/32x may be made substantially top-emitting while the lateral aspect 1110 of a second emissive region 1401 of a neighbouring (sub-) pixel 2210/32x may be made substantially bottom-emitting, such that a subset of the (sub-) pixel(s) 2210/32x may be substantially top-emitting and a subset of the (sub-) pixel(s) 2210/32x may be substantially bottom-emitting, in an alternating (sub-) pixel 2210/32x sequence, while only a single electrode 1020, 1040 of each (sub-) pixel 2210/32x may be made substantially transmissive.

In some non-limiting examples, a mechanism to make an electrode 1020, 1040, in the case of a bottom-emission device, and/or a double-sided emission device, the first electrode 1020, and/or in the case of a top-emission device, and/or a double-sided emission device, the second electrode 1040, transmissive, may be to form such electrode 1020, 1040 of a transmissive thin film.

In some non-limiting examples, an electrically conductive deposited layer 130, in a thin film, including without limitation, those formed by a depositing a thin conductive film layer of a metal, including without limitation, Ag, Al, and/or by depositing a thin layer of a metallic alloy, including without limitation, an Mg:Ag alloy, and/or a Yb:Ag alloy, may exhibit transmissive characteristics. In some non-limiting examples, the alloy may comprise a composition ranging from between about 1:9-9:1 by volume. In some non-limiting examples, the electrode 1020, 1040 may be formed of a plurality of thin conductive film layers of any combination of deposited layers 130, any at least one of which may be comprised of TCOs, thin metal films, thin metallic alloy films, and/or any combination of any of these.

In some non-limiting examples, especially in the case of such thin conductive films, a relatively thin layer thickness may be up to substantially a few tens of nm to contribute to enhanced transmissive qualities but also favorable optical properties (including without limitation, reduced microcavity effects) for use in an OLED device 1000.

In some non-limiting examples, a reduction in the thickness of an electrode 1020, 1040 to promote transmissive qualities may be accompanied by an increase in the sheet resistance of the electrode 1020, 1040.

In some non-limiting examples, a device 1000 having at least one electrode 1020, 1040 with a high sheet resistance may create a large current resistance (IR) drop when coupled with the power source 1005, in operation. In some non-limiting examples, such an IR drop may be compensated for, to some extent, by increasing a level of the power source 1005. However, in some non-limiting examples, increasing the level of the power source 1005 to compensate for the IR drop due to high sheet resistance, for at least one (sub-) pixel 2210/32x may call for increasing the level of a voltage to be supplied to other components to maintain effective operation of the device 1000.

In some non-limiting examples, to reduce power supply demands for a device 1000 without significantly impacting an ability to make an electrode 1020, 1040 substantially transmissive (by employing at least one thin film layer of any combination of TCOs, thin metal films, and/or thin metallic alloy films), an auxiliary electrode 1550 may be formed on the device 1000 to allow current to be carried more effectively to various emissive region(s) 1401 of the device 1000, while at the same time, reducing the sheet resistance and its associated IR drop of the transmissive electrode 1020, 1040.

In some non-limiting examples, a sheet resistance specification, for a common electrode 1020, 1040 of a display device 1000, may vary according to several parameters, including without limitation, a (panel) size of the device 1000, and/or a tolerance for voltage variation across the device 1000. In some non-limiting examples, the sheet resistance specification may increase (that is, a lower sheet resistance is specified) as the panel size increases. In some non-limiting examples, the sheet resistance specification may increase as the tolerance for voltage variation decreases.

In some non-limiting examples, a sheet resistance specification may be used to derive an example thickness of an auxiliary electrode 1550 to comply with such specification for various panel sizes.

In some non-limiting examples, for a top-emission device, the second electrode 1040 may be made transmissive. On the other hand, in some non-limiting examples, such auxiliary electrode 1550 may not be substantially transmissive but may be electrically coupled with the second electrode 1040, including without limitation, by deposition of a conductive deposited layer 130 therebetween, to reduce an effective sheet resistance of the second electrode 1040.

In some non-limiting examples, such auxiliary electrode 1550 may be positioned, and/or shaped in either, or both of, a lateral aspect, and/or cross-sectional aspect to not interfere with the emission of photons from the lateral aspect of the emissive region 1401 of a (sub-) pixel 2210/32x.

In some non-limiting examples, a mechanism to make the first electrode 1020, and/or the second electrode 1040, may be to form such electrode 1020, 1040 in a pattern across at least a part of the lateral aspect of the emissive region(s) 1401 thereof, and/or in some non-limiting examples, across at least a part of the lateral aspect 1120 of the non-emissive region(s) 1402 surrounding them. In some non-limiting examples, such mechanism may be employed to form the auxiliary electrode 1550 in a position, and/or shape in either, or both of, a lateral aspect, and/or cross-sectional aspect to not interfere with the emission of photons from the lateral aspect 1110 of the emissive region 1401 of a (sub-) pixel 2210/32x, as discussed above.

In some non-limiting examples, the device 1000 may be configured such that it may be substantially devoid of a conductive oxide material in an optical path of EM radiation emitted by the device 1000. In some non-limiting examples, in the lateral aspect 1110 of at least one emissive region 1401 corresponding to a (sub-) pixel 2210/32x, at least one of the layers, and/or coatings deposited after the at least one semiconducting layer 1030, including without limitation, the second electrode 1040, the patterning coating 110, and/or any other layers, and/or coatings deposited thereon, may be substantially devoid of any conductive oxide material. In some non-limiting examples, being substantially devoid of any conductive oxide material may reduce absorption, and/or reflection of EM radiation emitted by the device 1000. In some non-limiting examples, conductive oxide materials, including without limitation, ITO, and/or IZO, may absorb EM radiation in at least the B(lue) region of the visible spectrum, which may, in generally, reduce efficiency, and/or performance of the device 1000.

In some non-limiting examples, a combination of these, and/or other mechanisms may be employed.

Additionally, in some non-limiting examples, in addition to rendering at least one of the first electrode 1020, the second electrode 1040, and/or the auxiliary electrode 1550, substantially transmissive across at least across a substantial part of the lateral aspect 1110 of the emissive region 1401 corresponding to the (sub-) pixel(s) 2210/32x of the device 1000, to allow EM radiation to be emitted substantially across the lateral aspect 1110 thereof, there may be an aim to make at least one of the lateral aspect(s) 1120 of the surrounding non-emissive region(s) 1402 of the device 1000 substantially transmissive in both the bottom and top directions, to render the device 1000 substantially transmissive relative to EM radiation incident on an external surface thereof, such that a substantial part of such externally-incident EM radiation may be transmitted through the device 1000, in addition to the emission (in a top-emission, bottom-emission, and/or double-sided emission) of EM radiation generated internally within the device 1000 as disclosed herein.

Turning now to FIG. 22A, there may be shown an example view in plan of a transmissive (transparent) version, shown generally at 2200, of the device 1000. In some non-limiting examples, the device 2200 may be an active matrix OLED (AMOLED) device having a plurality of pixels or pixel regions 2210 and a plurality of transmissive regions 31x. In some non-limiting examples, at least one auxiliary electrode 1550 may be deposited on an exposed layer surface 11 of an underlying layer between the pixel region(s) 2210, and/or the transmissive region(s) 31x.

In some non-limiting examples, each pixel region 2210 may comprise a plurality of emissive regions 1401 each corresponding to a (sub-) pixel 2210/32x. In some non-limiting examples, the (sub-) pixels 2210/32x may correspond to, respectively, R(ed) sub-pixels 321, G(reen) sub-pixels 322, and/or B(lue) sub-pixels 323.

In some non-limiting examples, each transmissive region 31x may be substantially transparent and allows EM radiation to pass through the entirety of a cross-sectional aspect thereof.

Turning now to FIG. 22B, there may be shown an example cross-sectional view of a version 2200 of the device 1000, taken along line 22B-22B in FIG. 22A. In the figure, the device 2200 may be shown as comprising a substrate 10, a TFT insulating layer 1109 and a first electrode 1020 formed on a surface of the TFT insulating layer 1109. In some non-limiting examples, the substrate 10 may comprise the base substrate 1012 (not shown for purposes of simplicity of illustration), and/or at least one TFT structure 1101, corresponding to, and for driving, each (sub-) pixel 2210/32x positioned substantially thereunder and electrically coupled with the first electrode 1020 thereof. In some non-limiting examples, PDL(s) 1140 may be formed in non-emissive regions 1402 over the substrate 10, to define emissive region(s) 1401 also corresponding to each (sub-) pixel 2210/32x, over the first electrode 1020 corresponding thereto. In some non-limiting examples, the PDL(s) 1140 may cover edges of the first electrode 1020.

In some non-limiting examples, at least one semiconducting layer 1030 may be deposited over exposed region(s) of the first electrode 1020 and, in some non-limiting examples, at least parts of the surrounding PDLs 1140.

In some non-limiting examples, a second electrode 1040 may be deposited over the at least one semiconducting layer(s) 1030, including over the pixel region 2210 to form the sub-pixel(s) 32x thereof and, in some non-limiting examples, at least partially over the surrounding PDLs 1140 in the transmissive region 31x.

In some non-limiting examples, a patterning coating 110 may be selectively deposited over first portion(s) 101 of the device 2200, comprising both the pixel region 2210 and the transmissive region 31x but not the region of the second electrode 1040 corresponding to the auxiliary electrode 1550 comprising second portion(s) 102 thereof.

In some non-limiting examples, the entire exposed layer surface 11 of the device 2200 may then be exposed to a vapor flux 732 of the deposited material 731, which in some non-limiting examples may be Mg. The deposited layer 130 may be selectively deposited over second portion(s) 102 of the second electrode 1040 that may be substantially devoid of the patterning coating 110 to form an auxiliary electrode 1550 that may be electrically coupled with and in some non-limiting examples, in physical contact with uncoated parts of the second electrode 1040.

At the same time, the transmissive region 31x of the device 2200 may remain substantially devoid of any materials that may substantially affect the transmission of EM radiation therethrough. In particular, as shown in the figure, the TFT structure 1101 and the first electrode 1020 may be positioned, in a cross-sectional aspect, below the (sub-) pixel 2210/32x corresponding thereto, and together with the auxiliary electrode 1550, may lie beyond the transmissive region 31x. As a result, these components may not attenuate or impede light from being transmitted through the transmissive region 31x. In some non-limiting examples, such arrangement may allow a viewer viewing the device 2200 from a typical viewing distance to see through the device 2200, in some non-limiting examples, when all the (sub-) pixel(s) 2210/32x may not be emitting, thus creating a transparent device 2200.

While not shown in the figure, in some non-limiting examples, the device 2200 may further comprise an NPC 920 disposed between the auxiliary electrode 1550 and the second electrode 1040. In some non-limiting examples, the NPC 920 may also be disposed between the patterning coating 110 and the second electrode 1040.

In some non-limiting examples, the patterning coating 110 may be formed concurrently with the at least one semiconducting layer(s) 1030. In some non-limiting examples, at least one material used to form the patterning coating 110 may also be used to form the at least one semiconducting layer(s) 1030. In such non-limiting example, several stages for fabricating the device 2200 may be reduced.

Those having ordinary skill in the relevant art will appreciate that in some non-limiting examples, various other layers, and/or coatings, including without limitation those forming the at least one semiconducting layer(s) 1030, and/or the second electrode 1040, may cover a part of the transmissive region 31x, especially if such layers, and/or coatings are substantially transparent. In some non-limiting examples, the PDL(s) 1140 may have a reduced thickness, including without limitation, by forming a well therein, which in some non-limiting examples may be similar to the well defined for emissive region(s) 1401, to further facilitate transmission of EM radiation through the transmissive region 31x.

Those having ordinary skill in the relevant art will appreciate that (sub-) pixel(s) 2210/32x arrangements other than the arrangement shown in FIGS. 22A and 22B may, in some non-limiting examples, be employed.

Those having ordinary skill in the relevant art will appreciate that arrangements of the auxiliary electrode(s) 1550 other than the arrangement shown in FIGS. 22A and 22B may, in some non-limiting examples, be employed. In some non-limiting examples, the auxiliary electrode(s) 1550 may be disposed between the pixel region 2210 and the transmissive region 31x. In some non-limiting examples, the auxiliary electrode(s) 1150 may be disposed between sub-pixel(s) 32x within a pixel region 2210.

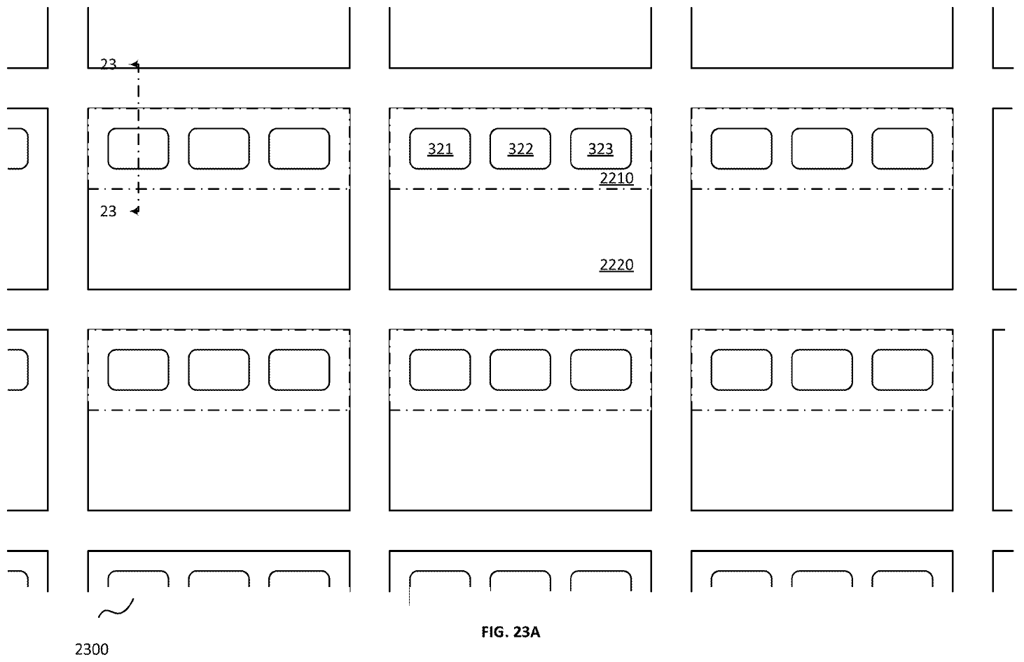

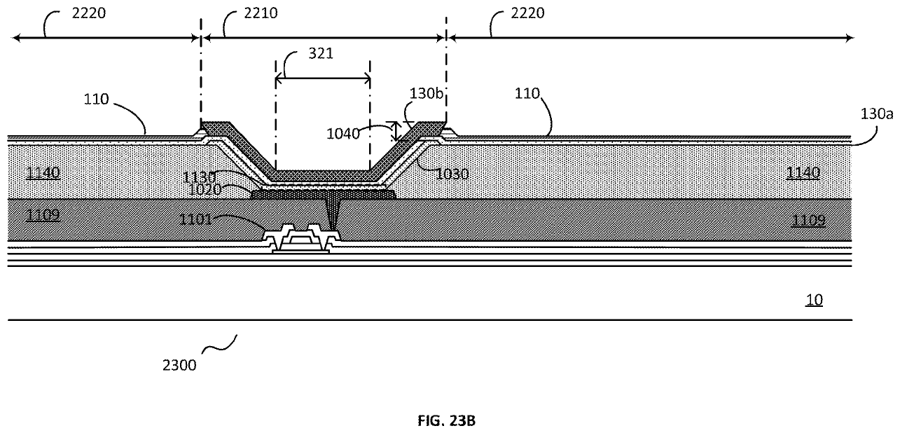

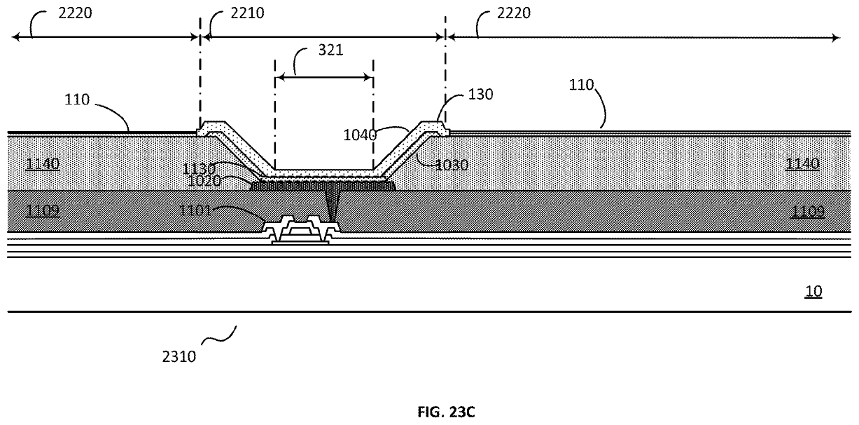

Turning now to FIG. 23A, there may be shown an example plan view of a transparent version, shown generally at 2300, of the device 1000. In some non-limiting examples, the device 2300 may be an AMOLED device having a plurality of pixel regions 2210 and a plurality of transmissive regions 31x. The device 2300 may differ from device 2200 in that no auxiliary electrode(s) 1150 lie between the pixel region(s) 2210, and/or the transmissive region(s) 31x.

In some non-limiting examples, each pixel region 2210 may comprise a plurality of emissive regions 1401, each corresponding to a sub-pixel 32x. In some non-limiting examples, the (sub-) pixels 2210/32x may correspond to, respectively, R(ed) sub-pixels 321, G(reen) sub-pixels 322, and/or B(lue) sub-pixels 323.

In some non-limiting examples, each transmissive region 31x may be substantially transparent and may allow light to pass through the entirety of a cross-sectional aspect thereof.

Turning now to FIG. 23B, there may be shown an example cross-sectional view of the device 2300, taken along line 23-23 in FIG. 23A. In the figure, the device 2300 may be shown as comprising a substrate 10, a TFT insulating layer 1109 and a first electrode 1020 formed on a surface of the TFT insulating layer 1109. The substrate 10 may comprise the base substrate 1012 (not shown for purposes of simplicity of illustration), and/or at least one TFT structure 1101 corresponding to, and for driving, each (sub-) pixel 2210/32x positioned substantially thereunder and electrically coupled with the first electrode 1020 thereof. PDL(s) 1140 may be formed in non-emissive regions 1402 over the substrate 10, to define emissive region(s) 1401 also corresponding to each (sub-) pixel 2210/32x, over the first electrode 1020 corresponding thereto. The PDL(s) 1140 cover edges of the first electrode 1020.

In some non-limiting examples, at least one semiconducting layer 1030 may be deposited over exposed region(s) of the first electrode 1020 and, in some non-limiting examples, at least parts of the surrounding PDLs 1140.

In some non-limiting examples, a first deposited layer 130a may be deposited over the at least one semiconducting layer(s) 1030, including over the pixel region 2210 to form the sub-pixel(s) 32x thereof and over the surrounding PDLs 1140 in the transmissive region 31x. In some non-limiting examples, the average layer thickness of the first deposited layer 130a may be relatively thin such that the presence of the first deposited layer 130a across the transmissive region 31x does not substantially attenuate transmission of EM radiation therethrough. In some non-limiting examples, the first deposited layer 130a may be deposited using an open mask and/or mask-free deposition process.

In some non-limiting examples, a patterning coating 110 may be selectively deposited over first portions 101 of the device 2300, comprising the transmissive region 31x.

In some non-limiting examples, the entire exposed layer surface 11 of the device 2300 may then be exposed to a vapor flux 732 of the deposited material 731, which in some non-limiting examples may be Mg, to selectively deposit a second deposited layer 130b, over second portion(s) 102 of the first deposited layer 130a that may be substantially devoid of the patterning coating 110, in some examples, the pixel region 2210, such that the second deposited layer 130b may be electrically coupled with and in some non-limiting examples, in physical contact with uncoated parts of the first deposited layer 130a, to form the second electrode 1040.

In some non-limiting examples, an average layer thickness of the first deposited layer 130a may be no more than an average layer thickness of the second deposited layer 130b. In this way, relatively high transmittance may be maintained in the transmissive region 31x, over which only the first deposited layer 130a may extend. In some non-limiting examples, an average layer thickness of the first deposited layer 130a may be one of no more than about: 30 nm, 25 nm, 20 nm, 15 nm, 10 nm, 8 nm, and 5 nm. In some non-limiting examples, an average layer thickness of the second deposited layer 130b may be one of no more than about: 30 nm, 25 nm, 20 nm, 15 nm, 10 nm, and 8 nm.

Thus, in some non-limiting examples, an average layer thickness of the second electrode 1040 may be no more than about 40 nm, and/or in some non-limiting examples, one of between about: 5-30 nm, 10-25 nm, and 15-25 nm.

In some non-limiting examples, the average layer thickness of the first deposited layer 130a may exceed the average layer thickness of the second deposited layer 130b. In some non-limiting examples, the average layer thickness of the first deposited layer 130a and the average layer thickness of the second deposited layer 130b may be substantially the same.

In some non-limiting examples, at least one deposited material 731 used to form the first deposited layer 130a may be substantially the same as at least one deposited material 731 used to form the second deposited layer 130b. In some non-limiting examples, such at least one deposited material 731 may be substantially as described herein in respect of the first electrode 1020, the second electrode 1040, the auxiliary electrode 1550, and/or a deposited layer 130 thereof.

In some non-limiting examples, the first deposited layer 130a may provide, at least in part, the functionality of an EIL 1039, in the pixel region 2210. Non-limiting examples, of the deposited material 731 for forming the first deposited layer 130a include Yb, which for example, may be about 1-3 nm in thickness.

In some non-limiting examples, the transmissive region 31x of the device 2300 may remain substantially devoid of any materials that may substantially inhibit the transmission of EM radiation, including without limitation, EM signals, including without limitation, in the IR spectrum and/or NIR spectrum, therethrough. In particular, as shown in the figure, the TFT structure 1109, and/or the first electrode 1020 may be positioned, in a cross-sectional aspect below the (sub-) pixel 2210/32x corresponding thereto and beyond the transmissive region 31x. As a result, these components may not attenuate or impede EM radiation from being transmitted through the transmissive region 31x. In some non-limiting examples, such arrangement may allow a viewer viewing the device 2300 from a typical viewing distance to see through the device 2300, in some non-limiting examples, when the (sub-) pixel(s) 2210/32x are not emitting, thus creating a transparent AMOLED device 2300.

In some non-limiting examples, such arrangement may also allow an IR emitter and/or an IR detector to be arranged behind the AMOLED device 2300 such that EM signals, including without limitation, in the IR and/or NIR spectrum, to be exchanged through the AMOLED device 2300 by such under-display components 230.

While not shown in the figure, in some non-limiting examples, the device 2300 may further comprise an NPC 920 disposed between the second deposited layer 130b and the first deposited layer 130a. In some non-limiting examples, the NPC 920 may also be disposed between the patterning coating 110 and the first deposited layer 130a.

In some non-limiting examples, the patterning coating 110 may be formed concurrently with the at least one semiconducting layer(s) 1030. In some non-limiting examples, at least one material used to form the patterning coating 110 may also be used to form the at least one semiconducting layer(s) 1030. In such non-limiting example, several stages for fabricating the device 2300 may be reduced.

Those having ordinary skill in the relevant art will appreciate that in some non-limiting examples, various other layers, and/or coatings, including without limitation those forming the at least one semiconducting layer(s) 1030, and/or the first deposited layer 130a, may cover a part of the transmissive region 31x, especially if such layers, and/or coatings are substantially transparent. In some non-limiting examples, the PDL(s) 1140 may have a reduced thickness, including without limitation, by forming a well therein, which in some non-limiting examples may be similar to the well defined for emissive region(s) 1401, to further facilitate transmission of EM radiation through the transmissive region 31x.

Those having ordinary skill in the relevant art will appreciate that (sub-) pixel(s) 2210/32x arrangements other than the arrangement shown in FIGS. 23A and 23B may, in some non-limiting examples, be employed.

Turning now to FIG. 23C, there may be shown an example cross-sectional view of a different version 2310 of the device 1000, taken along the same line 23-23 in FIG. 23A. In the figure, the device 2310 may be shown as comprising a substrate 10, a TFT insulating layer 1109 and a first electrode 1020 formed on a surface of the TFT insulating layer 1109. The substrate 10 may comprise the base substrate 1012 (not shown for purposes of simplicity of illustration), and/or at least one TFT structure 1101 corresponding to and for driving each (sub-) pixel 2210/32x positioned substantially thereunder and electrically coupled with the first electrode 1020 thereof. PDL(s) 1140 may be formed in non-emissive regions 1402 over the substrate 10, to define emissive region(s) 1401 also corresponding to each (sub-) pixel 2210/32x, over the first electrode 1020 corresponding thereto. The PDL(s) 1140 may cover edges of the first electrode 1020.

In some non-limiting examples, at least one semiconducting layer 1030 may be deposited over exposed region(s) of the first electrode 1020 and, in some non-limiting examples, at least parts of the surrounding PDLs 1140.

In some non-limiting examples, a patterning coating 110 may be selectively deposited over first portions 101 of the device 2310, comprising the transmissive region 31x.

In some non-limiting examples, a deposited layer 130 may be deposited over the at least one semiconducting layer(s) 1030, including over the pixel region 2210 to form the sub-pixel(s) 32x thereof but not over the surrounding PDLs 1140 in the transmissive region 31x. In some non-limiting examples, the first deposited layer 130a may be deposited using an open mask and/or mask-free deposition process. In some non-limiting examples, such deposition may be effected by exposing the entire exposed layer surface 11 of the device 2310 to a vapor flux 732 of the deposited material 731, which in some non-limiting examples may be Mg, to selectively deposit the deposited layer 130 over second portions 102 of the at least one semiconducting layer(s) 1030 that are substantially devoid of the patterning coating 110, in some non-limiting examples, the pixel region 2210, such that the deposited layer 130 may be deposited on the at least one semiconducting layer(s) 1030 to form the second electrode 1040.

In some non-limiting examples, the transmissive region 31x of the device 2310 may remain substantially devoid of any materials that may substantially affect the transmission of EM radiation therethrough, including without limitation, EM signals, including without limitation, in the IR and/or NIR spectrum. In particular, as shown in the figure, the TFT structure 1101, and/or the first electrode 1020 may be positioned, in a cross-sectional aspect below the (sub-) pixel 2210/32x corresponding thereto and beyond the transmissive region 31x. As a result, these components may not attenuate or impede EM radiation from being transmitted through the transmissive region 31x. In some non-limiting examples, such arrangement may allow a viewer viewing the device 2310 from a typical viewing distance to see through the device 2310, in some non-limiting examples, when the (sub-) pixel(s) 2210/32x are not emitting, thus creating a transparent AMOLED device 2310.

By providing a transmissive region 31x that may be free, and/or substantially devoid of any deposited layer 130, the transmittance in such region 31x may, in some non-limiting examples, be favorably enhanced, in some non-limiting examples, by comparison to the device 2300 of FIG. 23B.

While not shown in the figure, in some non-limiting examples, the device 2310 may further comprise an NPC 920 disposed between the deposited layer 130 and the at least one semiconducting layer(s) 1030. In some non-limiting examples, the NPC 920 may also be disposed between the patterning coating 110 and the PDL(s) 1140.

While not shown in FIGS. 23B and 23C for sake of simplicity, those having ordinary skill in the relevant art will appreciate that in some non-limiting examples, at least one particle structures 841 may be disposed thereon, to facilitate absorption of EM radiation in the transmissive region 31x in at least a part of the visible spectrum, while allowing EM signals having a wavelength in at least a part of the IR and/or NIR spectrum to be exchanged through the device in the transmissive region 31x.

In some non-limiting examples, the patterning coating 110 may be formed concurrently with the at least one semiconducting layer(s) 1030. In some non-limiting examples, at least one material used to form the patterning coating 110 may also be used to form the at least one semiconducting layer(s) 1030. In such non-limiting example, several stages for fabricating the device 2310 may be reduced.

In some non-limiting examples, at least one layer of the at least one semiconducting layer 1030 may be deposited in the transmissive region 31x to provide the pattering coating 110. In some non-limiting examples, the ETL 1037 of the at least one semiconducting layer 1030 may be a patterning coating 110 that may be deposited in both the emissive region 1401 and the transmissive region 31x during the deposition of the at least one semiconducting layer 1030. The EIL 1039 may then be selectively deposited in the emissive region 1401 over the ETL 1037, such that the exposed layer surface 11 of the ETL 1037 in the transmissive region 31x may be substantially devoid of the EIL 1039. The exposed layer surface 11 of the EIL 1039 in the emissive region 1401 and the exposed layer surface of the ETL 1037, which acts as the patterning coating 110, may then be exposed to a vapor flux 732 of the deposited material 731 to form a closed coating 140 of the deposited layer 130 on the EIL 1039 in the emissive region 1401, and a discontinuous layer 840 of the deposited material 731 on the EIL 1039 in the transmissive region 31x.

Those having ordinary skill in the relevant art will appreciate that in some non-limiting examples, various other layers, and/or coatings, including without limitation those forming the at least one semiconducting layer(s) 1030, and/or the deposited layer 130, may cover a part of the transmissive region 31x, especially if such layers, and/or coatings are substantially transparent. In some non-limiting examples, the PDL(s) 1140 may have a reduced thickness, including without limitation, by forming a well therein, which in some non-limiting examples may be similar to the well defined for emissive region(s) 1401, to further facilitate transmission of EM radiation through the transmissive region 31x.

Those having ordinary skill in the relevant art will appreciate that (sub-) pixel(s) 2210/32x arrangements other than the arrangement shown in FIGS. 23A and 23C may, in some non-limiting examples, be employed.

Selective Deposition to Modulate Electrode Thickness over Emissive Region(s)

As discussed above, modulating the thickness of an electrode 1020, 1040, 1550 in and across a lateral aspect 1110 of emissive region(s) 1401 of a (sub-) pixel 2210/32x may impact the microcavity effect observable. In some non-limiting examples, selective deposition of at least one deposited layer 130 through deposition of at least one patterning coating 110, including without limitation, an NIC and/or an NPC 920, in the lateral aspects 1110 of emissive region(s) 1401 corresponding to different sub-pixel(s) 32x in a pixel region 2210 may allow the optical microcavity effect in each emissive region 1401 to be controlled, and/or modulated to optimize desirable optical microcavity effects on a (sub-) pixel 2210/32x basis, including without limitation, an emission spectrum, a luminous intensity, and/or an angular dependence of a brightness, and/or a color shift of emitted light.

Such effects may be controlled by independently modulating an average layer thickness and/or a number of the deposited layer(s) 130, disposed in each emissive region 1401 of the sub-pixel(s) 32x. In some non-limiting examples, the average layer thickness of a second electrode 1040 disposed over a B(lue) sub-pixel 323 may be less than the average layer thickness of a second electrode 1040 disposed over a G(reen) sub-pixel 322, and the average layer thickness of a second electrode 1040 disposed over a G(reen) sub-pixel 322 may be less than the average layer thickness of a second electrode 1040 disposed over a R(ed) sub-pixel 321.

In some non-limiting examples, such effects may be controlled to an even greater extent by independently modulating the average layer thickness and/or a number of the deposited layers 130, but also of the patterning coating 110 and/or an NPC 920, deposited in part(s) of each emissive region 1401 of the sub-pixel(s) 32x.

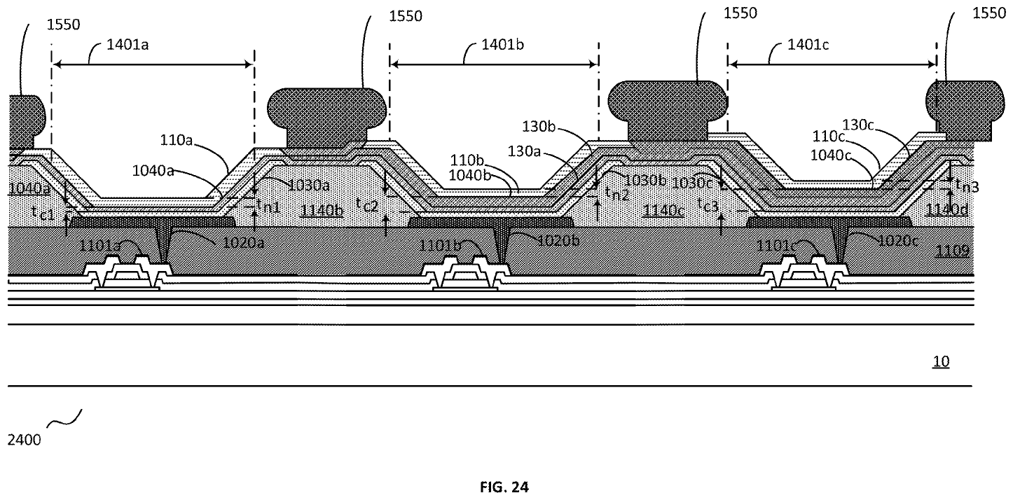

As shown in some non-limiting examples in FIG. 24, there may be deposited layer(s) 130 of varying average layer thickness selectively deposited for emissive region(s) 1401 corresponding to sub-pixel(s) 32x, in some non-limiting examples, in a version 2400 of an OLED display device 1000, having different emission spectra. In some non-limiting examples, a first emissive region 1401a may correspond to a (sub-) pixel 2210/32x configured to emit EM radiation of a first wavelength, and/or emission spectrum, and/or in some non-limiting examples, a second emissive region 1401b may correspond to a (sub-) pixel 2210/32x configured to emit EM radiation of a second wavelength, and/or emission spectrum. In some non-limiting examples, a device 2400 may comprise a third emissive region 1401c that may correspond to a (sub-) pixel 2210/32x configured to emit EM radiation of a third wavelength, and/or emission spectrum.

In some non-limiting examples, the first wavelength may be less than, greater than, and/or equal to at least one of the second wavelength, and/or the third wavelength. In some non-limiting examples, the second wavelength may be less than, greater than, and/or equal to at least one of the first wavelength, and/or the third wavelength. In some non-limiting examples, the third wavelength may be less than, greater than, and/or equal to at least one of the first wavelength, and/or the second wavelength.

In some non-limiting examples, the device 2400 may also comprise at least one additional emissive region 1401 (not shown) that may in some non-limiting examples be configured to emit EM radiation having a wavelength, and/or emission spectrum that is substantially identical to at least one of the first emissive region 1401a, the second emissive region 1401b, and/or the third emissive region 1401c.

In some non-limiting examples, the patterning coating 110 may be selectively deposited using a shadow mask 615 that may also have been used to deposit the at least one semiconducting layer 1030 of the first emissive region 1401a. In some non-limiting examples, such shared use of a shadow mask 615 may allow the optical microcavity effect(s) to be tuned for each (sub-) pixel 2210/32x in a cost-effective manner.

The device 2400 may be shown as comprising a substrate 10, a TFT insulating layer 1109 and a plurality of first electrodes 1020, formed on an exposed layer surface 11 of the TFT insulating layer 1109.

In some non-limiting examples, the substrate 10 may comprise the base substrate 1012 (not shown for purposes of simplicity of illustration), and/or at least one TFT structure 1101 corresponding to, and for driving, a corresponding emissive region 1401, each having a corresponding (sub-) pixel 2210/32x, positioned substantially thereunder and electrically coupled with its associated first electrode 1020. PDL(s) 1140 may be formed over the substrate 10, to define emissive region(s) 1401. In some non-limiting examples, the PDL(s) 1140 may cover edges of their respective first electrode 1020.

In some non-limiting examples, at least one semiconducting layer 1030 may be deposited over exposed region(s) of their respective first electrode 1020 and, in some non-limiting examples, at least parts of the surrounding PDLs 1140.

In some non-limiting examples, a first deposited layer 130a may be deposited over the at least one semiconducting layer(s) 1030. In some non-limiting examples, the first deposited layer 130a may be deposited using an open mask and/or mask-free deposition process. In some non-limiting examples, such deposition may be effected by exposing the entire exposed layer surface 11 of the device 2400 to a vapor flux 732 of deposited material 731, which in some non-limiting examples may be Mg, to deposit the first deposited layer 130a over the at least one semiconducting layer(s) 1030 to form a first layer of the second electrode 1040a (not shown), which in some non-limiting examples may be a common electrode, at least for the first emissive region 1401a. Such common electrode may have a first thickness t_{c1} in the first emissive region 1401a. In some non-limiting examples, the first thickness t_{c1} may correspond to a thickness of the first deposited layer 130a.

In some non-limiting examples, a first pattering coating 110a may be selectively deposited over first portions 101 of the device 2400, comprising the first emissive region 1401a.

In some non-limiting examples, a second deposited layer 130b may be deposited over the device 2400. In some non-limiting examples, the second deposited layer 130b may be deposited using an open mask and/or mask-free deposition process. In some non-limiting examples, such deposition may be effected by exposing the entire exposed layer surface 11 of the device 2400 to a vapor flux 732 of deposited material 731, which in some non-limiting examples may be Mg, to deposit the second deposited layer 130b over the first deposited layer 130a that may be substantially devoid of the first patterning coating 110a, in some examples, the second and third emissive regions 1401b, 1401c, and/or at least part(s) of the non-emissive region(s) 1402 in which the PDLs 1140 lie, such that the second deposited layer 130b may be deposited on the second portion(s) 102 of the first deposited layer 130a that are substantially devoid of the first patterning coating 110a to form a second layer of the second electrode 1040b (not shown), which in some non-limiting examples, may be a common electrode, at least for the second emissive region 1401b. In some non-limiting examples, such common electrode may have a second thickness t_{c2} in the second emissive region 1401b. In some non-limiting examples, the second thickness t_{c2} may correspond to a combined average layer thickness of the first deposited layer 130a and of the second deposited layer 130b and may in some non-limiting examples exceed the first thickness ta.

In some non-limiting examples, a second patterning coating 110b may be selectively deposited over further first portions 101 of the device 2400, comprising the second emissive region 1401b.

In some non-limiting examples, a third deposited layer 130c may be deposited over the device 2400. In some non-limiting examples, the third deposited layer 130c may be deposited using an open mask and/or mask-free deposition process. In some non-limiting examples, such deposition may be effected by exposing the entire exposed layer surface 11 of the device 2400 to a vapor flux 732 of deposited material 731, which in some non-limiting examples may be Mg, to deposit the third deposited layer 130c over the second deposited layer 130b that may be substantially devoid of either the first patterning coating 110a or the second pattering coating 110b, in some examples, the third emissive region 1401c, and/or at least part(s) of the non-emissive region 1402 in which the PDLs 1140 lie, such that the third deposited layer 130c may be deposited on the further second portion(s) 102 of the second deposited layer 130b that are substantially devoid of the second patterning coating 110b to form a third layer of the second electrode 1040c (not shown), which in some non-limiting examples, may be a common electrode, at least for the third emissive region 1401c. In some non-limiting examples, such common electrode may have a third thickness t_{c3} in the third emissive region 1401c. In some non-limiting examples, the third thickness t_{c3} may correspond to a combined thickness of the first deposited layer 130a, the second deposited layer 130b and the third deposited layer 130c and may in some non-limiting examples exceed either, or both of, the first thickness t_{c1} and the second thickness t_{c2}.

In some non-limiting examples, a third patterning coating 110c may be selectively deposited over additional first portions 101 of the device 2400, comprising the third emissive region 1401c.

In some non-limiting examples, at least one auxiliary electrode 1550 may be disposed in the non-emissive region(s) 1402 of the device 2400 between neighbouring emissive regions 1401 thereof and in some non-limiting examples, over the PDLs 1140. In some non-limiting examples, the deposited layer 130 used to deposit the at least one auxiliary electrode 1550 may be deposited using an open mask and/or mask-free deposition process. In some non-limiting examples, such deposition may be effected by exposing the entire exposed layer surface 11 of the device 2400 to a vapor flux 732 of deposited material 731, which in some non-limiting examples may be Mg, to deposit the deposited layer 130 over the exposed parts of the first deposited layer 130a, the second deposited layer 130b and the third deposited layer 130c that may be substantially devoid of any of the first patterning coating 110a the second pattering coating 110b, and/or the third patterning coating 110c, such that the deposited layer 130 may be deposited on an additional second portion 102 comprising the exposed part(s) of the first deposited layer 130a, the second deposited layer 130b, and/or the third deposited layer 130c that may be substantially devoid of any of the first patterning coating 110a, the second patterning coating 110b, and/or the third patterning coating 110c to form the at least one auxiliary electrode 1550. In some non-limiting examples, each of the at least one auxiliary electrode 1550 may be electrically coupled with a respective one of the second electrodes 1040. In some non-limiting examples, each of the at least one auxiliary electrode 1550 may be in physical contact with such second electrode 1040.

In some non-limiting examples, the first emissive region 1401a, the second emissive region 1401b and the third emissive region 1401c may be substantially devoid of a closed coating 140 of the deposited material 731 used to form the at least one auxiliary electrode 1550.

In some non-limiting examples, at least one of the first deposited layer 130a, the second deposited layer 130b, and/or the third deposited layer 130c may be transmissive, and/or substantially transparent in at least a part of the visible spectrum. Thus, in some non-limiting examples, the second deposited layer 130b, and/or the third deposited layer 130a (and/or any additional deposited layer(s) 130) may be disposed on top of the first deposited layer 130a to form a multi-coating electrode 1020, 1040, 1550 that may also be transmissive, and/or substantially transparent in at least a part of the visible spectrum. In some non-limiting examples, the transmittance of any of the at least one of the first deposited layer 130a, the second deposited layer 130b, the third deposited layer 130c, any additional deposited layer(s) 130, and/or the multi-coating electrode 1020, 1040, 1550 may exceed one of about: 30%, 40% 45%, 50%, 60%, 70%, 75%, and 80% in at least a part of the visible spectrum.

In some non-limiting examples, an average layer thickness of the first deposited layer 130a, the second deposited layer 130b, and/or the third deposited layer 130c may be made relatively thin to maintain a relatively high transmittance. In some non-limiting examples, an average layer thickness of the first deposited layer 130a may be one of between about: 5-30 nm, 8-25 nm, and 10-20 nm. In some non-limiting examples, an average layer thickness of the second deposited layer 130b may be one of between about: 1-25 nm, 1-20 nm, 1-15 nm, 1-10 nm, and 3-6 nm. In some non-limiting examples, an average layer thickness of the third deposited layer 130c may be one of between about: 1-25 nm, 1-20 nm, 1-15 nm, 1-10 nm, and 3-6 nm. In some non-limiting examples, a thickness of a multi-coating electrode formed by a combination of the first deposited layer 130a, the second deposited layer 130b, the third deposited layer 130c, and/or any additional deposited layer(s) 130 may be one of between about: 6-35 nm, 10-30 nm, 10-25 nm, and 12-18 nm.

In some non-limiting examples, a thickness of the at least one auxiliary electrode 1550 may exceed an average layer thickness of the first deposited layer 130a, the second deposited layer 130b, the third deposited layer 130c, and/or a common electrode. In some non-limiting examples, the thickness of the at least one auxiliary electrode 1550 may exceed one of about: 50 nm, 80 nm, 100 nm, 150 nm, 200 nm, 300 nm, 400 nm, 500 nm, 700 nm, 800 nm, 1 μm, 1.2 μm, 1.5 μm, 2 μm, 2.5 μm, and 3 μm.

In some non-limiting examples, the at least one auxiliary electrode 1550 may be substantially non-transparent, and/or opaque. However, since the at least one auxiliary electrode 1550 may be, in some non-limiting examples, provided in a non-emissive region 1402 of the device 2400, the at least one auxiliary electrode 1550 may not cause or contribute to significant optical interference. In some non-limiting examples, the transmittance of the at least one auxiliary electrode 1550 may be one of no more than about: 50%, 70%, 80%, 85%, 90%, and 95% in at least a part of the visible spectrum.

In some non-limiting examples, the at least one auxiliary electrode 1550 may absorb EM radiation in at least a part of the visible spectrum.

In some non-limiting examples, an average layer thickness of the first patterning coating 110a, the second patterning coating 110b, and/or the third patterning coating 110c disposed in the first emissive region 1401a, the second emissive region 1401b, and/or the third emissive region 1401c respectively, may be varied according to a colour, and/or emission spectrum of EM radiation emitted by each emissive region 1401. In some non-limiting examples, the first patterning coating 110a may have a first patterning coating thickness tₙ₁, the second patterning coating 110b may have a second patterning coating thickness tₙ₂, and/or the third patterning coating 110c may have a third patterning coating thickness tₙ₃. In some non-limiting examples, the first patterning coating thickness tₙ₁, the second patterning coating thickness tₙ₂, and/or the third patterning coating thickness tₙ₃, may be substantially the same. In some non-limiting examples, the first patterning coating thickness tₙ₁, the second patterning coating thickness tₙ₂, and/or the third patterning coating thickness tₙ₃, may be different from one another.

In some non-limiting examples, the device 2400 may also comprise any number of emissive regions 1401a-1401c, and/or (sub-) pixel(s) 2210/32x thereof. In some non-limiting examples, a device may comprise a plurality of pixels 2210, wherein each pixel 2210 comprises two, three or more sub-pixel(s) 32x.

### Conductive Coating for Electrically Coupling an Electrode to an Auxiliary Electrode

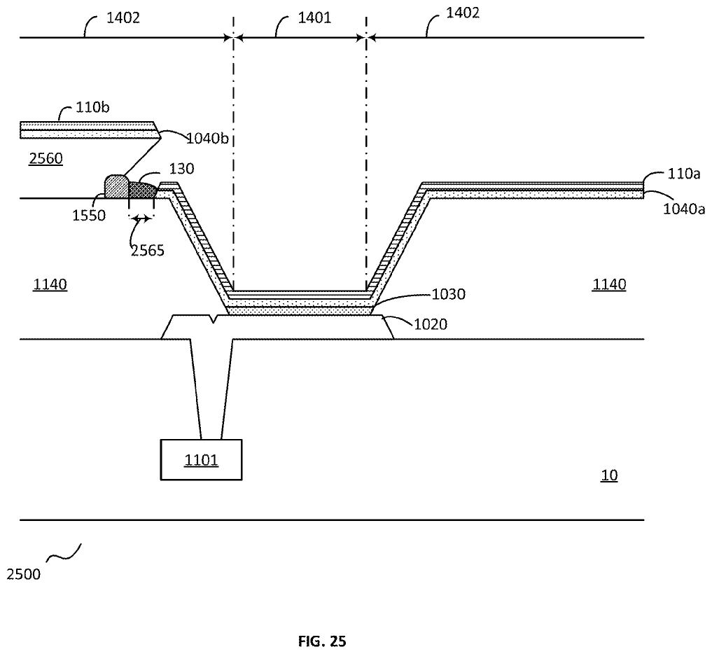

Turning to FIG. 25, there may be shown a cross-sectional view of an example version 2500 of the device 1000. The device 2500 may comprise in a lateral aspect, an emissive region 1401 and an adjacent non-emissive region 1402.

In some non-limiting examples, the emissive region 1401 may correspond to a (sub-) pixel 2210/32x of the device 2500. The emissive region 1401 may have a substrate 10, a first electrode 1020, a second electrode 1040 and at least one semiconducting layer 1030 arranged therebetween.

The first electrode 1020 may be disposed on an exposed layer surface 11 of the substrate 10. The substrate 10 may comprise a TFT structure 1101, that may be electrically coupled with the first electrode 1020. The edges, and/or perimeter of the first electrode 1020 may generally be covered by at least one PDL 1140.

The non-emissive region 1402 may have an auxiliary electrode 1550 and a first part of the non-emissive region 1402 may have a projecting structure 2560 arranged to project over and overlap a lateral aspect of the auxiliary electrode 1550. The projecting structure 2560 may extend laterally to provide a sheltered region 2565. In some non-limiting examples, the projecting structure 2560 may be recessed at, and/or near the auxiliary electrode 1550 on at least one side to provide the sheltered region 2565. As shown, the sheltered region 2565 may in some non-limiting examples, correspond to a region on a surface of the PDL 1140 that may overlap with a lateral projection of the projecting structure 2560. The non-emissive region 1402 may further comprise a deposited layer 130 disposed in the sheltered region 2565. The deposited layer 130 may electrically couple the auxiliary electrode 1550 with the second electrode 1040.

A patterning coating 110a may be disposed in the emissive region 1401 over the exposed layer surface 11 of the second electrode 1040. In some non-limiting examples, an exposed layer surface 11 of the projecting structure 2560 may be coated with a residual thin conductive film from deposition of a thin conductive film to form a second electrode 1040. In some non-limiting examples, an exposed layer surface 11 of the residual thin conductive film may be coated with a residual pattering coating 110b from deposition of the patterning coating 110.

However, because of the lateral projection of the projecting structure 2560 over the sheltered region 2565, the sheltered region 2565 may be substantially devoid of patterning coating 110. Thus, when a deposited layer 130 may be deposited on the device 2500 after deposition of the patterning coating 110, the deposited layer 130 may be deposited on, and/or migrate to the sheltered region 2565 to couple the auxiliary electrode 1550 to the second electrode 1040.

Those having ordinary skill in the relevant art will appreciate that a non-limiting example has been shown in FIG. 25 and that various modifications may be apparent. In some non-limiting examples, the projecting structure 2560 may provide a sheltered region 2565 along at least two of its sides. In some non-limiting examples, the projecting structure 2560 may be omitted and the auxiliary electrode 1550 may comprise a recessed portion that may define the sheltered region 2565. In some non-limiting examples, the auxiliary electrode 1550 and the deposited layer 130 may be disposed directly on a surface of the substrate 10, instead of the PDL 1140.

### Selective Deposition of Optical Coating

In some non-limiting examples, a device (not shown), which in some non-limiting examples may be an opto-electronic device, may comprise a substrate 10, a pattering coating 110 and an optical coating. The patterning coating 110 may cover, in a lateral aspect, a first lateral portion 101 of the substrate 10. The optical coating may cover, in a lateral aspect, a second lateral portion 102 of the substrate 10. At least a part of the patterning coating 110 may be substantially devoid of a closed coating 140 of the optical coating.

In some non-limiting examples, the optical coating may be used to modulate optical properties of EM radiation being transmitted, emitted, and/or absorbed by the device, including without limitation, plasmon modes. In some non-limiting examples, the optical coating may be used as an optical filter, index-matching coating, optical outcoupling coating, scattering layer, diffraction grating, and/or parts thereof.

In some non-limiting examples, the optical coating may be used to modulate at least one optical microcavity effect in the device by, without limitation, tuning the total optical path length, and/or the refractive index thereof. At least one optical property of the device may be affected by modulating at least one optical microcavity effect including without limitation, the output EM radiation, including without limitation, an angular dependence of an intensity thereof, and/or a wavelength shift thereof. In some non-limiting examples, the optical coating may be a non-electrical component, that is, the optical coating may not be configured to conduct, and/or transmit electrical current during normal device operations.

In some non-limiting examples, the optical coating may be formed of any deposited material 731, and/or may employ any mechanism of depositing a deposited layer 130 as described herein.

### Partition and Recess

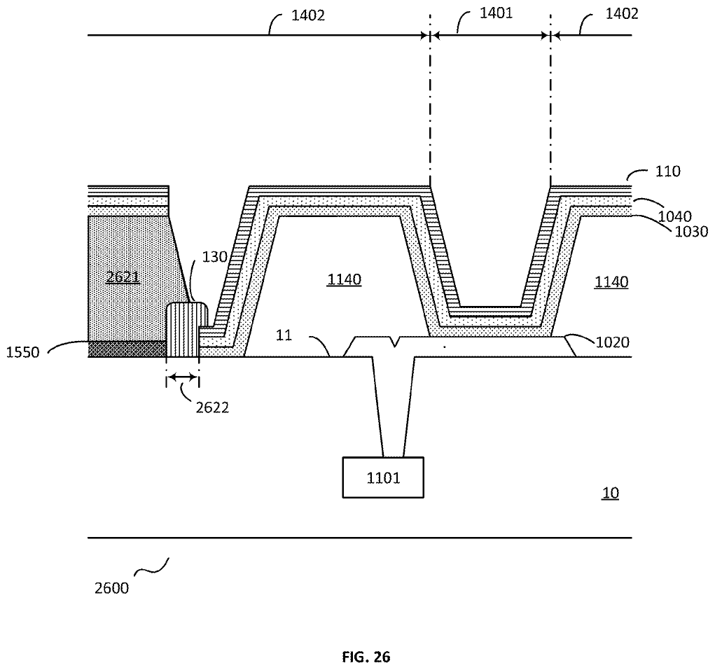

Turning to FIG. 26, there may be shown a cross-sectional view of an example version 2600 of the device 1000. The device 2600 may comprise a substrate 10 having an exposed layer surface 11. The substrate 10 may comprise at least one TFT structure 1101. In some non-limiting examples, the at least one TFT structure 1101 may be formed by depositing and patterning a series of thin films when fabricating the substrate 10, in some non-limiting examples, as described herein.

The device 2600 may comprise, in a lateral aspect, an emissive region 1401 having an associated lateral aspect 1110 and at least one adjacent non-emissive region 1402, each having an associated lateral aspect 1120. The exposed layer surface 11 of the substrate 10 in the emissive region 1401 may be provided with a first electrode 1020, that may be electrically coupled with the at least one TFT structure 1101. A PDL 1140 may be provided on the exposed layer surface 11, such that the PDL 1140 covers the exposed layer surface 11 as well as at least one edge, and/or perimeter of the first electrode 1020. The PDL 1140 may, in some non-limiting examples, be provided in the lateral aspect 1120 of the non-emissive region 1402. The PDL 1140 may define a valley-shaped configuration that may provide an opening that generally may correspond to the lateral aspect 1110 of the emissive region 1401 through which a layer surface of the first electrode 1020 may be exposed. In some non-limiting examples, the device 3500 may comprise a plurality of such openings defined by the PDLs 1140, each of which may correspond to a (sub-) pixel 2210/32x region of the device 2600.

As shown, in some non-limiting examples, a partition 2621 may be provided on the exposed layer surface 11 in the lateral aspect 1120 of a non-emissive region 1402 and, as described herein, may define a sheltered region 2565, such as a recess 2622. In some non-limiting examples, the recess 2622 may be formed by an edge of a lower section of the partition 2621 being recessed, staggered, and/or offset with respect to an edge of an upper section of the partition 2621 that may overlap, and/or project beyond the recess 2622.

In some non-limiting examples, the lateral aspect 1110 of the emissive region 1401 may comprise at least one semiconducting layer 1030 disposed over the first electrode 1020, a second electrode 1040, disposed over the at least one semiconducting layer 1030, and a patterning coating 110 disposed over the second electrode 1040. In some non-limiting examples, the at least one semiconducting layer 1030, the second electrode 1040 and the patterning coating 110 may extend laterally to cover at least the lateral aspect 1120 of a part of at least one adjacent non-emissive region 1402. In some non-limiting examples, as shown, the at least one semiconducting layer 1030, the second electrode 1040 and the patterning coating 110 may be disposed on at least a part of at least one PDL 1140 and at least a part of the partition 2621. Thus, as shown, the lateral aspect 1110 of the emissive region 1401, the lateral aspect 1120 of a part of at least one adjacent non-emissive region 1402, a part of at least one PDL 1140, and at least a part of the partition 2621, together may make up a first portion 101, in which the second electrode 1040 may lie between the patterning coating 110 and the at least one semiconducting layer 1030.

An auxiliary electrode 1550 may be disposed proximate to, and/or within the recess 2622 and a deposited layer 130 may be arranged to electrically couple the auxiliary electrode 1550 with the second electrode 1040. Thus as shown, in some non-limiting examples, the recess 2622 may comprise a second portion 102, in which the deposited layer 130 is disposed on the exposed layer surface 11.

In some non-limiting examples, in depositing the deposited layer 130, at least a part of the evaporated flux 732 of the deposited material 731 may be directed at a non-normal angle relative to a lateral plane of the exposed layer surface 11. In some non-limiting examples, at least a part of the evaporated flux 732 may be incident on the device 2600 at a non-zero angle of incidence that is, relative to such lateral plane of the exposed layer surface 11, one of no more than about: 90°, 85°, 80°, 75°, 70°, 60°, and 50°. By directing an evaporated flux 732 of a deposited material 731, including at least a part thereof incident at a non-normal angle, at least one exposed layer surface 11 of, and/or in the recess 2622 may be exposed to such evaporated flux 732.

In some non-limiting examples, a likelihood of such evaporated flux 732 being precluded from being incident onto at least one exposed layer surface 11 of, and/or in the recess 2622 due to the presence of the partition 2621, may be reduced since at least a part of such evaporated flux 732 may be flowed at a non-normal angle of incidence.

In some non-limiting examples, at least a part of such evaporated flux 732 may be non-collimated. In some non-limiting examples, at least a part of such evaporated flux 732 may be generated by an evaporation source that is a point source, a linear source, and/or a surface source.

In some non-limiting examples, the device 2600 may be displaced during deposition of the deposited layer 130. In some non-limiting examples, the device 2600, and/or the substrate 10 thereof, and/or any layer(s) deposited thereon, may be subjected to a displacement that is angular, in a lateral aspect, and/or in an aspect substantially parallel to the cross-sectional aspect.

In some non-limiting examples, the device 2600 may be rotated about an axis that substantially normal to the lateral plane of the exposed layer surface 11 while being subjected to the evaporated flux 732.

In some non-limiting examples, at least a part of such evaporated flux 732 may be directed toward the exposed layer surface 11 of the device 2600 in a direction that is substantially normal to the lateral plane of the exposed layer surface 11.

Without wishing to be bound by a particular theory, it may be postulated that the deposited material 731 may nevertheless be deposited within the recess 2622 due to lateral migration, and/or desorption of adatoms adsorbed onto the exposed layer surface 11 of the patterning coating 110. In some non-limiting examples, it may be postulated that any adatoms adsorbed onto the exposed layer surface 11 of the patterning coating 110 may tend to migrate, and/or desorb from such exposed layer surface 11 due to unfavorable thermodynamic properties of the exposed layer surface 11 for forming a stable nucleus. In some non-limiting examples, it may be postulated that at least some of the adatoms migrating, and/or desorbing off such exposed layer surface 11 may be re-deposited onto the surfaces in the recess 2622 to form the deposited layer 130.

In some non-limiting examples, the deposited layer 130 may be formed such that the deposited layer 130 may be electrically coupled with both the auxiliary electrode 1550 and the second electrode 1040. In some non-limiting examples, the deposited layer 130 may be in physical contact with at least one of the auxiliary electrode 1550, and/or the second electrode 1040. In some non-limiting examples, an intermediate layer may be present between the deposited layer 130 and at least one of the auxiliary electrode 1550, and/or the second electrode 1040. However, in such example, such intermediate layer may not substantially preclude the deposited layer 130 from being electrically coupled with the at least one of the auxiliary electrode 1550, and/or the second electrode 1040. In some non-limiting examples, such intermediate layer may be relatively thin and be such as to permit electrical coupling therethrough. In some non-limiting examples, a sheet resistance of the deposited layer 130 may be no more than a sheet resistance of the second electrode 1040.

As shown in FIG. 26, the recess 2622 may be substantially devoid of the second electrode 1040. In some non-limiting examples, during the deposition of the second electrode 1040, the recess 2622 may be masked, by the partition 2621, such that the evaporated flux 732 of the deposited material 731 for forming the second electrode 1040 may be substantially precluded from being incident on at least one exposed layer surface 11 of, and/or in, the recess 2622. In some non-limiting examples, at least a part of the evaporated flux 732 of the deposited material 731 for forming the second electrode 1040 may be incident on at least one exposed layer surface 11 of, and/or in, the recess 2622, such that the second electrode 1040 may extend to cover at least a part of the recess 2622.

In some non-limiting examples, the auxiliary electrode 1550, the deposited layer 130, and/or the partition 2621 may be selectively provided in certain region(s) of a display panel 200 (FIG. 2A). In some non-limiting examples, any of these features may be provided at, and/or proximate to, at least one edge of such display panel for electrically coupling at least one element of the frontplane 1010, including without limitation, the second electrode 1040, to at least one element of the backplane 1015. In some non-limiting examples, providing such features at, and/or proximate to, such edges may facilitate supplying and distributing electrical current to the second electrode 1040 from an auxiliary electrode 1550 located at, and/or proximate to, such edges. In some non-limiting examples, such configuration may facilitate reducing a bezel size of the display panel.

In some non-limiting examples, the auxiliary electrode 1550, the deposited layer 130, and/or the partition 2621 may be omitted from certain regions(s) of such display panel 200. In some non-limiting examples, such features may be omitted from parts of the display panel 200, including without limitation, where a relatively high pixel density may be provided, other than at, and/or proximate to, at least one edge thereof.

### Aperture in Non-Emissive Region

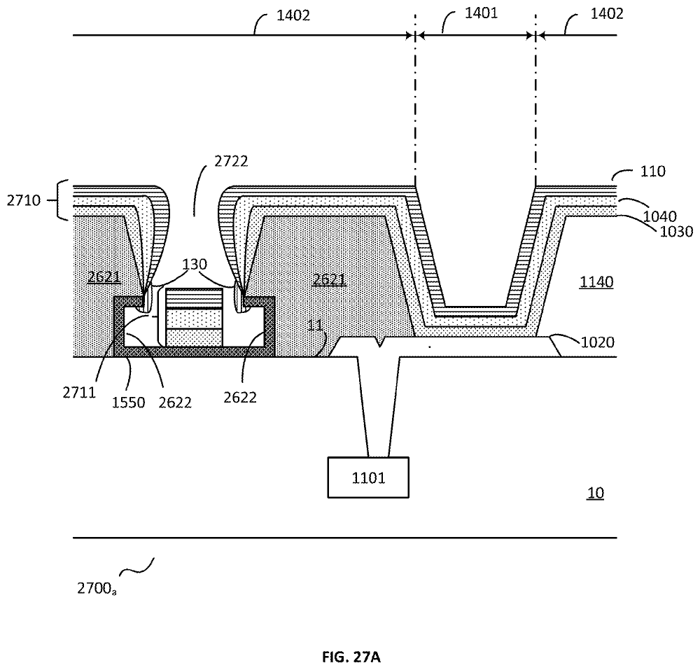

Turning now to FIG. 27A, there may be shown a cross-sectional view of an example version 2700ₐ of the device 1000. The device 2700ₐ may differ from the device 2600 in that a pair of partitions 2621 in the non-emissive region 1402 may be disposed in a facing arrangement to define a sheltered region 2565, such as an aperture 2722, therebetween. As shown, in some non-limiting examples, at least one of the partitions 2621 may function as a PDL 1140 that covers at least an edge of the first electrode 1020 and that defines at least one emissive region 1401. In some non-limiting examples, at least one of the partitions 2621 may be provided separately from a PDL 1140.

A sheltered region 2565, such as the recess 2622, may be defined by at least one of the partitions 2621. In some non-limiting examples, the recess 2622 may be provided in a part of the aperture 2722 proximal to the substrate 10. In some non-limiting examples, the aperture 2722 may be substantially elliptical when viewed in plan. In some non-limiting examples, the recess 2622 may be substantially annular when viewed in plan and surround the aperture 2722.

In some non-limiting examples, the recess 2622 may be substantially devoid of materials for forming each of the layers of a device stack 2710, and/or of a residual device stack 2711.

In these figures, a device stack 2710 may be shown comprising the at least one semiconducting layer 1030, the second electrode 1040 and the patterning coating 110 deposited on an upper section of the partition 2621.

In these figures, a residual device stack 2711 may be shown comprising the at least one semiconducting layer 1030, the second electrode 1040 and the patterning coating 110 deposited on the substrate 10 beyond the partition 2621 and recess 2622. From comparison with FIG. 26, it may be seen that the residual device stack 2711 may, in some non-limiting examples, correspond to the semiconductor layer 1030, second electrode 1040 and the patterning coating 110 as it approaches the recess 2622 at, and/or proximate to, a lip of the partition 2621. In some non-limiting examples, the residual device stack 2711 may be formed when an open mask and/or mask-free deposition process is used to deposit various materials of the device stack 2710.

In some non-limiting examples, the residual device stack 2711 may be disposed within the aperture 2722. In some non-limiting examples, evaporated materials for forming each of the layers of the device stack 2710 may be deposited within the aperture 2722 to form the residual device stack 2711 therein.

In some non-limiting examples, the auxiliary electrode 1550 may be arranged such that at least a part thereof is disposed within the recess 2722. As shown, in some non-limiting examples, the auxiliary electrode 1550 may be arranged within the aperture 2722, such that the residual device stack 3611 is deposited onto a surface of the auxiliary electrode 1550.

A deposited layer 130 may be disposed within the aperture 2722 for electrically coupling the second electrode 1040 with the auxiliary electrode 1550. In some non-limiting examples, at least a part of the deposited layer 130 may be disposed within the recess 2622.

Turning now to FIG. 27B, there may be shown a cross-sectional view of a further example of the device 2300_{b}. As shown, the auxiliary electrode 1550 may be arranged to form at least a part of a side of the partition 2621. As such, the auxiliary electrode 1550 may be substantially annular, when viewed in plan view, and may surround the aperture 2722. As shown, in some non-limiting examples, the residual device stack 2711 may be deposited onto an exposed layer surface 11 of the substrate 10.

In some non-limiting examples, the partition 2621 may comprise, and/or be formed by, an NPC 920. In some non-limiting examples, the auxiliary electrode 1550 may act as an NPC 920.

In some non-limiting examples, the NPC 920 may be provided by the second electrode 1040, and/or a portion, layer, and/or material thereof. In some non-limiting examples, the second electrode 1040 may extend laterally to cover the exposed layer surface 11 arranged in the sheltered region 2565. In some non-limiting examples, the second electrode 1040 may comprise a lower layer thereof and a second layer thereof, wherein the second layer thereof may be deposited on the lower layer thereof. In some non-limiting examples, the lower layer of the second electrode 1040 may comprise an oxide such as, without limitation, ITO, IZO, or ZnO. In some non-limiting examples, the upper layer of the second electrode 1040 may comprise a metal such as, without limitation, at least one of Ag, Mg, Mg:Ag, Yb/Ag, other alkali metals, and other alkali earth metals.

In some non-limiting examples, the lower layer of the second electrode 1040 may extend laterally to cover a surface of the sheltered region 2565, such that it forms the NPC 920. In some non-limiting examples, at least one surface defining the sheltered region 2565 may be treated to form the NPC 920. In some non-limiting examples, such NPC 920 may be formed by chemical, and/or physical treatment, including without limitation, subjecting the surface(s) of the sheltered region 2565 to a plasma, UV, and/or UV-ozone treatment.

Without wishing to be bound to any particular theory, it may be postulated that such treatment may chemically, and/or physically alter such surface(s) to modify at least one property thereof. In some non-limiting examples, such treatment of the surface(s) may increase a concentration of C—O, and/or C—OH bonds on such surface(s), may increase a roughness of such surface(s), and/or may increase a concentration of certain species, and/or functional groups, including without limitation, halogens, nitrogen-containing functional groups, and/or oxygen-containing functional groups to thereafter act as an NPC 920.

### **Diffraction Reduction

It has been discovered that, in some non-limiting examples, the at least one EM signal 231 passing through the at least one signal transmissive region 31x may be impacted by a diffraction characteristic of a diffraction pattern imposed by a shape of the at least one signal transmissive region 31x.

At least in some non-limiting examples, a display panel 200 that causes at least one EM signal 231 to pass through the at least one signal transmissive region 31x that is shaped to exhibit a distinctive and non-uniform diffraction pattern, may interfere with the capture of an image and/or EM radiation pattern represented thereby.

In some non-limiting examples, such diffraction pattern may interfere with an ability to facilitate mitigating interference by such diffraction pattern, that is, to permit an under-display component 230 to be able to accurately receive and process such image or pattern, even with the application of optical post-processing techniques, or to allow a viewer of such image and/or pattern through such display panel 200 to discern information contained therein.

In some non-limiting examples, a distinctive and/or non-uniform diffraction pattern may result from a shape of the at least one signal transmissive region 31x that may cause distinct and/or angularly separated diffraction spikes in the diffraction pattern.

In some non-limiting examples, a first diffraction spike may be distinguished from a second proximate diffraction spike by simple observation, such that a total number of diffraction spikes along a full angular revolution may be counted. However, in some non-limiting examples, especially where the number of diffraction spikes is large, it may be more difficult to identify individual diffraction spikes. In such circumstances, the distortion effect of the resulting diffraction pattern may in fact facilitate mitigation of the interference caused thereby, since the distortion effect tends to be blurred and/or distributed more evenly. Such blurring and/or more even distribution of the distortion effect may, in some non-limiting examples, be more amenable to mitigation, including without limitation, by optical post-processing techniques, in order to recover the original image and/or information contained therein.

In some non-limiting examples, an ability to facilitate mitigation of the interference caused by the diffraction pattern may increase as the number of diffraction spikes increases.

In some non-limiting examples, a distinctive and non-uniform diffraction pattern may result from a shape of the at least one signal transmissive region 31x that increase a length of a pattern boundary within the diffraction pattern between region(s) of high intensity of EM radiation and region(s) of low intensity of EM radiation as a function of a pattern circumference of the diffraction pattern and/or that reduces a ratio of the pattern circumference relative to the length of the pattern boundary thereof.

Without wishing to be bound by any specific theory, it may be postulated that display panels 200 having closed boundaries of transmissive regions 31x defined by a corresponding signal transmissive region 31x that are polygonal may exhibit a distinctive and non-uniform diffraction pattern that may adversely impact an ability to facilitate mitigation of interference caused by the diffraction pattern, relative to a display panel 200 having closed boundaries of transmissive regions 31x defined by a corresponding signal transmissive region 31x that is non-polygonal.

In the present disclosure, the term “polygonal” may refer generally to shapes, figures, closed boundaries, and/or perimeters formed by a finite number of linear and/or straight segments and the term “non-polygonal” may refer generally to shapes, figures, closed boundaries, and/or perimeters that are not polygonal. In some non-limiting examples, a closed boundary formed by a finite number of linear segments and at least one non-linear or curved segment may be considered non-polygonal.

Without wishing to be bound by a particular theory, it may be postulated that when a closed boundary of an EM radiation transmissive region 31x defined by a corresponding signal transmissive region 31x comprises at least one non-linear and/or curved segment, EM signals incident thereon and transmitted therethrough may exhibit a less distinctive and/or more uniform diffraction pattern that facilitates mitigation of interference caused by the diffraction pattern.

In some non-limiting examples, a display panel 200 having a closed boundary of the EM radiation transmissive regions 31x defined by a corresponding signal transmissive region 31x that is substantially elliptical and/or circular may further facilitate mitigation of interference caused by the diffraction pattern.

In some non-limiting examples, a signal transmissive region 31x may be defined by a finite plurality of convex rounded segments. In some non-limiting examples, at least some of these segments coincide at a concave notch or peak.

### Removal of Selective Coating

In some non-limiting examples, the patterning coating 110 may be removed after deposition of the deposited layer 130, such that at least a part of a previously exposed layer surface 11 of an underlying material covered by the patterning coating 110 may become exposed once again. In some non-limiting examples, the patterning coating 110 may be selectively removed by etching, and/or dissolving the patterning coating 110, and/or by employing plasma, and/or solvent processing techniques that do not substantially affect or erode the deposited layer 130.

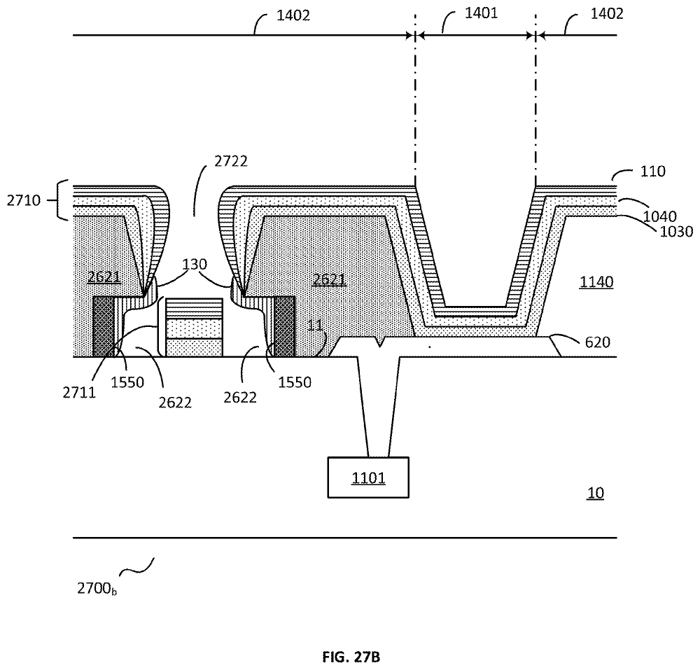

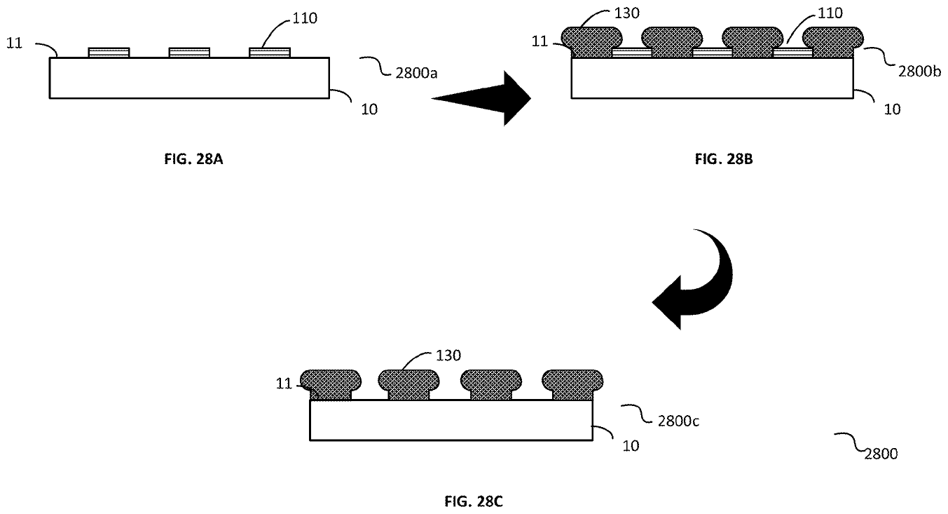

Turning now to FIG. 28A, there may be shown an example cross-sectional view of an example version 2800 of the device 1000, at a deposition stage 2800a, in which a patterning coating 110 may have been selectively deposited on a first portion 101 of an exposed layer surface 11 of an underlying material. In the figure, the underlying material may be the substrate 10.

In FIG. 28B, the device 2800 may be shown at a deposition stage 2800b, in which a deposited layer 130 may be deposited on the exposed layer surface 11 of the underlying material, that is, on both the exposed layer surface 11 of pattering coating 110 where the patterning coating 110 may have been deposited during the stage 2800a, as well as the exposed layer surface 11 of the substrate 10 where that pattering coating 110 may not have been deposited during the stage 2800a. Because of the nucleation-inhibiting properties of the first portion 101 where the pattering coating 110 may have been disposed, the deposited layer 130 disposed thereon may tend to not remain, resulting in a pattern of selective deposition of the deposited layer 130, that may correspond to a second portion 102, leaving the first portion 101 substantially devoid of the deposited layer 130.

In FIG. 28C, the device 2800 may be shown at a deposition stage 2800c, in which the patterning coating 110 may have been removed from the first portion 101 of the exposed layer surface 11 of the substrate 10, such that the deposited layer 130 deposited during the stage 2800b may remain on the substrate 10 and regions of the substrate 10 on which the patterning coating 110 may have been deposited during the stage 2800a may now be exposed or uncovered.

In some non-limiting examples, the removal of the patterning coating 110 in the stage 2800c may be effected by exposing the device 2800 to a solvent, and/or a plasma that reacts with, and/or etches away the patterning coating 110 without substantially impacting the deposited layer 130.

### Thin Film Formation

The formation of thin films during vapor deposition on an exposed layer surface 11 of an underlying layer may involve processes of nucleation and growth.

During initial stages of film formation, a sufficient number of vapor monomers which in some non-limiting examples may be molecules, and/or atoms of a deposited material 731 in vapor form 722) may typically condense from a vapor phase to form initial nuclei on the exposed layer surface 11 presented of an underlying layer. As vapor monomers may impinge on such surface, a characteristic size, and/or deposited density of these initial nuclei may increase to form small particle structures 841. Non-limiting examples of a dimension to which such characteristic size refers may include a height, width, length, and/or diameter of such particle structure 841.

After reaching a saturation island density, adjacent particle structures 841 may typically start to coalesce, increasing an average characteristic size of such particle structures 841, while decreasing a deposited density thereof.

With continued vapor deposition of monomers, coalescence of adjacent particle structures 841 may continue until a substantially closed coating 140 may eventually be deposited on an exposed layer surface 11 of an underlying layer. The behaviour, including optical effects caused thereby, of such closed coatings 140 may be generally relatively uniform, consistent, and unsurprising.

There may be at least three basic growth modes for the formation of thin films, in some non-limiting examples, culminating in a closed coating 140: 1) island (Volmer-Weber), 2) layer-by-layer (Frank-van der Merwe), and 3) Stranski-Krastanov.

Island growth may typically occur when stale clusters of monomers nucleate on an exposed layer surface 11 and grow to form discrete islands. This growth mode may occur when the interaction between the monomers is stronger than that between the monomers and the surface.

The nucleation rate may describe how many nuclei of a given size (where the free energy does not push a cluster of such nuclei to either grow or shrink) (“critical nuclei”) may be formed on a surface per unit time. During initial stages of film formation, it may be unlikely that nuclei will grow from direct impingement of monomers on the surface, since the deposited density of nuclei is low, and thus the nuclei may cover a relatively small fraction of the surface (e.g., there are large gaps/spaces between neighboring nuclei). Therefore, the rate at which critical nuclei may grow may typically depend on the rate at which adatoms (e.g., adsorbed monomers) on the surface migrate and attach to nearby nuclei.

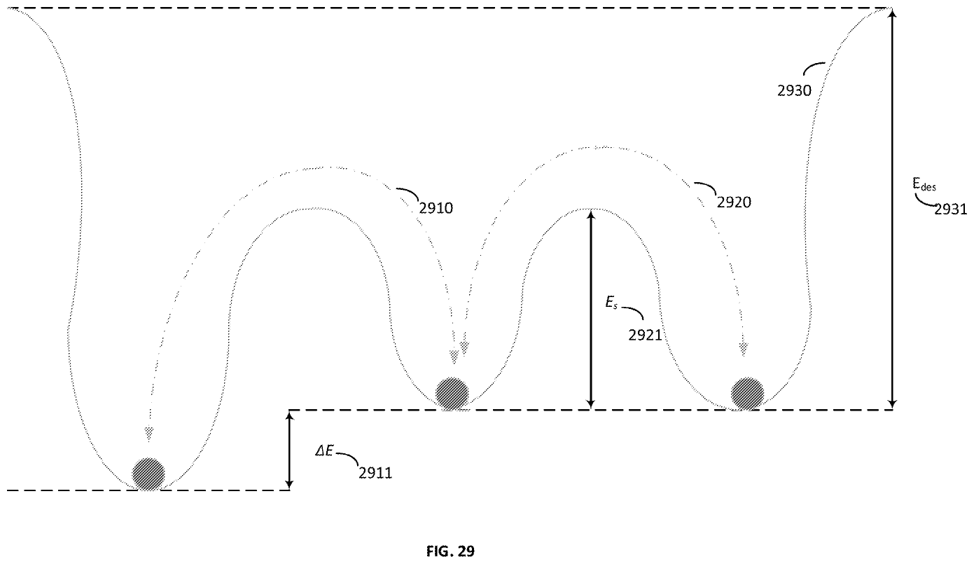

An example of an energy profile of an adatom adsorbed onto an exposed layer surface 11 of an underlying material is illustrated in FIG. 29. Specifically, FIG. 29 may illustrate example qualitative energy profiles corresponding to: an adatom escaping from a local low energy site (2910); diffusion of the adatom on the exposed layer surface 11 (2920); and desorption of the adatom (2930).

In 2910, the local low energy site may be any site on the exposed layer surface 11 of an underlying layer, onto which an adatom will be at a lower energy. Typically, the nucleation site may comprise a defect, and/or an anomaly on the exposed layer surface 11, including without limitation, a ledge, a step edge, a chemical impurity, a bonding site, and/or a kink (“heterogeneity”).

Sites of substrate heterogeneity may increase an energy involved to desorb the adatom from the surface E_{des} 2931, leading to a higher deposited density of nuclei observed at such sites. Also, impurities or contamination on a surface may also increase E_{des} 2931, leading to a higher deposited density of nuclei. For vapor deposition processes, conducted under high vacuum conditions, the type and deposited density of contaminants on a surface may be affected by a vacuum pressure and a composition of residual gases that make up that pressure.

Once the adatom is trapped at the local low energy site, there may typically, in some non-limiting examples, be an energy barrier before surface diffusion takes place. Such energy barrier may be represented as ΔE 2911 in FIG. 29. In some non-limiting examples, if the energy barrier ΔE 2911 to escape the local low energy site is sufficiently large, the site may act as a nucleation site.

In 2920, the adatom may diffuse on the exposed layer surface 11. In some non-limiting examples, in the case of localized absorbates, adatoms may tend to oscillate near a minimum of the surface potential and migrate to various neighboring sites until the adatom is either desorbed, and/or is incorporated into growing islands 841 formed by a cluster of adatoms, and/or a growing film. In FIG. 29, the activation energy associated with surface diffusion of adatoms may be represented as Eₛ 2921.

In 2930, the activation energy associated with desorption of the adatom from the surface may be represented as E_{des} 2931. Those having ordinary skill in the relevant art will appreciate that any adatoms that are not desorbed may remain on the exposed layer surface 11. In some non-limiting examples, such adatoms may diffuse on the exposed layer surface 11, become part of a cluster of adatoms that form islands 841 on the exposed layer surface 11, and/or be incorporated as part of a growing film, and/or coating.

After adsorption of an adatom on a surface, the adatom may either desorb from the surface, or may migrate some distance on the surface before either desorbing, interacting with other adatoms to form a small cluster, or attaching to a growing nucleus. An average amount of time that an adatom may remain on the surface after initial adsorption may be given by:

$${τ}_{s} = \frac{1}{v} exp ( \frac{{E}_{des}}{kT} ) \qquad ( TF1 )$$

In the above equation:
v is a vibrational frequency of the adatom on the surface,
k is the Botzmann constant, and
T is temperature.

From Equation TF1 it may be noted that the lower the value of E_{des} 2931, the easier it may be for the adatom to desorb from the surface, and hence the shorter the time the adatom may remain on the surface. A mean distance an adatom can diffuse may be given by,

$$X = {a}_{0} exp ( \frac{{E}_{des} - {E}_{s}}{2 kT} ) \qquad ( TF2 )$$

where:
α₀ is a lattice constant.

For low values of E_{des} 2931, and/or high values of Eₛ 2921, the adatom may diffuse a shorter distance before desorbing, and hence may be less likely to attach to growing nuclei or interact with another adatom or cluster of adatoms.

During initial stages of formation of a deposited layer of particle structures 841, adsorbed adatoms may interact to form particle structures 841, with a critical concentration of particle structures 841 per unit area being given by,

$$\frac{{N}_{i}}{{n}_{0}} = {\vert \frac{{N}_{1}}{{n}_{0}} \vert}^{i} exp ( \frac{{E}_{i}}{kT} ) \qquad ( TF3 )$$

where:
Eᵢ is an energy involved to dissociate a critical cluster containing i adatoms into separate adatoms,
n₀ is a total deposited density of adsorption sites, and
M is a monomer deposited density given by:

$${N}_{1} = \dot{R} {τ}_{s} \qquad ( TF4 )$$

where:
\dot{R} is a vapor impingement rate.

Typically, i may depend on a crystal structure of a material being deposited and may determine a critical size of particle structures 841 to form a stable nucleus.

A critical monomer supply rate for growing particle structures 841 may be given by the rate of vapor impingement and an average area over which an adatom can diffuse before desorbing:

$$\dot{R} {X}^{2} = {α}_{0}^{2} exp ( \frac{{E}_{des} - {E}_{s}}{kT} ) \qquad ( TF5 )$$

The critical nucleation rate may thus be given by the combination of the above equations:

$${\dot{N}}_{i} = \dot{R} {α}_{0}^{2} {{n}_{0} ( \frac{\dot{R}}{{vn}_{0}} )}^{i} exp ( \frac{( i + 1 ) {E}_{des} - {E}_{s} + {E}_{i}}{kT} ) \qquad ( TF6 )$$

From the above equation, it may be noted that the critical nucleation rate may be suppressed for surfaces that have a low desorption energy for adsorbed adatoms, a high activation energy for diffusion of an adatom, are at high temperatures, and/or are subjected to vapor impingement rates.

Under high vacuum conditions, a flux 732 of molecules that may impinge on a surface (per cm²-sec) may be given by:

$$ϕ = 3.513 \times {10}^{22} \frac{P}{MT} \qquad ( TF7 )$$

where:
P is pressure, and
M is molecular weight.

Therefore, a higher partial pressure of a reactive gas, such as H₂O, may lead to a higher deposited density of contamination on a surface during vapor deposition, leading to an increase in E_{des} 2931 and hence a higher deposited density of nuclei.

In the present disclosure, “nucleation-inhibiting” may refer to a coating, material, and/or a layer thereof, that may have a surface that exhibits an initial sticking probability against deposition of a deposited material 731 thereon, that may be close to 0, including without limitation, less than about 0.3, such that the deposition of the deposited material 331 on such surface may be inhibited.

In the present disclosure, “nucleation-promoting” may refer to a coating, material, and/or a layer thereof, that has a surface that exhibits an initial sticking probability against deposition of a deposited material 731 thereon, that may be close to 1, including without limitation, greater than about 0.7, such that the deposition of the deposited material 731 on such surface may be facilitated.

Without wishing to be bound by a particular theory, it may be postulated that the shapes and sizes of such nuclei and the subsequent growth of such nuclei into islands 841 and thereafter into a thin film may depend upon various factors, including without limitation, interfacial tensions between the vapor, the surface, and/or the condensed film nuclei.

One measure of a nucleation-inhibiting, and/or nucleation-promoting property of a surface may be the initial sticking probability of the surface against the deposition of a given deposited material 731.

In some non-limiting examples, the sticking probability S may be given by:

$$S = \frac{{N}_{ads}}{{N}_{total}} \qquad ( TF8 )$$

where:
N_{ads} is a number of adatoms that remain on an exposed layer surface 11 (that is, are incorporated into a film), and
Nₜₒₜₐₗ is a total number of impinging monomers on the surface.

A sticking probability S equal to 1 may indicate that all monomers that impinge on the surface are adsorbed and subsequently incorporated into a growing film. A sticking probability S equal to 0 may indicate that all monomers that impinge on the surface are desorbed and subsequently no film may be formed on the surface.

A sticking probability S of a deposited material 731 on various surfaces may be evaluated using various techniques of measuring the sticking probability S; including without limitation, a dual quartz crystal microbalance (QCM) technique as described by Walker et al., J. Phys. Chem. C 2007, 111, 765 (2006).

As the deposited density of a deposited material 731 may increase (e.g., increasing average film thickness), a sticking probability S may change.

An initial sticking probability S₀ may therefore be specified as a sticking probability S of a surface prior to the formation of any significant number of critical nuclei. One measure of an initial sticking probability S₀ may involve a sticking probability S of a surface against the deposition of a deposited material 731 during an initial stage of deposition thereof, where an average film thickness of the deposited material 731 across the surface is at or below a threshold value. In the description of some non-limiting examples a threshold value for an initial sticking probability may be specified as, in some non-limiting examples, 1 nm. An average sticking probability S may then be given by:

$$\overline{S} = {S}_{0} ( 1 - {A}_{nuc} ) + {S}_{nuc} ( {A}_{nuc} ) \qquad ( TF9 )$$

where:
S_{nuc} is a sticking probability S of an area covered by particle structures 841, and
A_{nuc} is a percentage of an area of a substrate surface covered by particle structures 841.

In some non-limiting examples, a low initial sticking probability may increase with increasing average film thickness. This may be understood based on a difference in sticking probability between an area of an exposed layer surface 11 with no particle structures 841, in some non-limiting examples, a bare substrate 10, and an area with a high deposited density. In some non-limiting examples, a monomer that may impinge on a surface of a particle structure 841 may have a sticking probability that may approach 1.

Based on the energy profiles 2910, 2920, 2930 shown in FIG. 29, it may be postulated that materials that exhibit relatively low activation energy for desorption (E_{des} 2931), and/or relatively high activation energy for surface diffusion (Eₛ 2921), may be deposited as a patterning coating 110, and may be suitable for use in various applications.

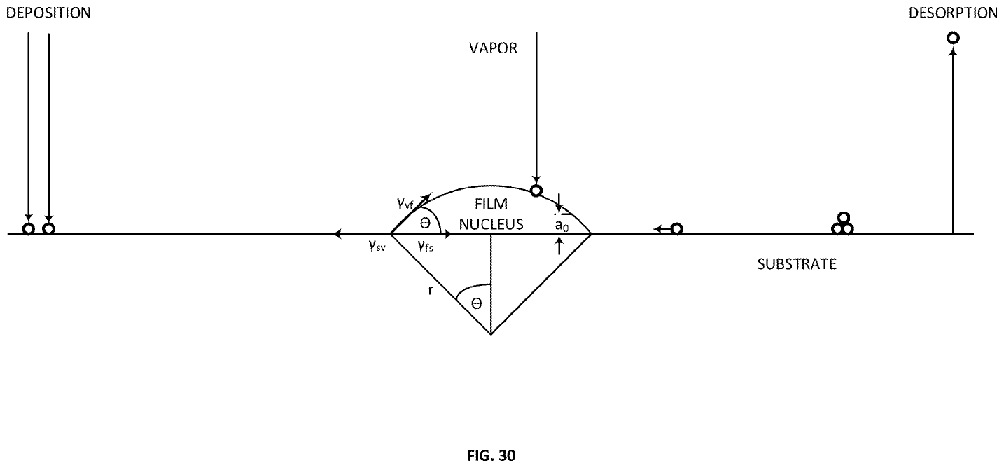

Without wishing to be bound by a particular theory, it may be postulated that, in some non-limiting examples, the relationship between various interfacial tensions present during nucleation and growth may be dictated according to Young's equation in capillarity theory:

$${γ}_{sv} = {γ}_{fs} + {γ}_{vf} cos θ \qquad ( TF10 )$$

where:
γₛᵥ (FIG. 30) corresponds to the interfacial tension between the substrate 10 and vapor 732,
γ_{fs} (FIG. 30) corresponds to the interfacial tension between the deposited material 731 and the substrate 10,
γ_{vf} (FIG. 30) corresponds to the interfacial tension between the vapor 732 and the film, and
θ is the film nucleus contact angle.

FIG. 30 may illustrate the relationship between the various parameters represented in this equation.

On the basis of Young's equation (Equation (TF10)), it may be derived that, for island growth, the film nucleus contact angle may exceed 0 and therefore: γₛᵥ<γ_{fs}+γ_{vf}.

For layer growth, where the deposited material 731 may “wet” the substrate 10, the nucleus contact angle θ may be equal to 0, and therefore: γₛᵥ=γ_{fs}+γ_{vf}.

For Stranski-Krastanov growth, where the strain energy per unit area of the film overgrowth may be large with respect to the interfacial tension between the vapor 732 and the deposited material 731: γₛᵥ>γ_{fs}+γ_{vf}.

Without wishing to be bound by any particular theory, it may be postulated that the nucleation and growth mode of a deposited material 731 at an interface between the patterning coating 110 and the exposed layer surface 11 of the substrate 10, may follow the island growth model, where θ>0.

Particularly in cases where the patterning coating 110 may exhibit a relatively low initial sticking probability (in some non-limiting examples, under the conditions identified in the dual QCM technique described by Walker et. al) against deposition of the deposited material 731, there may be a relatively high thin film contact angle of the deposited material 731.

On the contrary, when a deposited material 731 may be selectively deposited on an exposed layer surface 11 without the use of a patterning coating 110, in some non-limiting examples, by employing a shadow mask 615, the nucleation and growth mode of such deposited material 731 may differ. In particular, it has been observed that a coating formed using a shadow mask 615 patterning process may, at least in some non-limiting examples, exhibit relatively low thin film contact angle of less than about 10°.

It has now been found, somewhat surprisingly, that in some non-limiting examples, a patterning coating 110 (and/or the patterning material 611 of which it is comprised) may exhibit a relatively low critical surface tension.

Those having ordinary skill in the relevant art will appreciate that a “surface energy” of a coating, layer, and/or a material constituting such coating, and/or layer, may generally correspond to a critical surface tension of the coating, layer, and/or material. According to some models of surface energy, the critical surface tension of a surface may correspond substantially to the surface energy of such surface.

Generally, a material with a low surface energy may exhibit low intermolecular forces. Generally, a material with low intermolecular forces may readily crystallize or undergo other phase transformation at a lower temperature in comparison to another material with high intermolecular forces. In at least some applications, a material that may readily crystallize or undergo other phase transformations at relatively low temperatures may be detrimental to the long-term performance, stability, reliability, and/or lifetime of the device.

Without wishing to be bound by a particular theory, it may be postulated that certain low energy surfaces may exhibit relatively low initial sticking probabilities and may thus be suitable for forming the patterning coating 110.

Without wishing to be bound by any particular theory, it may be postulated that, especially for low surface energy surfaces, the critical surface tension may be positively correlated with the surface energy. In some non-limiting examples, a surface exhibiting a relatively low critical surface tension may also exhibit a relatively low surface energy, and a surface exhibiting a relatively high critical surface tension may also exhibit a relatively high surface energy.

In reference to Young's equation (Equation (TF10)), a lower surface energy may result in a greater contact angle, while also lowering the γₛᵥ, thus enhancing the likelihood of such surface having low wettability and low initial sticking probability with respect to the deposited material 731.

The critical surface tension values, in various non-limiting examples, herein may correspond to such values measured at around normal temperature and pressure (NTP), which in some non-limiting examples, may correspond to a temperature of 20° C., and an absolute pressure of 1 atm. In some non-limiting examples, the critical surface tension of a surface may be determined according to the Zisman method, as further detailed in Zisman, W. A., “Advances in Chemistry” 43 (1964), p. 1-51.

In some non-limiting examples, the exposed layer surface 11 of the patterning coating 110 may exhibit a critical surface tension of one of no more than about: 20 dynes/cm, 19 dynes/cm, 18 dynes/cm, 17 dynes/cm, 16 dynes/cm, 15 dynes/cm, 13 dynes/cm, 12 dynes/cm, and 11 dynes/cm.

In some non-limiting examples, the exposed layer surface 11 of the patterning coating 110 may exhibit a critical surface tension of one of at least about: 6 dynes/cm, 7 dynes/cm, 8 dynes/cm, 9 dynes/cm, and 10 dynes/cm.

Those having ordinary skill in the relevant art will appreciate that various methods and theories for determining the surface energy of a solid may be known. In some non-limiting examples, the surface energy may be calculated, and/or derived based on a series of measurements of contact angle, in which various liquids are brought into contact with a surface of a solid to measure the contact angle between the liquid-vapor interface and the surface. In some non-limiting examples, the surface energy of a solid surface may be equal to the surface tension of a liquid with the highest surface tension that completely wets the surface. In some non-limiting examples, a Zisman plot may be used to determine the highest surface tension value that would result in a contact angle of 0° with the surface. According to some theories of surface energy, various types of interactions between solid surfaces and liquids may be considered in determining the surface energy of the solid. In some non-limiting examples, according to some theories, including without limitation, the Owens/Wendt theory, and/or Fowkes' theory, the surface energy may comprise a dispersive component and a non-dispersive or “polar” component.

Without wishing to be bound by a particular theory, it may be postulated that, in some non-limiting examples, the contact angle of a coating of deposited material 731 may be determined, based at least partially on the properties (including, without limitation, initial sticking probability) of the patterning coating 110 onto which the deposited material 731 is deposited. Accordingly, patterning materials 611 that allow selective deposition of deposited materials 731 exhibiting relatively high contact angles may provide some benefit.

Those having ordinary skill in the relevant art will appreciate that various methods may be used to measure a contact angle θ, including without limitation, the static, and/or dynamic sessile drop method and the pendant drop method.

In some non-limiting examples, the activation energy for desorption (E_{des} 2931) (in some non-limiting examples, at a temperature T of about 300K) may be one of no more than about: 2 times, 1.5 times, 1.3 times, 1.2 times, 1.0 times, 0.8 times, and 0.5 times, the thermal energy. In some non-limiting examples, the activation energy for surface diffusion (Eₛ 2921) (in some non-limiting examples, at a temperature of about 300K) may exceed one of about: 1.0 times, 1.5 times, 1.8 times, 2 times, 3 times, 5 times, 7 times, and 10 times the thermal energy.

Without wishing to be bound by a particular theory, it may be postulated that, during thin film nucleation and growth of a deposited material 731 at, and/or near an interface between the exposed layer surface 11 of the underlying layer and the patterning coating 110, a relatively high contact angle between the edge of the deposited material 731 and the underlying layer may be observed due to the inhibition of nucleation of the solid surface of the deposited material 731 by the patterning coating 110. Such nucleation inhibiting property may be driven by minimization of surface energy between the underlying layer, thin film vapor and the patterning coating 110.

One measure of a nucleation-inhibiting, and/or nucleation-promoting property of a surface may be an initial deposition rate of a given (electrically conductive) deposited material 731, on the surface, relative to an initial deposition rate of the same deposited material 731 on a reference surface, where both surfaces are subjected to, and/or exposed to an evaporation flux of the deposited material 731.

### Definitions

In some non-limiting examples, the opto-electronic device may be an electro-luminescent device. In some non-limiting examples, the electro-luminescent device may be an organic light-emitting diode (OLED) device. In some non-limiting examples, the electro-luminescent device may be part of an electronic device. In some non-limiting examples, the electro-luminescent device may be an OLED lighting panel or module, and/or an OLED display or module of a computing device, such as a smartphone, a tablet, a laptop, an e-reader, and/or of some other electronic device such as a monitor, and/or a television set.

In some non-limiting examples, the opto-electronic device may be an organic photo-voltaic (OPV) device that converts photons into electricity. In some non-limiting examples, the opto-electronic device may be an electro-luminescent quantum dot (QD) device.

In the present disclosure, unless specifically indicated to the contrary, reference will be made to OLED devices, with the understanding that such disclosure could, in some examples, equally be made applicable to other opto-electronic devices, including without limitation, an OPV, and/or QD device, in a manner apparent to those having ordinary skill in the relevant art.

The structure of such devices may be described from each of two aspects, namely from a cross-sectional aspect, and/or from a lateral (plan view) aspect.

In the present disclosure, a directional convention may be followed, extending substantially normally to the lateral aspect described above, in which the substrate may be the “bottom” of the device, and the layers may be disposed on “top” of the substrate. Following such convention, the second electrode may be at the top of the device shown, even if (as may be the case in some examples, including without limitation, during a manufacturing process, in which at least one layers may be introduced by means of a vapor deposition process), the substrate may be physically inverted, such that the top surface, in which one of the layers, such as, without limitation, the first electrode, may be disposed, may be physically below the substrate, to allow the deposition material (not shown) to move upward and be deposited upon the top surface thereof as a thin film.

In the context of introducing the cross-sectional aspect herein, the components of such devices may be shown in substantially planar lateral strata. Those having ordinary skill in the relevant art will appreciate that such substantially planar representation may be for purposes of illustration only, and that across a lateral extent of such a device, there may be localized substantially planar strata of different thicknesses and dimension, including, in some non-limiting examples, the substantially complete absence of a layer, and/or layer(s) separated by non-planar transition regions (including lateral gaps and even discontinuities). Thus, while for illustrative purposes, the device may be shown below in its cross-sectional aspect as a substantially stratified structure, in the plan view aspect discussed below, such device may illustrate a diverse topography to define features, each of which may substantially exhibit the stratified profile discussed in the cross-sectional aspect.

In the present disclosure, the terms “layer” and “strata” may be used interchangeably to refer to similar concepts.

The thickness of each layer shown in the figures may be illustrative only and not necessarily representative of a thickness relative to another layer.

For purposes of simplicity of description, in the present disclosure, a combination of a plurality of elements in a single layer may be denoted by a colon “:”, while a plurality of (combination(s) of) elements comprising a plurality of layers in a multi-layer coating may be denoted by separating two such layers by a slash “/”. In some non-limiting examples, the layer after the slash may be deposited after, and/or on the layer preceding the slash.

For purposes of illustration, an exposed layer surface of an underlying material, onto which a coating, layer, and/or material may be deposited, may be understood to be a surface of such underlying material that may be presented for deposition of the coating, layer, and/or material thereon, at the time of deposition.

Those having ordinary skill in the relevant art will appreciate that when a component, a layer, a region, and/or a portion thereof, is referred to as being “formed”, “disposed”, and/or “deposited” on, and/or over another underlying material, component, layer, region, and/or portion, such formation, disposition, and/or deposition may be directly, and/or indirectly on an exposed layer surface (at the time of such formation, disposition, and/or deposition) of such underlying material, component, layer, region, and/or portion, with the potential of intervening material(s), component(s), layer(s), region(s), and/or portion(s) therebetween.

In the present disclosure, the terms “overlap”, and/or “overlapping” may refer generally to a plurality of layers, and/or structures arranged to intersect a cross-sectional axis extending substantially normally away from a surface onto which such layers, and/or structures may be disposed.

While the present disclosure discusses thin film formation, in reference to at least one layer or coating, in terms of vapor deposition, those having ordinary skill in the relevant art will appreciate that, in some non-limiting examples, various components of the device may be selectively deposited using a wide variety of techniques, including without limitation, evaporation (including without limitation, thermal evaporation, and/or electron beam evaporation), photolithography, printing (including without limitation, ink jet, and/or vapor jet printing, reel-to-reel printing, and/or micro-contact transfer printing), PVD (including without limitation, sputtering), chemical vapor deposition (CVD) (including without limitation, plasma-enhanced CVD (PECVD), and/or organic vapor phase deposition (OVPD)), laser annealing, laser-induced thermal imaging (LITI) patterning, atomic-layer deposition (ALD), coating (including without limitation, spin-coating, di coating, line coating, and/or spray coating), and/or combinations thereof (collectively “deposition process”).

Some processes may be used in combination with a shadow mask, which may, in some non-limiting examples, may be an open mask, and/or fine metal mask (FMM), during deposition of any of various layers, and/or coatings to achieve various patterns by masking, and/or precluding deposition of a deposited material on certain parts of a surface of an underlying material exposed thereto.

In the present disclosure, the terms “evaporation”, and/or “sublimation” may be used interchangeably to refer generally to deposition processes in which a source material is converted into a vapor, including without limitation, by heating, to be deposited onto a target surface in, without limitation, a solid state. As will be understood, an evaporation deposition process may be a type of PVD process where at least one source material is evaporated, and/or sublimed under a low pressure (including without limitation, a vacuum) environment to form vapor monomers, and deposited on a target surface through de-sublimation of the at least one evaporated source material. A variety of different evaporation sources may be used for heating a source material, and, as such, it will be appreciated by those having ordinary skill in the relevant art, that the source material may be heated in various ways. In some non-limiting examples, the source material may be heated by an electric filament, electron beam, inductive heating, and/or by resistive heating. In some non-limiting examples, the source material may be loaded into a heated crucible, a heated boat, a Knudsen cell (which may be an effusion evaporator source), and/or any other type of evaporation source.

In some non-limiting examples, a deposition source material may be a mixture. In some non-limiting examples, at least one component of a mixture of a deposition source material may not be deposited during the deposition process (or, in some non-limiting examples, be deposited in a relatively small amount compared to other components of such mixture).

In the present disclosure, a reference to a layer thickness, a film thickness, and/or an average layer, and/or film thickness, of a material, irrespective of the mechanism of deposition thereof, may refer to an amount of the material deposited on a target exposed layer surface, which corresponds to an amount of the material to cover the target surface with a uniformly thick layer of the material having the referenced layer thickness. In some non-limiting examples, depositing a layer thickness of 10 nm of material may indicate that an amount of the material deposited on the surface may correspond to an amount of the material to form a uniformly thick layer of the material that may be 10 nm thick. It will be appreciated that, having regard to the mechanism by which thin films are formed discussed above, in some non-limiting examples, due to possible stacking or clustering of monomers, an actual thickness of the deposited material may be non-uniform. In some non-limiting examples, depositing a layer thickness of 10 nm may yield some parts of the deposited material having an actual thickness greater than 10 nm, or other parts of the deposited material having an actual thickness of no more than 10 nm. A certain layer thickness of a material deposited on a surface may thus correspond, in some non-limiting examples, to an average thickness of the deposited material across the target surface.

In the present disclosure, a reference to a reference layer thickness may refer to a layer thickness of the deposited material (such as Mg), that may be deposited on a reference surface exhibiting a high initial sticking probability or initial sticking coefficient (that is, a surface having an initial sticking probability that is about, and/or close to 1.0). The reference layer thickness may not indicate an actual thickness of the deposited material deposited on a target surface (such as, without limitation, a surface of a patterning coating). Rather, the reference layer thickness may refer to a layer thickness of the deposited material that would be deposited on a reference surface, in some non-limiting examples, a surface of a quartz crystal, positioned inside a deposition chamber for monitoring a deposition rate and the reference layer thickness, upon subjecting the target surface and the reference surface to identical vapor flux of the deposited material for the same deposition period. Those having ordinary skill in the relevant art will appreciate that in the event that the target surface and the reference surface are not subjected to identical vapor flux simultaneously during deposition, an appropriate tooling factor may be used to determine, and/or to monitor the reference layer thickness.

In the present disclosure, a reference deposition rate may refer to a rate at which a layer of the deposited material would grow on the reference surface, if it were identically positioned and configured within a deposition chamber as the sample surface.

In the present disclosure, a reference to depositing a number X of monolayers of material may refer to depositing an amount of the material to cover a given area of an exposed layer surface with X single layer(s) of constituent monomers of the material, such as, without limitation, in a closed coating.

In the present disclosure, a reference to depositing a fraction of a monolayer of a material may refer to depositing an amount of the material to cover such fraction of a given area of an exposed layer surface with a single layer of constituent monomers of the material. Those having ordinary skill in the relevant art will appreciate that due to, in some non-limiting examples, possible stacking, and/or clustering of monomers, an actual local thickness of a deposited material across a given area of a surface may be non-uniform. In some non-limiting examples, depositing 1 monolayer of a material may result in some local regions of the given area of the surface being uncovered by the material, while other local regions of the given area of the surface may have multiple atomic, and/or molecular layers deposited thereon.

In the present disclosure a target surface (and/or target region(s) thereof) may be considered to be “substantially devoid of”, “substantially free of”, and/or “substantially uncovered by” a material if there may be a substantial absence of the material on the target surface as determined by any suitable determination mechanism.

In the present disclosure, the terms “sticking probability” and “sticking coefficient” may be used interchangeably.

In the present disclosure, the term “nucleation” may reference a nucleation stage of a thin film formation process, in which monomers in a vapor phase condense onto a surface to form nuclei.

In the present disclosure, in some non-limiting examples, as the context dictates, the terms “patterning coating” and “patterning material” may be used interchangeably to refer to similar concepts, and references to a patterning coating herein, in the context of being selectively deposited to pattern a deposited layer may, in some non-limiting examples, be applicable to a patterning material in the context of selective deposition thereof to pattern a deposited material, and/or an electrode coating material.

Similarly, in some non-limiting examples, as the context dictates, the term “patterning coating” and “patterning material” may be used interchangeably to refer to similar concepts, and reference to an NPC herein, in the context of being selectively deposited to pattern a deposited layer may, in some non-limiting examples, be applicable to an NPC in the context of selective deposition thereof to pattern a deposited material, and/or an electrode coating.

While a patterning material may be either nucleation-inhibiting or nucleation-promoting, in the present disclosure, unless the context dictates otherwise, a reference herein to a patterning material is intended to be a reference to an NIC.

In some non-limiting examples, reference to a patterning coating may signify a coating having a specific composition as described herein.

In the present disclosure, the terms “deposited layer”, “conductive coating”, and “electrode coating” may be used interchangeably to refer to similar concepts and references to a deposited layer herein, in the context of being patterned by selective deposition of a pattering coating, and/or an NPC may, in some non-limiting examples, be applicable to a deposited layer in the context of being patterned by selective deposition of a patterning material. In some non-limiting examples, reference to an electrode coating may signify a coating having a specific composition as described herein. Similarly, in the present disclosure, the terms “deposited layer material”, “deposited material”, “conductive coating material”, and “electrode coating mateial” may be used interchangeably to refer to similar concepts and references to a deposited material herein.

In some non-limiting examples, molecular formulae showing fragment(s) or part(s) of a compound may comprise at least one bond connected to an asterisk (denoted by the symbol *), which may be used to indicate the bonds to another atom (not shown) of the compound to which such fragment(s) or part(s) may be attached.

In the present disclosure, it will be appreciated by those having ordinary skill in the relevant art that an organic material may comprise, without limitation, a wide variety of organic molecules, and/or organic polymers. Further, it will be appreciated by those having ordinary skill in the relevant art that organic materials that are doped with various inorganic substances, including without limitation, elements, and/or inorganic compounds, may still be considered organic materials. Still further, it will be appreciated by those having ordinary skill in the relevant art that various organic materials may be used, and that the processes described herein are generally applicable to an entire range of such organic materials. Still further, it will be appreciated by those having ordinary skill in the relevant art that organic materials that contain metals, and/or other organic elements, may still be considered as organic materials. Still further, it will be appreciated by those having ordinary skill in the relevant art that various organic materials may be molecules, oligomers, and/or polymers.

As used herein, an organic-inorganic hybrid material may generally refer to a material that comprises both an organic component and an inorganic component. In some non-limiting examples, such organic-inorganic hybrid material may comprise an organic-inorganic hybrid compound that comprises an organic moiety and an inorganic moiety. Non-limiting examples of such organic-inorganic hybrid compounds include those in which an inorganic scaffold is functionalized with at least one organic functional group. Non-limiting examples of such organic-inorganic hybrid materials include those comprising at least one of: a siloxane group, a silsesquioxane group, a polyhedral oligomeric silsesquioxane (POSS) group, a phosphazene group, and a metal complex.

In the present disclosure, a semiconductor material may be described as a material that generally exhibits a band gap. In some non-limiting examples, the band gap may be formed between a highest occupied molecular orbital (HOMO) and a lowest unoccupied molecular orbital (LUMO) of the semiconductor material. Semiconductor materials thus generally exhibit electrical conductivity that is no more than that of a conductive material (including without limitation, a metal), but that is greater than that of an insulating material (including without limitation, a glass). In some non-limiting examples, the semiconductor material may comprise an organic semiconductor material. In some non-limiting examples, the semiconductor material may comprise an inorganic semiconductor material.

As used herein, an oligomer may generally refer to a material which includes at least two monomer units or monomers. As would be appreciated by a person skilled in the art, an oligomer may differ from a polymer in at least one aspect, including but not limited to: (1) the number of monomer units contained therein; (2) the molecular weight; and (3) other material properties, and/or characteristics. In some non-limiting examples, further description of polymers and oligomers may be found in Naka K. (2014) Monomers, Oligomers, Polymers, and Macromolecules (Overview), and in Kobayashi S., Müllen K. (eds.) Encyclopedia of Polymeric Nanomaterials, Springer, Berlin, Heidelberg.

An oligomer or a polymer may generally include monomer units that may be chemically bonded together to form a molecule. Such monomer units may be substantially identical to one another such that the molecule is primarily formed by repeating monomer units, or the molecule may include plurality different monomer units. Additionally, the molecule may include at least one terminal unit, which may be different from the monomer units of the molecule. An oligomer or a polymer may be linear, branched, cyclic, cyclo-linear, and/or cross-linked. An oligomer or a polymer may include a plurality of different monomer units which are arranged in a repeating pattern, and/or in alternating blocks of different monomer units.

In the present disclosure, the term “semiconducting layer(s)” may be used interchangeably with “organic layer(s)” since the layers in an OLED device may in some non-limiting examples, may comprise organic semiconducting materials.

In the present disclosure, an inorganic substance may refer to a substance that primarily includes an inorganic material. In the present disclosure, an inorganic material may comprise any material that is not considered to be an organic material, including without limitation, metals, glasses, and/or minerals.

In the present disclosure, the term “aperture ratio”, as used herein, generally refers to a percentage of area within a (part of a) display panel, in plan, occupied by, and/or attributed to at least one feature present in such (part of a) display panel.

In the present disclosure, the terms “EM radiation”, “photon”, and “light” may be used interchangeably to refer to similar concepts. In the present disclosure, EM radiation may have a wavelength that lies in the visible spectrum, in the infrared (IR) region (IR spectrum), near IR region (NIR spectrum), ultraviolet (UV) region (UV spectrum), and/or UVA region (UVA spectrum) (which may correspond to a wavelength range between about 315-400 nm) thereof, and/or UVB region (UVB spectrum) (which may correspond to a wavelength between about 280-315 nm) thereof.

In the present disclosure, the term “visible spectrum” as used herein, generally refers to at least one wavelength in the visible part of the EM spectrum.

As would be appreciated by those having ordinary skill in the relevant art, such visible part may correspond to any wavelength between about 380-740 nm. In general, electro-luminescent devices may be configured to emit, and/or transmit EM radiation having wavelengths in a range of between about 425-725 nm, and more specifically, in some non-limiting examples, EM radiation having peak emission wavelengths of 456 nm, 528 nm, and 624 nm, corresponding to B(lue), G(reen), and R(ed) sub-pixels, respectively. Accordingly, in the context of such electro-luminescent devices, the visible part may refer to any wavelength between about 425-725 nm, or between about 456-624 nm. EM radiation having a wavelength in the visible spectrum may, in some non-limiting examples, also be referred to as “visible light” herein.

In the present disclosure, the term “emission spectrum” as used herein, generally refers to an electroluminescence spectrum of light emitted by an opto-electronic device. In some non-limiting examples, an emission spectrum may be detected using an optical instrument, such as, in some non-limiting examples, a spectrophotometer, which may measure an intensity of EM radiation across a wavelength range.

In the present disclosure, the term “onset wavelength”, as used herein, may generally refer to a lowest wavelength at which an emission is detected within an emission spectrum.

In the present disclosure, the term “peak wavelength”, as used herein, may generally refer to a wavelength at which a maximum luminous intensity is detected within an emission spectrum.

In some non-limiting examples, the onset wavelength may be less than the peak wavelength. In some non-limiting examples, the onset wavelength λₒₙₛₑₜ may correspond to a wavelength at which a luminous intensity is one of no more than about: 10%, 5%, 3%, 1%, 0.5%, 0.1%, and 0.01%, of the luminous intensity at the peak wavelength.

In some non-limiting examples, an emission spectrum that lies in the R(ed) part of the visible spectrum may be characterized by a peak wavelength that may lie in a wavelength range of about 600-640 nm and in some non-limiting examples, may be substantially about 620 nm.

In some non-limiting examples, an emission spectrum that lies in the G(reen) part of the visible spectrum may be characterized by a peak wavelength that may lie in a wavelength range of about 510-540 nm and in some non-limiting examples, may be substantially about 530 nm.

In some non-limiting examples, an emission spectrum that lies in the B(lue) part of the visible spectrum may be characterized by a peak wavelength λₘₐₓ that may lie in a wavelength range of about 450-460 nm and in some non-limiting examples, may be substantially about 455 nm.

In the present disclosure, the term “IR signal” as used herein, may generally refer to EM radiation having a wavelength in an IR subset (IR spectrum) of the EM spectrum. An IR signal may, in some non-limiting examples, have a wavelength corresponding to a near-infrared (NIR) subset (NIR spectrum) thereof. In some non-limiting examples, an NIR signal may have a wavelength of one of between about: 750-1400 nm, 750-1300 nm, 800-1300 nm, 800-1200 nm, 850-1300 nm, and 900-1300 nm.

In the present disclosure, the term “absorption spectrum”, as used herein, may generally refer to a wavelength (sub-) range of the EM spectrum over which absorption may be concentrated.

In the present disclosure, the terms “absorption edge”, “absorption discontinuity”, and/or “absorption limit” as used herein, may generally refer to a sharp discontinuity in the absorption spectrum of a substance. In some non-limiting examples, an absorption edge may tend to occur at wavelengths where the energy of absorbed EM radiation may correspond to an electronic transition, and/or ionization potential.

In the present disclosure, the term “extinction coefficient” as used herein, may generally refer to a degree to which an EM coefficient may be attenuated when propagating through a material. In some non-limiting examples, the extinction coefficient may be understood to correspond to the imaginary component k of a complex refractive index. In some non-limiting examples, the extinction coefficient of a material may be measured by a variety of methods, including without limitation, by ellipsometry.

In the present disclosure, the terms “refractive index”, and/or “index”, as used herein to describe a medium, may refer to a value calculated from a ratio of the speed of light in such medium relative to the speed of light in a vacuum. In the present disclosure, particularly when used to describe the properties of substantially transparent materials, including without limitation, thin film layers, and/or coatings, the terms may correspond to the real part, n, in the expression N=n+ik, in which N may represent the complex refractive index and k may represent the extinction coefficient.

As would be appreciated by those having ordinary skill in the relevant art, substantially transparent materials, including without limitation, thin film layers, and/or coatings, may generally exhibit a relatively low extinction coefficient value in the visible spectrum, and therefore the imaginary component of the expression may have a negligible contribution to the complex refractive index. On the other hand, light-transmissive electrodes formed, for example, by a metallic thin film, may exhibit a relatively low refractive index value and a relatively high extinction coefficient value in the visible spectrum. Accordingly, the complex refractive index, N, of such thin films may be dictated primarily by its imaginary component k.

In the present disclosure, unless the context dictates otherwise, reference without specificity to a refractive index may be intended to be a reference to the real part n of the complex refractive index N.

In some non-limiting examples, there may be a generally positive correlation between refractive index and transmittance, or in other words, a generally negative correlation between refractive index and absorption. In some non-limiting examples, the absorption edge of a substance may correspond to a wavelength at which the extinction coefficient approaches 0.

In the present disclosure, the concept of a pixel may be discussed on conjunction with the concept of at least one sub-pixel thereof. For simplicity of description only, such composite concept may be referenced herein as a “(sub-) pixel” and such term may be understood to suggest either, or both of, a pixel, and/or at least one sub-pixel thereof, unless the context dictates otherwise.

In some nonlimiting examples, one measure of an amount of a material on a surface may be a percentage coverage of the surface by such material. In some non-limiting examples, surface coverage may be assessed using a variety of imaging techniques, including without limitation, TEM, AFM, and/or SEM.

In the present disclosure, the terms “particle”, “island”, and “cluster” may be used interchangeably to refer to similar concepts.

In the present disclosure, for purposes of simplicity of description, the terms “coating film”, “closed coating”, and/or “closed film”, as used herein, may refer to a thin film structure, and/or coating of a deposited material used for a deposited layer, in which a relevant part of a surface may be substantially coated thereby, such that such surface may be not substantially exposed by or through the coating film deposited thereon.

In the present disclosure, unless the context dictates otherwise, reference without specificity to a thin film may be intended to be a reference to a substantially closed coating.

In some non-limiting examples, a closed coating, in some non-limiting examples, of a deposited layer, and/or a deposited material, may be disposed to cover a part of an underlying surface, such that, within such part, one of no more than about: 40%, 30%, 25%, 20%, 15%, 10%, 5%, 3%, and 1% of the underlying surface therewithin may be exposed by, or through, the closed coating.

Those having ordinary skill in the relevant art will appreciate that a closed coating may be patterned using various techniques and processes, including without limitation, those described herein, to deliberately leave a part of the exposed layer surface of the underlying surface to be exposed after deposition of the closed coating. In the present disclosure, such patterned films may nevertheless be considered to constitute a closed coating, if, in some non-limiting examples, the thin film, and/or coating that is deposited, within the context of such patterning, and between such deliberately exposed parts of the exposed layer surface of the underlying surface, itself substantially comprises a closed coating.

Those having ordinary skill in the relevant art will appreciate that, due to inherent variability in the deposition process, and in some non-limiting examples, to the existence of impurities in either, or both of, the deposited materials, in some non-limiting examples, the deposited material, and the exposed layer surface of the underlying material, deposition of a thin film, using various techniques and processes, including without limitation, those described herein, may nevertheless result in the formation of small apertures, including without limitation, pin-holes, tears, and/or cracks, therein. In the present disclosure, such thin films may nevertheless be considered to constitute a closed coating, if, in some non-limiting examples, the thin film, and/or coating that is deposited substantially comprises a closed coating and meets any specified percentage coverage criterion set out, despite the presence of such apertures.

In the present disclosure, for purposes of simplicity of description, the term “discontinuous layer” as used herein, may refer to a thin film structure, and/or coating of a material used for a deposited layer, in which a relevant part of a surface coated thereby, may be neither substantially devoid of such material, nor forms a closed coating thereof. In some non-limiting examples, a discontinuous layer of a deposited material may manifest as a plurality of discrete islands disposed on such surface.

In the present disclosure, for purposes of simplicity of description, the result of deposition of vapor monomers onto an exposed layer surface of an underlying material, that has not (yet) reached a stage where a closed coating has been formed, may be referred to as a “intermediate stage layer”. In some non-limiting examples, such an intermediate stage layer may reflect that the deposition process has not been completed, in which such an intermediate stage layer may be considered as an interim stage of formation of a closed coating. In some non-limiting examples, an intermediate stage layer may be the result of a completed deposition process, and thus constitute a final stage of formation in and of itself.

In some non-limiting examples, an intermediate stage layer may more closely resemble a thin film than a discontinuous layer but may have apertures, and/or gaps in the surface coverage, including without limitation, at least one dendritic projection, and/or at least one dendritic recess. In some non-limiting examples, such an intermediate stage layer may comprise a fraction of a single monolayer of the deposited material such that it does not form a closed coating.

In the present disclosure, for purposes of simplicity of description, the term “dendritic”, with respect to a coating, including without limitation, the deposited layer, may refer to feature(s) that resemble a branched structure when viewed in a lateral aspect. In some non-limiting examples, the deposited layer may comprise a dendritic projection, and/or a dendritic recess. In some non-limiting examples, a dendritic projection may correspond to a part of the deposited layer that exhibits a branched structure comprising a plurality of short projections that are physically connected and extend substantially outwardly. In some non-limiting examples, a dendritic recess may correspond to a branched structure of gaps, openings, and/or uncovered parts of the deposited layer that are physically connected and extend substantially outwardly. In some non-limiting examples, a dendritic recess may correspond to, including without limitation, a mirror image, and/or inverse pattern, to the pattern of a dendritic projection. In some non-limiting examples, a dendritic projection, and/or a dendritic recess may have a configuration that exhibits, and/or mimics a fractal pattern, a mesh, a web, and/or an interdigitated structure.

In some non-limiting examples, sheet resistance may be a property of a component, layer, and/or part that may alter a characteristic of an electric current passing through such component, layer, and/or part. In some non-limiting examples, a sheet resistance of a coating may generally correspond to a characteristic sheet resistance of the coating, measured, and/or determined in isolation from other components, layers, and/or parts of the device.

In the present disclosure, a deposited density may refer to a distribution, within a region, which in some non-limiting examples may comprise an area, and/or a volume, of a deposited material therein. Those having ordinary skill in the relevant art will appreciate that such deposited density may be unrelated to a density of mass or material within a particle structure itself that may comprise such deposited material. In the present disclosure, unless the context dictates otherwise, reference to a deposited density, and/or to a density, may be intended to be a reference to a distribution of such deposited material, including without limitation, as at least one particle, within an area.

In some non-limiting examples, a bond dissociation energy of a metal may correspond to a standard-state enthalpy change measured at 298 K from the breaking of a bond of a diatomic molecule formed by two identical atoms of the metal. Bond dissociation energies may, in some non-limiting examples, be determined based on known literature including without limitation, Luo, Yu-Ran, “Bond Dissociation Energies” (2010).

Without wishing to be bound by a particular theory, it is postulated that providing an NPC may facilitate deposition of the deposited layer onto certain surfaces.

Non-limiting examples of suitable materials for forming an NPC may comprise without limitation, at least one metal, including without limitation, alkali metals, alkaline earth metals, transition metals, and/or post-transition metals, metal fluorides, metal oxides, and/or fullerene.

Non-limiting examples of such materials include Ca, Ag, Mg, Yb, ITO, IZO, ZnO, ytterbium fluoride (YbF₃), magnesium fluoride (MgF₂), and/or cesium fluoride (CsF).

In the present disclosure, the term “fullerene” may refer generally to a material including carbon molecules. Non-limiting examples of fullerene molecules include carbon cage molecules, including without limitation, a three-dimensional skeleton that includes multiple carbon atoms that form a closed shell, and which may be, without limitation, spherical, and/or semi-spherical in shape. In some non-limiting examples, a fullerene molecule may be designated as C, where n may be an integer corresponding to several carbon atoms included in a carbon skeleton of the fullerene molecule. Non-limiting examples of fullerene molecules include Cₙ, where n may be in the range of 50 to 250, such as, without limitation, C₆₀, C₇₀, C₇₂, C₇₄, C₇₆, C₇₈, C₈₀, C₈₂, and C₈₄. Additional non-limiting examples of fullerene molecules include carbon molecules in a tube, and/or a cylindrical shape, including without limitation, single-walled carbon nanotubes, and/or multi-walled carbon nanotubes.

Based on findings and experimental observations, it may be postulated that nucleation promoting materials, including without limitation, fullerenes, metals, including without limitation, Ag, and/or Yb, and/or metal oxides, including without limitation, ITO, and/or IZO, as discussed further herein, may act as nucleation sites for the deposition of a deposited layer, including without limitation Mg.

In some non-limiting examples, suitable materials for use to form an NPC, may include those exhibiting or characterized as having an initial sticking probability for a material of a deposited layer of at least one of at least about: 0.4, 0.5, 0.6, 0.7, 0.75, 0.8, 0.9, 0.93, 0.95, 0.98, or 0.99.

In some non-limiting examples, in scenarios where Mg is deposited using without limitation, an evaporation process on a fullerene-treated surface, in some non-limiting examples, the fullerene molecules may act as nucleation sites that may promote formation of stable nuclei for Mg deposition.

In some non-limiting examples, no more than a monolayer of an NPC, including without limitation, fullerene, may be provided on the treated surface to act as nucleation sites for deposition of Mg.

In some non-limiting examples, treating a surface by depositing several monolayers of an NPC thereon may result in a higher number of nucleation sites and accordingly, a higher initial sticking probability.

Those having ordinary skill in the relevant art will appreciate than an amount of material, including without limitation, fullerene, deposited on a surface, may be more, or less than one monolayer. In some non-limiting examples, such surface may be treated by depositing one of about: 0.1, 1, 10, and more monolayers of a nucleation promoting material, and/or a nucleation inhibiting material.

In some non-limiting examples, an average layer thickness of the NPC deposited on an exposed layer surface of underlying material(s) may be one of between about: 1-5 nm, and 1-3 nm.

Where features or aspects of the present disclosure may be described in terms of Markush groups, it will be appreciated by those having ordinary skill in the relevant art that the present disclosure may also be thereby described in terms of any individual member of sub-group of members of such Markush group.

### Terminology

References in the singular form may include the plural and vice versa, unless otherwise noted.

As used herein, relational terms, such as “first” and “second”, and numbering devices such as “a”, “b” and the like, may be used solely to distinguish one entity or element from another entity or element, without necessarily requiring or implying any physical or logical relationship or order between such entities or elements.

The terms “including” and “comprising” may be used expansively and in an open-ended fashion, and thus should be interpreted to mean “including, but not limited to”. The terms “example” and “exemplary” may be used simply to identify instances for illustrative purposes and should not be interpreted as limiting the scope of the invention to the stated instances. In particular, the term “exemplary” should not be interpreted to denote or confer any laudatory, beneficial, or other quality to the expression with which it is used, whether in terms of design, performance or otherwise.

Further, the term “critical”, especially when used in the expressions “critical nuclei”, “critical nucleation rate”, “critical concentration”, “critical cluster”, “critical monomer”, “critical particle structure size”, and/or “critical surface tension” may be a term familiar to those having ordinary skill in the relevant art, including as relating to or being in a state in which a measurement or point at which some quality, property or phenomenon undergoes a definite change. As such, the term “critical” should not be interpreted to denote or confer any significance or importance to the expression with which it is used, whether in terms of design, performance, or otherwise.

The terms “couple” and “communicate” in any form may be intended to mean either a direct connection or indirect connection through some interface, device, intermediate component, or connection, whether optically, electrically, mechanically, chemically, or otherwise.

The terms “on” or “over” when used in reference to a first component relative to another component, and/or “covering” or which “covers” another component, may encompass situations where the first component is directly on (including without limitation, in physical contact with) the other component, as well as cases where at least one intervening component is positioned between the first component and the other component.

Directional terms such as “upward”, “downward”, “left” and “right” may be used to refer to directions in the drawings to which reference is made unless otherwise stated. Similarly, words such as “inward” and “outward” may be used to refer to directions toward and away from, respectively, the geometric center of the device, area or volume or designated parts thereof. Moreover, all dimensions described herein may be intended solely to be by way of example of purposes of illustrating certain examples and may not be intended to limit the scope of the disclosure to any examples that may depart from such dimensions as may be specified.

As used herein, the terms “substantially”, “substantial”, “approximately”, and/or “about” may be used to denote and account for small variations. When used in conjunction with an event or circumstance, such terms may refer to instances in which the event or circumstance occurs precisely, as well as instances in which the event or circumstance occurs to a close approximation. In some non-limiting examples, when used in conjunction with a numerical value, such terms may refer to a range of variation of no more than about ±10% of such numerical value, such as one of no more than about: ±5%, ±4%, ±3%, ±2%, ±1%, ±0.5%, ±0.1%, and ±0.05%.

As used herein, the phrase “consisting substantially of” may be understood to include those elements specifically recited and any additional elements that do not materially affect the basic and novel characteristics of the described technology, while the phrase “consisting of” without the use of any modifier, may exclude any element not specifically recited.

As will be understood by those having ordinary skill in the relevant art, for any and all purposes, particularly in terms of providing a written description, all ranges disclosed herein may also encompass any and all possible sub-ranges, and/or combinations of sub-ranges thereof. Any listed range may be easily recognized as sufficiently describing, and/or enabling the same range being broken down at least into equal fractions thereof, including without limitation, halves, thirds, quarters, fifths, tenths etc. As a non-limiting example, each range discussed herein may be readily be broken down into a lower third, middle third, and/or upper third, etc.

As will also be understood by those having ordinary skill in the relevant art, all language, and/or terminology such as “up to”, “at least”, “greater than”, “less than”, and the like, may include, and/or refer the recited range(s) and may also refer to ranges that may be subsequently broken down into sub-ranges as discussed herein.

As will be understood by those having ordinary skill in the relevant art, a range may include each individual member of the recited range.

### General

The purpose of the Abstract is to enable the relevant patent office or the public generally, and specifically, persons of ordinary skill in the art who are not familiar with patent or legal terms or phraseology, to quickly determine from a cursory inspection, the nature of the technical disclosure. The Abstract is neither intended to define the scope of this disclosure, nor is it intended to be limiting as to the scope of this disclosure in any way.

The structure, manufacture and use of the presently disclosed examples have been discussed above. The specific examples discussed are merely illustrative of specific ways to make and use the concepts disclosed herein, and do not limit the scope of the present disclosure. Rather, the general principles set forth herein are merely illustrative of the scope of the present disclosure.

It should be appreciated that the present disclosure, which is described by the claims and not by the implementation details provided, and which can be modified by varying, omitting, adding or replacing, and/or in the absence of any element(s), and/or limitation(s) with alternatives, and/or equivalent functional elements, whether or not specifically disclosed herein, will be apparent to those having ordinary skill in the relevant art, may be made to the examples disclosed herein, and may provide many applicable inventive concepts that may be embodied in a wide variety of specific contexts, without straying from the present disclosure.

In particular, features, techniques, systems, sub-systems and methods described and illustrated in at least one of the above-described examples, whether or not described and illustrated as discrete or separate, may be combined or integrated in another system without departing from the scope of the present disclosure, to create alternative examples comprised of a combination or sub-combination of features that may not be explicitly described above, or certain features may be omitted, or not implemented. Features suitable for such combinations and sub-combinations would be readily apparent to persons skilled in the art upon review of the present application as a whole. Other examples of changes, substitutions, and alterations are easily ascertainable and could be made without departing from the spirit and scope disclosed herein.

All statements herein reciting principles, aspects, and examples of the disclosure, as well as specific examples thereof, are intended to encompass both structural and functional equivalents thereof and to cover and embrace all suitable changes in technology. Additionally, it is intended that such equivalents include both currently known equivalents as well as equivalents developed in the future, i.e., any elements developed that perform the same function, regardless of structure.

### Clauses

The present disclosure includes, without limitation, the following clauses:

The device according to at least one clause herein wherein the patterning coating comprises a patterning material 411.

The device according to at least one clause herein, wherein an initial sticking probability against deposition of the deposited material 531 of the pattering coating is no more than an initial sticking probability against deposition of the deposited material 531 of the exposed layer surface.

The device according to at least one clause herein, wherein the patterning coating is substantially devoid of a closed coating of the deposited material 531.

The device according to at least one clause herein, wherein at least one of the patterning coating and the patterning material 411 has an initial sticking probability against deposition of the deposited material 531 that is at least one of no more than about: 0.9, 0.3, 0.2, 0.15, 0.1, 0.08, 0.05, 0.03, 0.02, 0.01, 0.008, 0.005, 0.003, 0.001, 0.0008, 0.0005, 0.0003, and 0.0001.

The device according to at least one clause herein, wherein at least one of the patterning coating and the patterning material 411 has an initial sticking probability against deposition of at least one of silver (Ag) and magnesium (Mg) that is at least one of no more than about: 0.9, 0.3, 0.2, 0.15, 0.1, 0.08, 0.05, 0.03, 0.02, 0.01, 0.008, 0.005, 0.003, 0.001, 0.0008, 0.0005, 0.0003, and 0.0001.

The device according to at least one clause herein, wherein at least one of the patterning coating and the patterning material 411 has an initial sticking probability against deposition of the deposited material 531 of at least one of between about: 0.15-0.0001, 0.1-0.0003, 0.08-0.0005, 0.08-0.0008, 0.05-0.001, 0.03-0.0001, 0.03-0.0003, 0.03-0.0005, 0.03-0.0008, 0.03-0.001, 0.03-0.005, 0.03-0.008, 0.03-0.01, 0.02-0.0001, 0.02-0.0003, 0.02-0.0005, 0.02-0.0008, 0.02-0.001, 0.02-0.005, 0.02-0.008, 0.02-0.01, 0.01-0.0001, 0.01-0.0003, 0.01-0.0005, 0.01-0.0008, 0.01-0.001, 0.01-0.005, 0.01-0.008, 0.008-0.0001, 0.008-0.0003, 0.008-0.0005, 0.008-0.0008, 0.008-0.001, 0.008-0.005, 0.005-0.0001, 0.005-0.0003, 0.005-0.0005, 0.005-0.0008, and 0.005-0.001.

The device according to at least one clause herein, wherein at least one of the patterning coating and the patterning material 411 has an initial sticking probability against deposition of the deposited material 531 that is no more than a threshold value that is at least one of about: 0.3, 0.2, 0.18, 0.15, 0.13, 0.1, 0.08, 0.05, 0.03, 0.02, 0.01, 0.008, 0.005, 0.003, and 0.001.

The device according to at least one clause herein, wherein at least one of the patterning coating and the patterning material 411 has an initial sticking probability against the deposition of at least one of: Ag, Mg, ytterbium (Yb), cadmium (Cd), and zinc (Zn), that is no more than the threshold value.

The device according to at least one clause herein, wherein the threshold value has a first threshold value against the deposition of a first deposited material 531 and a second threshold value against the deposition of a second deposited material 531.

The device according to at least one clause herein, wherein the first deposited material 531 is Ag and the second deposited material 531 is Mg.

The device according to at least one clause herein, wherein the first deposited material 531 is Ag and the second deposited material 531 is Yb.

The device according to at least one clause herein, wherein the first deposited material 531 is Yb and the second deposited material 531 is Mg.

The device according to at least one clause herein, wherein the first threshold value exceeds the second threshold value.

The device according to at least one clause herein, wherein at least one of the patterning coating and the patterning material 411 has a transmittance for EM radiation of at least a threshold transmittance value after being subjected to a vapor flux 1832 of the deposited material 531.

The device according to at least one clause herein, wherein the threshold transmittance value is measured at a wavelength in the visible spectrum.

The device according to at least one clause herein, wherein the threshold transmittance value is at least one of at least about 60%, 65%, 70%, 75%, 80%, 85%, and 90% of incident EM power transmitted therethrough.

The device according to at least one clause herein, wherein at least one of the patterning coating and the pattering material 411 has a surface energy of at least one of no more than about: 24 dynes/cm, 22 dynes/cm, 20 dynes/cm, 18 dynes/cm, 16 dynes/cm, 15 dynes/cm, 13 dynes/cm, 12 dynes/cm, and 11 dynes/cm.

The device according to at least one clause herein, wherein at least one of the patterning coating and the patterning material 411 has a surface energy that is at least one of at least about: 6 dynes/cm, 7 dynes/cm, and 8 dynes/cm.

The device according to at least one clause herein, wherein at least one of the patterning coating and the patterning material 411 has a surface energy that is at least one of between about: 10-20 dynes/cm, and 13-19 dynes/cm.

The device according to at least one clause herein, wherein at least one of the patterning coating and the pattering material 411 has a refractive index for EM radiation at a wavelength of 550 nm that is at least one of no more than about: 1.55, 1.5, 1.45, 1.43, 1.4, 1.39, 1.37, 1.35, 1.32, and 1.3

The device according to at least one clause herein, wherein at least one of the patterning coating and the patterning material 411 has an extinction coefficient that is no more than about 0.01 for photons at a wavelength that exceeds at least one of about: 600 nm, 500 nm, 460 nm, 420 nm, and 410 nm.

The device according to at least one clause herein, wherein at least one of the patterning coating and the patterning material 411 has an extinction coefficient that is at least one of at least about: 0.05, 0.1, 0.2, 0.5 for EM radiation at a wavelength shorter than at least one of at least about: 400 nm, 390 nm, 380 nm, and 370 nm.

The device according to at least one clause herein, wherein at least one of the patterning coating and the pattering material 411 has a glass transition temperature that is that is at least one of: (i) at least one of at least about: 300° C., 150° C., 130° C., 120° C., and 100° C., and (ii) at least one of no more than about: 30° C., 0° C., −30° C., and −50° C.

The device according to at least one clause herein, wherein the patterning material 411 has a sublimation temperature of at least one of between about: 100-320° C., 120-300° C., 140-280° C., and 150-250° C.

The device according to at least one clause herein, wherein at least one of the patterning coating and the patterning material 411 comprises at least one of a fluorine atom and a silicon atom.

The device according to at least one clause herein, wherein the patterning coating comprises fluorine and carbon.

The device according to at least one clause herein, wherein an atomic ratio of a quotient of fluorine by carbon is at least one of about: 1, 1.5, and 2.

The device according to at least one clause herein, wherein the patterning coating comprises an oligomer.

The device according to at least one clause herein, wherein the patterning coating comprises a compound having a molecular structure containing a backbone and at least one functional group bonded thereto.

The device according to at least one clause herein, wherein the compound comprises at least one of: a siloxane group, a silsesquioxane group, an aryl group, a heteroaryl group, a fluoroalkyl group, a hydrocarbon group, a phosphazene group, a fluoropolymer, and a metal complex.

The device according to at least one clause herein, wherein a molecular weight of the compound is at least one of no more than about: 5,000 g/mol, 4,500 g/mol, 4,000 g/mol, 3,800 g/mol, and 3,500 g/mol.

The device according to at least one clause herein, wherein the molecular weight is at least about: 1,500 g/mol, 1,700 g/mol, 2,000 g/mol, 2,200 g/mol, and 2,500 g/mol.

The device according to at least one clause herein, wherein the molecular weight is at least one of between about: 1,500-5,000 g/mol, 1,500-4,500 g/mol, 1,700-4,500 g/mol, 2,000-4,000 g/mol, 2,200-4,000 g/mol, and 2,500-3,800 g/mol.

The device according to at least one clause herein, wherein a percentage of a molar weight of the compound that is attributable to a presence of fluorine atoms, is at least one of between about: 40-90%, 45-85%, 50-80%, 55-75%, and 60-75%.

The device according to at least one clause herein, wherein fluorine atoms comprise a majority of the molar weight of the compound.

The device according to at least one clause herein, wherein the patterning material 411 comprises an organic-inorganic hybrid material.

The device according to at least one clause herein, wherein the pattering coating has at least one nucleation site for the deposited material 531.

The device according to at least one clause herein, wherein the patterning coating is supplemented with a seed material that acts as a nucleation site for the deposited material 531.

The device according to at least one clause herein, wherein the seed material comprises at least one of: a nucleation promoting coating (NPC) material, an organic material, a polycyclic aromatic compound, and a material comprising a non-metallic element selected from at least one of oxygen (O), sulfur (S), nitrogen (N), I carbon (C).

The device according to at least one clause herein, wherein the patterning coating acts as an optical coating.

The device according to at least one clause herein, wherein the pattering coating modifies at least one of a property and a characteristic of EM radiation emitted by the device.

The device according to at least one clause herein, wherein the patterning coating comprises a crystalline material.

The device according to at least one clause herein, wherein the patterning coating is deposited as a non-crystalline material and becomes crystallized after deposition.

The device according to at least one clause herein, wherein the deposited layer comprises a deposited material 531.

The device according to at least one clause herein, wherein the deposited material 531 comprises an element selected from at least one of: potassium (K), sodium (Na), lithium (Li), barium (Ba), cesium (Cs), ytterbium (Yb), silver (Ag), gold (Au), copper (Cu), aluminum (Al), magnesium (Mg), zinc (Zn), cadmium (Cd), tin (Sn), nickel (Ni), and yttrium (Y).

The device according to at least one clause herein, wherein the deposited material 531 comprises a pure metal.

The device according to at least one clause herein, wherein the deposited material 531 is selected from at least one of pure Ag and substantially pure Ag.

The device according to at least one clause herein, wherein the substantially pure Ag has a purity of at least one of at least about: 95%, 99%, 99.9%, 99.99%, 99.999%, and 99.9995%.

The device according to at least one clause herein, wherein the deposited material 531 is selected from at least one of pure Mg and substantially pure Mg.

The device according to at least one clause herein, wherein the substantially pure Mg has a purity of at least one of at least about: 95%, 99%, 99.9%, 99.99%, 99.999%, or 99.9995%.

The device according to at least one clause herein, wherein the deposited material 531 comprises an alloy.

The device according to at least one clause herein, wherein the deposited material 531 comprises at least one of: an Ag-containing alloy, an Mg-containing alloy, and an AgMg-containing alloy.

The device according to at least one clause herein, wherein the AgMg-containing alloy has an alloy composition that ranges from 1:10 (Ag:Mg) to about 10:1 by volume.

The device according to at least one clause herein, wherein the deposited material 531 comprises at least one metal other than Ag.

The device according to at least one clause herein, wherein the deposited material 531 comprises an alloy of Ag with at least one metal.

The device according to at least one clause herein, wherein the at least one metal is selected from at least one of Mg and Yb.

The device according to at least one clause herein, wherein the alloy is a binary alloy having a composition between about 5-95 vol. % Ag.

The device according to at least one clause herein, wherein the alloy comprises a Yb:Ag alloy having a composition between about 1:20-10:1 by volume.

The device according to at least one clause herein, wherein the deposited material 531 comprises an Mg:Yb alloy.

The device according to at least one clause herein, wherein the deposited material 531 comprises an Ag:Mg:Yb alloy.

The device according to at least one clause herein, wherein the deposited layer comprises at least one additional element.

The device according to at least one clause herein, wherein the at least one additional element is a non-metallic element.

The device according to at least one clause herein, wherein the non-metallic element is selected from at least one of O, S, N, and C.

The device according to at least one clause herein, wherein a concentration of the non-metallic element is at least one of no more than about: 1%, 0.1%, 0.01%, 0.001%, 0.0001%, 0.00001%, 0.000001%, and 0.0000001%.

The device according to at least one clause herein, wherein the deposited layer has a composition in which a combined amount of O and C is at least one of no more than about: 10%, 5%, 1%, 0.1%, 0.01%, 0.001%, 0.0001%, 0.00001%, 0.000001%, and 0.0000001%.

The device according to at least one clause herein, wherein the non-metallic element acts as a nucleation site for the deposited material 531 on the NIC.

The device according to at least one clause herein, wherein the deposited material 531 and the underlying layer comprise a common metal.

The device according to at least one clause herein, the deposited layer comprises a plurality of layers of the deposited material 531.

The device according to at least one clause herein, a deposited material 531 of a first one of the plurality of layers is different from a deposited material 531 of a second one of the plurality of layers.

The device according to at least one clause herein, wherein the deposited layer comprises a multilayer coating.

The device according to at least one clause herein, wherein the multilayer coating is at least one of: Yb/Ag, Yb/Mg, Yb/Mg:Ag, Yb/Yb:Ag, Yb/Ag/Mg, and Yb/Mg/Ag.

The device according to at least one clause herein, wherein the deposited material 531 comprises a metal having a bond dissociation energy of at least one of no more than about: 300 kJ/mol, 200 kJ/mol, 165 kJ/mol, 150 kJ/mol, 100 kJ/mol, 50 kJ/mol, and 20 kJ/mol.

The device according to at least one clause herein, wherein the deposited material 531 comprises a metal having an electronegativity of at least one of no more than about: 1.4, 1.3, and 1.2.

The device according to at least one clause herein, wherein a sheet resistance of the deposited layer is at least one of no more than about: 10Ω/□, 5Ω/□, 1Ω/□, 0.5Ω/□, 0.2Ω/□, and 0.1Ω/□.

The device according to at least one clause herein, wherein the deposited layer is disposed in a pattern defined by at least one region therein that is substantially devoid of a closed coating thereof.

The device according to at least one clause herein, wherein the at least one region separates the deposited layer into a plurality of discrete fragments thereof.

The device according to at least one clause herein, wherein at least two discrete fragments are electrically coupled.

The device according to at least one clause herein, wherein the patterning coating has a boundary defined by a patterning coating edge.

The device according to at least one clause herein, wherein the patterning coating comprises at least one pattering coating transition region and a pattering coating non-transition part.

The device according to at least one clause herein, wherein the at least one patterning coating transition region transitions from a maximum thickness to a reduced thickness.

The device according to at least one clause herein, wherein the at least one patterning coating transition region extends between the patterning coating non-transition part and the pattering coating edge. The device according to at least one clause herein, wherein the patterning coating has an average film thickness in the patterning coating non-transition part that is in a range of at least one of between about: 1-100 nm, 2-50 nm, 3-30 nm, 4-20 nm, 5-15 nm, 5-10 nm, and 1-10 nm.

The device according to at least one clause herein, wherein a thickness of the patterning coating in the pattering coating non-transition part is within at least one of about: 95%, and 90% of the average film thickness of the NIC.

The device according to at least one clause herein, wherein the average film thickness is at least one of no more than about: 80 nm, 60 nm, 50 nm, 40 nm, 30 nm, 20 nm, 15 nm, and 10 nm.

The device according to at least one clause herein, wherein the average film thickness exceeds at least one of about: 3 nm, 5 nm, and 8 nm.

The device according to at least one clause herein, wherein the average film thickness is no more than about 10 nm.

The device according to at least one clause herein, wherein the patterning coating has a patterning coating thickness that decreases from a maximum to a minimum within the patterning coating transition region.

The device according to at least one clause herein, wherein the maximum is proximate to a boundary between the patterning coating transition region and the patterning coating non-transition part.

The device according to at least one clause herein, wherein the maximum is a percentage of the average film thickness that is at least one of about: 100%, 95%, and 90%.

The device according to at least one clause herein, wherein the minimum is proximate to the patterning coating edge.

The device according to at least one clause herein, wherein the minimum is in a range of between about: 0-0.1 nm.

The device according to at least one clause herein, wherein a profile of the patterning coating thickness is at least one of sloped, tapered, and defined by a gradient.

The device according to at least one clause herein, wherein the tapered profile follows at least one of a linear, non-linear, parabolic, and exponential decaying profile.

The device according to at least one clause herein, wherein a non-transition width along a lateral axis of the patterning coating non-transition region exceeds a transition width along the axis of the patterning coating transition region.

The device according to at least one clause herein, wherein a quotient of the non-transition width by the transition width is at least one of at least about: 5, 10, 20, 50, 100, 500, 1,000, 1,500, 5,000, 10,000, 50,000, or 100,000.

The device according to at least one clause herein, wherein at least one of the non-transition width and the transition width exceeds an average film thickness of the underlying layer.

The device according to at least one clause herein, wherein at least one of the non-transition width and the transition width exceeds the average film thickness of the patterning coating.

The device according to at least one clause herein, wherein the average film thickness of the underlying layer exceeds the average film thickness of the patterning coating.

The device according to at least one clause herein, wherein the deposited layer has a boundary defined by a deposited layer edge.

The device according to at least one clause herein, wherein the deposited layer comprises at least one deposited layer transition region and a deposited layer non-transition part.

The device according to at least one clause herein, wherein the at least one deposited layer transition region transitions from a maximum thickness to a reduced thickness.

The device according to at least one clause herein, wherein the at least one deposited layer transition region extends between the deposited layer non-transition part and the deposited layer edge.

The device according to at least one clause herein, wherein the deposited layer has an average film thickness in the deposited layer non-transition part that is in a range of at least one of between about: 1-500 nm, 5-200 nm, 5-40 nm, 10-30 nm, and 10-100 nm.

The device according to at least one clause herein, wherein the average film thickness exceeds at least one of about: 10 nm, 50 nm, and 100 nm.

The device according to at least one clause herein, wherein the average film thickness of is substantially constant thereacross.

The device according to at least one clause herein, wherein the average film thickness exceeds an average film thickness of the underlying layer.

The device according to at least one clause herein, wherein a quotient of the average film thickness of the deposited layer by the average film thickness of the underlying layer is at least one of at least about: 1.5, 2, 5, 10, 20, 50, and 100.

The device according to at least one clause herein, wherein the quotient is in a range of at least one of between about: 0.1-10, and 0.2-40.

The device according to at least one clause herein, wherein the average film thickness of the deposited layer exceeds an average film thickness of the patterning coating.

The device according to at least one clause herein, wherein a quotient of the average film thickness of the deposited layer by the average film thickness of the pattering coating is at least one of at least about: 1.5, 2, 5, 10, 20, 50, and 100.

The device according to at least one clause herein, wherein the quotient is in a range of at least one of between about: 0.2-10, and 0.5-40.

The device according to at least one clause herein, wherein a deposited layer non-transition width along a lateral axis of the deposited layer non-transition part exceeds a patterning coating non-transition width along the axis of the patterning coating non-transition part.

The device according to at least one clause herein, wherein a quotient of the patterning coating non-transition width by the deposited layer non-transition width is at least one of between about: 0.1-10, 0.2-5, 0.3-3, and 0.4-2.

The device according to at least one clause herein, wherein a quotient of the deposited layer non-transition width by the patterning coating non-transition width is at least one of at least: 1, 2, 3, and 4.

The device according to at least one clause herein, wherein the deposited layer non-transition width exceeds the average film thickness of the deposited layer.

The device according to at least one clause herein, wherein a quotient of the deposited layer non-transition width by the average film thickness is at least one of at least about: 10, 50, 100, and 500.

The device according to at least one clause herein, wherein the quotient is no more than about 100,000. The device according to at least one clause herein, wherein the deposited layer has a deposited layer thickness that decreases from a maximum to a minimum within the deposited layer transition region.

The device according to at least one clause herein, wherein the maximum is proximate to a boundary between the deposited layer transition region and the deposited layer non-transition part.

The device according to at least one clause herein, wherein the maximum is the average film thickness.

The device according to at least one clause herein, wherein the minimum is proximate to the deposited layer edge.

The device according to at least one clause herein, wherein the minimum is in a range of between about: 0-0.1 nm.

The device according to at least one clause herein, wherein the minimum is the average film thickness.

The device according to at least one clause herein, wherein a profile of the deposited layer thickness is at least one of sloped, tapered, and defined by a gradient.

The device according to at least one clause herein, wherein the tapered profile follows at least one of a linear, non-linear, parabolic, and exponential decaying profile.

The device according to at least one clause herein, wherein the deposited layer comprises a discontinuous layer in at least a part of the deposited layer transition region.

The device according to at least one clause herein, wherein the deposited layer overlaps the patterning coating in an overlap portion.

The device according to at least one clause herein, wherein the patterning coating overlaps the deposited layer in an overlap portion.

The device according to at least one clause herein, further comprising at least one particle structure disposed on an exposed layer surface of an underlying layer.

The device according to at least one clause herein, wherein the underlying layer is the patterning coating.

The device according to at least one clause herein, wherein the at least one particle structure comprises a particle material.

The device according to at least one clause herein, wherein the particle material is the same as the deposited material 531.

The device according to at least one clause herein, wherein at least two of the particle material, the deposited material 531, and a material of which the underlying layer is comprised, comprises a common metal.

The device according to at least one clause herein, wherein the particle material comprises an element selected from at least one of: potassium (K), sodium (Na), lithium (Li), barium (Ba), cesium (Cs), ytterbium (Yb), silver (Ag), gold (Au), copper (Cu), aluminum (Al), magnesium (Mg), zinc (Zn), cadmium (Cd), tin (Sn), nickel (Ni), and yttrium (Y).

The device according to at least one clause herein, wherein the particle material comprises a pure metal.

The device according to at least one clause herein, wherein the particle material is selected from at least one of pure Ag and substantially pure Ag.

The device according to at least one clause herein, wherein the substantially pure Ag has a purity of at least one of at least about: 95%, 99%, 99.9%, 99.99%, 99.999%, and 99.9995%.

The device according to at least one clause herein, wherein the particle material is selected from at least one of pure Mg and substantially pure Mg.

The device according to at least one clause herein, wherein the substantially pure Mg has a purity of at least one of at least about: 95%, 99%, 99.9%, 99.99%, 99.999%, or 99.9995%.

The device according to at least one clause herein, wherein the particle material comprises an alloy.

The device according to at least one clause herein, wherein the particle material comprises at least one of: an Ag-containing alloy, an Mg-containing alloy, and an AgMg-containing alloy.

The device according to at least one clause herein, wherein the AgMg-containing alloy has an alloy composition that ranges from 1:10 (Ag:Mg) to about 10:1 by volume.

The device according to at least one clause herein, wherein the particle material comprises at least one metal other than Ag.

The device according to at least one clause herein, wherein the particle material comprises an alloy of Ag with at least one metal.

The device according to at least one clause herein, wherein the at least one metal is selected from at least one of Mg and Yb.

The device according to at least one clause herein, wherein the alloy is a binary alloy having a composition between about 5-95 vol. % Ag.

The device according to at least one clause herein, wherein the alloy comprises a Yb:Ag alloy having a composition between about 1:20-10:1 by volume.

The device according to at least one clause herein, wherein the particle material comprises an Mg:Yb alloy.

The device according to at least one clause herein, wherein the particle material comprises an Ag:Mg:Yb alloy.

The device according to at least one clause herein, wherein the at least one particle structure comprises at least one additional element.

The device according to at least one clause herein, wherein the at least one additional element is a non-metallic element.

The device according to at least one clause herein, wherein the non-metallic element is selected from at least one of O, S, N, and C.

The device according to at least one clause herein, wherein a concentration of the non-metallic element is at least one of no more than about: 1%, 0.1%, 0.01%, 0.001%, 0.0001%, 0.00001%, 0.000001%, and 0.0000001%.

The device according to at least one clause herein, wherein the at least one particle structure has a composition in which a combined amount of O and C is at least one of no more than about: 10%, 5%, 1%, 0.1%, 0.01%, 0.001%, 0.0001%, 0.00001%, 0.000001%, and 0.0000001%.

The device according to at least one clause herein, wherein the at least one particle is disposed at an interface between the patterning coating and at least one covering layer in the device.

The device according to at least one clause herein, wherein the at least one particle is in physical contact with an exposed layer surface of the patterning coating.

The device according to at least one clause herein, wherein the at least one particle structure affects at least one optical property of the device.

The device according to at least one clause herein, wherein the at least one optical property is controlled by selection of at least one property of the at least one particle structure selected from at least one of: a characteristic size, a length, a width, a diameter, a height, a size distribution, a shape, a surface coverage, a configuration, a deposited density, a dispersity, and a composition.

The device according to at least one clause herein, wherein the at least one property of the at least one particle structure is controlled by selection of at least one of: at least one characteristic of the patterning material 411, an average film thickness of the patterning coating, at least one heterogeneity in the patterning coating, and a deposition environment for the patterning coating, selected from at least one of a temperature, pressure, duration, deposition rate, and deposition process.

The device according to at least one clause herein, wherein the at least one property of the at least one particle structure is controlled by selection of at least one of: at least one characteristic of the particle material, an extent to which the patterning coating is exposed to deposition of the particle material, a thickness of the discontinuous layer, and a deposition environment for the particle material, selected from at least one of a temperature, pressure, duration, deposition rate, and deposition process.

The device according to at least one clause herein, wherein the at least one particle structures are disconnected from one another.

The device according to at least one clause herein, wherein the at least one particle structure forms a discontinuous layer.

The device according to at least one clause herein, wherein the discontinuous layer is disposed in a pattern defined by at least one region therein that is substantially devoid of the at least one particle structure.

The device according to at least one clause herein, wherein a characteristic of the discontinuous layer is determined by an assessment according to at least one criterion selected from at least one of: a characteristic size, length, width, diameter, height, size distribution, shape, configuration, surface coverage, deposited distribution, dispersity, presence of aggregation instances, and extent of such aggregation instances.

The device according to at least one clause herein, wherein the assessment is performed by determining at least one attribute of the discontinuous layer by an applied imaging technique selected from at least one of: electron microscopy, atomic force microscopy, and scanning electron microscopy.

The device according to at least one clause herein, wherein the assessment is performed across an extent defined by at least one observation window.

The device according to at least one clause herein, wherein the at least one observation window is located at at least one of: a perimeter, interior location, and grid coordinate of the lateral aspect.

The device according to at least one clause herein, wherein the observation window corresponds to a field of view of the applied imaging technique.

The device according to at least one clause herein, wherein the observation window corresponds to a magnification level selected from at least one of: 2.00 μm, 1.00 μm, 500 nm, and 200 nm.

The device according to at least one clause herein, wherein the assessment incorporates at least one of: manual counting, curve fitting, polygon fitting, shape fitting, and an estimation technique.

The device according to at least one clause herein, wherein the assessment incorporates a manipulation selected from at least one of: an average, median, mode, maximum, minimum, probabilistic, statistical, and data calculation.

The device according to at least one clause herein, wherein the characteristic size is determined from at least one of: a mass, volume, diameter, perimeter, major axis, and minor axis of the at least one particle structure.

The device according to at least one clause herein, wherein the dispersity is determined from:

$$D = \frac{\overline{{S}_{s}}}{\overline{{S}_{n}}}$$

$$where :$$

$$\overline{{S}_{s}} = \frac{{\sum }_{i = 1}^{n} {{S}_{i}}^{2}}{{\sum }_{i = 1}^{n} {S}_{i}} , \overline{{S}_{n}} = \frac{{\sum }_{i = 1}^{n} {S}_{i}}{n} ,$$

n is the number of particles in a sample area,
Sᵢ is the (area) size of the i^{th} particle,
S̅ₙ is the number average of the particle (area) sizes; and
S̅ₛ is the (area) size average of the particle (area) sizes.

Accordingly, the specification and the examples disclosed therein are to be considered illustrative only, with a true scope of the disclosure being disclosed by the following numbered claims.

1-54. (canceled)

55. A display panel comprising at least one display part comprising a display part (sub-) pixel arrangement comprising a plurality of emissive regions each corresponding to a (sub-) pixel, and at least one signal-exchanging part comprising a signal-exchanging part (sub-) pixel arrangement comprising at least one transmissive region and a plurality of emissive regions each corresponding to a (sub-) pixel, wherein the signal-exchanging part (sub-) pixel arrangement accommodates the at least one transmissive region by varying from the display part (sub-) pixel arrangement in at least one feature selected from:
at least one of a size, shape, configuration, and orientation of at least one (sub-) pixel therein;
a pixel density; and
a pitch of the (sub-) pixels therein.

56. The display panel of claim 55, wherein a separation between a boundary of the at least one transmissive region and a boundary of a sub-pixel proximate thereto is one of at least about: 5 microns, 6 microns, 8 microns, 10 microns, 11 microns, and 12 microns.

57. The display panel of claim 55, wherein a size of each transmissive region is at least 10 microns.

58. The display panel of claim 55, wherein a total combined aperture ratio of all of the emissive regions and transmissive regions in the signal-exchanging part is one of no more than about: 60%, 55%, 50%, 45%, and 40%.

59. The display panel of claim 55, wherein the at least one transmissive region has a boundary defined by a plurality of transmissive boundary segments.

60. The display panel of claim 55, wherein the transmissive boundary segments comprise at least one curved segment.

61. The display panel of claim 59, wherein a majority of the transmissive boundary segments is substantially parallel to a part of a boundary of an emissive region corresponding to a (sub-) pixel proximate thereto.

62. The display panel of claim 55, wherein the at least one transmissive region is substantially devoid of a cathode material.

63. The display panel of claim 62, wherein the cathode material is substantially precluded from nucleating within the at least one transmissive region by depositing a patterning coating within the at least one transmissive region prior to deposition of the cathode material.

64. The display panel of claim 62, wherein the cathode material is removed from the at least one transmissive region by laser ablation thereof.

65. The display panel of claim 55, wherein the at least one feature is at least one of a size, shape, configuration, and the signal-exchanging part (sub-) pixel arrangement and the display part (sub-) pixel arrangement have in common, a pixel density of the at least one (sub-) pixels therein.

66. The display panel of claim 65, wherein the signal-exchanging part (sub-) pixel arrangement and the display part (sub-) pixel arrangement have in common, a pitch of the at least one (sub-) pixels therein.

67. The display panel of claim 65, wherein a size of at least one of the (sub-) pixels in the signal-exchanging part (sub-) pixel arrangement is less than a size of corresponding (sub-) pixels in the display part (sub-) pixel arrangement.

68. The display panel of claim 65, wherein a region defined by a plurality of non-overlapping vectors each having endpoints located within the emissive region associated with a pair of the sub-pixels of the pixel of the signal-exchanging part (sub-) pixel arrangement defines an outline associated with the pixel.

69. The display panel of claim 68, wherein each vector is a linear vector.

70. The display panel of claim 68, wherein each vector has an endpoint located at a centroid of the emissive region of the sub-pixel.

71. The display panel of claim 68, wherein the outline comprises four vectors defining a box and a unit cell comprising four adjacent boxes each having a common vertex defines a smallest repeating unit of the signal-exchanging part (sub-) pixel arrangement.

72. The display panel of claim 71, wherein at least one transmissive region is disposed in at least one outline in the unit cell.

73. The display panel of claim 68, wherein the at least one transmissive region lies entirely within a single at least one outline.

74. The display panel of claim 65, wherein an aperture ratio of the transmissive regions of the signal-exchanging part is one of no more than about: 50%, 45%, 40%, 35%, 33%, and 25%.

75. The display panel of claim 65, wherein an aperture ratio of the transmissive regions of the signal-exchanging part is one of at least about: 5%, 10%, and 15%.

76. The display panel of claim 65, wherein an aperture ratio of all emissive regions of the signal-exchanging part is one of no more than about: 20%, 15%, and 10%.

77. The display panel of claim 55, wherein the at least one feature is a pixel density, and the signal-exchanging part (sub-) pixel arrangement and the display part (sub-) pixel arrangement have in common, at least one of a size, shape, configuration, orientation, and pitch of at least one (sub-) pixel therein.

78. The display panel of claim 77, wherein the signal-exchanging part (sub-) pixel arrangement and the display part (sub-) pixel arrangement have in common, a pitch of the at least one (sub-) pixels therein.

79. The display panel of claim 77, wherein a pixel density of the signal-exchanging part (sub-) pixel arrangement is less than a pixel density of the display part (sub-) pixel arrangement.

80. The display panel of claim 77, wherein at least one sub-pixel of at least one pixel corresponding to a sub-pixel of a pixel in the display part (sub-) pixel arrangement is omitted in the signal-exchanging part (sub-) pixel arrangement.

81. The display panel of claim 80, wherein the omitted sub-pixels are chosen to maximize a size of at least one void formed thereby.

82. The display of claim 80, wherein a pixel density in the signal-exchanging part (sub-) pixel arrangement is one of: 50%, 62.5%, and 75% of a pixel density in the display part (sub-) pixel arrangement.

83. The display panel of claim 77, wherein at least one transmissive region is disposed in at least one void formed by omitting at least one sub-pixel of at least one pixel in the signal-exchanging part (sub-) pixel arrangement.

84. The display panel of claim 77, wherein an aperture ratio of the transmissive regions of the signal-exchanging part is one of between about: 15-40%, 20-40%, 15-35%, and 20-35%.

85. The display panel of claim 77, wherein an aperture ratio of the transmissive regions of the signal-exchanging part is one of at least about: 5%, 10%, and 15%.

86. The display panel of claim 77, wherein an aperture ratio of all emissive regions of the signal-exchanging part is between about: 12-25%.

87. The display panel of claim 55, wherein the at least one feature is a pitch and a pitch of the (sub-) pixels in the signal-exchanging part (sub-) pixel arrangement is less than a pitch of the (sub-) pixels in the display part (sub-) pixel arrangement.

88. The display panel of claim 55, wherein the at least one feature comprises a plurality of the features.

89. The display panel of claim 55, further comprising at least one transition region disposed between the display part and the signal-exchanging part, comprising a transition region (sub-) pixel arrangement comprising a plurality of emissive regions each corresponding to a (sub-) pixel, wherein the transition region (sub-) pixel arrangement varies from both the display part (sub-) pixel arrangement and the signal-exchanging (sub-) pixel arrangement in the at least one feature, such that the interposition of the at least one transition region therebetween reduces a visually perceived difference therebetween.

90. The display panel of claim 89, wherein the at least one transition region comprises at least one transmissive region.
